(19) United States
(12) Patent Application Publication
(10) Pub. No.: US 2015/0111154 A1
(43) Pub. Date: Apr. 23, 2015

(54) PATTERN FORMING METHOD, ACTINIC RAY-SENSITIVE OR RADIATION-SENSITIVE RESIN COMPOSITION, RESIST FILM, METHOD OF MANUFACTURING ELECTRONIC DEVICE, AND ELECTRONIC DEVICE

(71) Applicant: FUJIFILM Corporation, Tokyo (JP)

(72) Inventor: Hidenori TAKAHASHI, Haibara-gun (JP)

(73) Assignee: FUJIFILM CORPORATION, Tokyo (JP)

(21) Appl. No.: 14/582,636

(22) Filed: Dec. 24, 2014

Related U.S. Application Data
(63) Continuation of application No. PCT/JP2013/065110, filed on May 30, 2013.

(30) Foreign Application Priority Data
Jun. 28, 2012 (JP) 2012-146001

(51) Int. Cl. G03F 7/004; G03F 7/20

(52) U.S. Cl. CPC G03F 7/004; G03F 7/20
USPC 430/283.1; 430/285.1; 430/325

(57) ABSTRACT

There is provided a pattern forming method including: (a) a process of forming a film by resin (P) having a repeating unit (a) having a cyclic structure and a partial structure represented by the following Formula (I), (II-1) or (II-2), and a repeating unit (b) having a group which decomposes by the action of an acid to generates a polar group, and an actinic ray-sensitive or radiation-sensitive resin composition containing compound (B) which generates acid upon irradiation with an actinic ray or radiation; (b) a process of exposing the film; and (c) a process of forming a negative-type pattern by performing development using a developer including an organic solvent, an actinic ray-sensitive or radiation-sensitive resin composition used therefor, a resist film, a method of manufacturing an electronic device, and an electronic device.

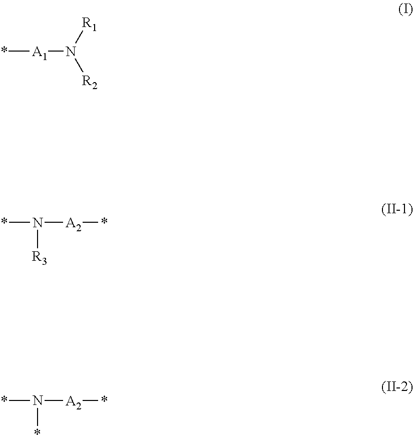

### CROSS REFERENCE TO RELATED APPLICATION

This is a continuation of International Application No. PCT/JP2013/065110 filed on May 30, 2013, and claims priority from Japanese Patent Application No. 2012-146001 filed on Jun. 28, 2012, the entire disclosures of which are incorporated herein by response.

### TECHNICAL FIELD

The present invention relates to a pattern forming method, an actinic ray-sensitive or radiation-sensitive resin composition and a resist film used therefor, a method of manufacturing an electronic device, and an electronic device. More specifically, the present invention relates to a pattern forming method suitable for a manufacturing process of a semiconductor such as an IC, a manufacture of a liquid crystal and a circuit board such as a thermal head, and furthermore, other lithography processes of photofabrication, an actinic ray-sensitive or radiation-sensitive resin composition and a resist film used for the pattern forming method, a method of manufacturing an electronic device, and an electronic device. In particular, the present invention relates to a pattern forming method suitable for exposure in an ArF exposure apparatus and an ArF liquid immersion projection exposure apparatus which uses far-ultraviolet rays having a wavelength of 300 nm or less as a light source, an actinic ray-sensitive or radiation-sensitive resin composition and a resist film used for the pattern forming method, a method of manufacturing an electronic device, and an electronic device.

### BACKGROUND ART

Since a resist for a KrF excimer laser (248 nm) was developed, a pattern forming method using chemical amplification has been used in order to complement desensitization caused by light absorption. For example, in a positive-type chemical amplification method, first, a photoacid-generating agent included in an exposed portion decomposes upon irradiation with light and generates an acid. Thereafter, in a process such as post exposure bake (PEB), and the like, an alkali-insoluble group included in the photosensitive composition is changed to an alkali-soluble group by the catalytic action of the generated acid. Subsequently, development is performed using, for example, an alkaline solution. Accordingly, the exposed portion is removed, so that a desired pattern is obtained.

In the above method, various alkaline developers have been suggested as an alkaline developer. For example, as the alkaline developer, a water-based alkaline developer with 2.38% by mass of TMAH (tetramethylammonium hydroxide aqueous solution) is universally used.

Further, in order to make semiconductor elements finer, a wavelength of an exposure light source has been shortened and a projection lens with a high numerical aperture (high NA) has been used, and thus an exposure machine using an ArF excimer laser having a wavelength of 193 nm as a light source has been currently developed. As a technique for further improving resolution, a method (that is, a liquid immersion method) of filling a liquid having a high refractive index (hereinafter, also referred to as a “liquid for liquid immersion”) between a projection lens and a sample has been proposed. In addition, EUV lithography that performs exposure with ultraviolet rays having a shorter wavelength (13.5 nm) has also been proposed.

However, it is very difficult to find an appropriate combination of a resist composition, a developer, a rinsing liquid and the like required to form a pattern having comprehensively excellent performance.

For example, as a method for forming the positive-type chemically amplified image, a technology which uses a resist composition containing a resin having a specific polar group-containing aliphatic polycyclic group is known (see Patent Document 1), and according to the method for forming a positive-type image described in the Examples of Patent Document 1, it is said that high sensitivity and low line edge roughness may be achieved.

Recently, a pattern forming method using a developer including an organic solvent has also been developed (see, for example, Patent Documents 2 to 5). For example, Patent Document 2 discloses a pattern forming method including a process of coating, on a substrate, a resist composition of which solubility increases with respect to an alkaline developer and solubility decreases with respect to an organic solvent developer upon irradiation with an actinic ray or radiation, an exposure process, and a development process using the organic solvent developer. According to this method, it is possible to stably form a fine pattern with high accuracy.

Furthermore, Patent Documents 4 and 5 and the like disclose a method for forming a pattern using a developer which includes an organic solvent, in which from the viewpoint of enhancing substrate adhesion, a resin containing a repeating unit having a polycyclic hydrocarbon structure (for example, an adamantly group and a norbornyl group) including a polar group such as a cyano group as a substituent is used.

### PRIOR ART DOCUMENTS

### Patent Documents

Patent Document 1: Japanese Patent Application Laid-Open No. 2012-88658

Patent Document 2: Japanese Patent Application Laid-Open No. 2008-292975

Patent Document 3: Japanese Patent Application Laid-Open No. 2010-197619

Patent Document 4: Japanese Patent Application Laid-Open No. 2010-152353

Patent Document 5: Japanese Patent Application Laid-Open No. 2009-25707

### SUMMARY OF INVENTION

### Problems to be Solved

However, in any of the pattern forming methods using a developer including an organic solvent as described above, it is required to further improve exposure latitude and uniformity of a local pattern dimension.

An object of the present invention is to provide a pattern forming method having excellent exposure latitude and uniformity of a local pattern dimension, an actinic ray-sensitive or radiation-sensitive resin composition used therefor, a resist film, a method of manufacturing an electronic device, and an electronic device.

### Means for Solving the Problems

The present invention has the following configuration, and the problems of the present invention are accordingly solved.

[1] A pattern forming method including:

(i) forming a film by an actinic ray-sensitive or radiation-sensitive resin composition containing a resin (P) having a repeating unit (a) having a cyclic structure and a partial structure represented by Formula (I), (II-1) or (II-2), and a repeating unit (b) having a group which decomposes by the action of an acid to generate a polar group and a compound (B) which generates acid upon irradiation with an actinic ray or radiation,

(ii) exposing the film, and

(iii) forming a negative pattern by performing development using a developer containing an organic solvent:

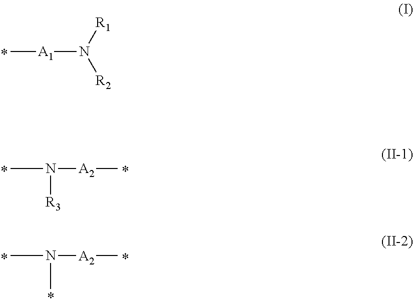

wherein, in the formulas, each of A₁ and A₂ independently represents —CO— or —SO₂—,

each of R₁ and R₂ independently represents a hydrogen atom or an alkyl group, and R₁ and R₂ optionally combine with each other to form a ring,

R₃ represents a hydrogen atom or an alkyl group, and

* represents a bonding hand, provided that two bonding hands of the partial structure of Formula (II-1) are directly or indirectly bonded to a ring of the cyclic structure, and two or more of the three bonding hands of the partial structure of Formula (II-2) are directly or indirectly bonded to the ring of the cyclic structure.

[2] The pattern forming method according to [1],

wherein the resin (P) is a resin having a repeating unit represented by Formula (III′) as the repeating unit (b):

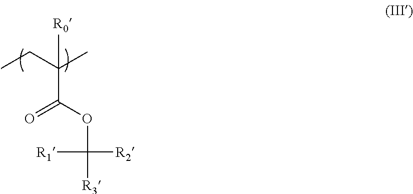

wherein in the formula, R₀′ represents a hydrogen atom or an alkyl group, each of R₁′, R₂′ and R₃′ independently represents a straight chained or branched alkyl group.

[3] The pattern forming method according to [1] or [2],

wherein the resin (P) contains 55 mol % or more of the repeating unit (b) based on all repeating units of the resin (P).

[4] The pattern forming method according to any one of [1] to [3],

wherein the actinic ray-sensitive or radiation-sensitive resin composition contains a compound represented by Formula (ZI-2), (ZI-3) or (ZI-4) as the compound (B):

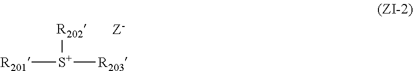

wherein in Formula (ZI-2),

each of R₂₀₁′ to R₂₀₃′ independently represents an organic group having no aromatic ring, and

Z⁻ represents a non-nucleophilic anion:

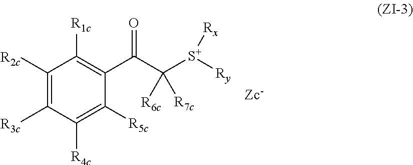

wherein in Formula (ZI-3),

each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group,

each of R_{6c} and R_{7c} independently represents a hydrogen atom, an alkyl group, a cycloalkyl group, a halogen atom, a cyano group or an aryl group,

each of Rₓ and R_{y} independently represents an alkyl group, a cycloalkyl group, a 2-oxoalkyl group, a 2-oxocycloalkyl group, an alkoxycarbonylalkyl group, an allyl group or a vinyl group,

any two or more of R_{1c} to R_{5c}, R_{5c} and R_{6c}, R_{6c} and R_{7c}, R_{5c} and Rₓ, and Rₓ and R_{y} optionally combine with each other to form a ring structure, respectively, and

Z⁻ represents a non-nucleophilic anion:

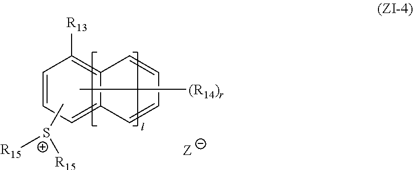

wherein in Formula (ZI-4),

R₁₃ represents a hydrogen atom, a fluorine atom, a hydroxyl group, an alkyl group, a cycloalkyl group, an alkoxy group, an alkoxycarbonyl group or a group having a cycloalkyl group,

each R₁₄ independently represents, when a plurality of R₁₄ is present, a hydroxyl group, an alkyl group, a cycloalkyl group, an alkoxy group, an alkoxycarbonyl group, an alkylcarbonyl group, an alkylsulfonyl group, a cycloalkylsulfonyl group or a group having a cycloalkyl group,

each R₁₅ independently represents an alkyl group, a cycloalkyl group or a naphthyl group, and two of R₁₅ optionally combine with each other to form a ring,

l represents an integer of 0 to 2,

r represents an integer of 0 to 8, and

Z⁻ represents a non-nucleophilic anion.

[5] The pattern forming method according to any one of [1] to [4],

wherein the repeating unit (a) is a repeating unit represented by Formula (V) or (VI):

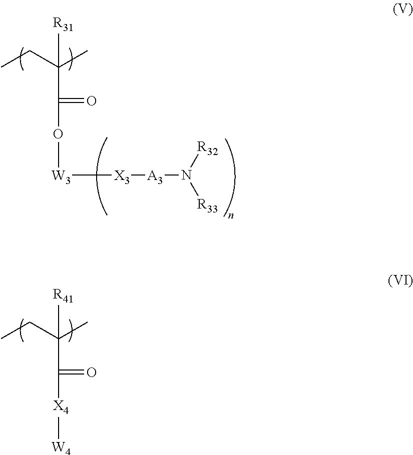

wherein in Formula (V), each of R₃₁, R₃₂ and R₃₃ independently represents a hydrogen atom or an alkyl group, and R₃₂ and R₃₃ optionally combine with each other to form a ring,

W₃ represents a (n+1)-valent alicyclic group which optionally includes an oxygen atom as a ring member,

X₃ represents a single bond, —O— or —NR₃₄—,

R₃₄ represents a hydrogen atom or an alkyl group,

A₃ represents —CO— or —SO₂—, and

n represents 1 or 2,

wherein in Formula (VI), R₄₁ represents a hydrogen atom or an alkyl group,

X₄ represents a single bond or —O—, and

W₄ represents an alicyclic group which optionally includes an oxygen atom as a ring member, and which is directly or indirectly bonded to two bonding hands of a partial structure represented by Formula (VII-1) or two or more of the three bonding hands of a partial structure represented by Formula (VII-2):

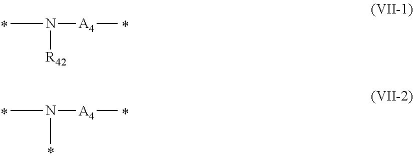

wherein A₄ represents —CO— or —SO₂—,

R₄₂ represents a hydrogen atom or an alkyl group, and

* represents a bonding hand.

[6] The pattern forming method according to any one of [1] to [5],

wherein the resin (P) is a resin having at least any one of the following repeating units as the repeating unit (a):

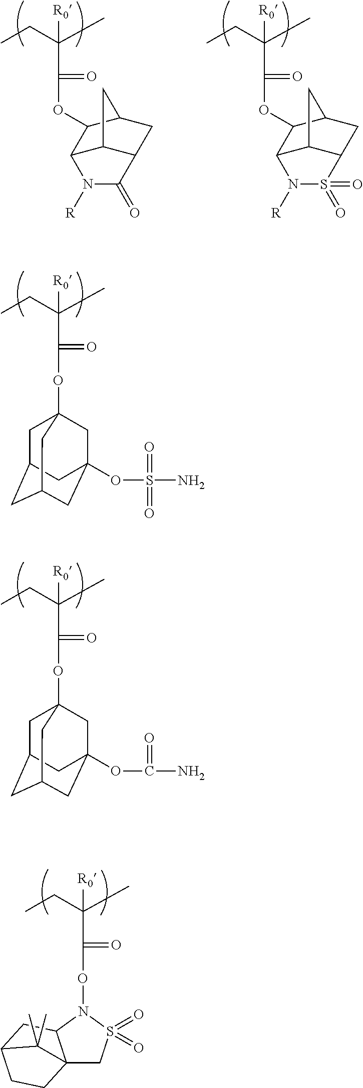

wherein R₀′ represents a hydrogen atom or an alkyl group, and

R represents a hydrogen atom or an alkyl group.

[7] The pattern forming method according to any one of [1] to [6],

wherein the actinic ray-sensitive or radiation-sensitive resin composition further contains a basic compound or an ammonium salt compound (N) whose basicity decreases upon irradiation with an actinic ray or radiation.

[8] The pattern forming method according to any one of [1] to [7],

wherein the actinic ray-sensitive or radiation-sensitive resin composition further contains a hydrophobic resin.

[⁹] The pattern forming method according to any one of [1] to [8],

wherein the developer is a developer containing at least one organic solvent selected from the group consisting of a ketone-based solvent, an ester-based solvent, an alcohol-based solvent, an amide-based solvent, and an ether-based solvent.

[10] The pattern forming method according to any one of [1] to [9], further including:

(d) performing rinsing using a rinsing liquid containing an organic solvent.

[11] An actinic ray-sensitive or radiation-sensitive resin composition provided by the pattern forming method according to any one of [2] to [10].

[12] A resist film formed from the actinic ray-sensitive or radiation-sensitive resin composition of [11].

[13] A method of manufacturing an electronic device, including the pattern forming method according to any one of [1] to [10].

[14] An electronic device manufactured from the method of manufacturing an electronic device according to [13].

It is also preferred that the present invention has the following constitution.

[15] The pattern forming method described in any one of the above [1] to [10], in which repeating unit (a) is a repeating unit having a cyclic structure and the partial structure represented by Formula (II-1) or (II-2).

[16] The pattern forming method described in any one of the above [1] to [10] and [15], in which compound (B) is different from resin (P).

[17] The pattern forming method described in any one of the above [1] to [10], [15], and [16], in which resin (P) substantially does not have an aromatic ring.

[18] The pattern forming method described in any one of the above [1] to [10] and [15] to [17], in which the exposure in process (b) is an ArF exposure.

[19] The pattern forming method described in any one of the above [1] to [10] and [15] to [18], in which the exposure in process (b) is a liquid immersion exposure.

### Effect of Invention

According to the present invention, it is possible is to provide a pattern forming method having excellent exposure latitude and uniformity of a local pattern dimension, an actinic ray-sensitive or radiation-sensitive resin composition used therefor, a resist film, a method of manufacturing an electronic device, and an electronic device.

### DESCRIPTION OF EMBODIMENTS

Hereinafter, embodiments of the present invention will be described in detail.

In the notation of a group (atomic group) in the present specification, the representation which does not describe the substitution and unsubstitution includes a representation having a substituent along with a representation having no substituent. For example, “an alkyl group” includes not only an alkyl group having no substituent (an unsubstituted alkyl group) but also an alkyl group having a substituent (a substituted alkyl group).

The term “actinic ray” or “radiation” in the present specification refers to, for example, a bright line spectrum of a mercury lamp and the like, far-ultraviolet rays represented by an excimer laser, extreme ultraviolet rays (EUV light), X-rays, an electron beam (EB) and the like. Further, the term “light” in the present invention refers to an actinic ray or radiation.

In addition, unless otherwise specifically indicated, the term “exposure” in the present specification includes not only the exposure performed using a mercury lamp, far-ultraviolet rays represented by an excimer laser, extreme-ultraviolet rays, X-rays, EUV light and the like, but also drawing performed by a particle beam such as an electron beam, an ion beam and the like.

The pattern forming method of the present invention is a pattern forming method including (a) a process of forming a film by resin (P), which has a repeating unit (a) having a cyclic structure and a partial structure represented by the following Formula (I), (II-1) or (II-2), and repeating unit (b) having a group that decomposes by the action of an acid to generate a polar group, and an actinic ray-sensitive or radiation-sensitive resin composition, which contains compound (B) that generates acid upon irradiation with an actinic ray or radiation, (b) a process of exposing the film, and (c) a process of forming a negative-type pattern by performing development using a developer including an organic solvent.

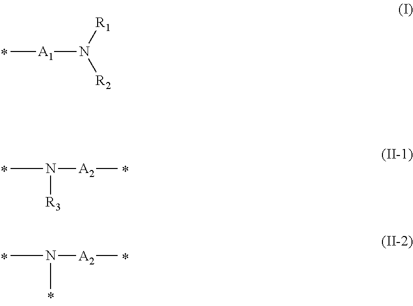

In the formulas, each of A₁ and A₂ independently represents —CO— or —SO₂—.

Each of R₁ to R₂ independently represents a hydrogen atom or an alkyl group. R₁ and

R₂ may combine with each other to form a ring.

R₃ represents a hydrogen atom or an alkyl group.

* represents a bonding hand. Provided that two bonding hands of the partial structure in Formula (II-1) are directly or indirectly bonded to a ring of the cyclic structure, and two or more of the three bonding hands of the partial structure in Formula (II-2) are directly or indirectly bonded to the ring of the cyclic structure.

The reason why the pattern forming method of the present invention, which uses resin (P) having repeating unit (a) having a cyclic structure and a partial structure represented by Formula (I), (II-1) or (II-2), and a repeating unit (b) having a group that decomposes by the action of an acid to generate a polar group, is excellent in exposure latitude and uniformity of a local pattern dimension in forming a negative-type pattern by a developer including an organic solvent is not clear, but is assumed as follows.

In the case where development is performed using a developer including an organic solvent, when dissolution contrast in the resist film is low, the pattern boundary portion is partially dissolved, thereby aggravating exposure latitude.

In contrast, according to the present invention, it is considered that the glass transition temperature (Tg) of the resin is increased by the presence of the cyclic structure in repeating unit (a), and as a result, acid generated from compound (B) upon irradiation with an actinic ray or radiation is suppressed from excessively diffusing into an unexposed portion, and thus exposure latitude and uniformity of a local pattern dimension are enhanced.

Furthermore, the partial structure represented by Formula (I), (II-1) or (II-2) in repeating unit (a) has high polarity. Accordingly, it is assumed that since solubility may be appropriately decreased with respect to a developer including an organic solvent of the resist film, the aforementioned pattern boundary portion may be suppressed from being partially dissolved, and as a result, exposure latitude is excellent.

In the pattern forming method of the present invention, it is preferred that the developer is a developer containing at least one organic solvent selected from the group consisting of a ketone-based solvent, an ester-based solvent, an alcohol-based solvent, an amide-based solvent, and an ether-based solvent.

The pattern forming method of the present invention may further include (d) a process of performing washing using a rinsing liquid including an organic solvent.

It is preferred that the rinsing liquid is a rinsing liquid containing at least one organic solvent selected from the group consisting of a hydrocarbon-based solvent, a ketone-based solvent, an ester-based solvent, an alcohol-based solvent, an amide-based solvent, and an ether-based solvent.

It is preferred that the pattern forming method of the present invention has (e) a heating process after (b) the exposure process.

Further, it is preferred that resin (P) is a resin capable of increasing the polarity by the action of an acid to decrease the solubility in the developer including an organic solvent, and in this case, resin (P) is also a resin capable of increasing the action of an acid to increase the solubility in the alkali developer.

Accordingly, the pattern forming method of the present invention may further have (f) a process of developing the film using the alkali developer.

The pattern forming method of the present invention may have plural times of (b) the exposure process.

The pattern forming method of the present invention may have plural times of (e) the heating process.

The resist film of the present invention is a film formed by the actinic ray-sensitive or radiation-sensitive resin composition, and for example, a film formed by applying the actinic ray-sensitive or radiation-sensitive resin composition on a substrate.

Hereinafter, an actinic ray-sensitive or radiation-sensitive resin composition that may be used in the present invention will be described.

Further, the present invention also relates to the actinic ray-sensitive or radiation-sensitive resin composition that will be described below.

The actinic ray-sensitive or radiation-sensitive resin composition according to the present invention is used in a negative-type development (development in which when a resist film is exposed, the solubility thereof in the developer is decreased, and thus the exposed portion remains as a pattern and the unexposed portion is removed). That is, the actinic ray-sensitive or radiation-sensitive resin composition according to the present invention may be used as an actinic ray-sensitive or radiation-sensitive resin composition for organic solvent development, which is used for development using a developer including an organic solvent. Here, the term, for organic solvent development refers to a use that is used in a process of developing a film using a developer including at least an organic solvent.

It is preferred that the actinic ray-sensitive or radiation-sensitive resin composition of the present invention is typically a resist composition and a negative-type resist composition (that is, a resist composition for organic solvent development), because a particularly good effect may be obtained. In addition, the composition according to the present invention is typically a chemical amplification resist composition.

[1] Resin (P) having a repeating unit (a) having a cyclic structure and the partial structure represented by Formula (I), (II-1) or (II-2), and a repeating unit (b) having a group which decomposes by the action of an acid to generate a polar group

Resin (P) is a resin having a repeating unit (a) having a cyclic structure and the partial structure represented by Formula (I), (II-1) or (II-2).

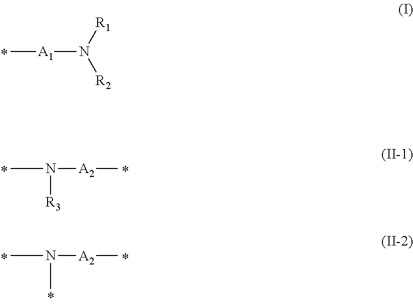

In the formulas, each of A₁ and A₂ independently represents —CO— or —SO₂—.

Each of R₁ to R₂ independently represents a hydrogen atom or an alkyl group. R₁ and R₂ may combine with each other to form a ring.

R₃ represents a hydrogen atom or an alkyl group.

* represents a bonding hand. Provided that two bonding hands of the partial structure in Formula (II-1) are directly or indirectly bonded to a ring of the cyclic structure, and two or more of the three bonding hands of the partial structure in Formula (II-2) are directly or indirectly bonded to the ring of the cyclic structure.

The cyclic structure in repeating unit (a) is not particularly limited, but a monocyclic or polycyclic aliphatic hydrocarbon structure is preferred, and a polycyclic aliphatic hydrocarbon structure is more preferred.

The cyclic structure may further have a substituent, and examples of the substituent include a hydroxyl group, a halogen atom (a fluorine atom, a chlorine atom, a bromine atom, an iodine atom and the like), a nitro group, an alkyl group (a methyl group, an ethyl group, a propyl group, an n-butyl group, a sec-butyl group, a hexyl group, a 2-ethylhexyl group, an octyl group and the like), a cyano group, an alkoxy group (a methoxy group, an ethoxy group, a hydroxyethoxy group, a propoxy group, a hydroxypropoxy group, a butoxy group and the like), an alkoxycarbonyl group (a methoxycarbonyl group, an ethoxycarbonyl group and the like), an acyl group (a formyl group, an acetyl group, a benzoyl group and the like), an acyloxy group (an acetoxy group, a butyryloxy group and the like), a cycloalkyl group (a cyclopentyl group, a cyclohexyl group) and the like, an aryl group (a phenyl group, a naphthyl group and the like) and a carboxy group.

The carbon number in the ring member of the monocyclic aliphatic hydrocarbon structure is preferably 3 to 10.

Specific examples of the monocyclic aliphatic hydrocarbon structure which may have a substituent include a cyclopropyl group, a cyclobutyl group, a cyclopentyl group, a cyclohexyl group, a cycloheptyl group, a cyclooctyl group, a cyclododecanyl group, a cyclopentenyl group, a cyclohexenyl group, a cyclooctadienyl group and the like, and particularly, a cyclopropyl group, a cyclopentyl group, a cyclohexyl group and a cyclooctyl group are preferred.

The carbon number in the ring member of the polycyclic aliphatic hydrocarbon structure is preferably 6 to 20.

Specific examples of the polycyclic aliphatic hydrocarbon structure which may have a substituent may have a substituent as described above, and include, for example, a bicyclo[4.3.0]nonanyl group, a naphthalenyl group, a decahydronaphthalenyl group, a 1,2,3,4-tetrahydronaphthalenyl group, a tricyclo[5.2.1.0(2,6)]decanyl group, a bornyl group, an isobornyl group, a norbornyl group, an adamantyl group, a noradamantyl group, a 1,7,7-trimethyltricyclo[2.2.1.0^{2,6}]heptanyl group and a 3,7,7-trimethylbicyclo[4.1.0]heptanyl group and the like, and particularly, a norbornyl group, an adamantly group and a noradamantyl group are preferred.

Examples of the monocyclic or polycyclic aliphatic hydrocarbon structure suitably include the following cyclic structure.

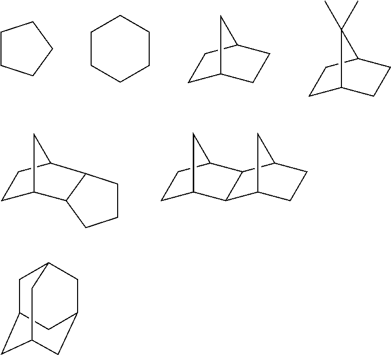

The alkyl group as R₁ and R₂ of Formula (I) may be straight chained or branched, and has preferably 1 to 12 carbon atom, more preferably 1 to 8, and most preferably 1 to 4.

The alkyl group may further have a substituent, and examples of the substituent include a hydroxyl group, a halogen atom (a fluorine atom, a chlorine atom, a bromine atom, an iodine atom and the like), a nitro group, a cyano group, an alkoxy group (a methoxy group, an ethoxy group, a hydroxyethyoxy group, a propoxy group, a hydroxypropoxy group, a butoxy group and the like), an alkoxycarbonyl group (a methoxycarbonyl group, an ethoxycarbonyl group and the like), an acyl group (a formyl group, an acetyl group, a benzoyl group and the like), an acyloxy group (an acetoxy group, a butyryloxy group and the like) and the like, a cycloalkyl group (a cyclopentyl group, a cyclohexyl group) and the like, an aryl group (a phenyl group, a naphthyl group and the like) and a carboxy group.

Each of R₁ and R₂ is independently preferably a hydrogen atom or an alkyl group having 1 to 4 carbon atoms, more preferably a hydrogen atom or an alkyl group having 1 or 2 carbon atoms, and most preferably a hydrogen atom.

The ring which may be formed by combining R₁ and R₂ with each other is preferably a 4- to 10-membered aliphatic ring, more preferably a 5- to 8-membered aliphatic ring, and even more preferably 5- or 6-membered aliphatic ring.

Meanwhile, when R₁ and R₂ are combined with each other to form a ring, the ring is a ring different from the cyclic structure which repeating unit (a) has.

Preferred examples of the partial structure represented by Formula (I) will be shown below.

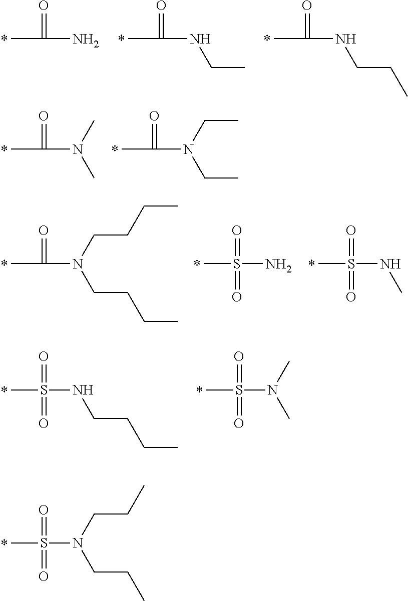

The alkyl group as R₃ of Formula (II-1) may be straight chained or branched, and has preferably 1 to 12 carbon atom, more preferably 2 to 10, and most preferably 4 to 8. The alkyl group may further have a substituent, and examples of the substituent similarly include the group exemplified in the substituent which the alkyl group as R₁ and R₂ of Formula (I) may further have

R₃ is preferably an alkyl group having 2 to 10 carbon atoms, and more preferably an alkyl group having 4 to 8 carbon atoms.

As described above, two bonding hands of the partial structure in Formula (II-1) are directly or indirectly bonded to a ring of the cyclic structure which repeating unit (a) has, and two or more of the three bonding hands of the partial structure in Formula (II-2) are directly or indirectly bonded to the ring of the cyclic structure which repeating unit (a) has.

The phrase that the bonding hands are directly or indirectly bonded to the ring of the cyclic structure specifically means that each of a plurality of bonding hands is independently bonded to the ring of the cyclic structure through a single bond or a linking group, and examples of the linking group include —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), or a linking group formed by combining a plurality of these groups and the like, and a linking group having a total carbon number of 12 or less is preferred.

It is preferred that each of the two bonding hands of the partial structure of Formula (II-1) is bonded to the ring of the cyclic structure, which repeating unit (a) has, through a single bond or an alkylene group. In addition, it is preferred that two or more of the three bonding hands of the partial structure in Formula (II-2) are bonded to the ring of the cyclic structure, which repeating unit (a) has, through a single bond or an alkylene group.

Preferred examples of the partial structure represented by Formula (I-1) and the partial structure represented by Formula (I-2) will be shown below. In the following examples, * represents a bonding hand.

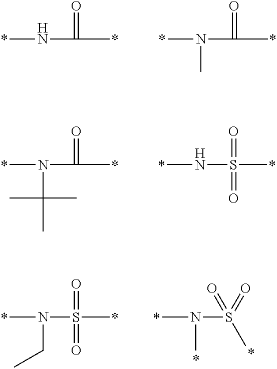

Repeating unit (a) is preferably a repeating unit having a cyclic structure and the partial structure represented by Formula (II-1) or (II-2).

Repeating unit (a) is preferably a repeating unit represented by the following Formula (V) or (VI).

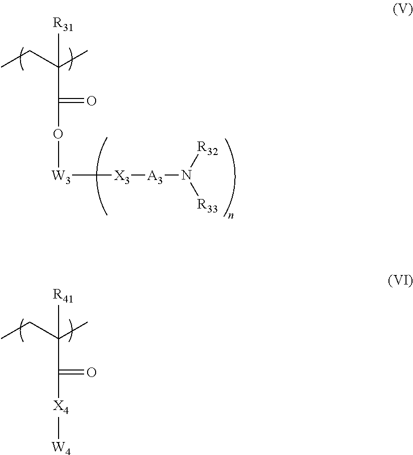

In Formula (V), each of R₃₁, R₃₂ and R₃₃ independently represents a hydrogen atom or an alkyl group. R₃₂ and R₃₃ may combine with each other to form a ring.

W₃ represents a (n+1)-valent alicyclic group which may include an oxygen atom as a ring member.

X₃ represents a single bond, —O— or —NR₃₄—.

R₃₄ represents a hydrogen atom or an alkyl group.

A₃ represents —CO— or —SO₂—.

n represents 1 or 2.

In Formula (VI), R₄₁ represents a hydrogen atom or an alkyl group.

X₄ represents a single bond or —O—.

W₄ represents an alicyclic group which may include an oxygen atom as a ring member, and is directly or indirectly bonded to two or more bonding hands of a partial structure represented by the following Formula (VII-1), or two or more of the three bonding hands of a partial structure represented by the following Formula (VII-2).

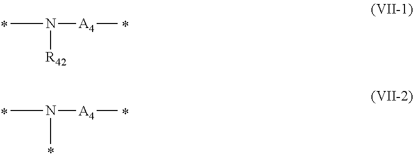

A₄ represents —CO— or —SO₂—.

R₄₂ represents a hydrogen atom or an alkyl group.

* represents a bonding hand.

The alkyl group as R₃₁ and R₄₁ is not particularly limited, but examples thereof include a methyl group, an ethyl group, a butyl group and the like.

R₃₁ and R₄₁ are preferably a hydrogen atom or a methyl group.

Specific examples and preferred examples of the alkyl group as R₃₂ and R₃₃ are the same as those of the alkyl group as R₁ and R₂.

Preferred examples of R₃₂ and R₃₃ are the same as the aforementioned preferred examples of R₁ and R₂.

Preferred examples of the ring which may be formed by combining R₃₂ and R₃₃ with each other are the same as the aforementioned preferred examples of the ring which may be formed by combining R₁ and R₂ with each other.

“A (n+1)-valent alicyclic group which may include an oxygen atom as a ring member” as W₃ may be monocyclic or polycyclic, and is preferably a cycloalkylene group having 3 to 20 carbon atoms when n is 1. Examples of the monocyclic cycloalkylene group include a cyclobutylene group, a cyclopentylene group, a cyclohexylene group and the like. Examples of the polycyclic cycloalkylene group include a norbornylene group, an isobornylene group, a tricyclodecanylene group, a tetracyclodecanylene group, a tetracyclododecanylene group, an adamantylene group, a group in which a carbon atom as a ring member which forms a ring in these groups is substituted with an oxygen atom, and the like.

When n is 1, W₃ is preferably a cyclohexylene group, a norbornylene group, an isobornylene group, a tricyclodecanylene group or an adamantylene group, more preferably a cyclohexylene group, a tricyclodecanylene group or an adamantylene group, and most preferably an adamantylene group.

When n is 2, examples of W₃ suitably include a group in which arbitrary one arbitrary hydrogen atom is removed in the above specific examples of the cycloalkylene group.

The alkyl group as R₃₄ is not particularly limited, but examples thereof include a methyl group, an ethyl group, a butyl group and the like.

The alicyclic group as W₄ may be monocyclic or polycyclic, and is preferably a cycloalkyl group having 3 to 20 carbon atoms. Examples of the monocyclic cycloalkyl group include a cyclobutyl group, a cyclopentyl group, a cyclohexyl group and the like. Examples of the polycyclic cycloalkyl group include a norbornyl group, an isobornyl group, a tricyclodecanyl group, a tetracyclodecanyl group, a tetracyclododecanyl group, an adamantyl group, a group in which a carbon atom as a ring member which forms a ring in these groups is substituted with an oxygen atom, and the like.

As described above, the alicyclic group as W₄ is directly or indirectly bonded to two bonding hands of the partial structure represented by Formula (VII-1), or two or more of the three bonding hands of the partial structure represented by Formula (VII-2).

More specifically, the alicyclic group as W₄ is bonded to two bonding hands of the partial structure represented by Formula (VII-1) or two or more of the three bonding hands of the partial structure represented by Formula (VII-2) through a single bond or a linking group, and specific examples and preferred examples of the linking group likewise include those described as the linking group which may be intervened when a plurality of bonding hands in the partial structure represented by Formula (II-1) or (II-2) is bonded to the ring of the cyclic structure which repeating unit (a) has. Furthermore, the “single bond or the linking group” is preferably a single bond or an alkylene group.

Preferred examples of W₄ will be shown below. In the following examples, * represents a bonding hand which is bonded to X₄.

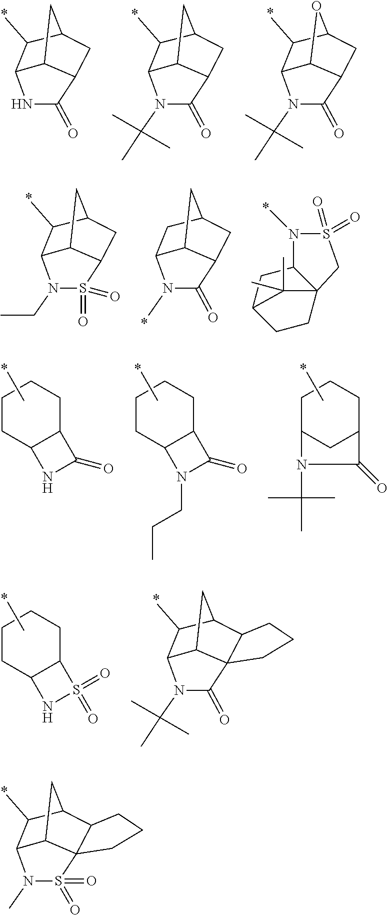

Specific examples of the repeating unit represented by Formula (V) will be shown below, but are not limited thereto. R₀″ represents a hydrogen atom or a methyl group.

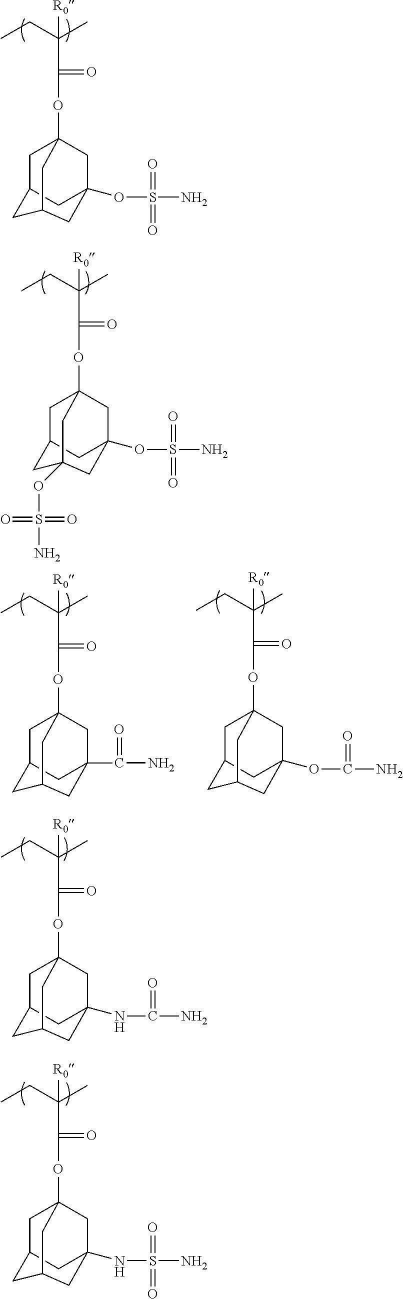

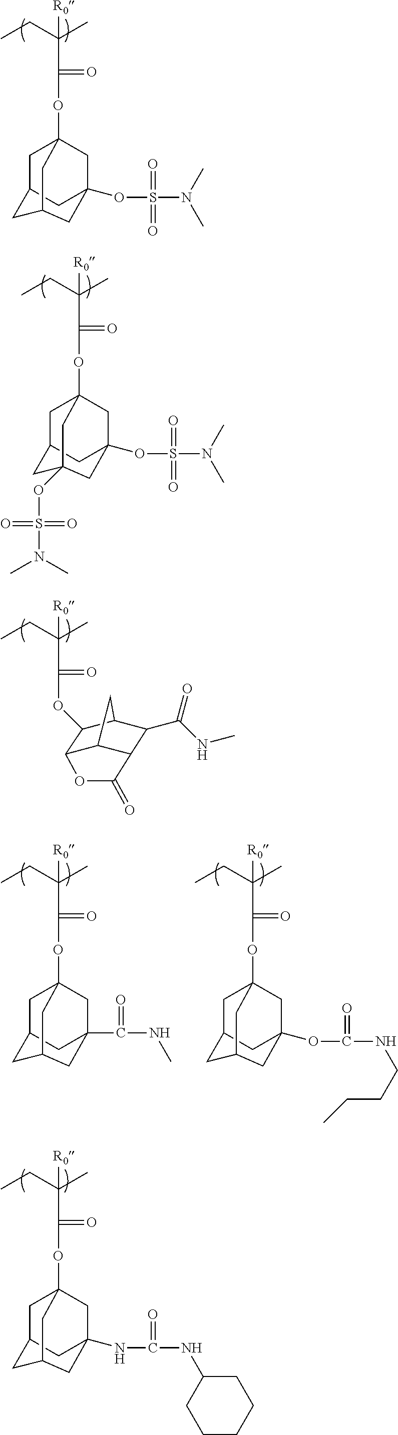

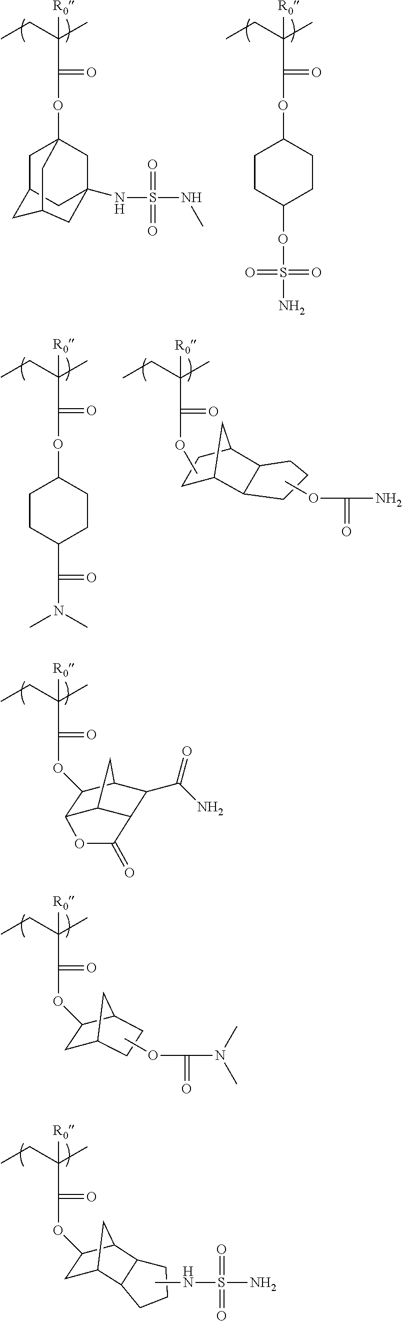

Specific examples of the repeating unit represented by Formula (VI) will be shown below, but are not limited thereto. R₀″ represents a hydrogen atom or a methyl group.

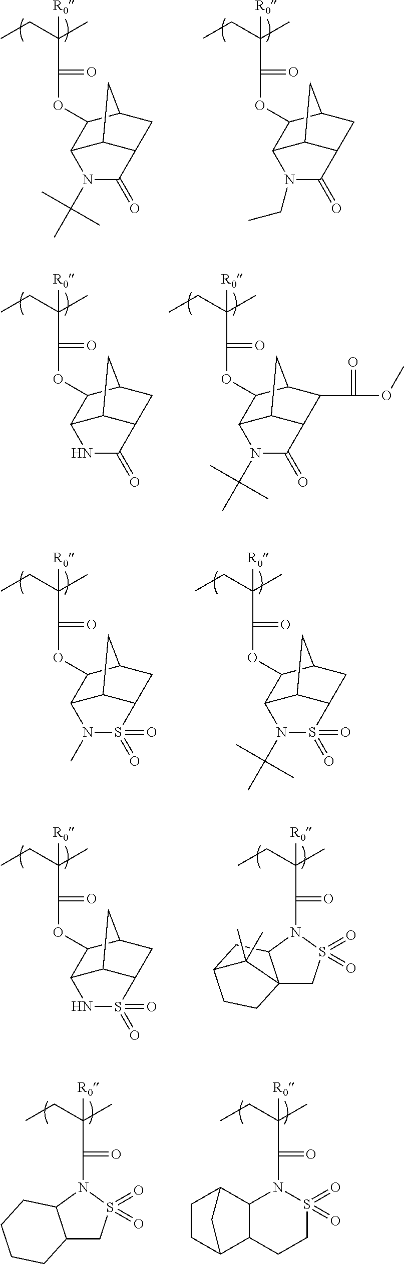

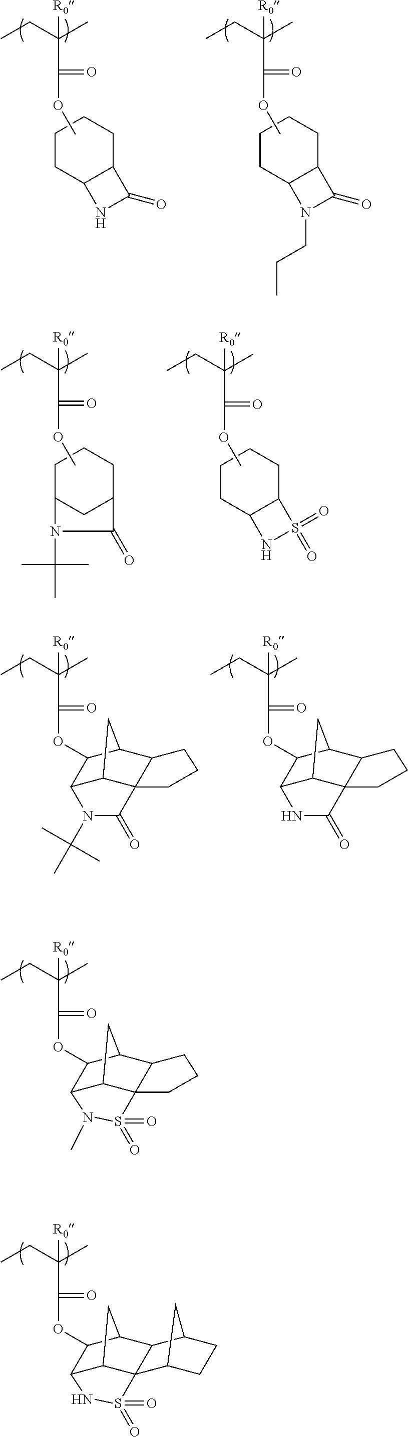

Resin (P) is preferably a resin having at least any one of the repeating units as repeating unit (a).

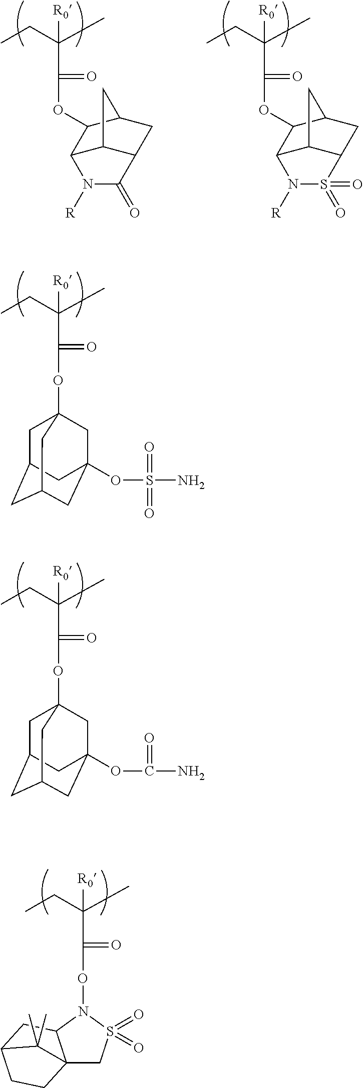

R₀′ represents a hydrogen atom or an alkyl group. R represents a hydrogen atom or an alkyl group.

Specific examples and preferred examples of the alkyl group as R₀′ are the same as the specific examples and preferred examples of the alkyl group as R₃₁ in Formula (V) and R₄₁ in Formula (VI).

Specific examples and preferred examples of the alkyl group as R are the same as the specific examples and preferred examples of the alkyl group as R₃ in Formula (II-1).

Repeating unit (a) may be used either alone or in combination of two or more thereof.

The content of repeating unit (a) (in the case of containing a plurality of kinds of repeating units, the sum thereof) is preferably 1 to 60 mol %, more preferably 5 to 55 mol %, and even more preferably 10 to 50 mol %, based on the total repeating units in resin (P).

Resin (P) has a repeating unit (b) having a group (hereinafter, also referred to as “an acid-decomposable group”) which decomposes by the action of an acid to generate a polar group.

The polar group is not particularly limited as long as the polar group is a group capable of being sparingly solubilized or insolubilized in a developer including an organic solvent, but examples thereof include a carboxyl group, an acidic group (a group capable of dissociating in 2.38% by mass of a tetramethylammonium hydroxide aqueous solution which has been used as a developer of a resist in the related art) such as a sulfonic acid group, or an alcoholic hydroxyl group and the like.

Meanwhile, the alcoholic hydroxyl group is a hydroxyl group bonded to a hydrocarbon group and refers to a hydroxyl group except for a hydroxyl group (a phenolic hydroxyl group) directly bonded on an aromatic ring, and an aliphatic alcohol (for example, a fuorinated alcohol group (a hexafluoroisopropanol group and the like)), in which an α-position thereof as a hydroxyl group is substituted with an electron-withdrawing group such as a fluorine atom, is excluded. The alcoholic hydroxyl group is preferably a hydroxyl group having a pKa of 12 to 20.

The group preferred as the acid-decomposable group is a group in which a hydrogen atom of these groups is substituted with a group capable of leaving by the action of an acid.

Examples of the group capable of leaving by the action of an acid include —C(R₃₆)(R₃₇)(R₃₈), —C(R₃₆)(R₃₇)(OR₃₉), —C(R₀₁)(R₀₂)(OR₃₉) and the like.

In the Formula, each of R₃₆ to R₃₉ independently represents an alkyl group, a cycloalkyl group, an aryl group, an aralkyl group, or an alkenyl group. R₃₆ and R₃₇ may combine with each other to form a ring.

Each of R₀₁ and R₀₂ independently represents a hydrogen atom, an alkyl group, a cycloalkyl group, an aryl group, an aralkyl group, or an alkenyl group.

The alkyl group of R₃₆ to R₃₉, R₀₁ and R₀₂ is preferably an alkyl group having from 1 to 8 carbon atoms, and examples thereof include a methyl group, an ethyl group, a propyl group, an n-butyl group, a sec-butyl group, a hexyl group, an octyl group and the like.

The cycloalkyl group of R₃₆ to R₃₉, R₀₁ and R₀₂ may be monocyclic or polycyclic. The monocyclic cycloalkyl group is preferably a cycloalkyl group having 3 to 8 carbon atoms, and examples thereof include a cyclopropyl group, a cyclobutyl group, a cyclopentyl group, a cyclohexyl group, a cyclooctyl group, and the like. The polycyclic cycloalkyl group is preferably a cycloalkyl group having 6 to 20 carbon atoms, and examples thereof include an adamantyl group, a norbornyl group, an isobornyl group, a camphanyl group, a dicyclopentyl group, an α-pinel group, a tricyclodecanyl group, a tetracyclododecyl group, an androstanyl group and the like. Meanwhile, at least one carbon atom in the cycloalkyl group may be substituted with a heteroatom such as an oxygen atom.

The aryl group of R₃₆ to R₃₉, R₀₁ and R₀₂ is preferably an aryl group having 6 to 10 carbon atoms, and examples thereof include a phenyl group, a naphthyl group, an anthryl group and the like.

The aralkyl group of R₃₆ to R₃₉, R₀₁ and R₀₂ is preferably an aralkyl group having 7 to 12 carbon atoms, and examples thereof include a benzyl group, a phenethyl group, a naphthylmethyl group and the like.

The alkenyl group of R₃₆ to R₃₉, R₀₁ and R₀₂ is preferably an alkenyl group having 2 to 8 carbon atoms, and examples thereof include a vinyl group, an allyl group, a butenyl group, a cyclohexenyl group and the like.

The ring formed by combining R₃₆ and R₃₇ with each other is preferably a cycloalkyl group (monocyclic or polycyclic). The cycloalkyl group is preferably a monocyclic cycloalkyl group such as a cyclopentyl group and a cyclohexyl group, and a polycyclic cycloalkyl group such as a norbornyl group, a tetracyclodecanyl group, a tetracyclododecanyl group and an adamantyl group. A monocyclic cycloalkyl group having 5 to 6 carbon atoms is more preferred, and a monocyclic cycloalkyl group having 5 carbon atoms is particularly preferred.

It is preferred that resin (P) has a repeating unit represented by the following Formula (III) as a repeating unit having an acid-decomposable group.

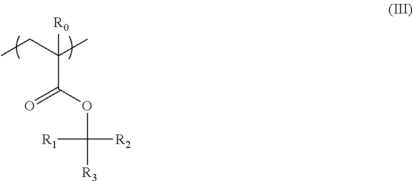

In Formula, R₀ represents a hydrogen atom, an alkyl group, a cyano group or a halogen atom.

Each of R₁ to R₃ independently represents an alkyl group (straight chained or branched) or a cycloalkyl group (monocyclic or polycyclic).

Two of R₁ to R₃ may combine with each other to form a ring (monocyclic or polycyclic).

The alkyl group of R₀ may have a substituent, and examples of the substituent include a hydroxyl group and a halogen atom (preferably a fluorine atom).

The alkyl group of R₀ is preferably an alkyl group having 1 to 4 carbon atoms, and examples thereof include a methyl group, an ethyl group, a propyl group, a hydroxymethyl group, or a trifluoromethyl group and the like, but a methyl group is preferred.

R₀ is preferably a hydrogen atom or a methyl group.

The alkyl group of R₁ to R₃ is preferably an alkyl group having 1 to 4 carbon atoms, such as a methyl group, an ethyl group, an n-propyl group, an isopropyl group, an n-butyl group, an isobutyl group, and a t-butyl group.

The cycloalkyl group of R₁ to R₃ is preferably a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group.

The ring formed by combining two of R₁ to R₃ with each other is preferably a monocyclic hydrocarbon ring such as a cyclopentane ring and a cyclohexane ring, and a polycyclic hydrocarbon ring such as a norbornane ring, a tetracyclodecane ring, a tetracyclododecane ring and an adamantane ring. A monocyclic hydrocarbon ring having 5 or 6 carbon atoms is particularly preferred.

Each of R₁ to R₃ is independently preferably a straight chained or branched alkyl group, and more preferably a straight chained or branched alkyl group having 1 to 4 carbon atoms.

Each group may further have a substituent, and examples of the substituent include an alkyl group (having 1 to 4 carbon atoms), a cycloalkyl group (having 3 to 8 carbon atoms), a halogen atom (for example, a fluorine atom), an alkoxy group (having 1 to 4 carbon atoms), a carboxylic group, an alkoxycarbonyl group (having 2 to 6 carbon atoms) and the like, and a group having 8 or less carbon atoms is preferred. Among them, from the viewpoint of further enhancing the dissolution contrast in a developer containing an organic solvent before and after the acid decomposition, the substituent is more preferably a substituent that does not have a heteroatom such as an oxygen atom, a nitrogen atom and a sulfur atom (for example, it is more preferred that the substituent is not an alkyl group substituted with a hydroxyl group, and the like), even more preferably a group consisting of only a hydrogen atom and a carbon atom, and particularly preferably a straight chained or branched alkyl group and a cycloalkyl group.

Resin (P) is preferably a resin having a repeating unit represented by the following Formula (III′) as the repeating unit represented by Formula (III).

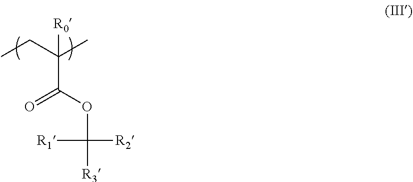

In the formula, R₀′ represents a hydrogen atom or an alkyl group. Each of R₁′, R₂′ and R₃′ independently represents a straight chained or branched alkyl group.

Meanwhile, there is no case where two or more of R₁′, R₂′ and R₃′ combine with each other to form a ring.

Specific examples and preferred examples of the alkyl group as R₀′ are the same as the specific examples and preferred examples of the alkyl group as R₀ in Formula (III).

R₀ is preferably a hydrogen atom or a methyl group.

Specific examples and preferred examples of the straight chained or branched alkyl group as R₁′, R₂′ and R₃′ are the same as the specific examples and preferred examples of the straight chained or branched alkyl group as R₁, R₂ and R₃ in Formula (III).

Resin (P) may include two or more types of the repeating unit represented by Formula (III), and thus it is possible to finely adjust reactivity and/or developability, thereby facilitating optimization of all the performances.

Preferred specific examples of a repeating unit having the acid-decomposable group will be shown below, but the present invention is not limited thereto.

In the specific examples, Rₓ and Xₐ₁ represent a hydrogen atom, CH₃, CF₃ or CH₂OH. Each of Rₓₐ and R_{xb} represents an alkyl group having 1 to 4 carbon atoms. Z represents a substituent, and when a plurality of Z's is present, each Z may be the same as or different from every other Z. p represents 0 or a positive integer. Specific examples and preferred examples of Z are the same as the specific examples and preferred examples of the substituent that R₁ to R₃ may further have.

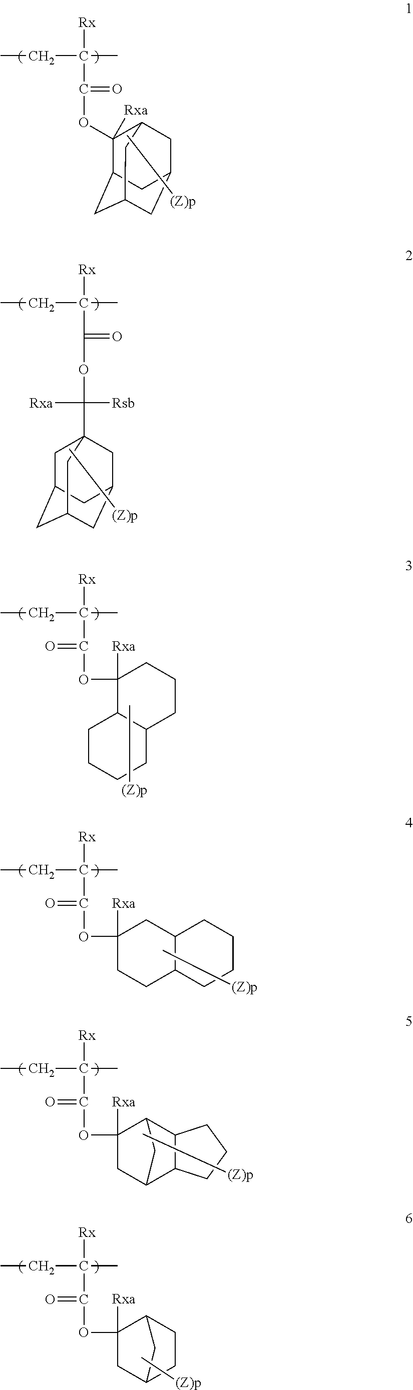

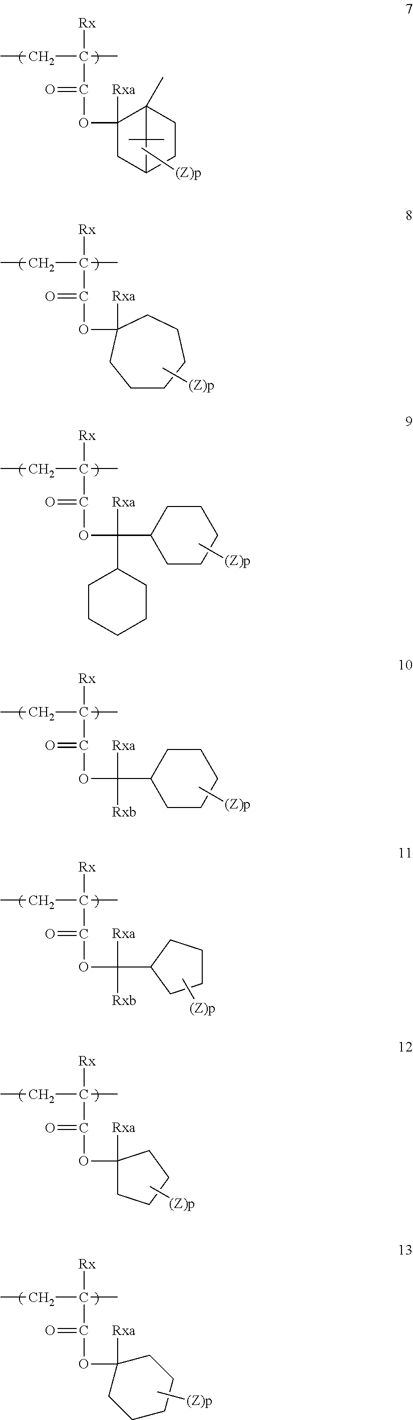

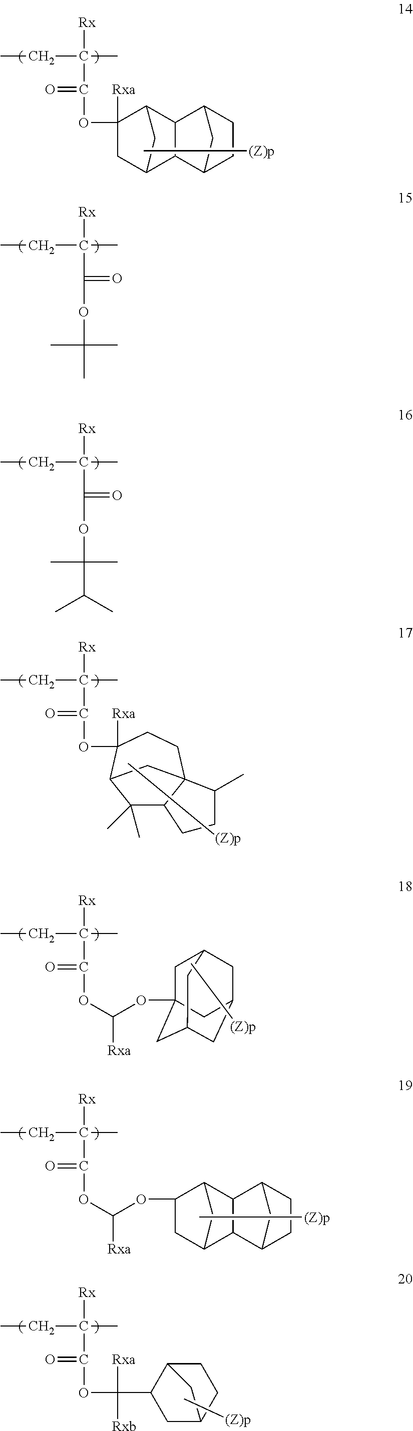

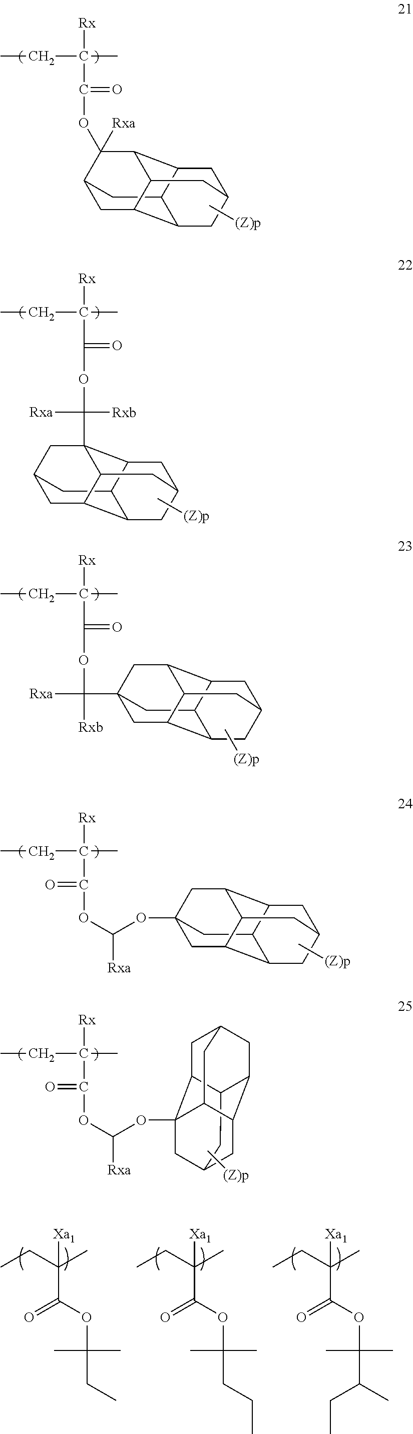

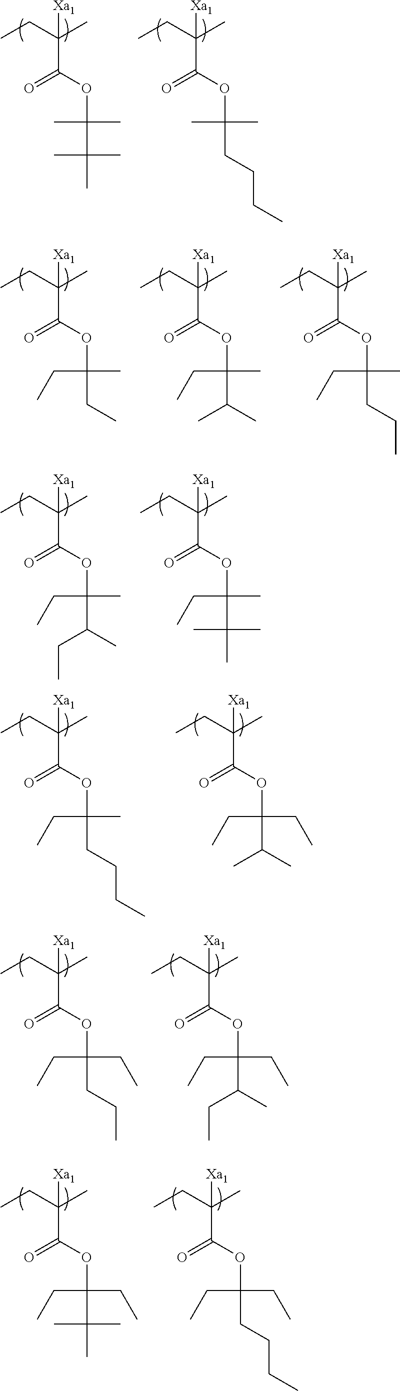

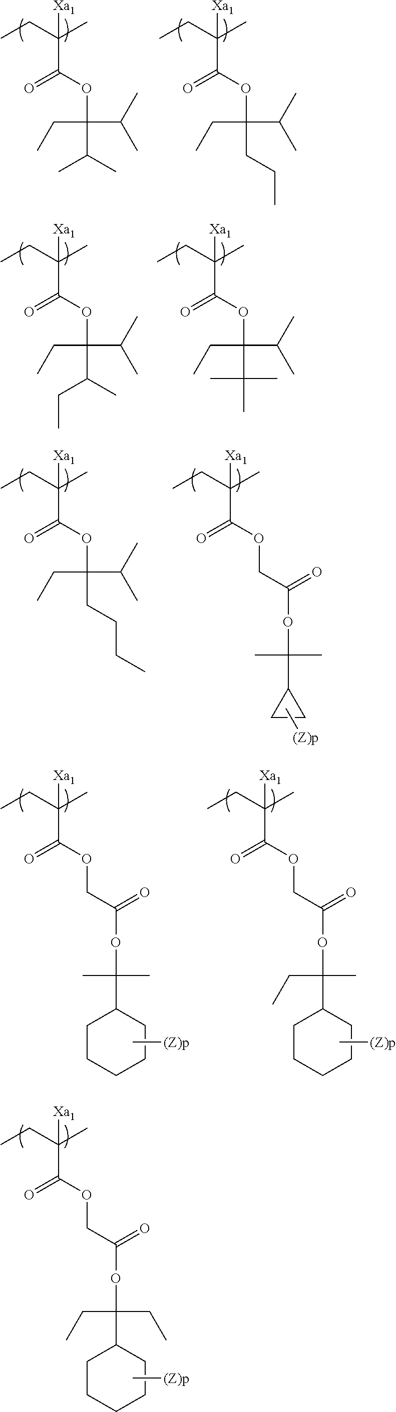

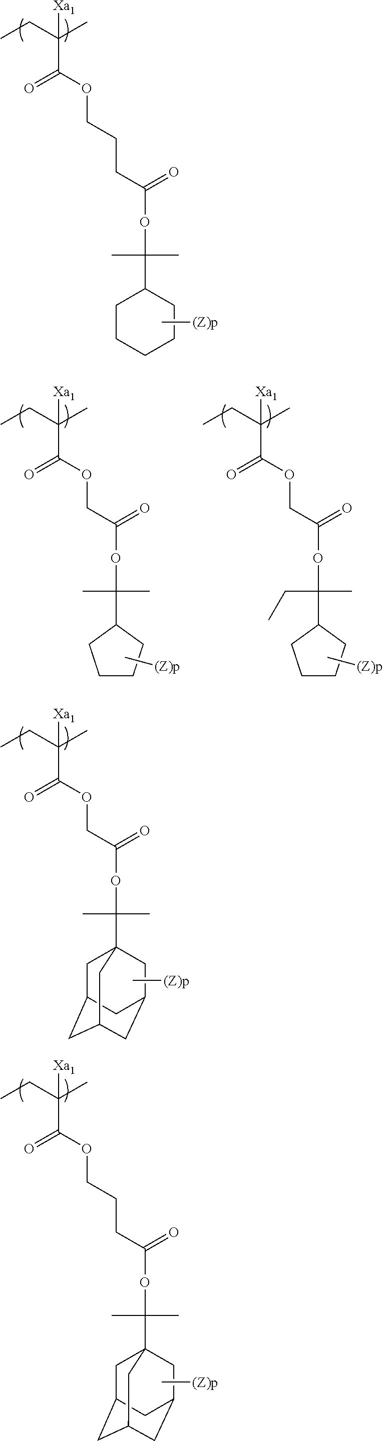

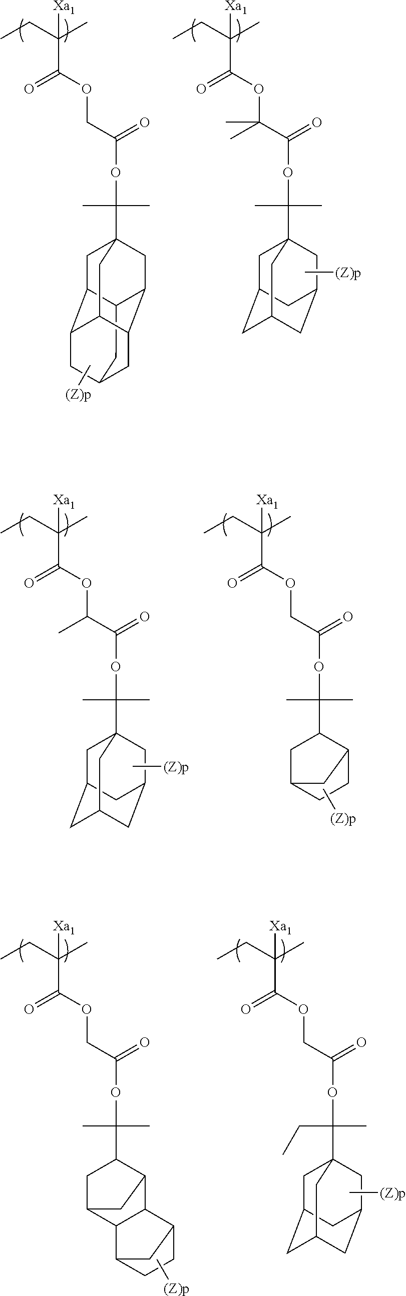

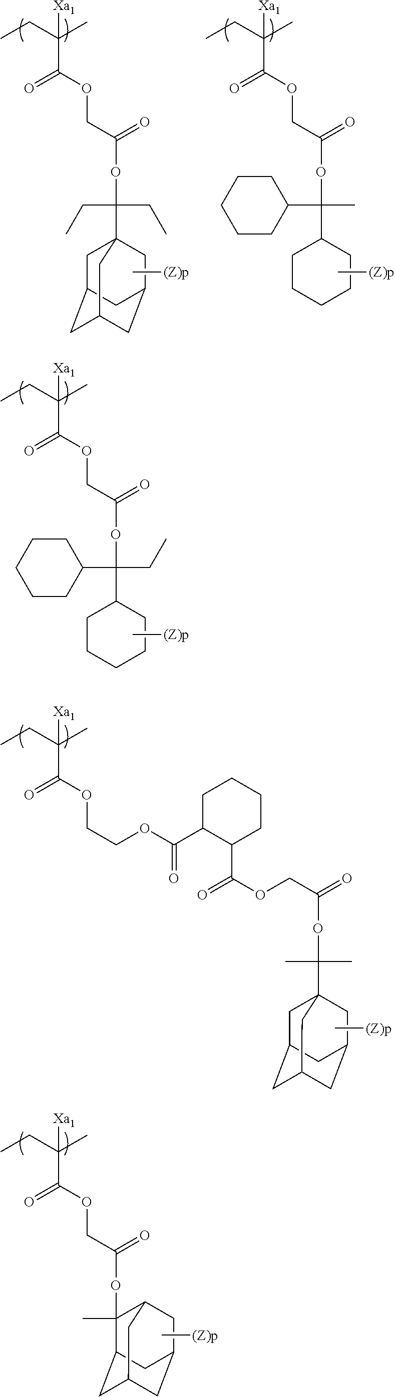

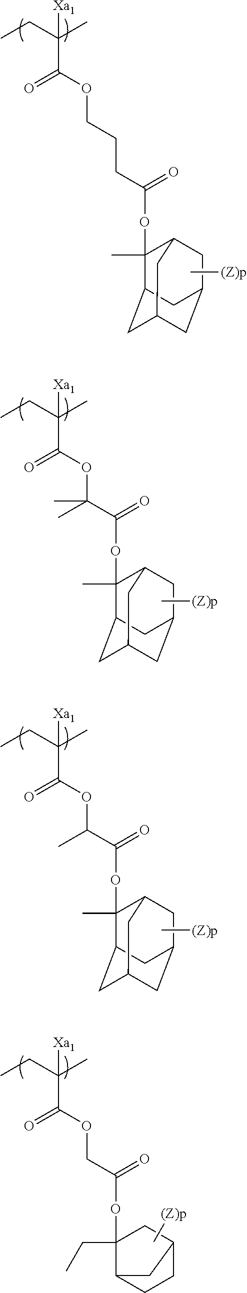

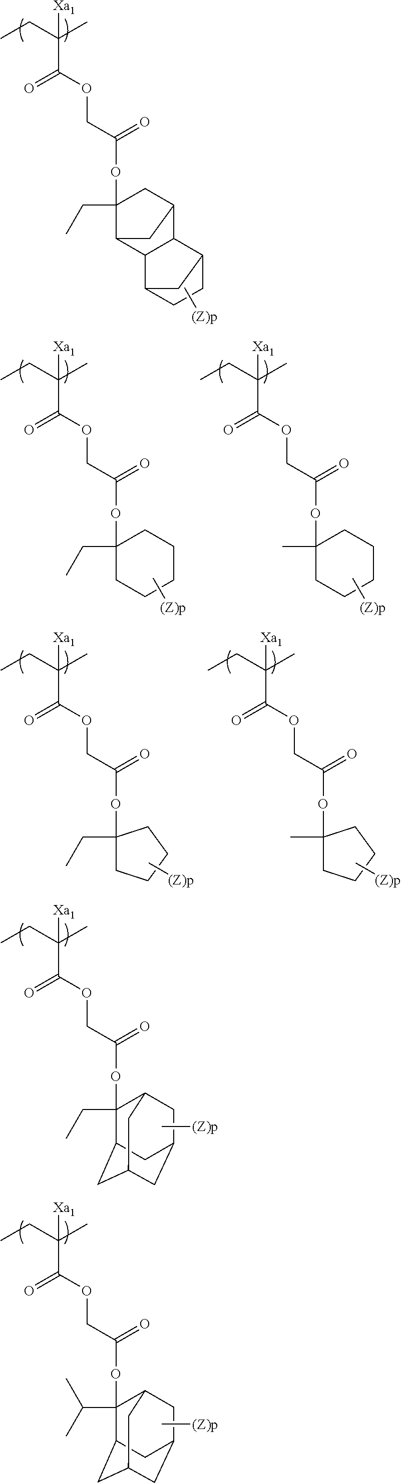

Further, the repeating unit represented by Formula (III′) is preferably a repeating unit represented by any one of the following Formulas (2-1), (2-2), (2-3) and (2-4). In the specific examples, Xₐ₁ represents a hydrogen atom, CH₃, CF₃ or CH₂OH.

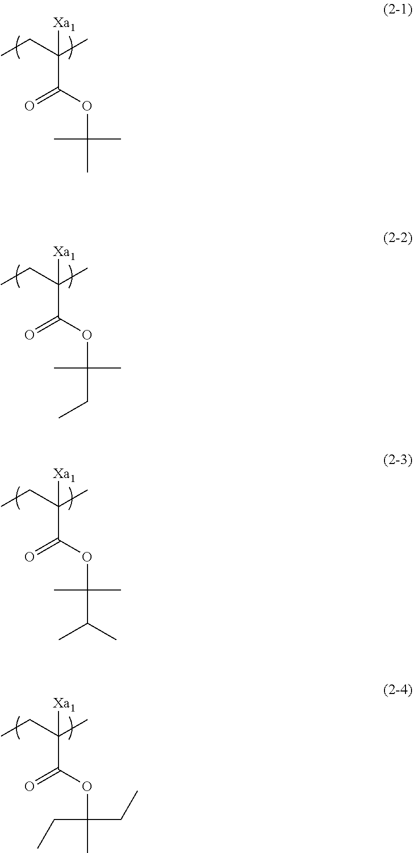

It is preferred that Resin (P) also has a repeating unit represented by the following Formula (IV) as a repeating unit having an acid-decomposable group.

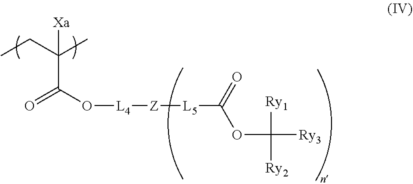

In the Formula, Xa represents a hydrogen atom, an alkyl group, a cyano group or a halogen atom.

Each of Ry₁ to Ry₃ independently represents an alkyl group or a cycloalkyl group. Two of Ry₁ to Ry₃ may be linked to each other to form a ring.

Z represents a linking group having a polycyclic hydrocarbon structure that may have a heteroatom as a (′)-valent ring member. Z may contain an ester bond as an atomic group which constitutes a polycyclic ring.

Each of L₄ and L₅ independently represents a single bond or a divalent linking group.

n′ represents an integer of 1 to 3.

When n′ is 2 or 3, each of L₂, Ry₁, Ry₂ and Ry₃ may be the same as or different from every other of L₂, Ry₁, Ry₂ and Ry₃.

Specific examples and preferred examples of Xₐ include those which are the same as the specific examples and preferred examples of R₀ in Formula (III).

The alkyl group of Ry₁ to Ry₃ is preferably a chained alkyl group, may be straight chained or branched, and is preferably an alkyl group having 1 to 4 carbon atoms such as a methyl group, an ethyl group, an n-propyl group, an isopropyl group, an n-butyl group, an isobutyl group and a t-butyl group.

The cycloalkyl group of Ry₁ to Ry₃ is preferably a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group.

The ring formed by combining two of R₁ to R₃ with each other is preferably a monocyclic hydrocarbon ring such as a cyclopentane ring and a cyclohexane ring, and a polycyclic hydrocarbon ring such as a norbornane ring, a tetracyclodecane ring, a tetracyclododecane ring and an adamantane ring. A monocyclic hydrocarbon ring having 5 or 6 carbon atoms is particularly preferred.

Each of Ry₁ to Ry₃ is independently preferably a chained alkyl group, and more preferably a straight chained or branched alkyl group having 1 to 4 carbon atoms. Furthermore, the sum of carbon atoms of the chained alkyl group as Ry₁ to Ry₃ is preferably 5 or less.

Ry₁ to Ry₃ may further have a substituent, and specific examples and preferred examples of such a further substituted substituent include those which are the same as the specific examples and preferred examples of the substituent which R₁ to R₃ in Formula (III) may further have. Among them, from the viewpoint of further enhancing the dissolution contrast in a developer containing an organic solvent before and after the acid decomposition, the substituent is more preferably a substituent that does not have a heteroatom such as an oxygen atom, a nitrogen atom and a sulfur atom (for example, it is more preferred that the substituent is not an alkyl group substituted with a hydroxyl group, and the like), even more preferably a group consisting of only a hydrogen atom and a carbon atom, and particularly preferably a straight chained or branched alkyl group and a cycloalkyl group.

A linking group having a polycyclic hydrocarbon structure of Z include a ring-aggregated hydrocarbon ring group and a crosslinked cyclic hydrocarbon ring group, and examples thereof include a group in which arbitrary (n′+1) hydrogen atoms are removed from a ring-aggregated hydrocarbon rign and a group in which arbitrary (n′+1) hydrogen atoms are removed from a crosslinked cyclic hydrocarbon ring.

Examples of the ring-aggregated hydrocarbon ring group include a bicyclohexane ring group, a perhydronaphthalene ring group and the like. Examples of the crosslinked cyclic hydrocarbon ring group include a bicyclic hydrocarbon ring group such as a pinane ring group, a bornane ring group, a norpinane ring group, a norbornane ring group, and a bicyclooctane ring group (a bicyclo[2.2.2]octane ring group, a bicyclo[3.2.1]octane ring group and the like), a tricyclic hydrocarbon ring group such as a homobrendane ring group, an adamantane ring group, a tricyclo[5.2.1.0^{2,6}]decane ring group and a tricyclo[4.3.1.1^{2,5}]undecane ring group, a tetracyclic hydrocarbon ring group such as a tetracyclo[4.4.0.1^{2,5}.1^{7,10}ldodecane ring group and a perhydro-1,4-methano-5,8-methanonaphthalene ring group, and the like. Furthermore, the crosslinked cyclic hydrocarbon ring group also includes a condensed cyclic hydrocarbon ring group, for example, a condensed ring group in which a plurality of 5 to 8-membered cycloalkane rings such as a perhydronaphthalene (decalin) ring group, a perhydroanthracene ring group, a perhydrophenanthrene ring group, a perhydroacenaphthene ring group, a perhydrofluorene ring group, a perhydroindene ring group, and a perhydrophenalene ring group is condensed.

Preferred examples of the crosslinked cyclic hydrocarbon ring group include a norbornane ring group, an adamantane ring group, a bicyclooctane ring group, a tricyclo[5.2.1.0^{2,6}]decane ring group and the like. More preferred examples of the crosslinked cyclic hydrocarbon ring include a norbornane ring group and an adamantane ring group.

The linking group having a polycyclic hydrocarbon structure represented by Z may have a substituent. Examples of the substituent that Z may have include a substituent such as an alkyl group, a hydroxyl group, a cyano group, a keto group (an alkylcarbonyl group and the like), an acyloxy group, —COOR, —CONR₂, —SO₂R, —SO₃R, and —SO₂NR₂. Here, R represents a hydrogen atom, an alkyl group, a cycloalkyl group or an aryl group.

An alkyl group, an alkylcarbonyl group, an acyloxy group, —COOR, —CONR₂, —SO₂R, —SO₃R and —SO₂NR₂ as the substituent, which Z may have may further have a substituent, and examples of the substituent include a halogen atom (preferably, a fluorine atom).

In the linking group having a polycyclic hydrocarbon structure represented by Z, the carbon constituting the polycyclic ring (the carbon contributing to ring formation) may be carbonyl carbon. Further, as described above, the polycyclic ring may have, as a ring member, a heteroatom such as an oxygen atom and a sulfur atom. As described above, Z may contain an ester bond as an atomic group which constitutes a polycyclic ring.

Examples of the linking group represented by L₄ and L₅ include —COO—, —OCO—, —CONH—, —NHCO—, —CO—, —O—, —S—, —SO—, —SO₂—, an alkylene group (preferably having from 1 to 6 carbon atoms), a cycloalkylene group (preferably having 3 to 10 carbon atoms), an alkenylene group (preferably having 2 to 6 carbon atoms), a linking group formed by combining a plurality of these groups and the like, and a linking group having a total carbon number of 12 or less is preferred.

L₄ is preferably a single bond, an alkylene group, —COO—, —OCO—, —CONH—, —NHCO—, -an alkylene group-COO—, -an alkylene group-OCO—, -an alkylene group-CONH—, -an alkylene group-NHCO—, —CO—, —O—, —SO₂— and -an alkylene group-O—, and more preferably a single bond, an alkylene group, -an alkylene group-COO— or -an alkylene group-O—.

L₅ is preferably a single bond, an alkylene group, —COO—, —OCO—, —CONH—, —NHCO—, —COO-an alkylene group-, —OCO-an alkylene group-, —CONH-an alkylene group-, —NHCO-an alkylene group-, —CO—, —O—, —SO₂—, —O-an alkylene group- and —O-a cycloalkylene group-, and more preferably a single bond, an alkylene group, —COO-an alkylene group- —O-an alkylene group- or —O-a cycloalkylene group-.

In the above-described method, the bonding hand “-” at the left end means to be connected to the ester bond on the main chain side in L₄ and connected to Z in L₅, and the bonding hand “-” at the right end means to be bonded to Z in L₄ and bonded to the ester bond connected to the group represented by (Ry₁)(Ry₂)(Ry₃)C— in L₅.

Meanwhile, L₄ and L₅ may be bonded to the same atom constituting the polycyclic ring in Z.

n′ is preferably 1 or 2, and more preferably 1.

Hereinafter, specific examples of the repeating unit represented by Formula (IV) will be shown, but the present invention is not limited thereto. In the following specific example, Xa represents a hydrogen atom, an alkyl group, a cyano group or a halogen atom.

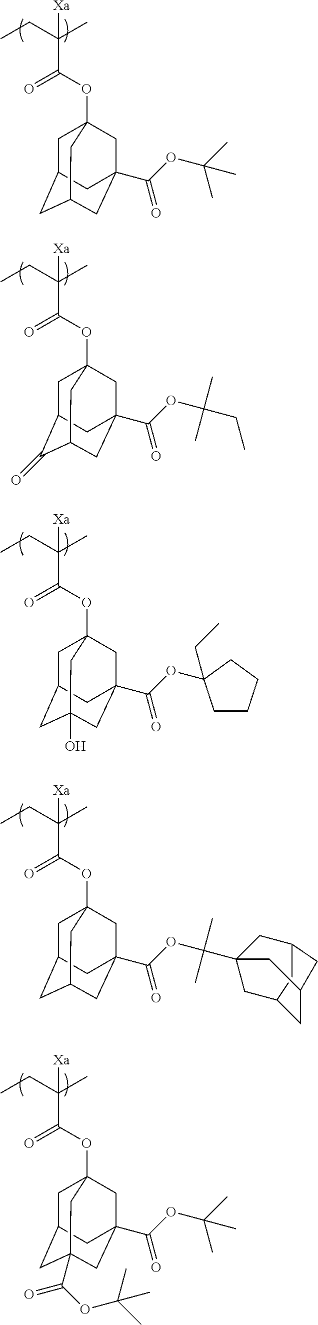

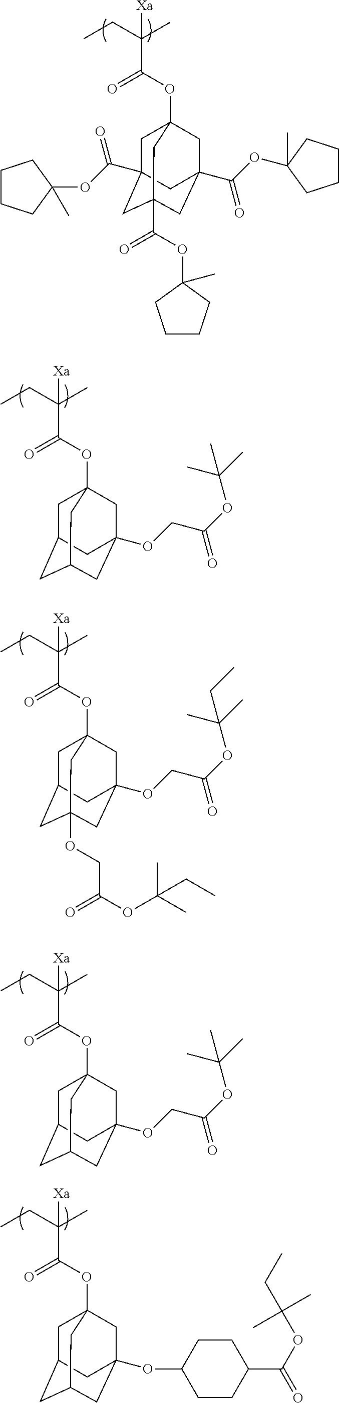

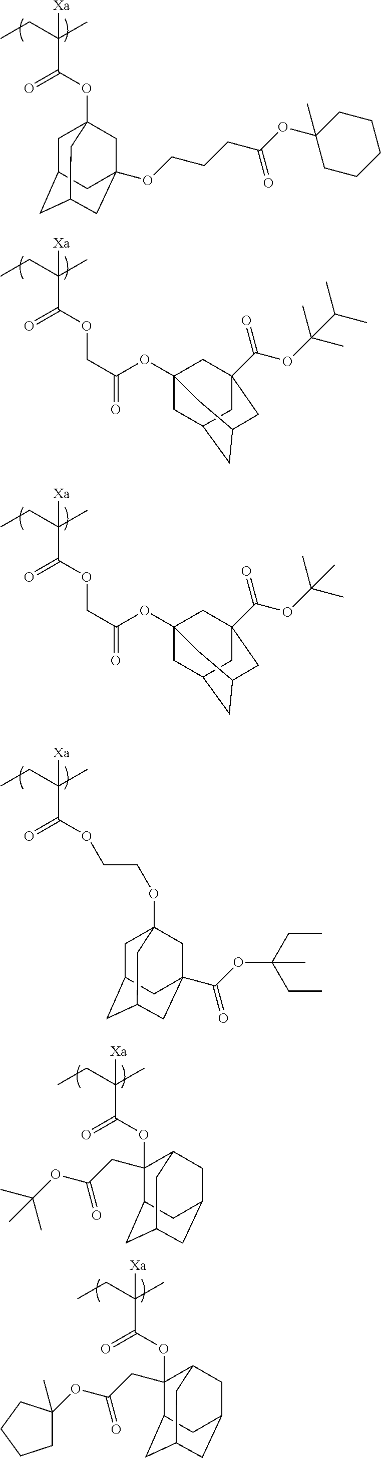

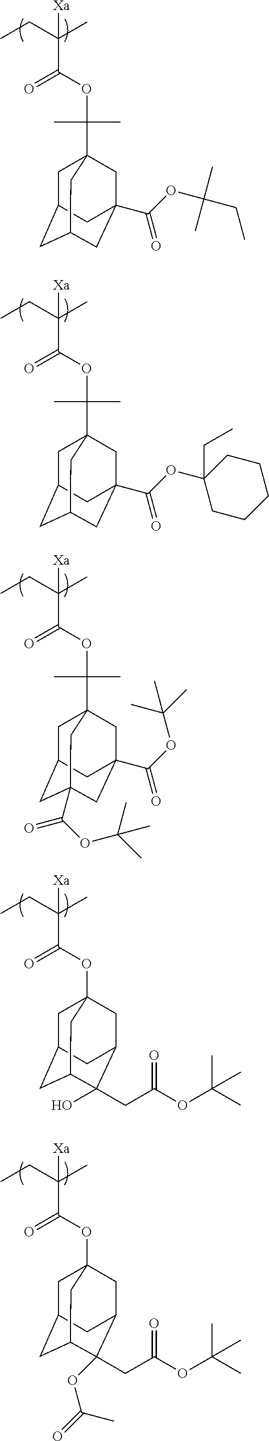

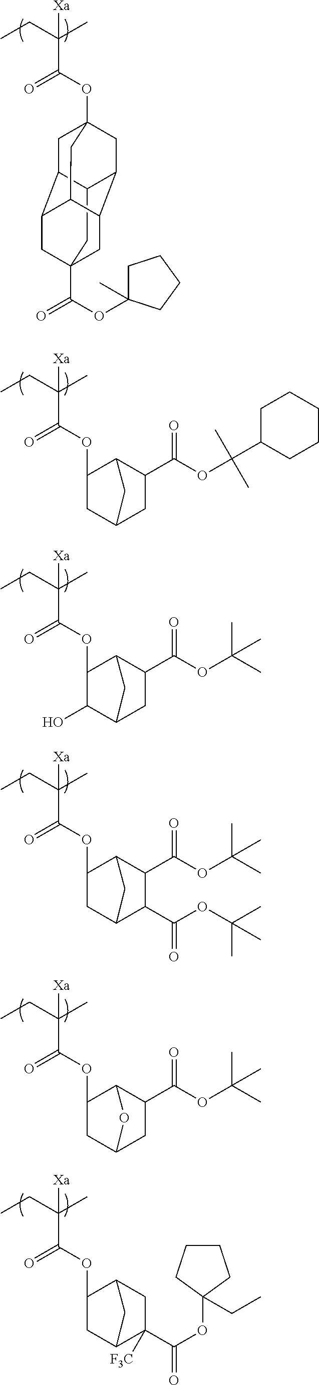

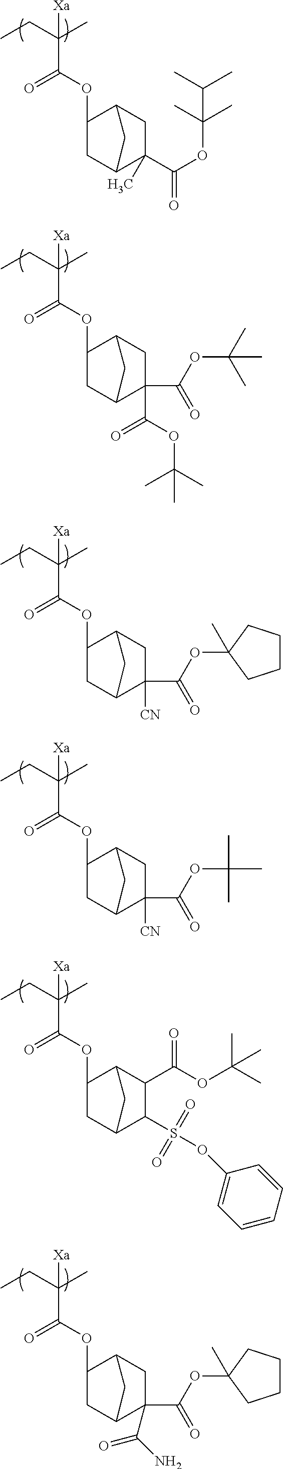

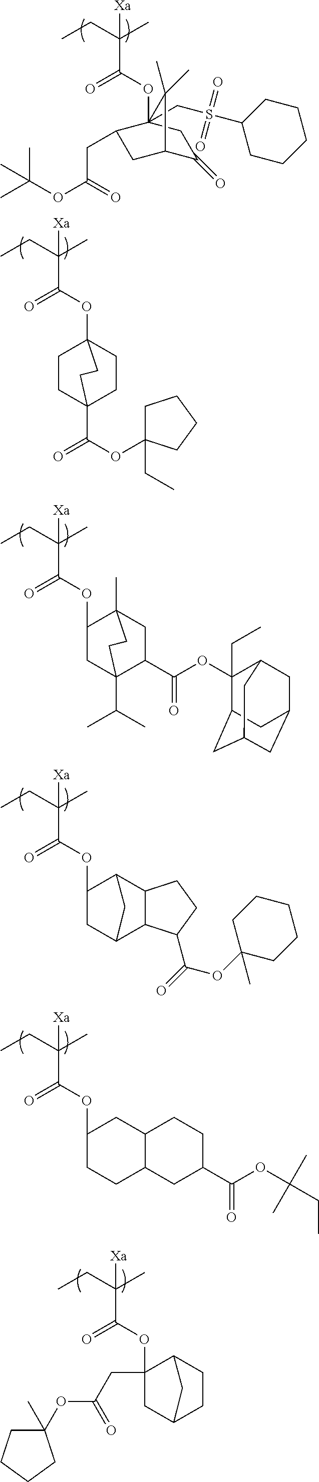

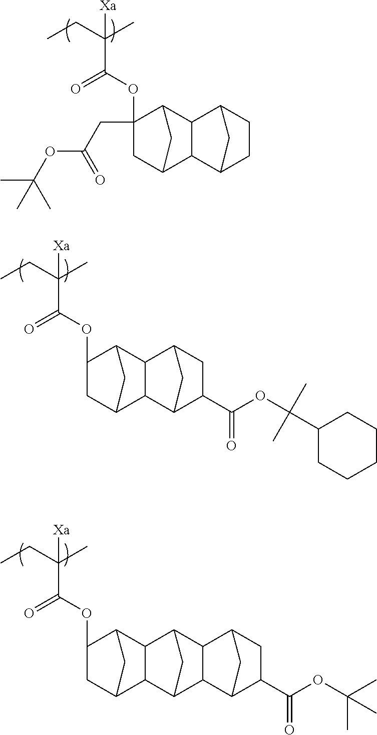

In addition, as the aspect of the repeating unit having an acid-decomposable group, which is different from the repeating units exemplified above, the repeating unit may have an aspect of the following repeating units capable of producing an alcoholic hydroxyl group.

In the following specific examples, Xa₁ represents a hydrogen atom, CH₃, CF₃ or CH₂OH.

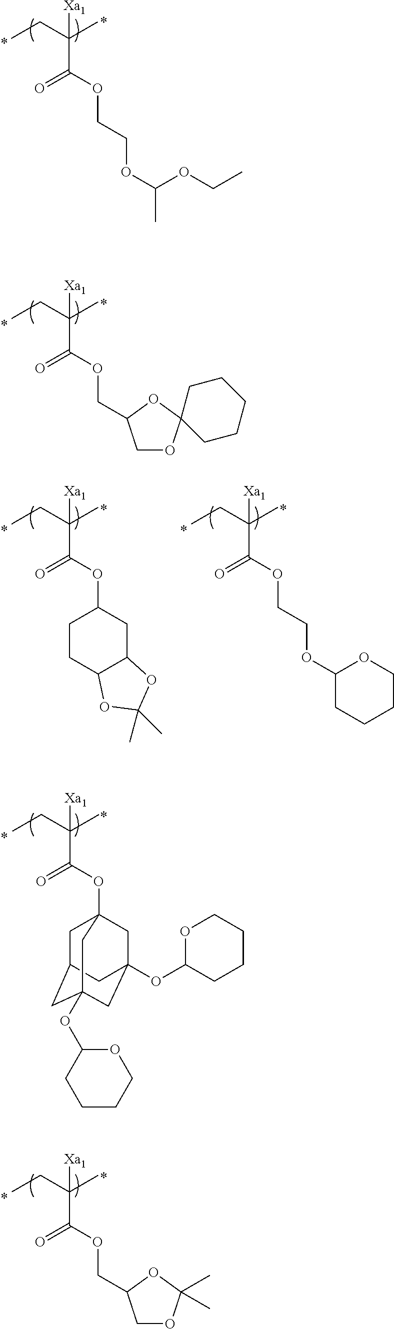

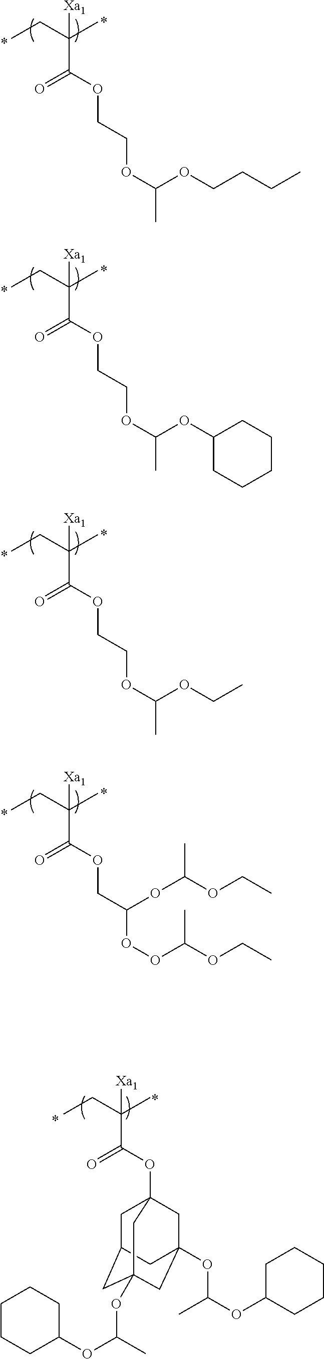

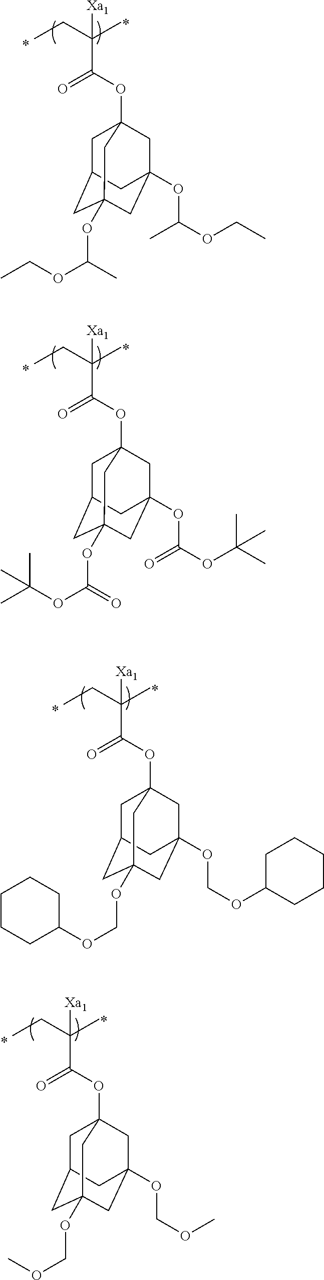

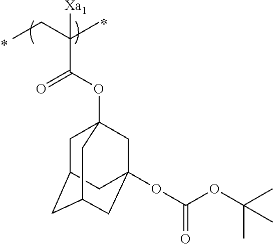

The repeating unit having an acid-decomposable group may be used either alone or in combination of two or more thereof.

The content of the repeating unit having an acid-decomposable group (in the case of containing a plurality of kinds of repeating units, the total thereof) in resin (P) is preferably 5 mol % to 80 mol %, more preferably 5 mol % to 75 mol %, and even more preferably 10 mol % to 65 mol %, based on the total repeating units in resin (P).

When resin (P) contains at least one of the repeating units represented by Formula (III) or (IV), the sum of the contents of the repeating units represented by Formulas (III) and (IV) is particularly preferably 50 mol % or more, and most preferably 55 mol % or more, based on the total repeating units in resin (P). The upper limit of the sum of the contents of the repeating units represented by Formulas (III) and (IV) is preferably 80 mol % or less, and more preferably 75 mol % or less, based on the total repeating units in resin (P).

When resin (P) is a resin containing the repeating unit represented by Formula (III′), the content of the repeating unit represented by Formula (III′) is preferably 55 mol % or more, and more preferably 60 mol % or more based on the total repeating units of resin (P). Furthermore, the content of the repeating unit represented by Formula (III′) is preferably 80 mol % or less, and more preferably 75 mol % or less, based on the total repeating units of resin (P).

Resin (A) may contain a repeating unit further having a lactone structure or a sultone structure.

The repeating unit having a lactone structure or a sultone structure is more preferably a repeating unit represented by the following Formula (AII).

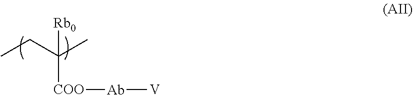

In Formula (AII),

Rb₀ represents a hydrogen atom, a halogen atom or an alkyl group (preferably having 1 to 4 carbon atoms) that may have a substituent.

Preferred examples of the substituent that an alkyl group of Rb₀ may have include a hydroxyl group and a halogen atom. Examples of the halogen atom of Rb₀ include a fluorine atom, a chlorine atom, a bromine atom and an iodine atom. Rb₀ is preferably a hydrogen atom, a methyl group, a hydroxymethyl group and a trifluoromethyl group, and particularly preferably a hydrogen atom and a methyl group.

Ab represents a single bond, an alkylene group, a divalent linking group having a monocyclic or polycyclic cycloalkyl structure, an ether bond, an ester bond, a carbonyl group or a divalent linking group in which these groups are combined. Ab is preferably a single bond and a divalent linking group represented by -Ab₁—CO₂—.

Ab₁ is a straight chained or branched alkylene group and a monocyclic or polycyclic cycloalkylene group, and preferably a methylene group, an ethylene group, a cyclohexylene group, an adamantylene group and a norbornylene group.

V represents a group having a lactone structure or a sultone structure.

As the group having a lactone structure or a sultone structure, any group may be used as long as the group has a lactone structure or a sultone structure, but a lactone structure having a 5- to 7-membered ring or a sultone structure having a 5- to 7-membered ring is preferred, and a group in which another ring structure is condensed to a lactone structure having a 5- to 7-membered ring in the form of forming a bicyclo structure or a Spiro structure, or a group in which another ring structure is condensed to a sultone structure having a 5- to 7-membered ring in the form of forming a bicyclo structure or a Spiro structure is preferred. It is more preferred that the group has a repeating unit having a lactone structure represented by any one of the following Formulas (LC1-1) to (LC1-21) or a sultone structure represented by any one of the following Formulas (SL1-1) to (SL1-3). Further, the lactone structure may be bonded directly to the main chain. A preferred lactone structure is (LC1-1), (LC1-4), (LC1-5), (LC1-6), (LC1-8), (LC1-13), (LC1-14) and (LC1-17).

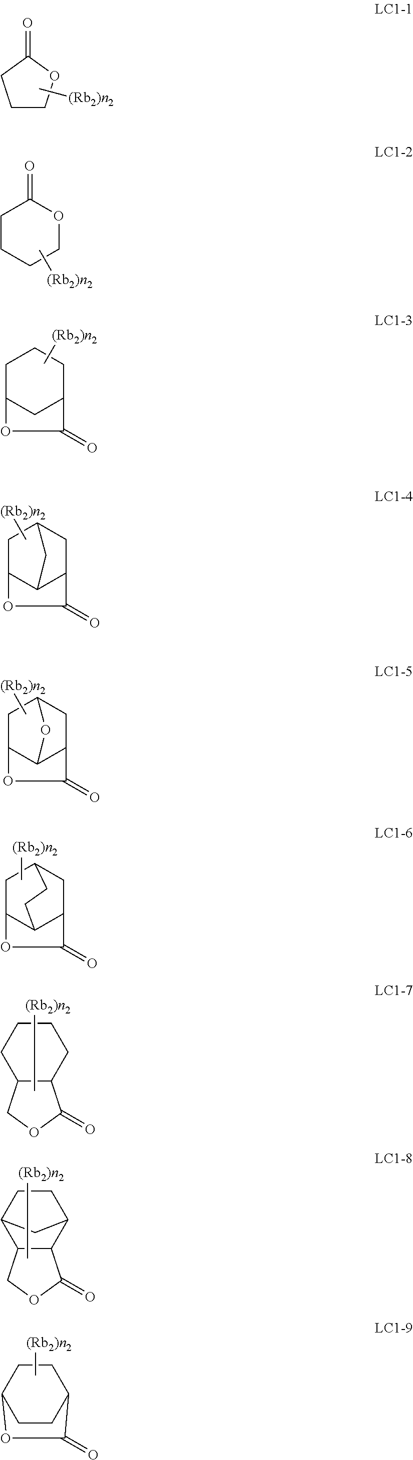

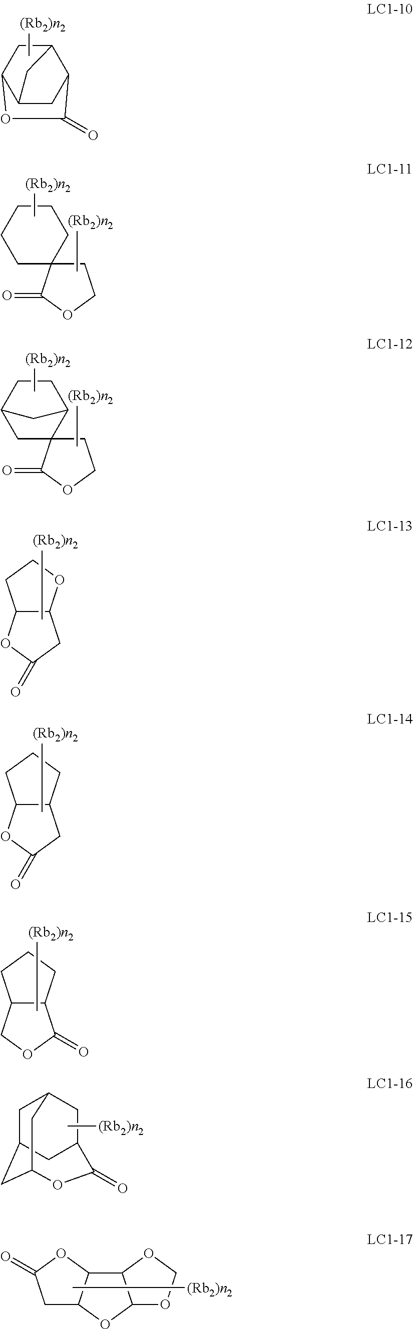

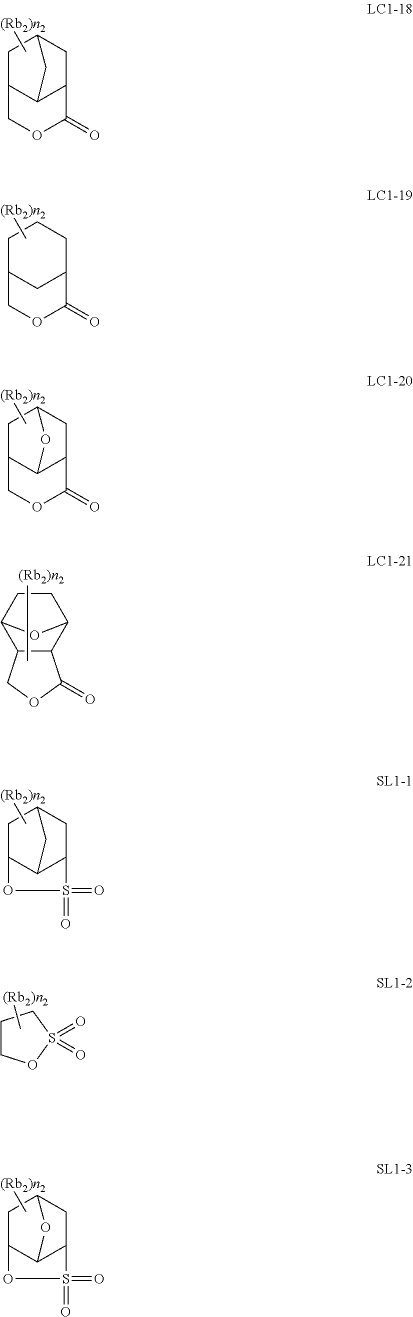

The lactone structure or sultone structure moiety may or may not have a substituent (Rb₂). Preferred examples of the substituent (Rb₂) include an alkyl group having 1 to 8 carbon atoms, a monovalent cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group and the like. An alkyl group having 1 to 4 carbon atoms, a cyano group and an acid-decomposable group are more preferred. n₂ represents an integer of 0 to 4. When n₂ is 2 or more, each substituent (Rb₂) may be the same as or different from every other substituent, and a plurality of substituents (Rb₂) may combine with each other to form a ring.

The repeating unit having a lactone group or a sultone structure usually has an optical isomer, and any optical isomer may be used. In addition, one kind of optical isomer may be used alone, or a plurality of optical isomers may be used in mixtures. When one kind of optical isomer is mainly used, the optical purity (ee) thereof is preferably 90% or more, and more preferably 95% or more.

Resin (P) may or may not contain a repeating unit having a lactone structure or a sultone structure, but when resin (P) contains the repeating unit having a lactone structure or a sultone structure, the content of the repeating unit having a lactone structure or a sultone structure is in a range of preferably 1 to 30 mol %, more preferably 3 to 20 mol %, and even more preferably 5 to 10 mol %, based on the total repeating units of resin (P).

Hereinafter, specific examples of the repeating unit having a lactone structure or a sultone structure in resin (P) will be shown, but the present is not limited thereto.

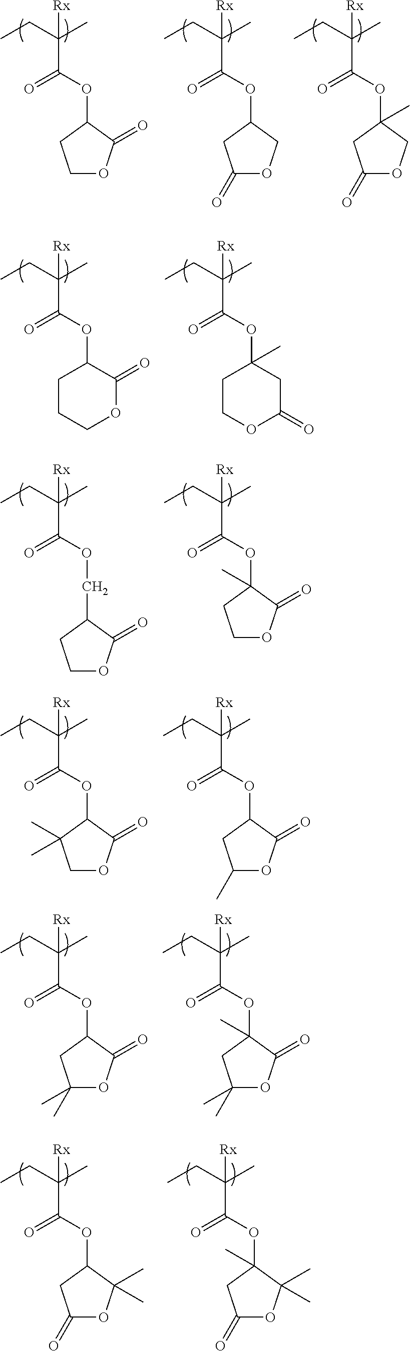

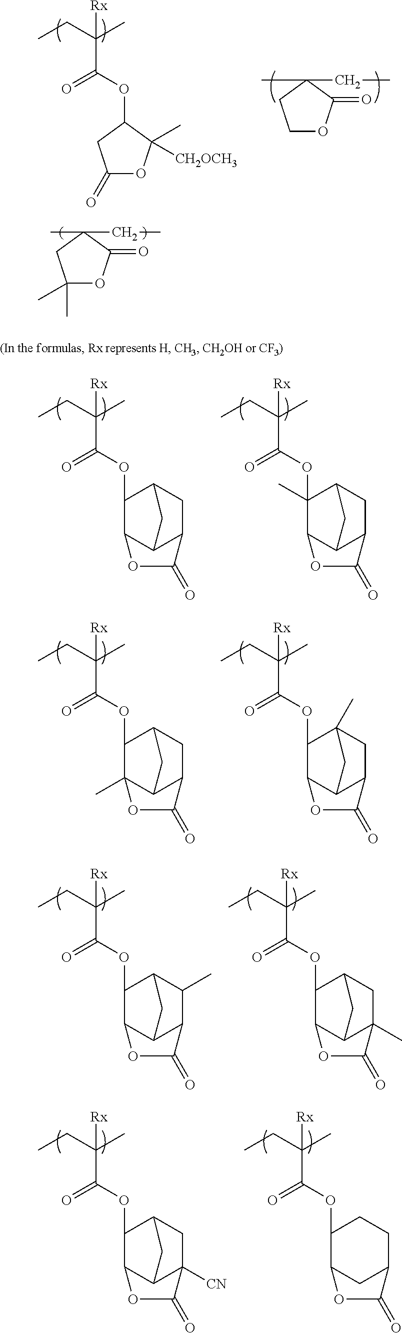

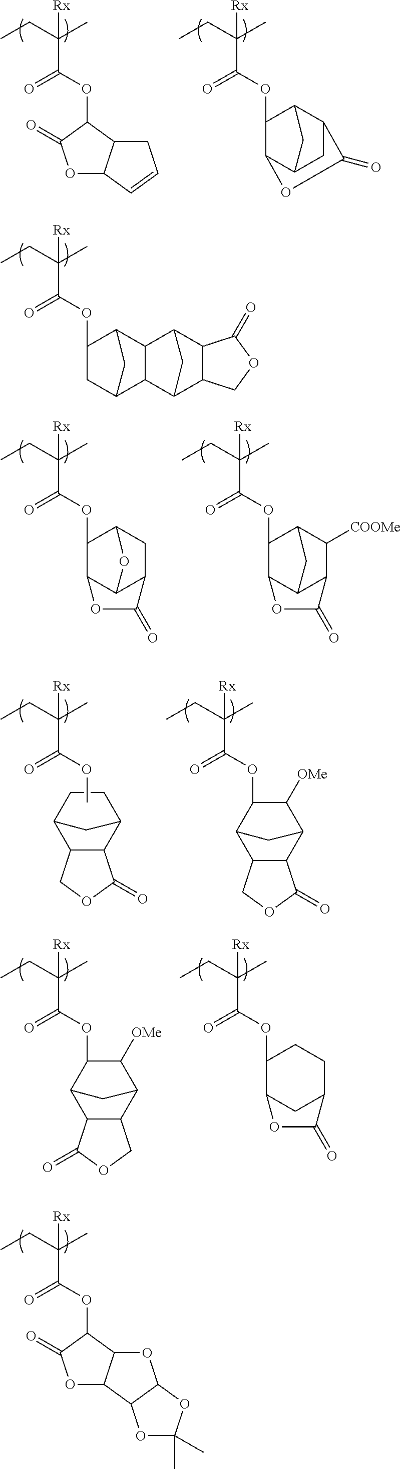

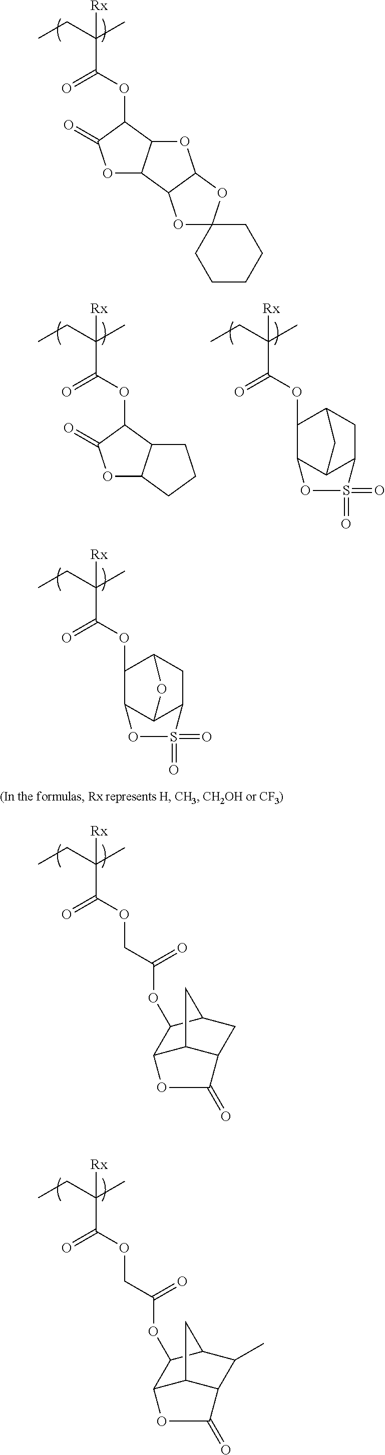

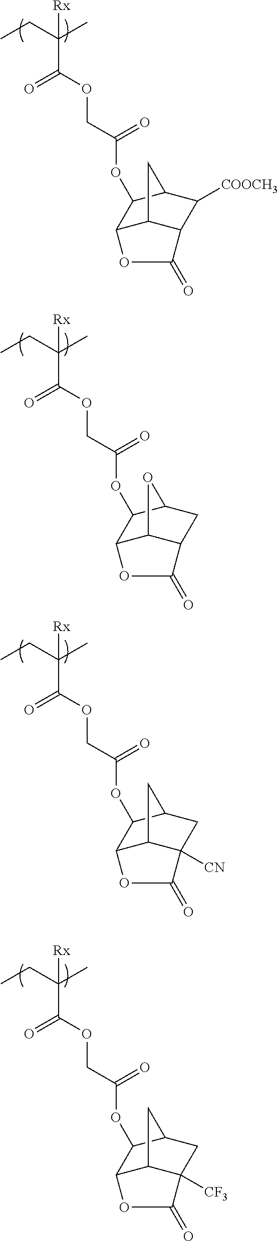

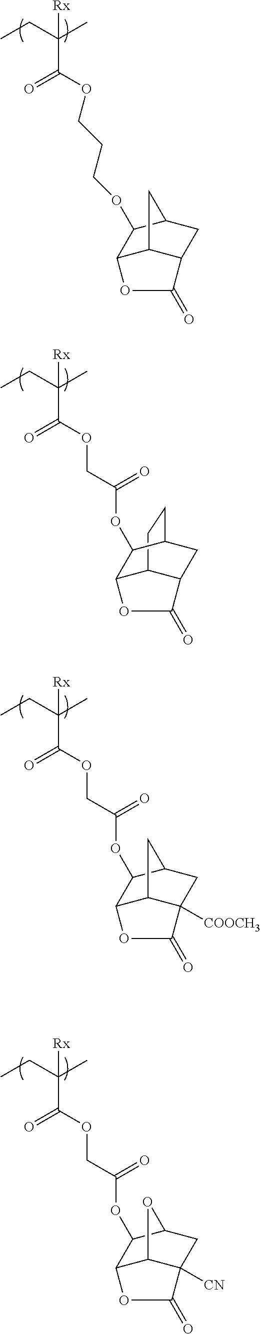

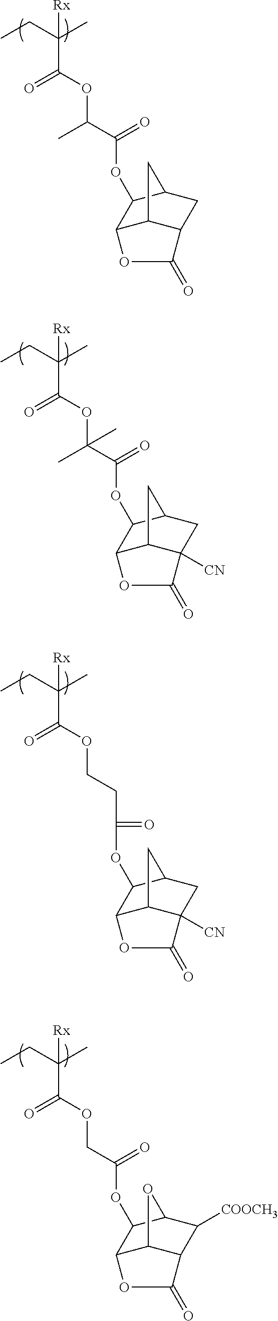

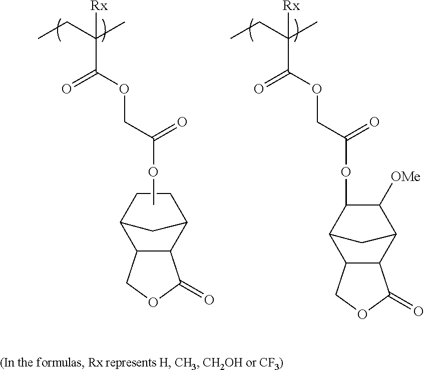

Furthermore, resin (P) may have a repeating unit having a cyclic carbonic acid ester structure.

The repeating unit having a cyclic carbonic acid ester structure is preferably a repeating unit represented by the following Formula (A-1).

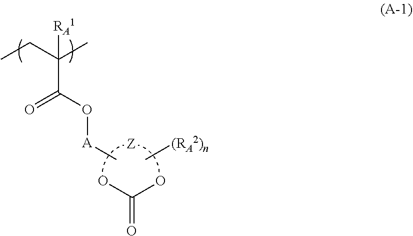

In Formula (A-1), R_{A}¹ represents a hydrogen atom or an alkyl group.

When n is 2 or more, each R_{A}² independently represents a substituent.

A represents a single bond or a divalent linking group.

Z represents an atomic group which forms a monocyclic or polycyclic structure along with a group represented by —O—C(═O)—O— in the Formulas.

n represents an integer of 0 or more.

Formula (A-1) will be described in detail.

An alkyl group represented by R_{A}¹ may have a substituent such as a fluorine atom. R_{A}¹ represents preferably a hydrogen atom, a methyl group or a trifluoromethyl group, and more preferably a methyl group.

A substituent represented by R_{A}² is, for example, an alkyl group, a cycloalkyl group, a hydroxyl group, an alkoxy group, an amino group and an alkoxycarbonylamino group. The substituent is preferably an alkyl group having 1 to 5 carbon atoms, and examples thereof include a straight chained alkyl group having 1 to 5 carbon atoms, such as a methyl group, an ethyl group, a propyl group and a butyl group; a branched alkyl group having 3 to 5 carbon atoms, such as an isopropyl group, an isobutyl group and a t-butyl group, and the like. The alkyl group may have a substituent such as a hydroxyl group.

n is an integer of 0 or more, which represents the number of substituents. n is, for example, preferably 0 to 4, and more preferably 0.

Examples of the divalent linking group represented by A include an alkylene group, a cycloalkylene group, an ester bond, an amide bond, an ether bond, a urethane bond, a urea bond, or a combination thereof, and the like. The alkylene group is preferably an alkylene group having 1 to 10 carbon atoms, and more preferably an alkylene group having 1 to 5 carbon atoms, and examples thereof include a methylene group, an ethylene group, a propylene group and the like.

In one embodiment of the present invention, A is preferably a single bond or an alkylene group.

Examples of the monocyclic ring including —O—C(═O)—O— represented by Z include a 5- to 7-membered ring where in the cyclic carbonic acid ester represented by the following Formula (a), n_{A} is 2 to 4, and is preferably a 5- or 6-membered ring (n_{A} is 2 or 3), and more preferably a 5-membered ring (n_{A} is 2).

Examples of the polycyclic ring containing —O—C(═O)—O— represented by Z include a structure where the cyclic carbonic acid ester represented by the following Formula (a) forms a condensed ring together with another ring structure or a structure where the cyclic carbonic acid ester forms a Spiro ring with another ring structure or two or more other ring structures. The “another ring structure” capable of forming a condensed ring or a spiro ring may be an alicyclic hydrocarbon group, an aromatic hydrocarbon group or a heterocyclic ring.

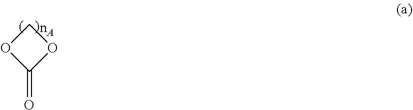

The monomer corresponding to the repeating unit represented by Formula (A-1) may be synthesized by publicly known methods in the related art, which are described in, for example, Tetrahedron Letters, Vol. 27, No. 32, p. 3741 (1986), Organic Letters, Vol. 4, No. 15, p. 2561 (2002), and the like.

In resin (P), one of the repeating units represented by Formula (A-1) may be included alone, or two or more thereof may be included.

Hereinafter, specific examples of the repeating unit having a cyclic carbonic acid ester structure will be shown, but the present invention is not limited thereto.

Meanwhile, R_{A}¹ in the following specific examples has the same meaning as R_{A}¹ in Formula (A-1).

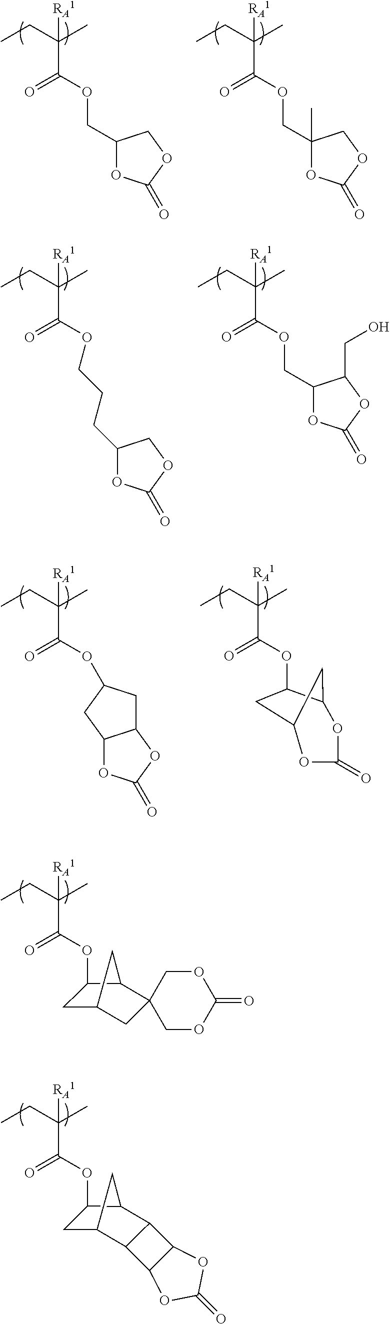

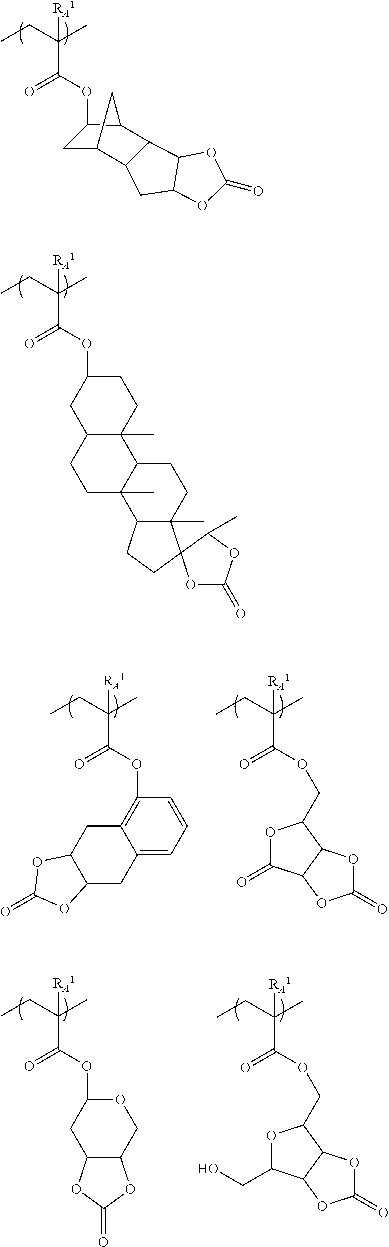

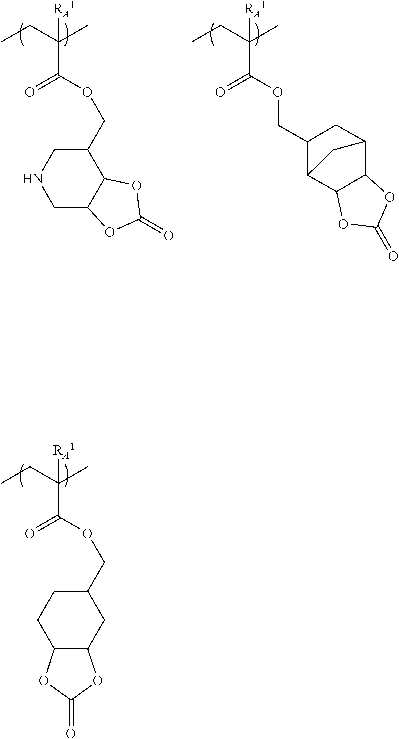

Resin (P) may contain one kind of repeating unit having a cyclic carbonic acid ester structure, or two or more kinds thereof.

When resin (P) contains a repeating unit having a cyclic carbonic acid ester structure, the content of the repeating unit having a cyclic carbonic acid ester structure is preferably 5 to 60 mol %, more preferably 5 to 55 mol %, and even more preferably 10 to 50 mol %, based on the total repeating units in resin (P).

Resin (P) may have a repeating unit having a hydroxyl group. Accordingly, adhesion to a substrate and affinity for a developer are enhanced. The repeating unit having a hydroxyl group is preferably a repeating unit having an alicyclic hydrocarbon structure substituted with a hydroxyl group, and preferably has no acid-decomposable group. In the alicyclic hydrocarbon structure substituted with a hydroxyl group, the alicyclic hydrocarbon structure is preferably an adamantyl group, a diamantyl group and a norbornane group. A preferred alicyclic hydrocarbon structure substituted with a hydroxyl group is preferably a partial structure represented by the following Formulas (VIIa) to (VIIc).

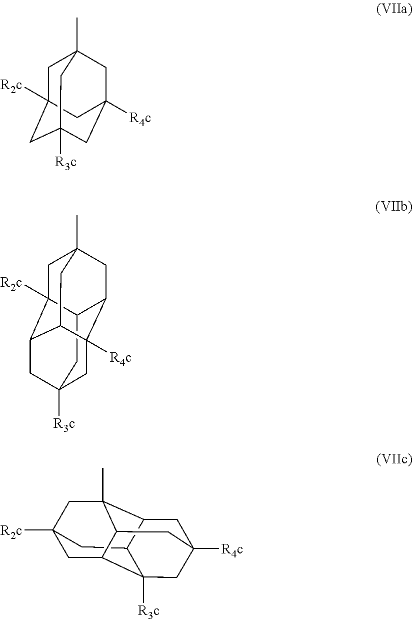

In Formulas (VIIa) to (Vile),

each of R_{2c} to R_{4c} independently represents a hydrogen atom or a hydroxyl group, provided that at least one of R_{2c} to R_{4c} represents a hydroxyl group. Preferably, one or two of R_{2c} to R_{4c} are a hydroxyl group with the remaining being a hydrogen atom. In Formula (VIIa), more preferably, two of R_{2c} to R_{4c} are a hydroxyl group with the remaining being a hydrogen atom.

Examples of the repeating unit having a partial structure represented by Formulas (VIIa) to (VIIc) include a repeating unit represented by the following Formulas (AIIa) to (AIIc).

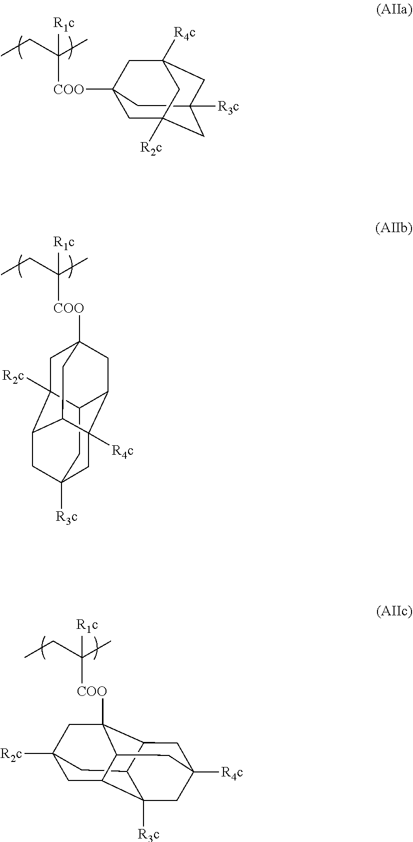

In Formulas (AIIa) to (AIIc),

R_{1c} represents a hydrogen atom, a methyl group, a trifluoromethyl group or a hydroxymethyl group.

R_{2c} to R_{4c} have the same meaning as R₂ to R_{4c} in Formulas (VIIa) to (VIIc).

Resin (P) may or may not contain the repeating unit having a hydroxyl group, but when resin (P) contains the repeating unit having a hydroxyl group, the content of the repeating unit having a hydroxyl group is preferably 1 to 20 mol %, more preferably 3 to 15 mol %, and even more preferably 5 to 10 mol %, based on the repeating units in resin (P).

Specific examples of the repeating unit having a hydroxyl group will be shown below, but the present invention is not limited thereto.

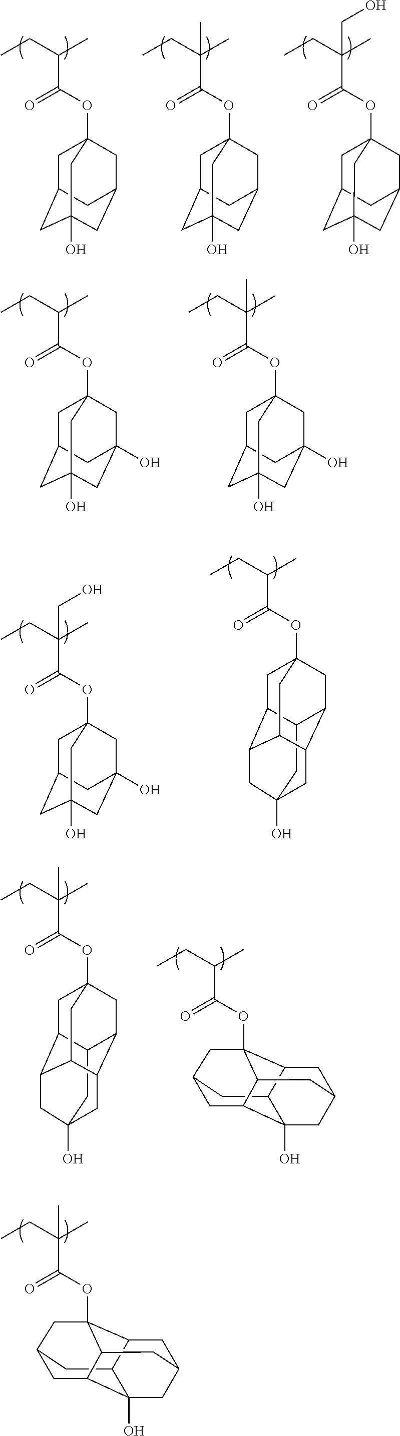

Resin (P) may have a repeating unit having an acid group. Examples of the acid group includes a carboxyl group, a sulfonamide group, a sulfonylimide group, a bissulfonylimide group, and an aliphatic alcohol (for example, a hexafluoroisopropanol group) in which an α-position thereof is substituted with an electron-withdrawing group, and it is more preferred that the resin has a repeating unit having a carboxyl group. By containing a repeating unit having an acid group, the resolution increases in the usage of contact holes. As for the repeating unit having an acid group, a repeating unit in which the acid group is directly bonded to the main chain of the resin, such as repeating unit by an acrylic acid or a methacrylic acid or a repeating unit in which the acid group is bonded to the main chain of the resin through a linking group, and a repeating unit in which the acid group is introduced into the end of the polymer chain by using a polymerization initiator or a chain transfer agent each having an acid group at the time of polymerization are all preferred. A repeating unit by an acrylic acid or a methacrylic acid is particularly preferred.

Resin (P) may or may not contain a repeating unit having an acid group, but when resin (P) contains a repeating unit having an acid group, the content of the repeating unit having an acid group is preferably 15 mol % or less, and more preferably 10 mol % or less, based on the total repeating units in resin (P). When resin (P) contains a repeating unit having an acid group, the content of the repeating unit having an acid group in resin (P) is usually 1 mol % or more.

Specific examples of the repeating unit having an acid group will be shown below, but the present invention is not limited thereto.

In the specific examples, Rx represents H, CH₃, CH₂OH or CF₃.

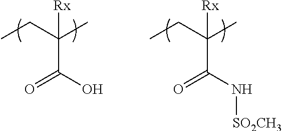

Resin (P) in the present invention may have a repeating unit which further has an alicyclic hydrocarbon structure having no polar group (for example, the acid group, the hydroxyl group, and the cyano group) and does not exhibit acid decomposability. Accordingly, elution of low molecular components from the resist film into the liquid for liquid immersion during the liquid immersion exposure may be reduced, and further, the solubility of the resin during the development using a developer including an organic solvent may be appropriately adjusted. Examples of the repeating unit include a repeating unit represented by Formula (VIII).

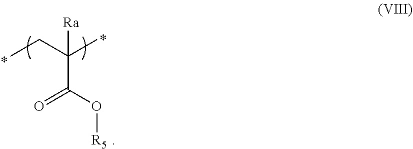

In Formula (VIII), R₅ represents a hydrocarbon group having at least one cyclic structure and having no polar group.

Ra represents a hydrogen atom, an alkyl group or a —CH₂—O—Ra₂ group. In the formula, Ra₂ represents a hydrogen atom, an alkyl group or an acyl group. Ra is preferably a hydrogen atom, a methyl group, a hydroxymethyl group and a trifluoromethyl group, and particularly preferably a hydrogen atom and a methyl group.

The cyclic structure that R₅ has includes a monocyclic hydrocarbon group and a polycyclic hydrocarbon group. Examples of the monocyclic hydrocarbon group include a cycloalkyl group having 3 to 12 carbon atoms, such as a cyclopentyl group, a cyclohexyl group, a cycloheptyl group, and a cyclooctyl group, and a cycloalkenyl group having 3 to 12 carbon atoms, such as a cyclohexenyl group. The monocyclic hydrocarbon group is preferably a monocyclic hydrocarbon group having 3 to 7 carbon atoms, and more preferably a cyclopentyl group or a cyclohexyl group.

The polycyclic hydrocarbon group includes a ring-aggregated hydrocarbon group and a crosslinked cyclic hydrocarbon group, and examples of the ring-aggregated hydrocarbon group include a bicyclohexyl group, a perhydronaphthalenyl group and the like. Examples of the crosslinked cyclic hydrocarbon ring include a bicyclic hydrocarbon ring such as a pinane ring, a bornane ring, a norpinane ring, a norbornane ring and a bicyclooctane ring (a bicyclo[2.2.2]octane ring, a bicyclo[3.2.1]octane ring and the like), a tricyclic hydrocarbon ring such as a homobrendane ring, an adamantine ring, a tricyclo[5.2.1.0^{2,6}]decane ring and a tricyclo[4.3.1.1^{2,5}]undecane ring, a tetracyclic hydrocarbon ring such as a tetracyclo[4.4.0.1^{2,5}.1^{7,10}ldodecane ring and a perhydro-1,4-methano-5,8-methanonaphthalene ring, and the like. Furthermore, the crosslinked cyclic hydrocarbon ring also includes a condensed cyclic hydrocarbon ring, for example, a condensed ring obtained by condensing a plurality of 5- to 8-membered cycloalkane rings, such as a perhydronaphthalene (decalin) ring, a perhydroanthracene ring, a perhydrophenanthrene ring, a perhydroacenaphthene ring, a perhydrofluorene ring, a perhydroindene ring, and a perhydrophenalene ring.

Preferred examples of the crosslinked cyclic hydrocarbon ring include a norbornyl group, an adamantyl group, a bicyclooctanyl group, a tricyclo[5,2,1,0^{2,6}]decanyl group and the like. More preferred examples of the crosslinked cyclic hydrocarbon ring include a norbornyl group and an adamantyl group.

The alicyclic hydrocarbon groups may have a substituent, and preferred examples of the substituent include a halogen atom, an alkyl group, a hydroxyl group with a hydrogen atom being substituted, an amino group with a hydrogen atom being substituted and the like. Preferred examples of the halogen atom include a bromine atom, a chlorine atom and a fluorine atom, and preferred examples of the alkyl group include a methyl group, an ethyl group, a butyl group and a t-butyl group. The aforementioned alkyl group may further have a substituent, and examples of the substituent, which the alkyl group may further have, include a halogen atom, an alkyl group, a hydroxyl group with a hydrogen atom being substituted, and an amino group with a hydrogen atom being substituted.

Examples of the substituent for hydrogen atom include an alkyl group, a cycloalkyl group, an aralkyl group, a substituted methyl group, a substituted ethyl group, an alkoxycarbonyl group, and an aralkyloxycarbonyl group. Preferred examples of the alkyl group include an alkyl group having 1 to 4 carbon atoms, preferred examples of the substituted methyl group include a methoxymethyl group, a methoxythiomethyl group, a benzyloxymethyl group, a t-butoxymethyl group, and a 2-methoxyethoxymethyl group, examples of the substituted ethyl group include a 1-ethoxy ethyl group and a 1-methyl-1-methoxyethyl group, preferred examples of the acyl group include an aliphatic acyl group having 1 to 6 carbon atoms, such as a formyl group, an acetyl group, a propionyl group, a butyryl group, an isobutyryl group, a valeryl group, and a pivaloyl group, and examples of the alkoxycarbonyl group include an alkoxycarbonyl group having from 1 to 4 carbon atoms and the like.

Resin (P) may or may not contain a repeating unit which has a polar group-free alicyclic hydrocarbon structure and does not exhibit acid decomposability, but when resin (P) contains the repeating unit, the content of the repeating unit is preferably 1 to 20 mol %, and more preferably 5 to 15 mol %, based on the total repeating units in resin (P).

Specific examples of the repeating unit, which has a polar group-free alicyclic hydrocarbon structure and does not exhibit acid decomposability, will be shown below, but the present invention is not limited thereto. In the formula, Ra represents H, CH₃, CH₂OH or CF₃.

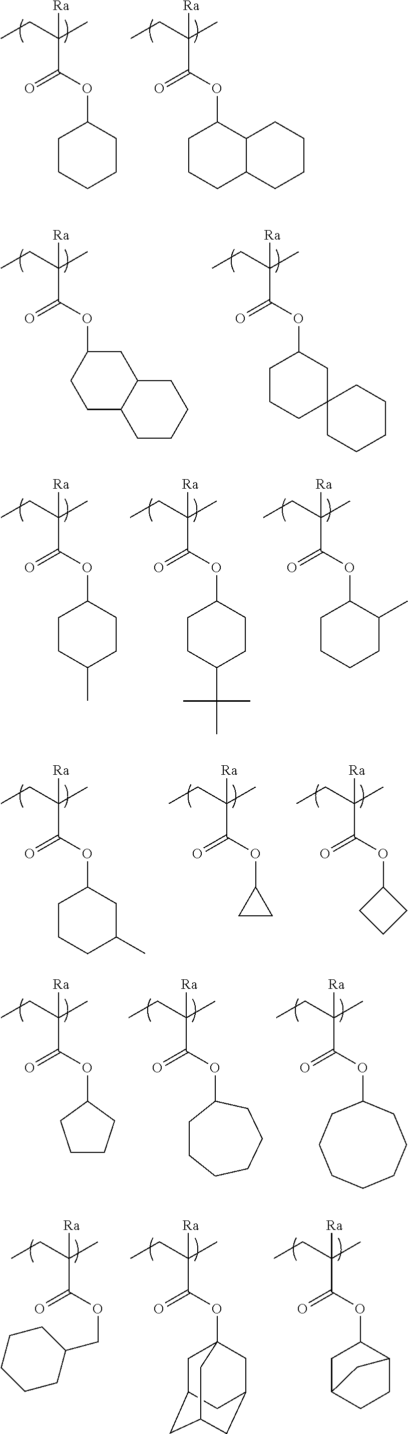

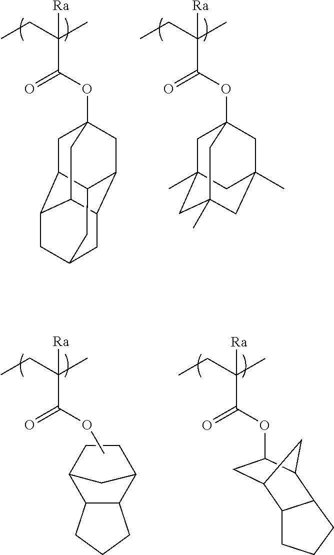

Resin (A) used in the composition of the present invention may have, in addition to the above-described repeating structural units, various repeating structural units for the purpose of controlling the dry etching resistance, suitability for a standard developer, adhesion to a substrate, and a resist profile, and resolution, heat resistance, sensitivity and the like, which are properties generally required for an actinic ray-sensitive or radiation-sensitive resin composition.

Examples of the repeating structural units include repeating structural units corresponding to the monomers described below, but are not limited thereto.

Accordingly, the performance required for the resin used in the composition according to the present invention, particularly

(1) solubility for a coating solvent,

(2) film-forming property (glass transition temperature),

(3) alkali developability,

(4) film reduction (selection of a hydrophilic, hydrophobic or alkali-soluble group)

(5) adhesion of unexposed portion to the substrate, and

(6) dry etching resistance, and the like may be finely adjusted.

Examples of the monomer include a compound having one addition-polymerizable unsaturated bond selected from acrylic acid esters, methacrylic acid esters, acrylamides, methacrylamides, allyl compounds, vinyl ethers, vinyl esters and the like, and the like.

Other than these, an addition-polymerizable unsaturated compound that is copolymerizable with the monomers corresponding to the above-described various repeating structural units may be copolymerized.

In resin (P) used in the composition of the present invention, the molar ratio of respective repeating structural units contained is appropriately set in order to control dry etching resistance, suitability for a standard developer, adhesion to a substrate, and resist profile of the actinic ray-sensitive or radiation-sensitive resin composition, and resolution, heat resistance, sensitivity and the like which are performances generally required for the actinic ray-sensitive or radiation-sensitive resin composition.

When the composition of the present invention is for ArF exposure, from the viewpoint of transparency to ArF light, resin (P) used in the composition of the present invention preferably substantially has no aromatic ring (specifically, the ratio of a repeating unit having an aromatic group in the resin is preferably 5 mol % or less, more preferably 3 mol % or less, and ideally 0 mol %, that is, the resin has no aromatic group), and resin (P) preferably has a monocyclic or polycyclic alicyclic hydrocarbon structure.

Further, when the composition of the present invention includes resin (D) to be described below, resin (P) preferably contains no fluorine atom and no silicon atom from the viewpoint of compatibility with resin (E).

Resin (P) used in the composition of the present invention is preferably a resin in which all the repeating units consist of a (meth)acrylate-based repeating unit. In this case, all the repeating units may be used as any one of a methacrylate-based repeating unit, an acrylate-based repeating unit, and a methacrylate-based repeating unit and an acrylate-based repeating unit, but the acrylate-based repeating unit is present in an amount of preferably 50 mol % or less based on all the repeating units.

When KrF excimer laser light, electron beam, X-ray or high-energy beam having a wavelength of 50 nm or less (EUV and the like) is irradiated on the composition of the present invention, resin (A) also has preferably a hydroxystyrene-based repeating unit. Resin (P) has more preferably a hydroxystyrene-based repeating unit, a hydroxystyrene-based repeating unit protected by an acid-decomposable group, and an acid-decomposable repeating unit such as (meth)acrylic acid tertiary alkyl ester.

Preferred examples of the hydroxystyrene-based repeating unit having an acid-decomposable group include repeating units consisting of t-butoxycarbonyloxystyrene, 1-alkoxyethoxystyrene, (meth)acrylic acid tertiary alkyl ester and the like, and repeating units consisting of 2-alkyl-2-adamantyl(meth)acrylate and dialkyl(1-adamantyl)methyl (meth)acrylate are more preferred.

Resin (P) in the present invention may be synthesized by a typical method (for example, radical polymerization). Examples of a general synthesis method include a batch polymerization method of dissolving monomer species and an initiator in a solvent and heating the solution to perform the polymerization, a dropping polymerization method of adding dropwise a solution containing monomer species and an initiator to a heated solvent over 1 to 10 hours, and the like, and a dropping polymerization method is preferred. Examples of a reaction solvent include tetrahydrofuran, 1,4-dioxane, ethers such as diisopropyl ether, ketones such as methyl ethyl ketone and methyl isobutyl ketone, an ester solvent such as ethyl acetate, an amide solvent such as dimethylformamide and dimethylacetamide, and a solvent capable of dissolving the composition of the present invention, which will be described below, such as propylene glycol monomethyl ether acetate, propylene glycol monomethyl ether, and cyclohexanone. The polymerization is more preferably performed by using the same solvent as the solvent used in the photosensitive composition of the present invention. Accordingly, generation of particles during storage may be suppressed.

The polymerization reaction is preferably performed under an inert gas atmosphere such as nitrogen and argon. As for the polymerization initiator, the polymerization is initiated by using a commercially available radical initiator (azo-based initiator, peroxide and the like). The radical initiator is preferably an azo-based initiator, and an azo-based initiator having an ester group, a cyano group or a carboxyl group is preferred. Preferred examples of the initiator include azobisisobutyronitrile, azobisdimethylvaleronitrile, dimethyl 2,2′-azobis(2-methylpropionate) and the like. The initiator is added additionally or in parts, if desired, and after the completion of reaction, the reaction product is poured in a solvent, and a desired polymer is recovered by a powder or solid recovery method, or the like. The reaction concentration is 5 to 50% by mass, and preferably 10 to 30% by mass. The reaction temperature is usually 10° C. to 150° C., preferably 30° C. to 120° C., and more preferably 60° C. to 100° C.

After the completion of reaction, the reaction solution is allowed to cool to room temperature and purified. The purification may be performed by a typical method, such as a liquid-liquid extraction method of applying water-washing or combining water-washing with an appropriate solvent to remove residual monomers or oligomer components, a purification method in a solution state, such as ultrafiltration of removing only those having a molecular weight not more than a specific molecular weight by virtue of extraction, a reprecipitation method of adding dropwise a resin solution in a poor solvent to solidify the resin in the poor solvent to remove residual monomers and the like, and a purification method in a solid state, such as washing of the resin slurry separated by filtration with a poor solvent. For example, the resin is precipitated as a solid by contacting the reaction solution with a solvent (poor solvent) in which the resin is sparingly soluble or insoluble and which is in a volumetric amount of 10 times or less and preferably from 10 to 5 times the reaction solution.

The solvent (precipitation or reprecipitation solvent) used at the time of operating precipitation or reprecipitation from the polymer solution may be sufficient if the solvent is a poor solvent for the polymer, and the solvent may be appropriately selected from a hydrocarbon, a halogenated hydrocarbon, a nitro compound, ether, ketone, ester, carbonate, alcohol, carboxylic acid, water, and a mixed solvent including these solvents, according to the kind of the polymer, and may be used. Among these solvents, a solvent including at least alcohol (particularly, methanol or the like) or water is preferred as the precipitation or reprecipitation solvent.

The amount of the precipitation or reprecipitation solvent used may be appropriately selected in consideration of the efficiency, yield and the like, but in general, the amount is 100 to 10,000 parts by mass, preferably 200 to 2,000 parts by mass, and more preferably 300 to 1,000 parts by mass, based on 100 parts by mass of the polymer solution.

The temperature during the precipitation or reprecipitation may be appropriately selected in consideration the efficiency or operability but is usually 0 to 50° C., and preferably in the vicinity of room temperature (for example, approximately 20 to 35° C.). The precipitation or reprecipitation operation may be performed by a publicly known method such as batch system and continuous system using a commonly-used mixing vessel such as stirring tank.

The precipitated or reprecipitated polymer is usually subjected to commonly-used solid-liquid separation such as filtration and centrifugation, and then dried and used. The filtration is performed by using a solvent-resistant filter element, and preferably under pressure. The drying is performed under normal pressure or reduced pressure (preferably under reduced pressure) at a temperature of approximately 30 to 100° C. and preferably at a temperature of approximately 30 to 50° C.

Meanwhile, after the resin is once precipitated and separated, the resin may be dissolved in a solvent again and then brought into contact with a solvent in which the resin is sparingly soluble or insoluble. That is, there may be used a method including, after the completion of radical polymerization reaction, bringing the polymer into contact with a solvent in which the polymer is sparingly soluble or insoluble, to precipitate a resin (process a), separating the resin from the solution (process b), dissolving the resin in a solvent again to prepare a resin solution A (process c), and then bringing the resin solution A into contact with a solvent in which the resin is sparingly soluble or insoluble and which is in a volumetric amount of less than 10 times (volumetric amount of preferably 5 times or less) the resin solution A, to precipitate a resin solid (process d), and separating the precipitated resin (process e).

In addition, for suppressing the resin after preparation of the composition from aggregation or the like, as described in, for example, Japanese Patent Application Laid-Open No. 2009-037108, a process of dissolving the synthesized resin in a solvent to prepare a solution, and heating the solution at approximately 30° C. to 90° C. for approximately 30 minutes to 4 hours may be added.

The weight average molecular weight of resin (P) in the present invention is preferably 1,000 to 200,000, more preferably 2,000 to 40,000, even more preferably 3,000 to 30,000, and particularly preferably 3,000 to 27,000, in terms of polystyrene by the GPC method. By setting the weight average molecular weight within 1,000 to 200,000, it is possible to prevent the heat resistance or dry etching resistance from deteriorating and prevent the film-forming property from deteriorating due to impaired developability or increased viscosity.

The polydispersity (molecular weight distribution) is usually in a range of 1.0 to 3.0, preferably 1.0 to 2.6, more preferably 1.0 to 2.0, and particularly preferably 1.4 to 2.0. The smaller the molecular weight distribution is, the better the resolution and resist shape are, and the smoother the side wall of the resist pattern is, and thus roughness is excellent.

In the actinic ray-sensitive or radiation-sensitive resin composition of the present invention, the blending ratio of resin (P) in the entire composition is preferably 30 to 99% by mass, and more preferably 60 to 95% by mass, based on the total solid content of the composition.

Furthermore, in the present invention, resin (P) may be used either alone or in combination of a plurality thereof

[2] Resin (A) Having No Repeating Unit (a)

The actinic ray-sensitive or radiation-sensitive resin composition of the present invention may contain resin (A) which has no repeating unit (a).

Resin (A) is preferably a resin capable of increasing the polarity by the action of an acid to decrease the solubility thereof in a developer including an organic solvent, and more specifically, is preferably a resin having the above-described “a repeating unit (b) having an acid-decomposable group”.

The content of the repeating unit having an acid-decomposable group is preferably 20 to 70 mol %, and more preferably 30 to 65 mol %, based on the total repeating units in resin (A).

Resin (A) may contain the repeating unit described as a repeating unit which resin (P) may not have in addition to the repeating unit having an acid-decomposable group. A preferred range of the content of these repeating units in resin (A) based on the total repeating units is the same as that described in resin (P).

Further, a preferred range of each physical property value (for example, molecular weight and polydispersity) of resin (A) and the synthesis method of resin (A) are the same as those described in resin (P).

The actinic ray-sensitive or radiation-sensitive resin composition of the present invention may or may not contain resin (A), but when the composition contains resin (A), the content of resin (A) is preferably 5 to 50% by mass, and more preferably 5 to 30% by mass, based on the total solid content of the composition.

[3] Compound (B) Capable of Generating Acid Upon Irradiation with an Actinic Ray or Radiation

The composition in the present invention also contains compound (B) capable of generating an acid upon irradiation with an actinic ray or radiation (hereinafter, also referred to as an “acid generator”). The acid generator may be in the form of a low-molecular compound, or in the form of being inserted into a portion of a polymer. In addition, the form of a low molecular compound and the form of being inserted into a portion of a polymer may be used in combination.

When the acid generator is in the form of a low molecular compound, the molecular weight is preferably 3,000 or less, more preferably 2,000 or less, and even more preferably 1,000 or less.

When the acid generator is in the form of being inserted into a portion of a polymer, the acid generator may be inserted into a portion of the above-described resin (P) to form resin (P), or may be inserted into a resin different from resin (P).

Here, the acid generator is preferably a resin different from (that is, not the same component as) resin (P) or resin (A), and more preferably a resin different from resin (P).

In the present invention, the acid generator is preferably in the form of a low molecular compound.

Compound (B) capable of generating an acid upon irradiation with an actinic ray or radiation is preferably a compound capable of generating an organic acid upon irradiation with an actinic ray or radiation.

The acid generator may be appropriately selected from a photo-initiator for cationic photopolymerization, a photo-initiator for radical photopolymerization, a photodecoloring agent for dyes, a photodiscoloring agent, or a publicly known compound capable of generating an acid upon irradiation with an actinic ray or radiation, which is used for microresist or the like, and a mixture thereof, and be used.

Examples thereof include a diazonium salt, a phosphonium salt, a sulfonium salt, an iodonium salt, imidosulfonate, oxime sulfonate, diazodisulfone, disulfone, and o-nitrobenzyl sulfonate.

Among the acid generators, examples of preferred compounds include compounds represented by the following Formulas (ZI), (ZII) and (ZIII).

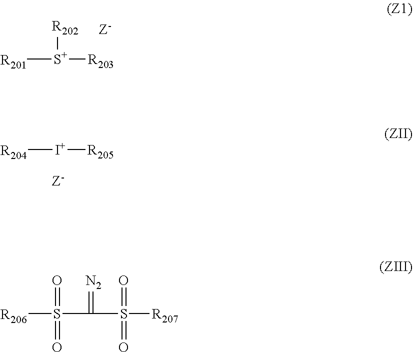

In Formula (ZI),

each of R₂₀₁, R₂₀₂ and R₂₀₃ independently represents an organic group. The carbon number of the organic group as R₂₀₁, R₂₀₂ and R₂₀₃ is generally 1 to 30, and preferably 1 to 20.

Furthermore, two of R₂₀₁ to R₂₀₃ may combine with each other to form a ring structure, and the ring may include an oxygen atom, a sulfur atom, an ester bond, an amide bond or a carbonyl group therein. Examples of the group formed by combining two of R₂₀₁ to R₂₀₃ include an alkylene group (for example, a butylene group and a pentylene group).

Z⁻ represents a non-nucleophilic anion.

Examples of the non-nucleophilic anion as Z⁻ include sulfonate anion, carboxylate anion, sulfonylimide anion, bis(alkylsulfonyl)imide anion, tris(alkylsulfonyl)methyl anion and the like.

The non-nucleophilic anion is an anion having an extremely low ability of causing a nucleophilic reaction and capable of suppressing the decomposition with time due to an intramolecular nucleophilic reaction. Accordingly, the stability of the resist composition with time is enhanced.

Examples of the sulfonate anion include an aliphatic sulfonate anion, an aromatic sulfonate anion, a camphorsulfonate anion and the like.

Examples of the carboxylate anion include an aliphatic carboxylate anion, an aromatic carboxylate anion, an aralkylcarboxylate anion and the like.

The aliphatic moiety in the aliphatic sulfonate anion and the aliphatic carboxylate anion may be an alkyl group or a cycloalkyl group and is preferably an alkyl group having 1 to 30 carbon atoms and a cycloalkyl group having 3 to 30 carbon atoms, and examples thereof include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, a bornyl group, and the like.

The aromatic group in the aromatic sulfonate anion and the aromatic carboxylate anion is preferably an aryl group having from 6 to 14 carbon atoms, and examples thereof include a phenyl group, a tolyl group, a naphthyl group, and the like.

The alkyl group, the cycloalkyl group and the aryl group in the aliphatic sulfonate anion and the aromatic sulfonate anion may have a substituent. Examples of the substituent of the alkyl group, the cycloalkyl group and the aryl group in the aliphatic sulfonate anion and the aromatic sulfonate anion include a nitro group, a halogen atom (a fluorine atom, a chlorine atom, a bromine atom and an iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), a cycloalkylalkyloxyalkyloxy group (preferably having 8 to 20 carbon atoms) and the like. Examples of the aryl group and the ring structure, which each group has, further include, as the substituent, an alkyl group (preferably having 1 to 15 carbon atoms) and a cycloalkyl group (preferably having 3 to 15 carbon atoms).

The aralkyl group in the aralkylcarboxylate anion is preferably an aralkyl group having 7 to 12 carbon atoms, and examples thereof include a benzyl group, a phenethyl group, a naphthylmethyl group, a naphthylethyl group, a naphthylbutyl group and the like.

The alkyl group, the cycloalkyl group, the aryl group and the aralkyl group in the aliphatic carboxylate anion, the aromatic carboxylate anion and the aralkylcarboxylate anion may have a substituent. Examples of the substituent include the halogen atom, the alkyl group, the cycloalkyl group, the alkoxy group, the alkylthio group and the like in the aromatic sulfonate anion.

Examples of the Sulfonylimide Anion Include Saccharin Anion.

The alkyl group in the bis(alkylsulfonyl)imide anion and the tris(alkylsulfonyl)methide anion is preferably an alkyl group having 1 to 5 carbon atoms, and examples thereof include a methyl group, an ethyl group, a propyl group, an isopropyl group, an n-butyl group, an isobutyl group, a sec-butyl group, a pentyl group, a neopentyl group and the like.

Two alkyl groups in the bis(alkylsulfonyl)imide anion may be linked to each other to form an alkylene group (preferably having 2 to 4 carbon atoms), and the alkylene group may combine with an imide group and two sulfonyl groups to form a ring. Examples of a substituent, which an alkylene group formed by linking two alkyl groups in the alkyl group and the bis(alkylsulfonyl)imide anion with each other may have, include a halogen atom, an alkyl group substituted with a halogen atom, an alkoxy group, an alkylthio group, an alkyloxysulfonyl group, an aryloxysulfonyl group, a cycloalkylaryloxysulfonyl group and the like, and an alkyl group substituted with a fluorine atom is preferred.

Examples of the other non-nucleophilic anions include fluorinated phosphate (for example, PF₆⁻), fluorinated boron (for example, BF₄⁻), fluorinated antimony (for example, SbF₆⁻) and the like.

The non-nucleophilic anion of Z⁻ is preferably an aliphatic sulfonate anion in which at least an α-position of sulfonic acid is substituted with a fluorine atom, an aromatic sulfonate anion substituted with a fluorine atom or a group having a fluorine atom, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion having 4 to 8 carbon atoms and a benzenesulfonate anion having a fluorine atom, and even more preferably a nonafluorobutanesulfonate anion, a perfluorooctanesulfonate anion, a pentafluorobenzenesulfonate anion and a 3,5-bis(trifluoromethyl)benzenesulfonate anion.

The acid generator is preferably a compound capable of generating an acid represented by the following Formula (V) or (VI) upon irradiation with an actinic ray or radiation. Since the acid generator is the compound capable of generating an acid represented by the following Formula (V) or (VI), the compound has a cyclic organic group, and thus the resolution and roughness performance may be more excellent.

The non-nucleophilic anion may be an anion capable of generating an organic acid represented by the following Formula (V) or (VI).

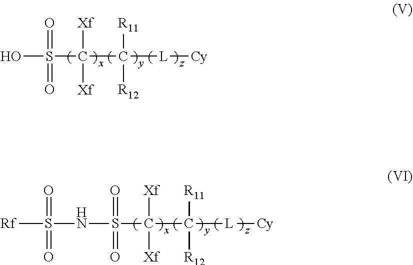

In the Formulas,

each Xf independently represents a fluorine atom or an alkyl group substituted with at least one fluorine atom.

Each of R₁₁ and R₁₂ independently represents a hydrogen atom, a fluorine atom or an alkyl group.

Each L independently represents a divalent linking group.

Cy represents a cyclic organic group.

Rf is a group including a fluorine atom.

x represents an integer of 1 to 20.

y represents an integer of 0 to 10.

z represents an integer of 0 to 10.

Xf represents a fluorine atom or an alkyl group substituted with at least one fluorine atom. The carbon number of the alkyl group is preferably 1 to 10, and more preferably 1 to 4. Further, the alkyl group substituted with at least one fluorine atom is preferably a perfluoroalkyl group.

Xf is preferably a fluorine atom or a perfluoroalkyl group having 1 to 4 carbon atoms. More specifically, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉, and more preferably a fluorine atom or CF₃. In particular, it is preferred that both Xfs are a fluorine atom.

Each of R₁₁ and R₁₂ independently represents a hydrogen atom, a fluorine atom or an alkyl group. The alkyl group may have a substituent (preferably a fluorine atom) and preferably has 1 to 4 carbon atoms. The alkyl group is more preferably a perfluoroalkyl group having 1 to 4 carbon atoms. Specific examples of the alkyl group having a substituent of R₁₁ and R₁₂ include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉, and among them, CF₃ is preferred.

L represents a divalent linking group. Examples of the divalent linking group include —COO—, —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms) or a divalent linking group formed by combining a plurality of these groups, and the like. Among them, —COO—, —OCO—, —CONH—, —NHCO—, —CO—, —O—, —SO₂—, —COO-an alkylene group-, —OCO-an alkylene group-, —CONH-an alkylene group- or —NHCO-an alkylene group- is preferred, and —COO—, —OCO—, —CONH—, —SO₂—, —COO-an alkylene group- or —OCO-an alkylene group- is more preferred.

Cy represents a cyclic organic group. Examples of the cyclic organic group include an alicyclic group, an aryl group and a heterocyclic group.

The alicyclic group may be monocyclic or polycyclic. Examples of the monocyclic alicyclic group include a monocyclic cycloalkyl group such as a cyclopentyl group, a cylohexyl group and a cyclooctyl group. Examples of the polycyclic alicyclic group include a polycyclic cycloalkyl group such as a norbornyl group, a tricyclodecanyl group, a tetracyclodecanyl group, a tetracyclododecanyl group and an adamantyl group. Among them, an alicyclic group with a bulky structure having 7 or more carbon atoms, such as a norbornyl group, a tricyclodecanyl group, a tetracyclodecanyl group, a tetracyclododecanyl group and an adamantyl group, is preferred from the viewpoint of restraining diffusion in film during a PEB (post-exposure baking) process and enhancing the MEEF (mask error enhancement factor).

The aryl group may be monocyclic or polycyclic. Examples of the aryl group include a phenyl group, a naphthyl group, a phenanthryl group and an anthryl group. Among them, a naphthyl group having relatively low light absorbance at 193 nm is preferred.

The heterocyclic group may be monocyclic or polycyclic, but a polycyclic heterocyclic group may further suppress the diffusion of an acid. In addition, the heterocyclic group may have aromaticity or may not have aromaticity. Examples of the heterocyclic ring having aromaticity include a furan ring, a thiophene ring, a benzofuran ring, a benzothiophene ring, a dibenzofuran ring, a dibenzothiophene ring and a pyridine ring. Examples of the heterocyclic ring having no aromaticity include a tetrahydropyran ring, a lactone ring, a sultone ring and a decahydroisoquinoline ring. The heterocyclic ring in the heterocyclic group is particularly preferably a furan ring, a thiophene ring, a pyridine ring or a decahydroisoquinoline ring. Furthermore, examples of the lactone ring or the sultone ring include the above-described lactone structure or a sultone structure exemplified in resin (A).

The cyclic organic group may have a substituent. Examples of the substituent include an alkyl group (may be straight chained or branched, and preferably has 1 to 12 carbon atoms), a cycloalkyl group (may be monocyclic, polycyclic or spirocyclic, and preferably has 3 to 20 carbon atoms), an aryl group (preferably has 6 to 14 carbon atoms), a hydroxyl group, an alkoxy group, an ester group, an amide group, a urethane group, a ureido group, a thioether group, a sulfonamide group and a sulfonic acid ester group. Meanwhile, the carbon constituting the cyclic organic group (the carbon contributing to ring formation) may be carbonyl carbon.

x is preferably 1 to 8, and among them, preferably 1 to 4, and particularly preferably 1. y is preferably 0 to 4, and more preferably 0. z is preferably 0 to 8, and among them, preferably 0 to 4.

Examples of the group having a fluorine atom, which is represented by Rf, include an alkyl group having at least one fluorine atom, a cycloalkyl group having at least one fluorine atom, and an aryl group having at least one fluorine atom.

The alkyl group, the cycloalkyl group and the aryl group may be substituted with a fluorine atom, or may be substituted with another substituent including a fluorine atom. When Rf is a cycloalkyl group having at least one fluorine atom or an aryl group having at least one fluorine atom, examples of the another substituent including a fluorine atom include an alkyl group substituted with at least one fluorine atom.

Further, the alkyl group, the cycloalkyl group and the aryl group may be further substituted with a substituent including no fluorine atom. Examples of the substituent include those including no fluorine atom among those for Cy described above.

Examples of the alkyl group having at least one fluorine atom, which is represented by Rf, include the same as those described above as the alkyl group substituted with at least one fluorine atom, which is represented by Xf. Examples of the cycloalkyl group having at least one fluorine atom, which is represented by Rf, include a perfluorocyclopentyl group and a perfluorocyclohexyl group. Examples of the aryl group having at least one fluorine atom, which is represented by Rf, include a perfluorophenyl group.

In addition, the non-nucleophilic anion is also preferably an anion represented by any one of the following Formulas (B-1) to (B-3).

First, an anion represented by the following Formula (B-1) will be described.

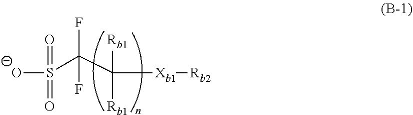

In the Formula (B-1),

each R_{b1} independently represents a hydrogen atom, a fluorine atom or a trifluoromethyl group (CF₃).

n represents an integer of 1 to 4.

n is preferably an integer of 1 to 3, and more preferably 1 or 2.

X_{b1} represents a single bond, an ether bond, an ester bond (—OCO— or —COO—), or a sulfonic acid ester bond (—OSO₂— or —SO₃—).

X_{b1} is preferably an ester bond (—OCO— or —COO—), or a sulfonic acid ester bond (—OSO₂— or —SO₃—).

R_{b2} represents a substituent having 6 or more carbon atoms.

The substituent having 6 or more carbon atoms for R_{b2} is preferably a bulky substituent, and examples thereof include an alkyl group, an alicyclic group, an aryl group, a heterocyclic group and the like, which have 6 or more carbon atoms.

The alkyl group having 6 or more carbon atoms for R_{b2} may be straight chained or branched and is preferably a straight chained or branched alkyl group having 6 to 20 carbon atoms, and examples thereof include a straight chained or branched hexyl group, a straight chained or branched heptyl group, a straight chained or branched octyl group, and the like. From the viewpoint of being bulky, the branched alkyl group is preferred.

The alicyclic group having 6 or more carbon atoms for R_{b2} may be monocyclic or polycyclic. Examples of the monocyclic alicyclic group include a monocyclic cycloalkyl group such as a cylohexyl group and a cyclooctyl group. Examples of the polycyclic alicyclic group include a polycyclic cycloalkyl group such as a norbornyl group, a tricyclodecanyl group, a tetracyclodecanyl group, a tetracyclododecanyl group and an adamantyl group. Among them, an alicyclic group with a bulky structure having 7 or more carbon atoms, such as a norbornyl group, a tricyclodecanyl group, a tetracyclodecanyl group, a tetracyclododecanyl group and an adamantyl group, is preferred from the viewpoint of restraining diffusion in the film during a PEB (post-exposure baking) process and enhancing the MEEF (mask error enhancement factor).

The aryl group having 6 or more carbon atoms for R_{b2} may be monocyclic or polycyclic. Examples of the aryl group include a phenyl group, a naphthyl group, a phenanthryl group and an anthryl group. Among them, a naphthyl group having relatively low light absorbance at 193 nm is preferred.

The heterocyclic group having 6 or more carbons for R_{b2} may be monocyclic or polycyclic, but a polycyclic heterocyclic group may further suppress the diffusion of an acid. Furthermore, the heterocyclic group may have aromaticity or may not have aromaticity. Examples of the heterocyclic ring having aromaticity include a benzofuran ring, a benzothiophene ring, a dibenzofuran ring and a dibenzothiophene ring. Examples of the heterocyclic ring having no aromaticity include a tetrahydropyran ring, a lactone ring and a decahydroisoquinoline ring. The heterocyclic ring in the heterocyclic group is particularly preferably a benzofuran ring or a decahydroisoquinoline ring. Further, examples of the lactone ring include the above-described lactone structure exemplified in resin (P).

The substituent having 6 or more carbon atoms for R_{b2} may further have a substituent. Examples of the substituent further having a substituent include an alkyl group (may be straight chained or branched, and preferably has 1 to 12 carbon atoms), a cycloalkyl group (may be any one of monocyclic, polycyclic or spirocyclic, and preferably has 3 to 20 carbon atoms), an aryl group (preferably has 6 to 14 carbon atoms), a hydroxyl group, an alkoxy group, an ester group, an amide group, a urethane group, a ureido group, a thioether group, a sulfonamide group and a sulfonic acid ester group. Meanwhile, the carbon constituting the above-described alicyclic group, aryl group or heterocyclic group (the carbon contributing to ring formation) may be carbonyl carbon.

Subsequently, an anion represented by the following Formula (B-2) will be described.

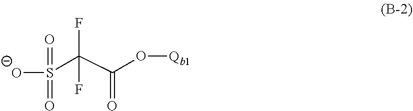

In the Formula (B-2),

Q_{b1} represents a group having a lactone structure, a group having a sultone structure or a group having a cyclic carbonate structure.

Examples of the lactone structure and the sultone structure for Q_{b1} include the lactone structure and the sultone structure in the repeating unit having the lactone structure and the sultone structure, which are previously described in the paragraph of resin (P). Specifically, examples thereof include the lactone structure represented by any one of Formulas (LC1-1) to (LC1-17), or the sultone structure represented by any one of Formulas (SL1-1) to (SL1-3).

The lactone structure or the sultone structure may be directly bonded to an oxygen atom of the ester group in Formula (B-2), but the lactone structure or the sultone structure may be bonded to an oxygen atom of an ester group through an alkylene group (for example, a methylene group and an ethylene group). In that case, a group having the lactone structure or the sultone structure may be an alkyl group having the lactone structure or the sultone structure as a substituent.

The cyclic carbonate structure for Q_{b1} is preferably a 5- to 7-membered cyclic carbonate structure, and examples thereof include 1,3-dioxolane-2-one, 1,3-dioxane-2-one and the like.

The cyclic carbonate structure may be directly bonded to an oxygen atom of the ester group in Formula (B-2), but the cyclic carbonate structure may be bonded to an oxygen atom of an ester group through an alkylene group (for example, a methylene group and an ethylene group). In that case, a group having the cyclic carbonate structure may be an alkyl group having a cyclic carbonate structure as a substituent.

Subsequently, an anion represented by the following Formula (B-3) will be described.

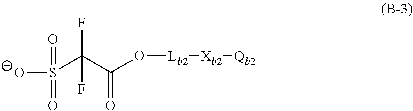

In the Formula (B-3),

L_{b2} represents an alkylene group having 1 to 6 carbon atoms, examples thereof include a methylene group, an ethylene group, a propylene group, a butylene group and the like, and an alkylene having 1 to 4 carbon atoms is preferred.

X_{b2} represents an ether bond or an ester bond (—OCO— or —COO—).

Q_{b2} represents an alicyclic group or a group containing an aromatic ring.

The alicyclic group for Q_{b2} may be monocyclic or polycyclic. Examples of the monocyclic alicyclic group include a monocyclic cycloalkyl group such as a cyclopentyl group, a cylohexyl group and a cyclooctyl group. Examples of the polycyclic alicyclic group include a polycyclic cycloalkyl group such as a norbornyl group, a tricyclodecanyl group, a tetracyclodecanyl group, a tetracyclododecanyl group and an adamantyl group. Among them, an alicyclic group with a bulky structure having 7 or more carbon atoms, such as a norbornyl group, a tricyclodecanyl group, a tetracyclodecanyl group, a tetracyclododecanyl group, and an adamantyl group, is preferred.

The aromatic ring in the group containing an aromatic ring for Q_{b2} is preferably an aromatic ring having 6 to 20 carbon atoms, examples thereof include a benzene ring, a naphthalene ring, a phenanthrene ring, an anthracene ring and the like, and among them, a benzene ring or a naphthalene ring is more preferred. The aromatic ring may be substituted with at least one fluorine atom, and examples of the aromatic ring substituted with at least one fluorine atom include a perfluorophenyl group and the like.

The aromatic ring may be directly bonded to X_{b2}, but may be bonded to X_{b2} through an alkylene group (for example, a methylene group and an ethylene group). In that case, a group containing the aromatic ring may be an alkyl group having the aromatic ring as a substituent.

Examples of the organic group represented by R₂₀₁, R₂₀₂ and R₂₀₃ include corresponding groups in the compounds (ZI-1), (ZI-2), (ZI-3) and (ZI-4) to be described below.

Meanwhile, a compound having a plurality of structures represented by Formula (ZI) may be used. For example, it is possible to use a compound having a structure in which at least one of R₂₀₁ to R₂₀₃ in a compound represented by Formula (ZI) is bonded to at least one of R₂₀₁ to R₂₀₃ in another compound represented by Formula (ZI) through a single bond or a linking group.

In addition, examples of a preferred (ZI) component include compounds (ZI-1), (ZI-2), (ZI-3) and (ZI-4) to be described below.

Compound (ZI-1) is an arylsulfonium compound in which at least one of R₂₀₁ to R₂₀₃ in Formula (ZI) is an aryl group, that is, a compound having arylsulfonium as a cation.

In the arylsulfonium compound, all of R₂₀₁ to R₂₀₃ may be an aryl group or a part of R₂₀₁ to R₂₀₃ may be an aryl group, with the remaining being an alkyl group or a cycloalkyl group.

Examples of the arylsulfonium compound include a triarylsulfonium compound, a diarylalkylsulfonium compound, an aryldialkylsulfonium compound, a diarylcycloalkylsulfonium compound and an aryldicycloalkylsulfonium compound.

The aryl group in the arylsulfonium compound is preferably a phenyl group and a naphthyl group, and more preferably a phenyl group. The aryl group may be an aryl group having a heterocyclic structure having an oxygen atom, a nitrogen atom, a sulfur atom and the like. Examples of the heterocyclic structure include a pyrrole residue, a furan residue, a thiophene residue, an indole residue, a benzofuran residue, a benzothiophene residue and the like. When the arylsulfonium compound has two or more aryl groups, each aryl group may be the same as or different from each other aryl group.

The alkyl group or the cycloalkyl group, which the arylsulfonium compound has, if necessary, is preferably a straight chained or branched alkyl group having 1 to 15 carbon atoms and a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, a cyclohexyl group and the like.

The aryl group, the alkyl group and the cycloalkyl group of R₂₀₁ to R₂₀₃ may have, as a substituent, an alkyl group (for example, having from 1 to 15 carbon atoms), a cycloalkyl group (for example, having from 3 to 15 carbon atoms), an aryl group (for example, having from 6 to 14 carbon atoms), an alkoxy group (for example, having from 1 to 15 carbon atoms), a halogen atom, a hydroxyl group or a phenylthio group. The substituent is preferably a straight chained or branched alkyl group having 1 to 12 carbon atoms, a cycloalkyl group having 3 to 12 carbon atoms, and a straight chained, branched or cyclic alkoxy group having 1 to 12 carbon atoms, and more preferably an alkyl group having 1 to 4 carbon atoms and an alkoxy group having 1 to 4 carbon atoms. The substituent may be substituted with any one of three R₂₀₁ to R₂₀₃ or may be substituted with all of the three. Furthermore, when R₂₀₁ to R₂₀₃ are an aryl group, the substituent is preferably substituted at the p-position of the aryl group.

Subsequently, compound (ZI-2) will be described.

Compound (ZI-2) is a compound represented by the following Formula (ZI-2). That is, compound (ZI-2) is a compound in which each of R₂₀₁ to R₂₀₃ in Formula (ZI) independently represents an organic group having no aromatic ring. Here, the aromatic ring also includes an aromatic ring containing a heteroatom.

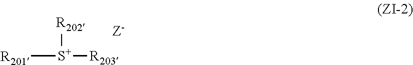

In Formula (ZI-2),

each of R₂₀₁′ to R₂₀₃′ independently represents an organic group having no aromatic ring.

Z⁻ represents a non-nucleophilic anion.

The organic group containing no aromatic ring as R₂₀₁′ to R₂₀₃′ has generally 1 to 30 carbon atoms, and preferably 1 to 20 carbon atoms.

Each of R₂₀₁′ to R₂₀₃′ independently represents preferably an alkyl group, a cycloalkyl group, an allyl group or a vinyl group, more preferably a straight chained or branched 2-oxoalkyl group, a 2-oxocycloalkyl group and an alkoxycarbonylmethyl group, and particularly preferably a straight chained or branched 2-oxoalkyl group.

Preferred examples of the alkyl group and the cycloalkyl group of R₂₀₁′ to R₂₀₃′ include a straight chained or branched alkyl group having 1 to 10 carbon atoms (for example, a methyl group, an ethyl group, a propyl group, a butyl group and a pentyl group) and a cycloalkyl group having 3 to 10 carbon atoms (a cyclopentyl group, a cyclohexyl group and a norbornyl group). More preferred examples of the alkyl group include a 2-oxoalkyl group and an alkoxycarbonylmethyl group. More preferred examples of the cycloalkyl group include a 2-oxocycloalkyl group.

The 2-oxoalkyl group may be either straight chained or branched, and preferred examples thereof include a group having >C═O at the 2-position of the aforementioned alkyl group.

Preferred examples of the 2-oxocycloalkyl group include a group having >C═O at the 2-position of the aforementioned cycloalkyl group.

Preferred examples of the alkoxy group in the alkoxycarbonylmethyl group include an alkoxy group having 1 to 5 carbon atoms (a methoxy group, an ethoxy group, a propoxy group, a butoxy group and a pentoxy group).

R₂₀₁′ to R₂₀₃′ may be further substituted with a halogen atom, an alkoxy group (for example, having 1 to 5 carbon atoms), a hydroxyl group, a cyano group or a nitro group.

Subsequently, compound (ZI-3) will be described.

Compound (ZI-3) is a compound represented by the following Formula (ZI-3), and a compound having a phenacylsulfonium salt structure.

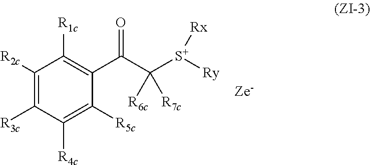

In Formula (ZI-3),

each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Each of R_{6c} and R_{7c} independently represents a hydrogen atom, an alkyl group, a cycloalkyl group, a halogen atom, a cyano group or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group or a vinyl group.

Any two or more of R₁ₑ to R_{5c}, R_{5c} and R_{6c}, R_{6c} and R_{7c}, R_{5c} and Rₓ, and Rₓ and R_{y} may combine with each other to form a ring structure, respectively, and the ring structure may include an oxygen atom, a sulfur atom, a ketone group, an ester bond and an amide bond.

Examples of the ring structure includes an aromatic or non-aromatic hydrocarbon ring, an aromatic or non-aromatic heterocyclic ring, or a polycyclic condensed ring formed by combining two or more of these rings. The ring structure includes a 3- to 10-membered ring and is preferably a 4- to 8-membered ring, and more preferably a 5- or 6-membered ring.

Examples of the group formed by combining any two or more of R_{1c} to R_{5c}, R_{6c} and R_{7c}, and Rₓ and R_{y} include a butylene group, a pentylene group and the like.

The group formed by combining R_{5c} and R_{6c} and R_{5c} and Rₓ is preferably a single bond or an alkylene group, and examples of the alkylene group include a methylene group, an ethylene group and the like.

Zc⁻ represents a non-nucleophilic anion, and examples thereof include the non-nucleophilic anion which is the same as Z⁻ in Formula (ZI).

The alkyl group as R_{1c} to R_{7c} may be either straight chained or branched, examples thereof include an alkyl group having 1 to 20 carbon atoms, and preferably a straight chained or branched alkyl group having 1 to 12 carbon atoms (for example, a methyl group, an ethyl group, a straight chained or branched propyl group, a straight chained or branched butyl group and a straight chained or branched pentyl group), and examples of the cycloalkyl group include a cycloalkyl group having 3 to 10 carbon atoms (for example, a cyclopentyl group and a cyclohexyl group).

The aryl group as R_{1c} to R_{5c} is preferably an aryl group having 5 to 15 carbon atoms, and examples thereof include a phenyl group and a naphthyl group.

The alkoxy group as R_{1c} to R_{5c} may be straight chained, branched or cyclic and examples thereof include an alkoxy group having 1 to 10 carbon atoms, preferably a straight chained or branched alkoxy group having 1 to 5 carbon atoms (for example, a methoxy group, an ethoxy group, a straight chained or branched propoxy group, a straight chained or branched butoxy group, and a straight chained or branched pentoxy group), and a cyclic alkoxy group having 3 to 10 carbon atoms (for example, a cyclopentyloxy group and a cyclohexyloxy group).

Specific examples of the alkoxy group in the alkoxycarbonyl group as R_{1c} to R_{5c} are the same as the specific examples of the alkoxy group as R_{1c} to R_{5c}.

Specific examples of the alkyl group in the alkylcarbonyloxy group and the alkylthio group as R_{1c} to R_{5c} are the same as the specific examples of the alkyl group as R_{1c} to R_{5c}.

Specific examples of the cycloalkyl group in the cycloalkylcarbonyloxy group as R_{1c} to R_{5c} are the same as the specific examples of the cycloalkyl group as R_{1c} to R_{5c}.

Specific examples of the aryl group in the aryloxy group and the arylthio group as R_{1c} to R_{5c} are the same as the specific examples of the aryl group as R_{1c} to R_{5c}.

Any one of R_{1c} to R_{5c} is preferably a straight chained or branched alkyl group, a cycloalkyl group, or a straight chained, branched or cyclic alkoxy group, and the sum of carbon numbers of R_{1c} to R_{5c} is more preferably from 2 to 15. Accordingly, the solvent solubility is more enhanced, and thus, generation of particles during storage is suppressed.

Examples of the ring structure which may be formed by combining any two or more of R_{1c} to R_{5c} with each other include preferably a 5- or 6-membered ring, and particularly preferably a 6-membered ring (for example, a phenyl ring).

Examples of the ring structure which may be formed by combining R_{5c} and R_{6c} with each other include a 4-membered or greater ring (particularly preferably a 5- or 6-membered ring) formed together with the carbonyl carbon atom and the carbon atom in Formula (I) by combining R_{5c} and R_{6c} with each other to constitute a single bond or an alkylene group (a methylene group, an ethylene group or the like).

The aryl group as R_{6c} to R_{7c} preferably has 5 to 15 carbon atoms, and examples thereof include a phenyl group and a naphthyl group.

An aspect in which both R_{6c} and R_{7c} are an alkyl group is preferred. In particular, an aspect in which each of R_{6c} and R_{7c} is a straight chained or branched alkyl group having 1 to 4 carbon atoms is preferred, and an aspect in which both are a methyl group is particularly preferred.

Furthermore, when R_{6c} and R_{7c} are combined with each other to form a ring, the group formed by combining R_{6c} and R_{7c} is preferably an alkylene group having 2 to 10 carbon atoms, and examples thereof include an ethylene group, a propylene group, a butylene group, a pentylene group, a hexylene group and the like. Further, the ring formed by combining R_{6c} and R_{7c} may have a heteroatom such as oxygen atom in the ring.

Examples of the alkyl group and the cycloalkyl group as Rₓ and R_{y} include the alkyl group and the cycloalkyl group in R_{1c} to R_{7c}.

Examples of the 2-oxoalkyl group and the 2-oxocycloalkyl group as Rₓ and R_{y} include a group having >C═O at the 2-position of the alkyl group and the cycloalkyl group as R_{1c} to R_{7c}.

Examples of the alkoxy group in the alkoxycarbonylalkyl group as Rₓ and R_{y} include the alkoxy group in R_{1c} to R_{5c}, and examples of the alkyl group include an alkyl group having 1 to 12 carbon atoms, and preferably a straight chained alkyl group having 1 to 5 carbon atoms (for example, a methyl group and an ethyl group).

The allyl group as Rₓ and R_{y} is not particularly limited, but is preferably an unsubstituted allyl group, or an allyl group substituted with a monocyclic or polycyclic cycloalkyl group (preferably a cycloalkyl group having from 3 to 10 carbon atoms).

The vinyl group as Rₓ and R_{y} is not particularly limited, but is preferably an unsubstituted vinyl group, or a vinyl group substituted with a monocyclic or polycyclic cycloalkyl group (preferably a cycloalkyl group having 3 to 10 carbon atoms).

Examples of the ring structure which may be formed by combining R_{5c} and Rₓ with each other include a 5-membered or greater membered ring (particularly preferably a 5-membered ring) formed together with a sulfur atom and a carbonyl carbon atom in Formula (I) by combining R_{5c} and Rₓ with each other to constitute a single bond or an alkylene group (a methylene group, an ethylene group and the like).

Examples of the ring structure which may be formed by combining Rₓ and R_{y} with each other include a 5- or 6-membered ring, particularly preferably a 5-membered ring (that is, a tetrahydrothiophene ring), which is formed together with a sulfur atom in Formula (ZI-3) by divalent Rₓ and R_{y} (for example, a methylene group, an ethylene group, a propylene group and the like).

Each of Rₓ and R_{y} is an alkyl group or a cycloalkyl group having preferably 4 or more carbon atoms, more preferably 6 or more carbon atoms, and even more preferably 8 or more carbon atoms.

Each of R_{1c} to R_{7c} and Rₓ and R_{y} may further have a substituent, and examples of the substituent include a halogen atom (for example, a fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, an aryloxycarbonyloxy group and the like.

In Formula (ZI-3), it is more preferred that each of R_{1c}, R_{2c}, R_{4c} and R_{5c} independently represents a hydrogen atom and R_{ic} represents a group other than a hydrogen atom, that is, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

A cation of the compound represented by Formula (ZI-2) or (ZI-3) in the present invention includes the following specific examples.

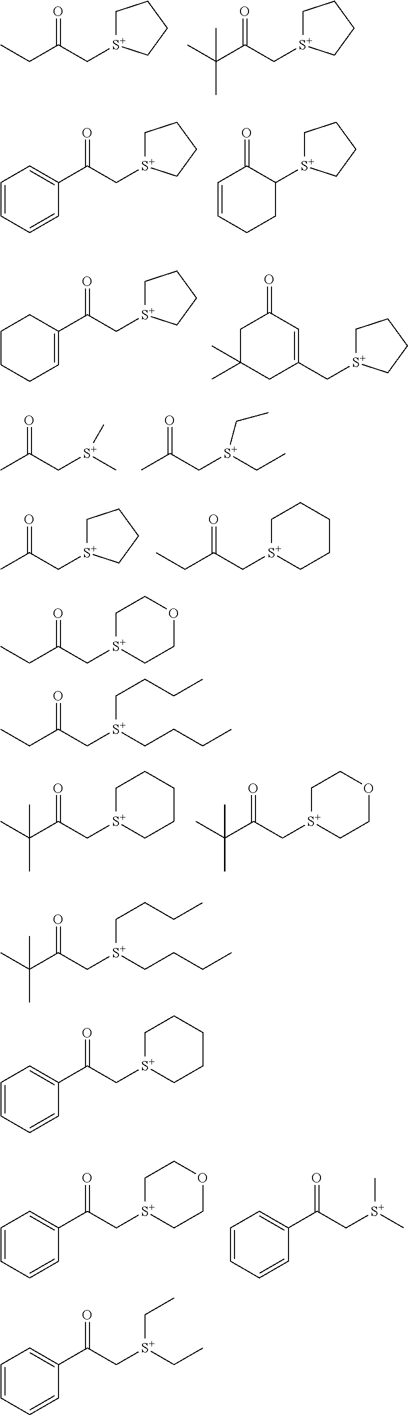

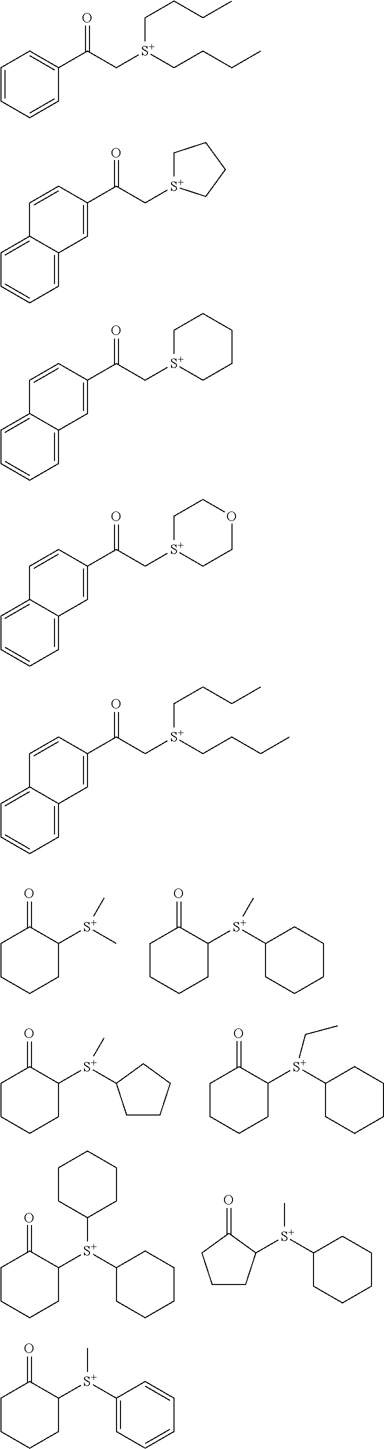

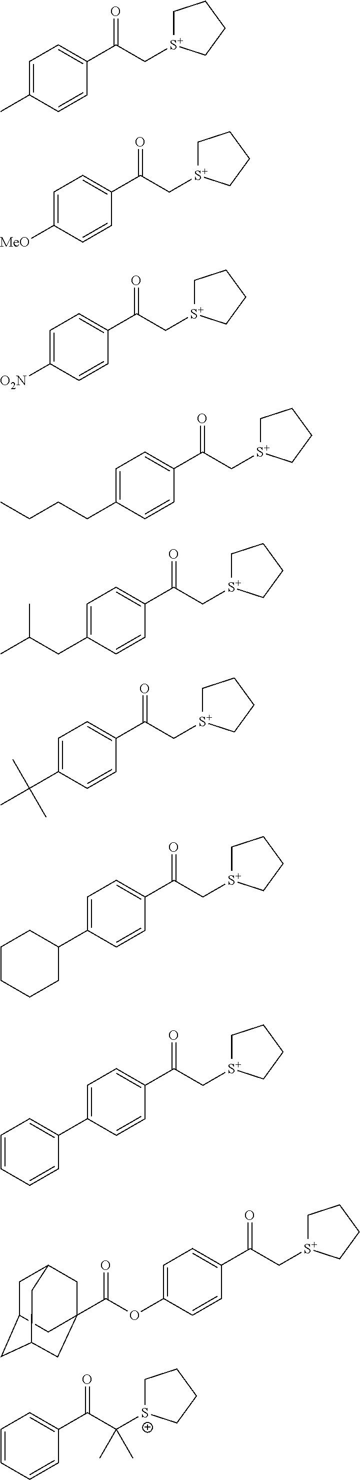

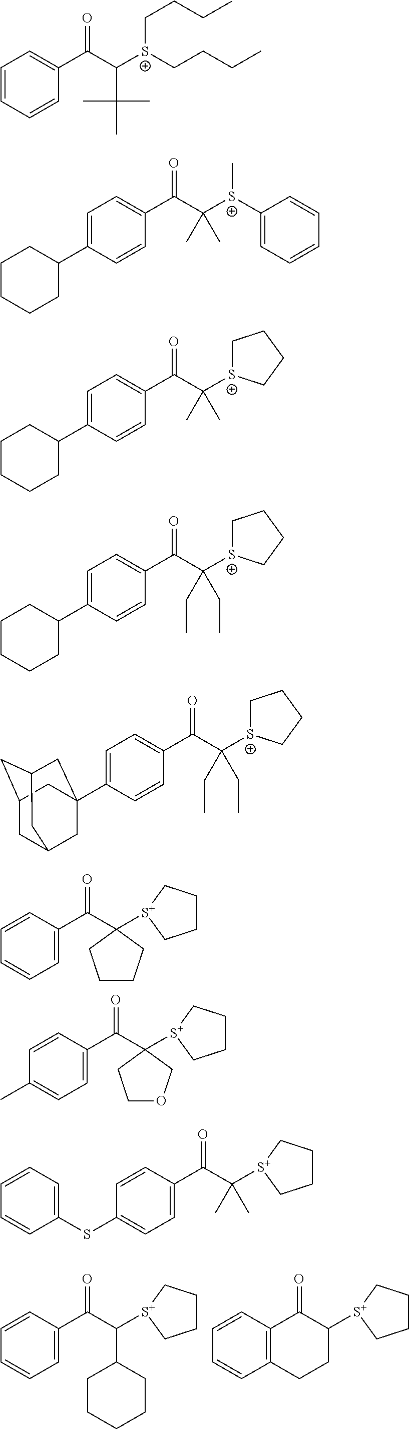

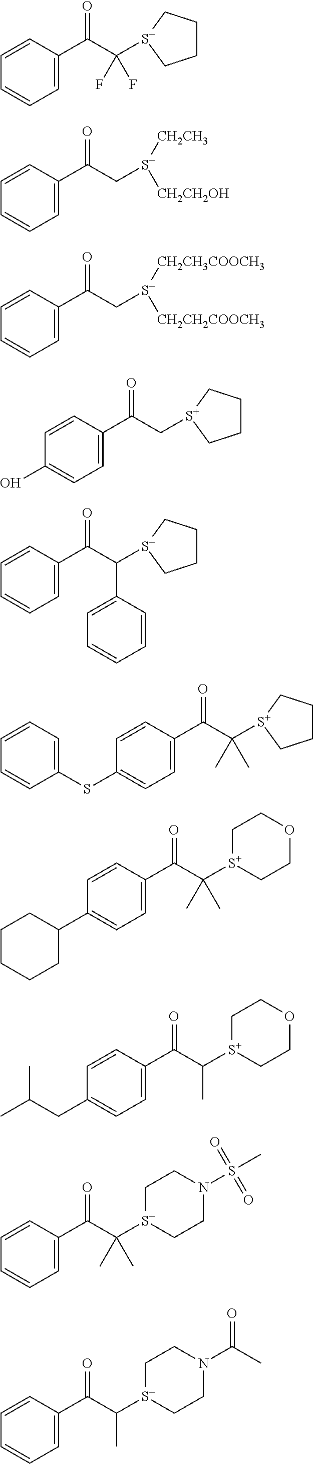

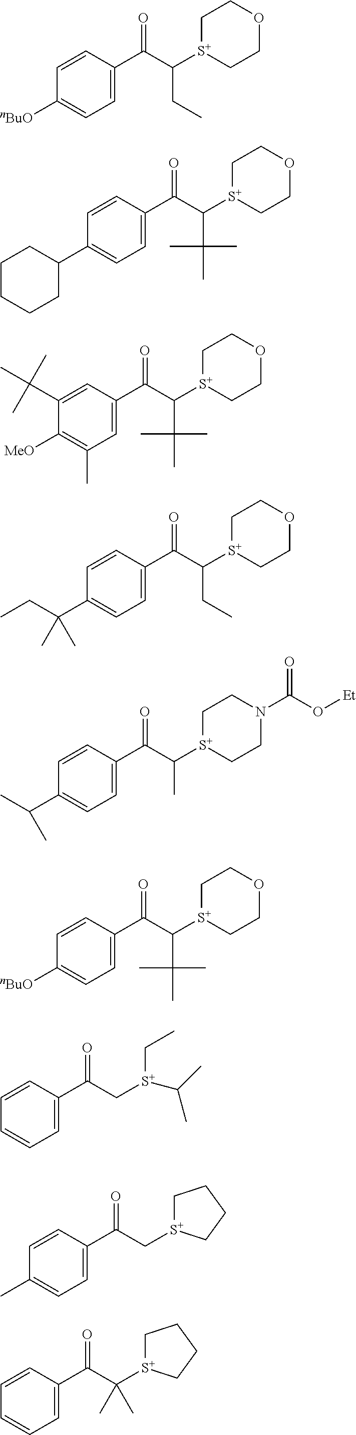

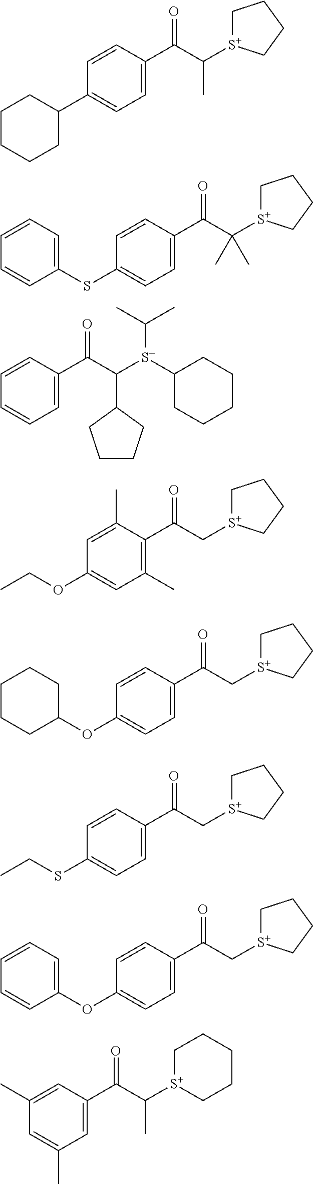

Subsequently, compound (ZI-4) will be described.

Compound (ZI-4) is represented by the following Formula (ZI-4).

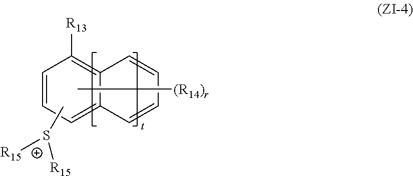

In Formula (ZI-4),

R₁₃ represents a hydrogen atom, a fluorine atom, a hydroxyl group, an alkyl group, a cycloalkyl group, an alkoxy group, an alkoxycarbonyl group or a group having a cycloalkyl group. These groups may have a substituent.

When a plurality of R₁₄ is present, each R₁₄ independently represents a hydroxyl group, an alkyl group, a cycloalkyl group, an alkoxy group, an alkoxycarbonyl group, an alkylcarbonyl group, an alkylsulfonyl group, a cycloalkylsulfonyl group or a group having a cycloalkyl group. These groups may have a substituent.

Each R₁₅ independently represents an alkyl group, a cycloalkyl group or a naphthyl group. Two of R₁₅ may combine with each other to form a ring. These groups may have a substituent.

1 represents an integer of 0 to 2.

r represents an integer of 0 to 8.

Z⁻ represents a non-nucleophilic anion, and examples thereof include the non-nucleophilic anion such as Z⁻ in Formula (ZI).

In Formula (ZI-4), the alkyl group of R₁₃, R₁₄ and R₁₅ is preferably a straight chained or branched alkyl group having 1 to 10 carbon atoms, and preferred examples thereof include a methyl group, an ethyl group, an n-butyl group, a t-butyl group and the like.

Examples of the cycloalkyl group of R₁₃, R₁₄ and R₁₅ include a monocyclic or polycyclic cycloalkyl group (preferably a cycloalkyl group having 3 to 20 carbon atoms), and cyclopropyl, cyclopentyl, cyclohexyl, cycloheptyl and cyclooctyl are particularly preferred.

The alkoxy group of R₁₃ and R₁₄ is preferably a straight chained or branched alkoxy group having 1 to 10 carbon atoms, and preferred examples thereof include a methoxy group, an ethoxy group, an n-propoxy group, an n-butoxy group and the like.

The alkoxycarbonyl group of R₁₃ and R₁₄ is preferably a straight chained or branched alkoxycarbonyl group having from 2 to 11 carbon atoms, and preferred examples thereof include a methoxycarbonyl group, an ethoxycarbonyl group, an n-butoxycarbonyl group and the like.

Examples of the group having a cycloalkyl group of R₁₃ and R₁₄ include a monocyclic or polycyclic cycloalkyl group (preferably a cycloalkyl group having 3 to 20 carbon atoms), and examples thereof include a monocyclic or polycyclic cycloalkyloxy group and an alkoxy group having a monocyclic or polycyclic cycloalkyl group. These groups may further have a substituent.

The monocyclic or polycyclic cycloalkyloxy group of R₁₃ and R₁₄ has a total carbon number of preferably 7 or more, and more preferably 7 to 15, and preferably has a monocyclic cycloalkyl group. The monocyclic cycloalkyloxy group having a total carbon number of 7 or more represents a monocyclic cycloalkyloxy group in which a cycloalkyloxy group such as a cyclopropyloxy group, a cyclobutyloxy group, a cyclopentyloxy group, a cyclohexyloxy group, a cycloheptyloxy group, a cyclooctyloxy group, and a cyclododecanyloxy group arbitrarily having a substituent such as an alkyl group such as a methyl group, an ethyl group, a propyl group, a butyl group, a pentyl group, a hexyl group, a heptyl group, an octyl group, a dodecyl group, a 2-ethylhexyl group, an isopropyl group, a sec-butyl group, a t-butyl group, and an iso-amyl group, a hydroxyl group, halogen atom (fluorine, chlorine, bromine and iodine), a nitro group, a cyano group, an amide group, a sulfonamide group, an alkoxy group such as a methoxy group, an ethoxy group, a hydroxyethoxy group, a propoxy group, a hydroxypropoxy group, and a butoxy group, an alkoxycarbonyl group such as a methoxycarbonyl group, and an ethoxycarbonyl group, an acyl group such as a formyl group, an acetyl group, and a benzoyl group, an acyloxy group such as an acetoxy group, and a butyryloxy group, and a carboxyl group, and in which the total carbon number inclusive of the carbon number of an arbitrary substituent on the cycloalkyl group is 7 or more.

In addition, examples of the polycyclic cycloalkyloxy group having a total carbon number of 7 or more include a norbornyloxy group, a tricyclodecanyloxy group, a tetracyclodecanyloxy group, an adamantyloxy group and the like.

The alkoxy group having a monocyclic or polycyclic cycloalkyl group of R₁₃ and R₁₄ has preferably a total carbon number of 7 or more, and more preferably a total carbon number from 7 to 15, and is preferably an alkoxy group having a monocyclic cycloalkyl group. The alkoxy group having a total carbon number of 7 or more and having a monocyclic cycloalkyl group represents an alkoxy group in which an alkoxy group such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy and iso-amyloxy is substituted with the above-described monocyclic cycloalkyl group which may have a substituent, and in which the total carbon number inclusive of the carbon number of the substituent is 7 or more. Examples thereof include a cyclohexylmethoxy group, a cyclopentylethoxy group, a cyclohexylethoxy group and the like, and a cyclohexylmethoxy group is preferred.

Furthermore, examples of the alkoxy group having a total carbon number of 7 or more and having a polycyclic cycloalkyl group include a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, an adamantylethoxy group and the like, and a norbornylmethoxy group, a norbornylethoxy group and the like are preferred.

Specific examples of the alkyl group in the alkylcarbonyl group of R₁₄ include those of the above-described alkyl group as R₁₃ to R₁₅.

The alkylsulfonyl group and the cycloalkylsulfonyl group of R₁₄ are preferably straight chained, branched or cyclic and have 1 to 10 carbon atoms, and preferred examples thereof include a methanesulfonyl group, an ethanesulfonyl group, an n-propanesulfonyl group, an n-butanesulfonyl group, a cyclopentanesulfonyl group, a cyclohexanesulfonyl group and the like.

Examples of the substituent which each of the groups may have include a halogen atom (for example, a fluorine atom), a hydroxyl group, a carboxyl group, a cyano group, a nitro group, an alkoxy group, an alkoxyalkyl group, an alkoxycarbonyl group, an alkoxycarbonyloxy group and the like.

Examples of the alkoxy group include a straight chained, branched or cyclic alkoxy group having 1 to 20 carbon atoms, and the like, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group and a cyclohexyloxy group.

Examples of the alkoxyalkyl group include a straight chained, branched or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group, a 2-ethoxyethyl group and the like.

Examples of the alkoxycarbonyl group include a straight chained, branched or cyclic alkoxycarbonyl group having 2 to 21 carbon atoms and the like, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group and a cyclohexyloxycarbonyl group.

Examples of the alkoxycarbonyloxy group include a straight chained, branched or cyclic alkoxycarbonyloxy group having 2 to 21 carbon atoms, and the like, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group and a cyclohexyloxycarbonyloxy group.

Examples of the ring structure which may be formed by combining two R₁₅'s with each other include a 5- or 6-membered ring formed together with the sulfur atom in Formula (ZI-4) by two R₁₅'s, and particularly preferably a 5-membered ring (that is, a tetrahydrothiophene ring), and may be condensed with an aryl group or a cycloalkyl group. The divalent R₁₅ may have a substituent, and examples of the substituent include a hydroxyl group, a carboxyl group, a cyano group, a nitro group, an alkyl group, a cycloalkyl group, an alkoxy group, an alkoxyalkyl group, an alkoxycarbonyl group, an alkoxycarbonyloxy group and the like. As for the substituent on the ring structure, a plurality of substituents may be present, and the substituents may combine with each other to form a ring (an aromatic or non-aromatic hydrocarbon ring, an aromatic or non-aromatic heterocyclic ring, a polycyclic condensed ring formed by combining two or more of these rings or the like).

In Formula (ZI-4), R₁₅ is preferably a methyl group, an ethyl group, a naphthyl group, a divalent group capable of forming a tetrahydrothiophene ring structure together with the sulfur atom by combining two R₁₅'s with each other, and the like.

The substituent that R₁₃ and R₁₄ may have is preferably a hydroxyl group, an alkoxy group, an alkoxycarbonyl group or a halogen atom (particularly a fluorine atom).

l is preferably 0 or 1, and more preferably 1.

r is preferably 0 to 2.

A cation of the compound represented by Formula (ZI-4) in the present invention may include the following specific examples.

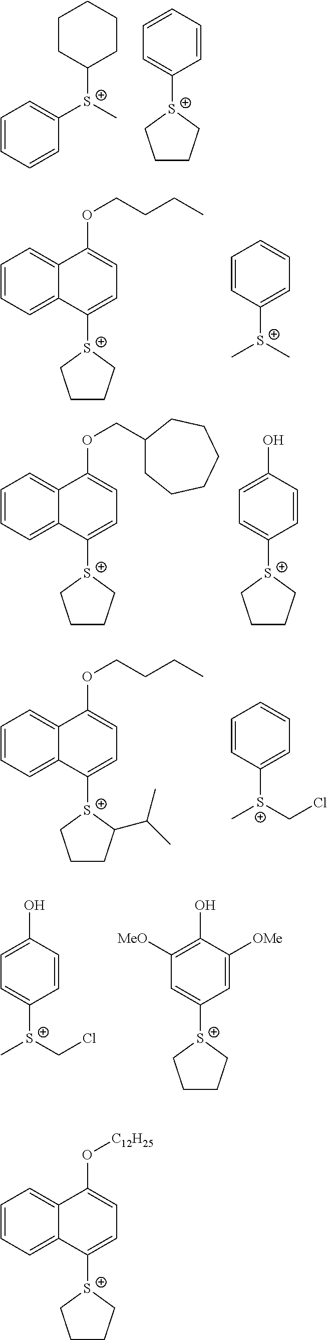

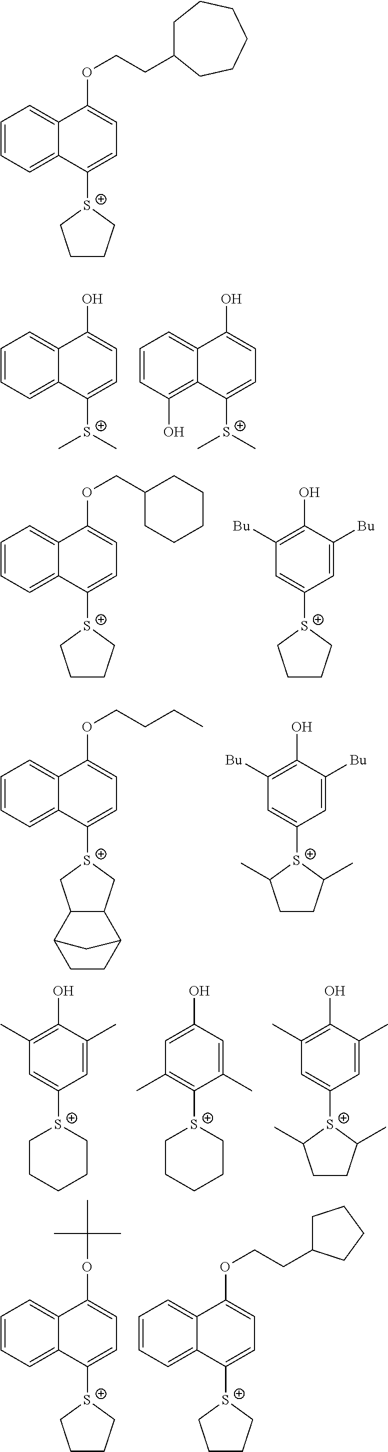

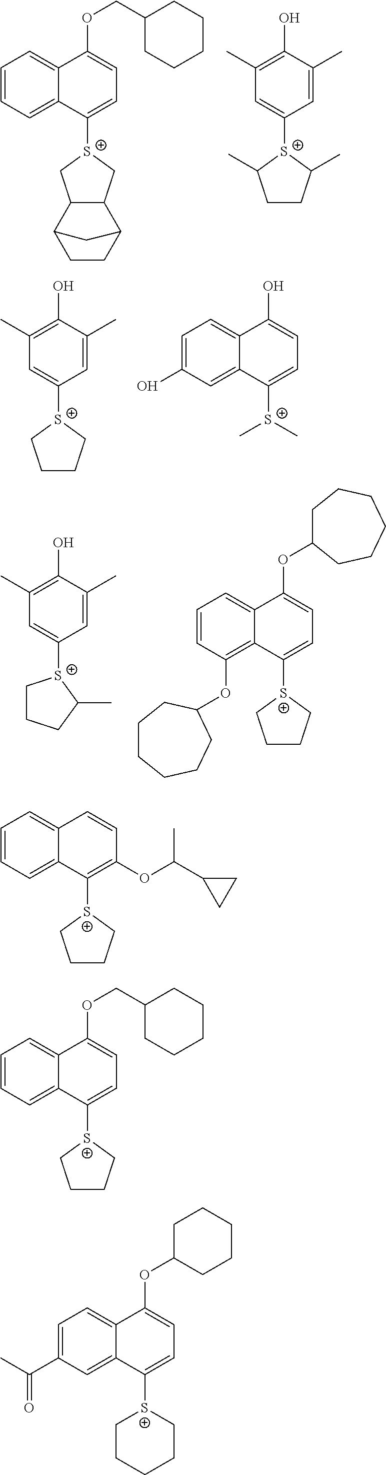

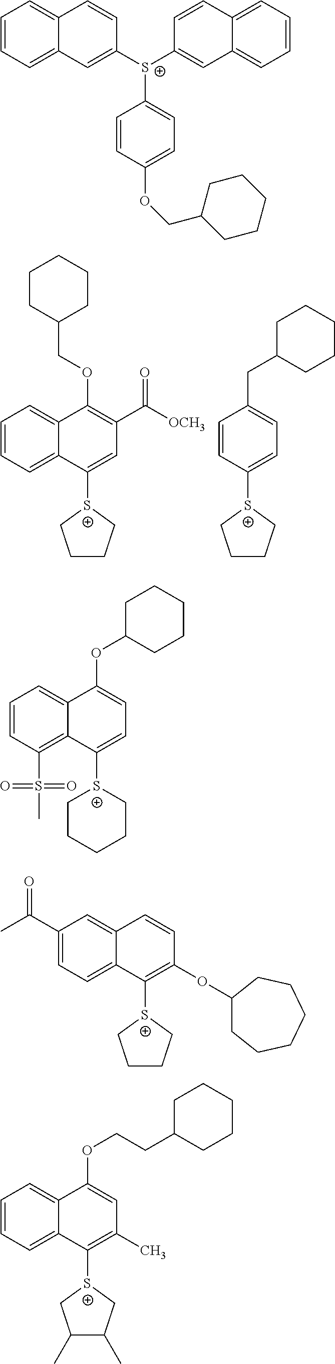 [SMILES: c1ccc2cc([S+](c3ccc(OCC4CCCCC4)cc3)c3ccc4ccccc4c3)ccc2c1 ; COC(=O)c1cc([S+]2CCCC2)c2ccccc2c1OCC1CCCCC1 ; c1cc([S+]2CCCC2)ccc1CC1CCCCC1 ; CS(=O)(=O)c1cccc2c(OC3CCCCC3)ccc([S+]3CCCCC3)c12 ; CC(=O)c1ccc2c([S+]3CCCC3)c(OC3CCCCCC3)ccc2c1 ; Cc1cc(OCCC2CCCCC2)c2ccccc2c1[S+]1CC(C)C(C)C1]

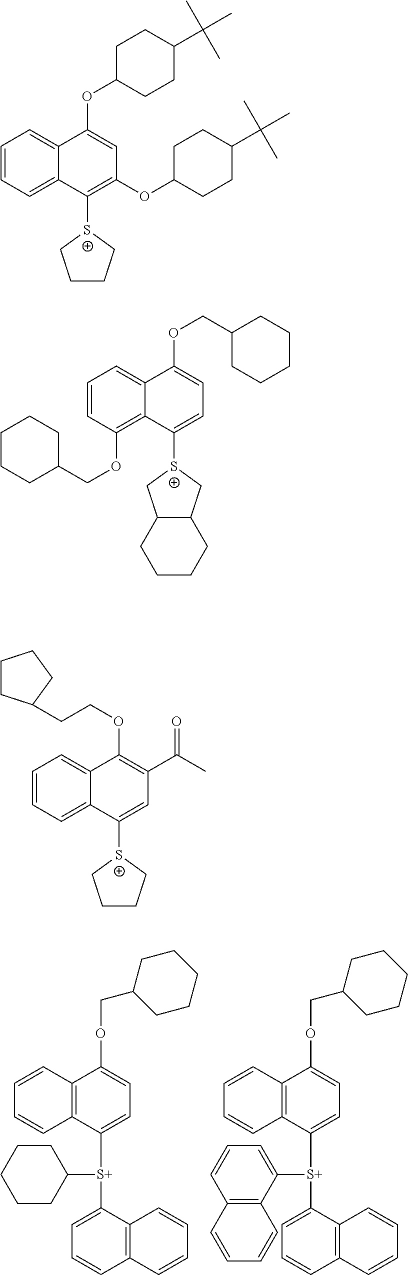 [SMILES: CC(C)(C)C1CCC(Oc2cc(OC3CCC(C(C)(C)C)CC3)c3ccccc3c2[S+]2CCCC2)CC1 ; c1cc(OCC2CCCCC2)c2c([S+]3CC4CCCCC4C3)ccc(OCC3CCCCC3)c2c1 ; CC(=O)c1cc([S+]2CCCC2)c2ccccc2c1OCCC1CCCC1 ; c1ccc2c([S+](c3ccc(OCC4CCCCC4)c4ccccc34)C3CCCCC3)cccc2c1 ; c1ccc2c([S+](c3cccc4ccccc34)c3ccc(OCC4CCCCC4)c4ccccc34)cccc2c1]

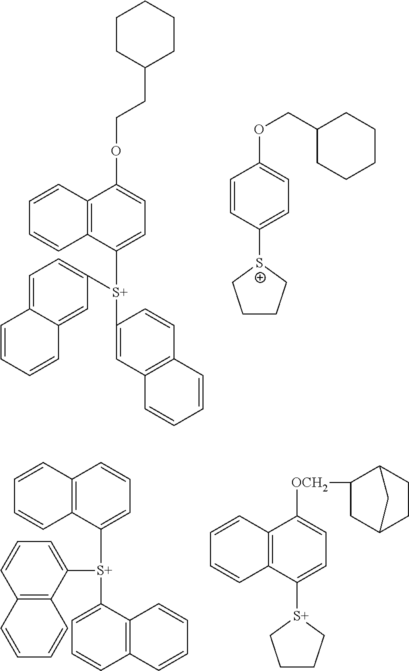

Subsequently, Formulas (ZII) and (ZIII) will be described.

In Formulas (ZII) and (ZIII),

each of R₂₀₄ to R₂₀₇ independently represents an aryl group, an alkyl group or a cycloalkyl group.

The aryl group of R₂₀₄ to R₂₀₇ is preferably a phenyl group or a naphthyl group, and more preferably a phenyl group. The aryl group of R₂₀₄ to R₂₀₇ may be an aryl group having a heterocyclic structure having an oxygen atom, a nitrogen atom, a sulfur atom or the like. Examples of the structure of the aryl group having a heterocyclic structure include pyrrole, furan, thiophene, indole, benzofuran, benzothiophene and the like.

The alkyl group and the cycloalkyl group in R₂₀₄ to R₂₀₇ are preferably a straight chained or branched alkyl group having 1 to 10 carbon atoms (for example, a methyl group, an ethyl group, a propyl group, a butyl group and a pentyl group) and a cycloalkyl group having 3 to 10 carbon atoms (a cyclopentyl group, a cyclohexyl group and a norbornyl group), respectively.

The aryl group, the alkyl group and the cycloalkyl group of R₂₀₄ to R₂₀₇ may have a substituent. Examples of the substituent that the aryl group, the alkyl group and the cycloalkyl group of R₂₀₄ to R₂₀₇ may have include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, a phenylthio group and the like.

Z⁻ represents a non-nucleophilic anion, and examples thereof include the non-nucleophilic anion of Z⁻ in Formula (ZI).

Examples of the acid generator further include compounds represented by the following Formulas (ZIV), (ZV) and (ZVI).

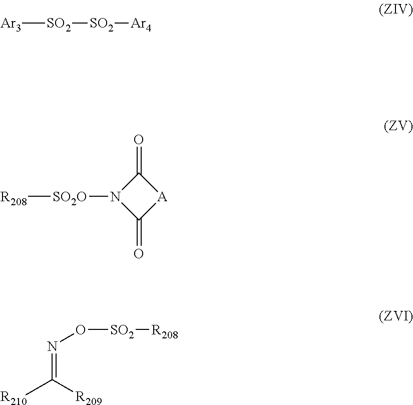

In Formulas (ZIV) to (ZVI),

each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Specific examples of the aryl group of Ar₃, Ar₄, R₂₀₈, R₂₀₉ and R₂₁₀ are the same as specific examples of the aryl group as R₂₀₁, R₂₀₂ and R₂₀₃ in Formula (ZI-1).

Specific examples of the alkyl group and cycloalkyl group of R₂₀₈, R₂₀₉ and R₂₁₀ are the same as specific examples of the alkyl group and cycloalkyl group as R₂₀₁, R₂₀₂ and R₂₀₃ in Formula (ZI-2).

Examples of the alkylene group of A include an alkylene group having 1 to 12 carbon atoms (for example, a methylene group, an ethylene group, a propylene group, an isopropylene group, a butylene group, an isobutylene group and the like), examples of the alkenylene group of A include an alkenylene group having 2 to 12 carbon atoms (for example, an ethenylene group, a propenylene group, a butenylene group and the like), and examples of the arylene group of A include an arylene group having 6 to 10 carbon atoms (for example, a phenylene group, a tolylene group, a naphthylene group and the like).

Among the acid generators, the compounds represented by Formulas (ZI) to (ZIII) are more preferred.

Further, the acid generator is preferably a compound capable of generating an acid having either a sulfonic acid group or an imide group, more preferably a compound capable of generating a monovalent perfluoroalkanesulfonic acid, or a compound capable of generating an aromatic sulfonic acid substituted with a monovalent fluorine atom or a fluorine atom-containing group, or a compound capable of generating an imide acid substituted with a monovalent fluorine atom or a fluorine atom-containing group, and even more preferably a sulfonium salt of fluoro-substituted alkanesulfonic acid, fluorine-substituted benzenesulfonic acid, fluorine-substituted imide acid or fluorine-substituted methide acid. The usable acid generator is particularly preferably a fluoro-substituted alkanesulfonic acid, a fluoro-substituted benzenesulfonic acid, or a fluoro-substituted imide acid, in which the acid generated has a pKa of −1 or less, and the sensitivity is enhanced.

The actinic ray-sensitive or radiation-sensitive resin composition of the present invention preferably contains the compound represented by Formula (ZI-2), (ZI-3) or (ZI-4) as an acid generator, and accordingly, may be much better in exposure latitude and uniformity of a local pattern dimension.

Among the acid generators, particularly preferred examples will be described below.

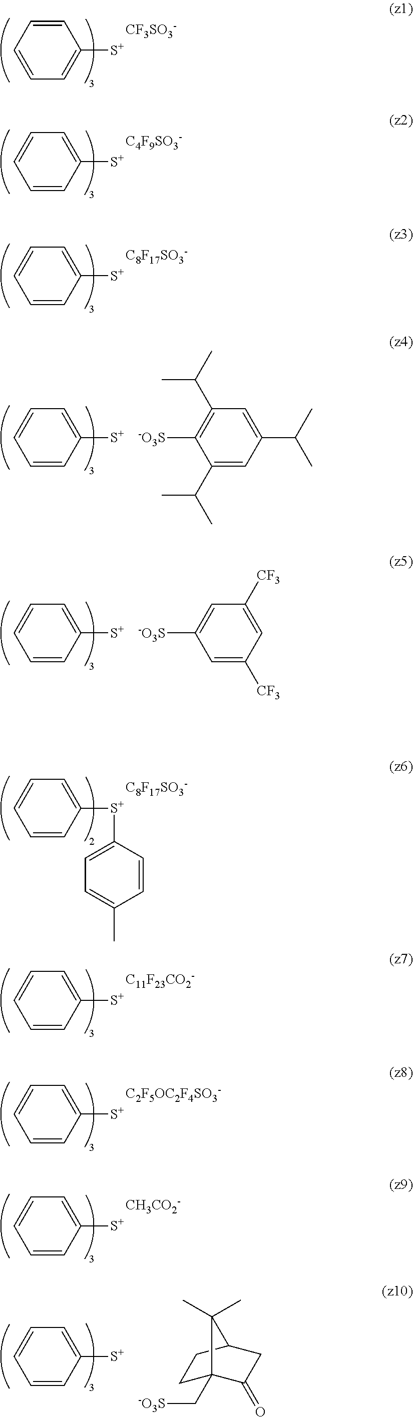

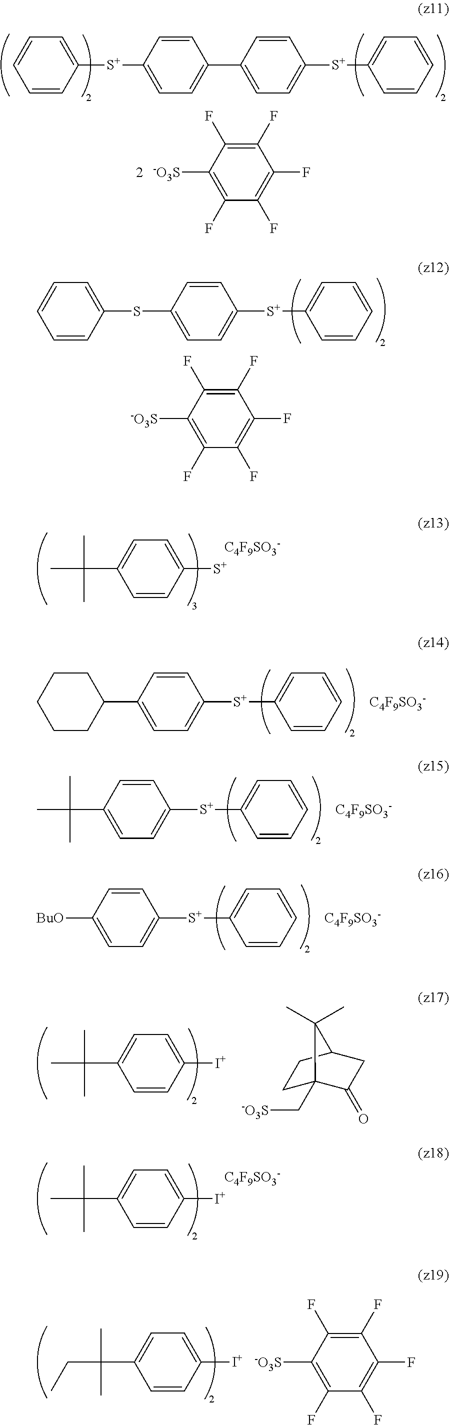

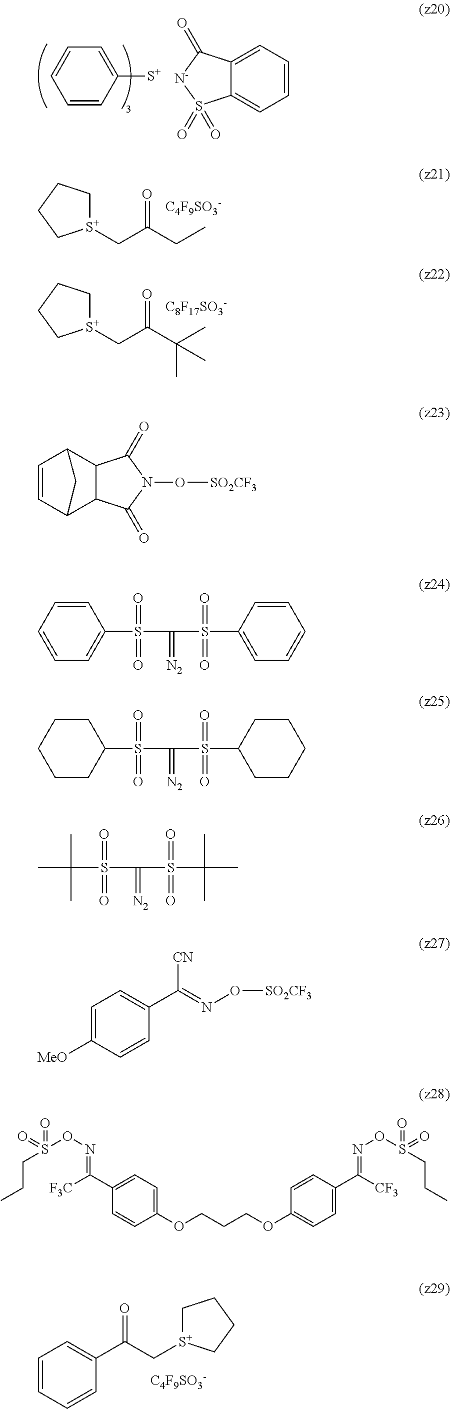

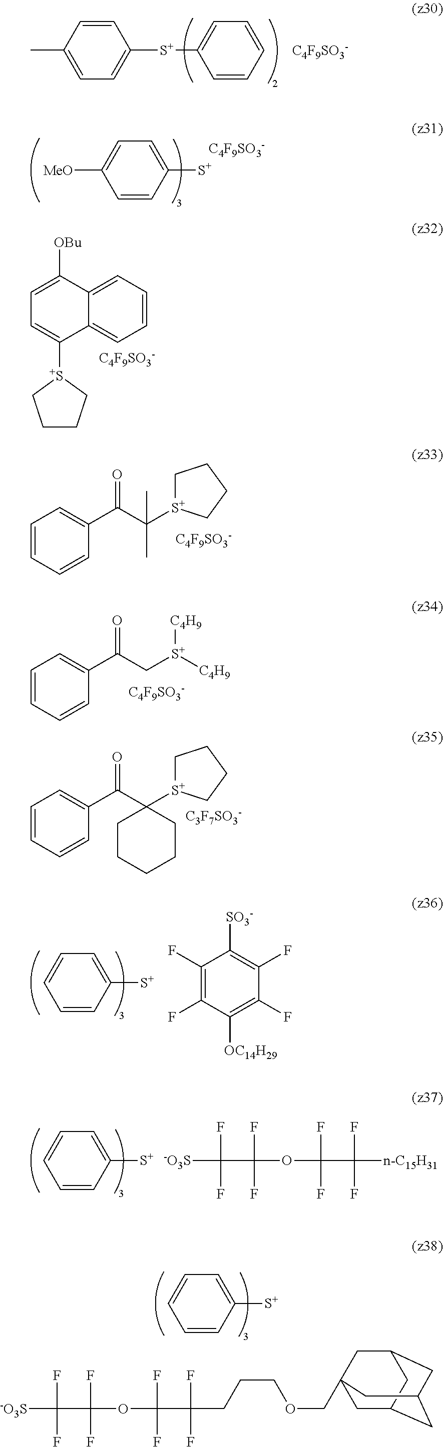

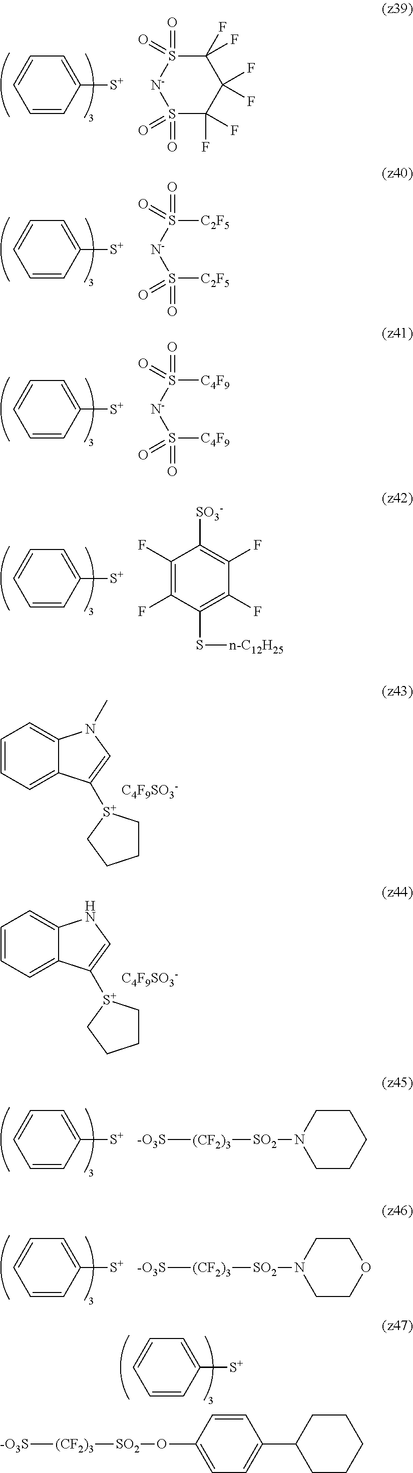

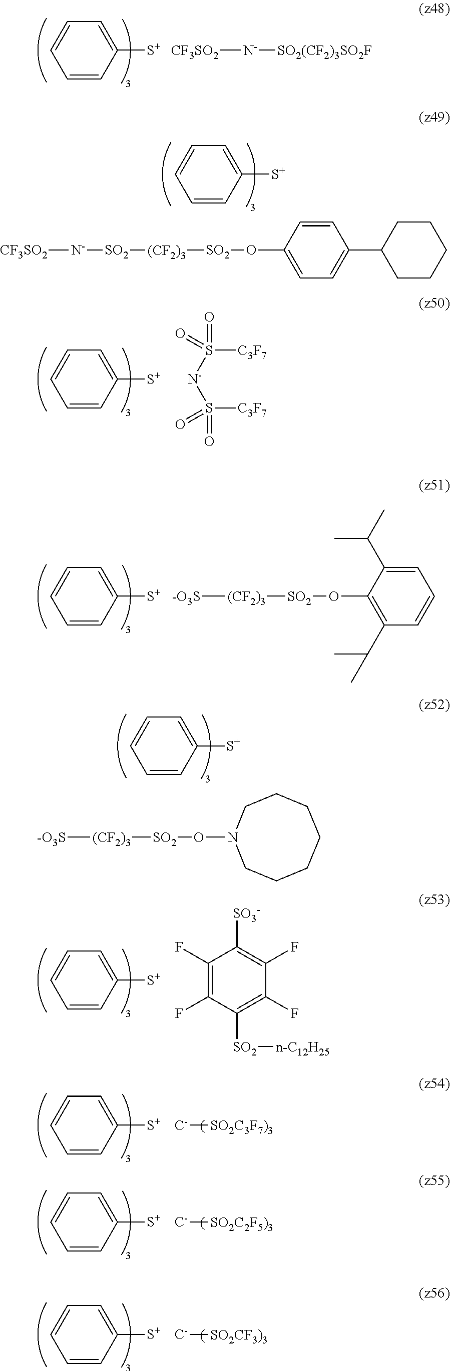

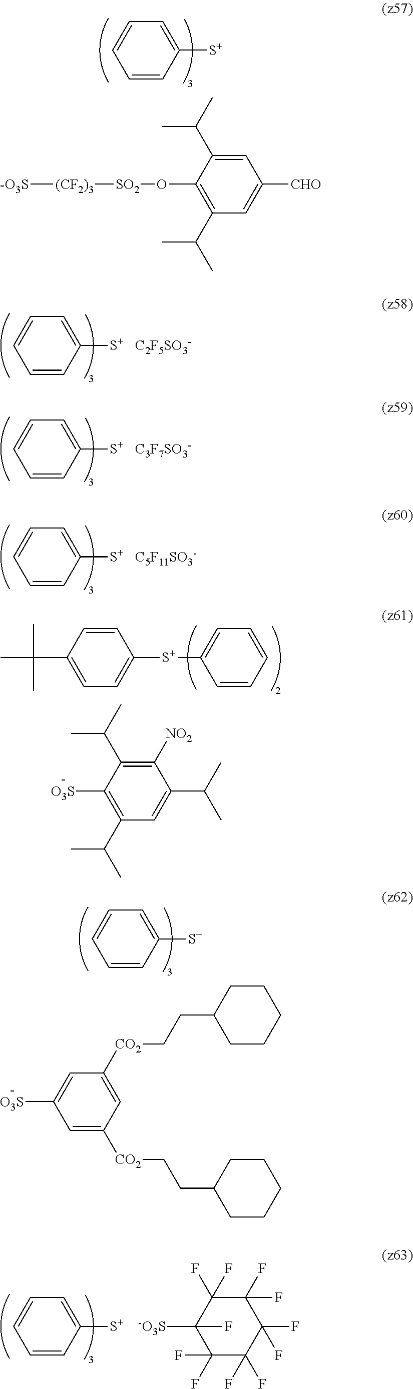

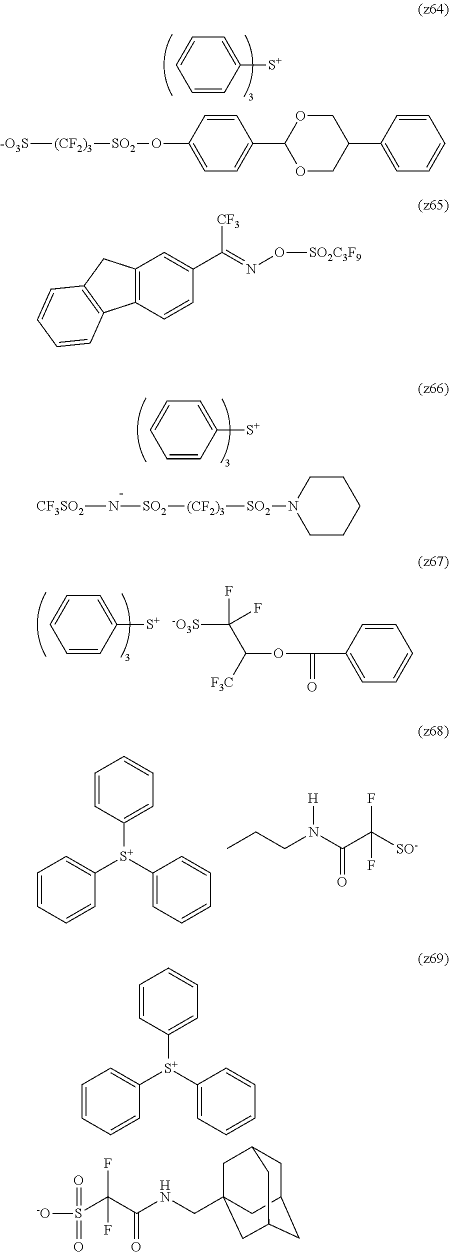

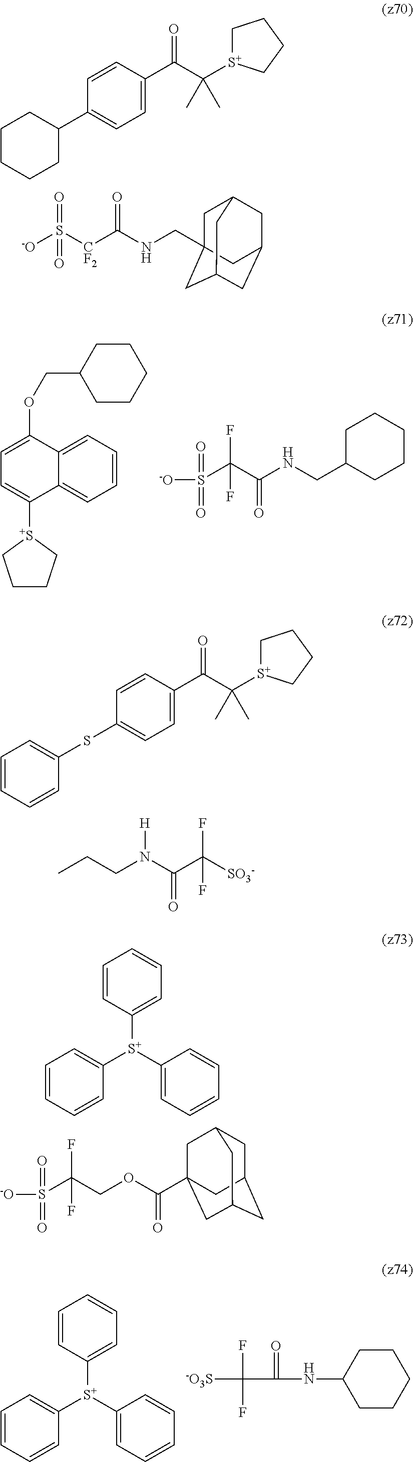

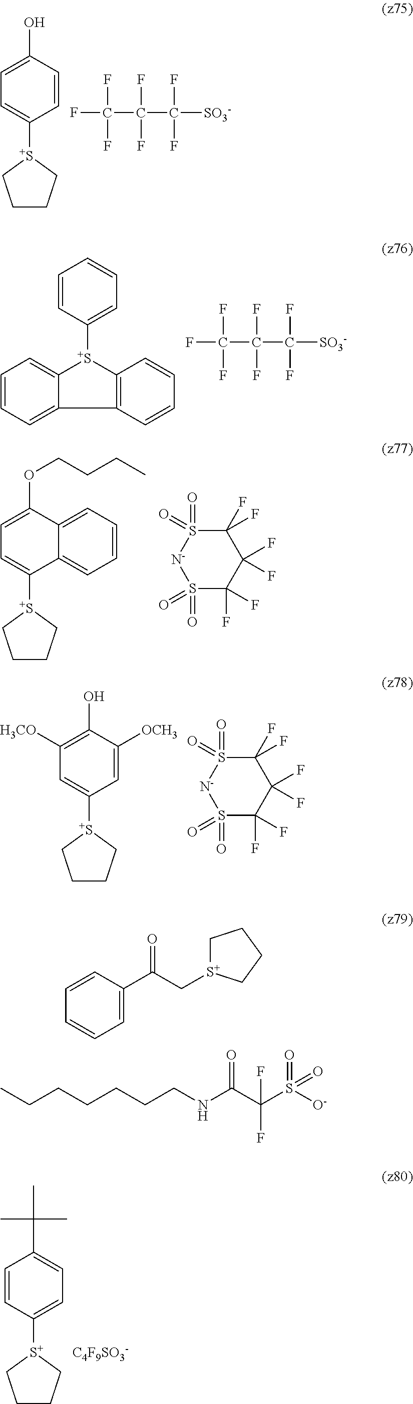

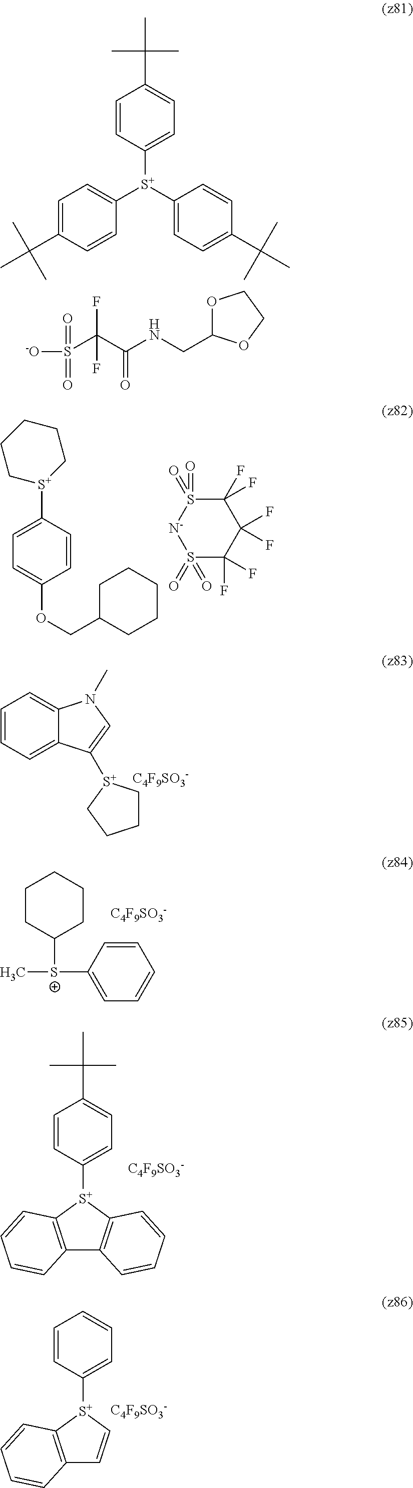

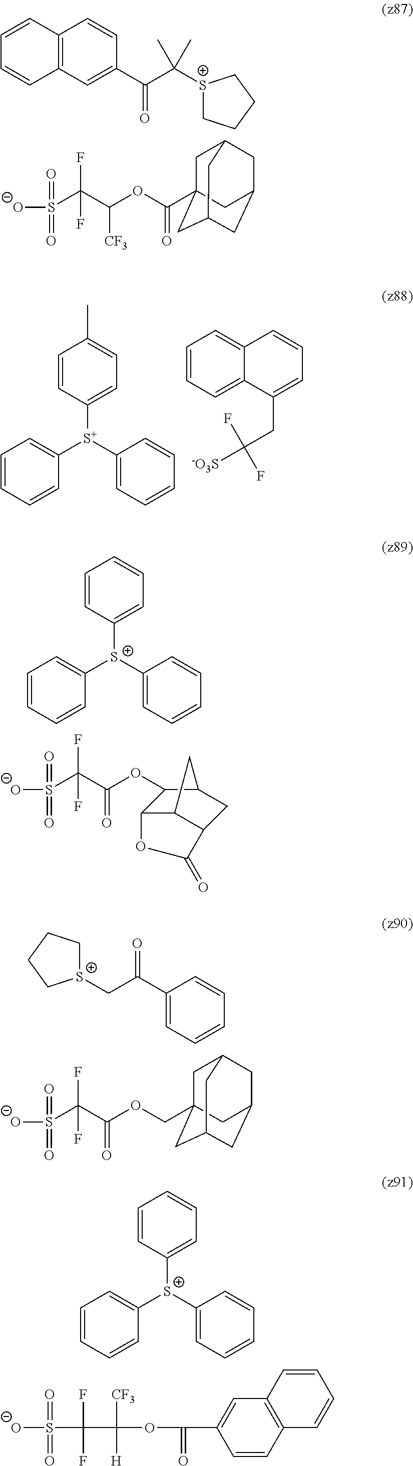

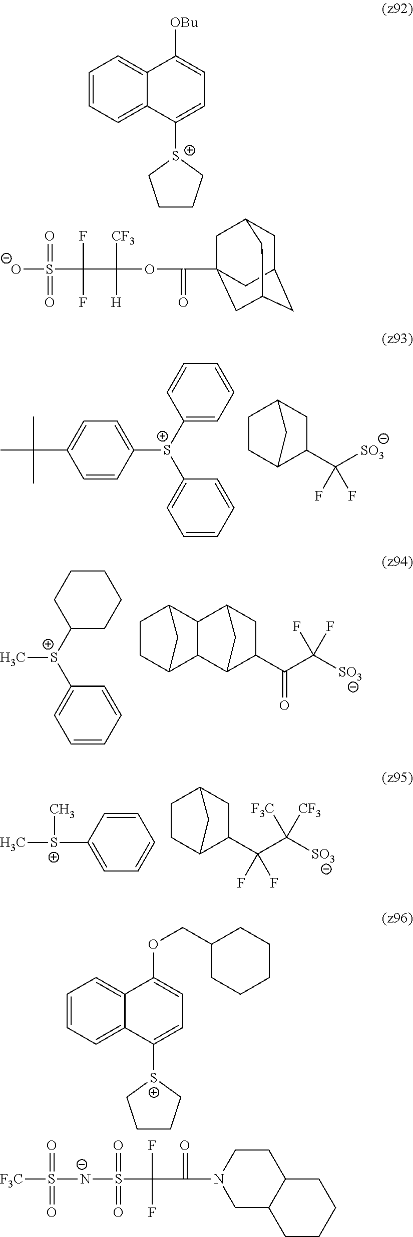

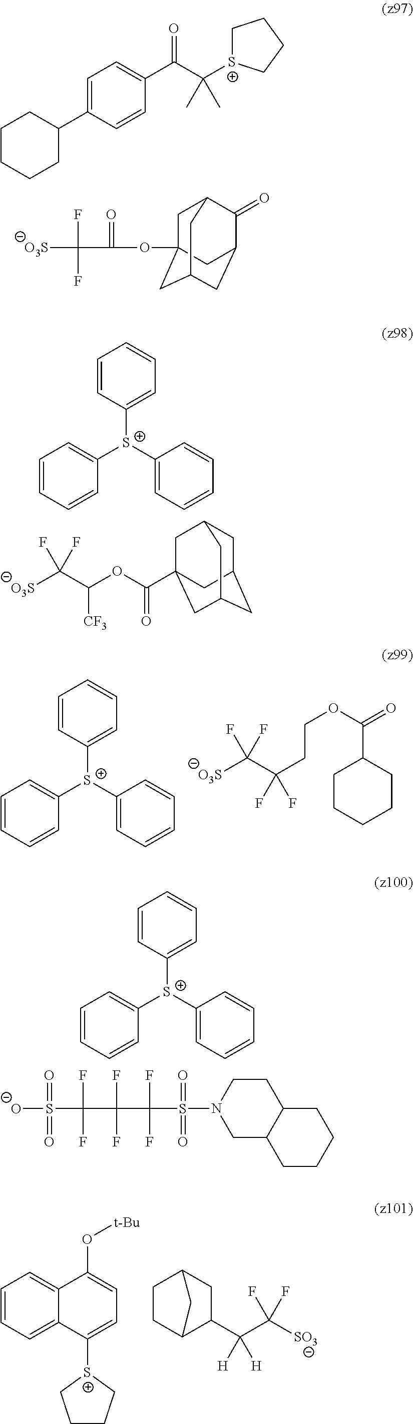

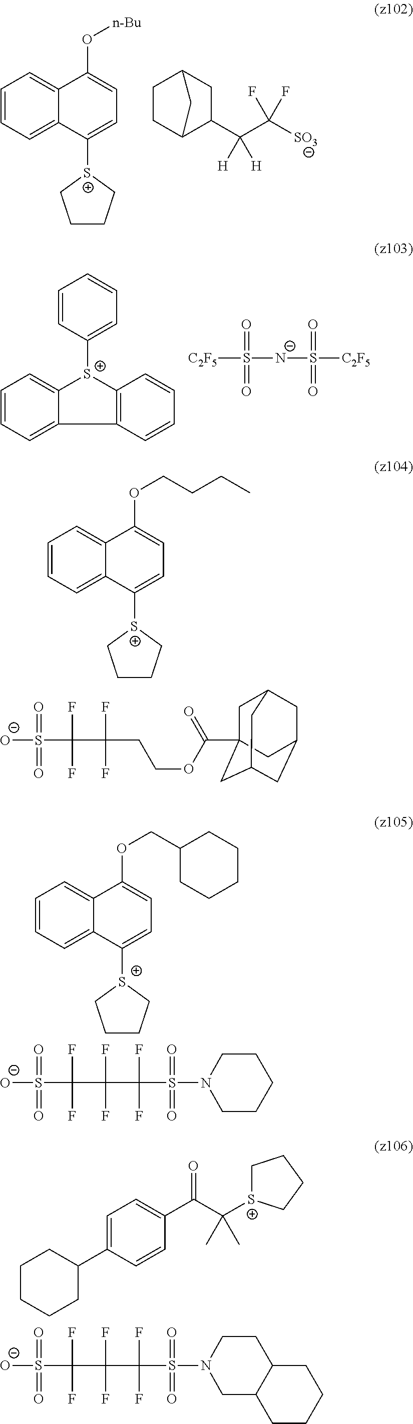

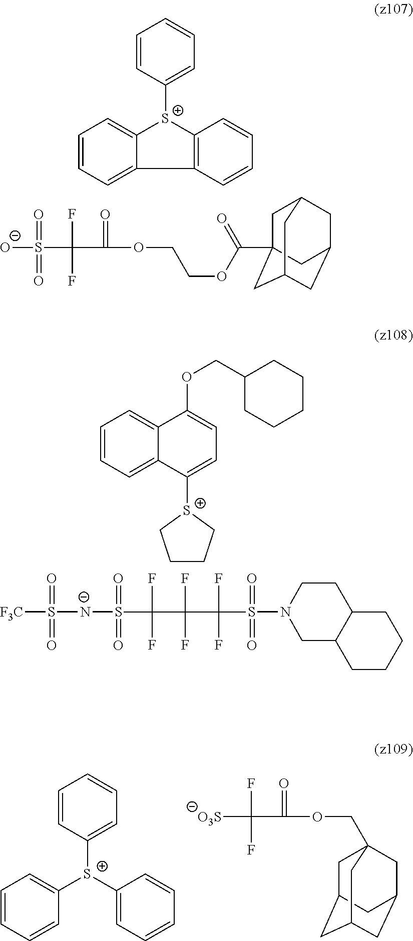

In addition, particularly preferred examples of compound (B) having the anion represented by any one of Formulas (B-1) to (B-3) will be described below, but the present invention is not limited thereto.

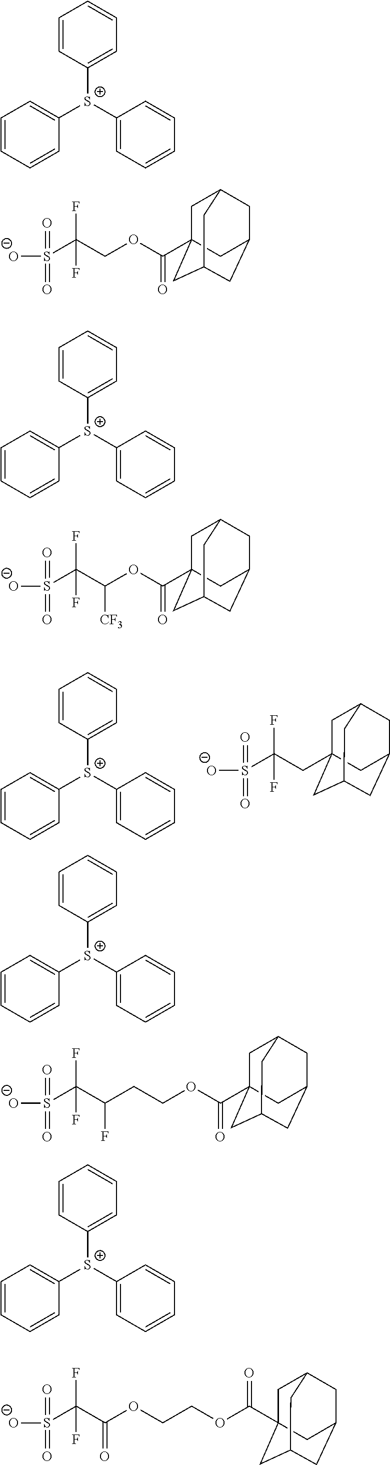

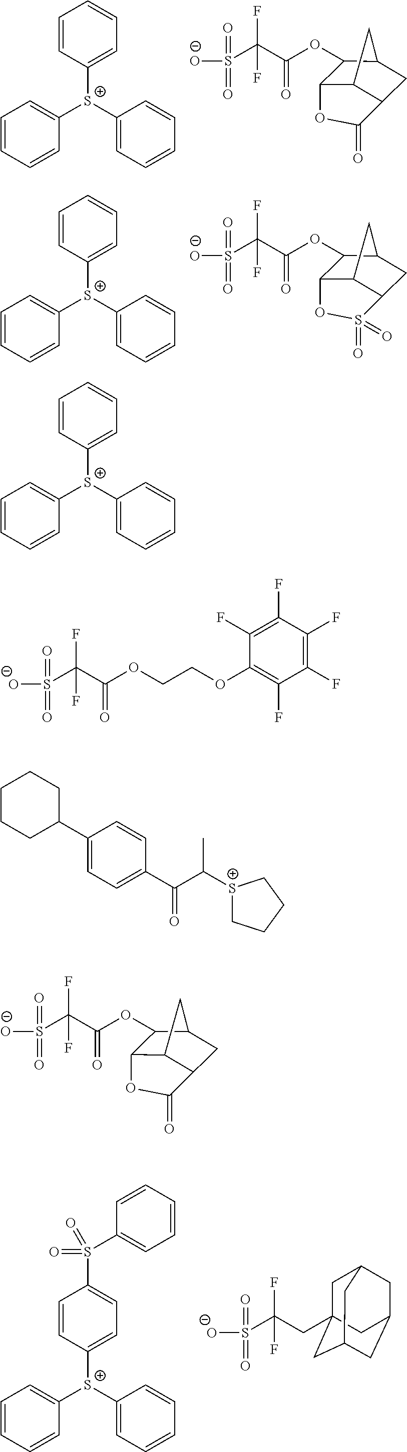

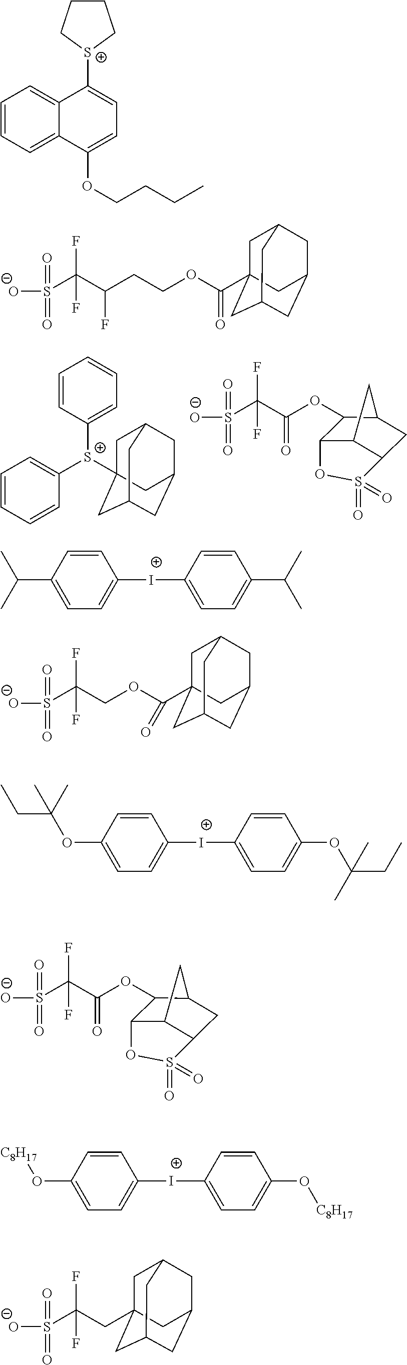

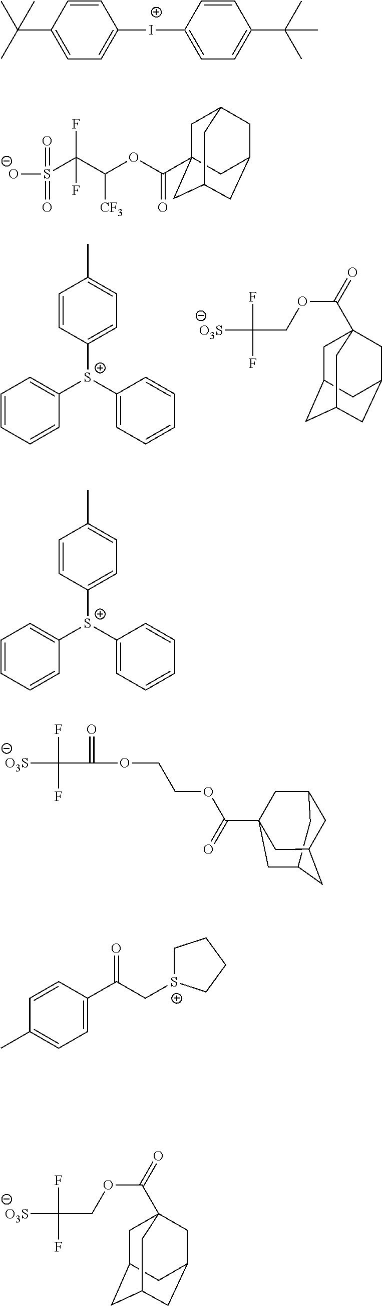

The acid generator may be synthesized by a publicly known method, and may be synthesized in accordance with the method described in, for example, Japanese Patent Application Laid-Open No. 2007-161707, [0200] to [0210] of Japanese Patent Application Laid-Open No. 2010-100595, [0051] to [0058] of International Publication No. 2011/093280, [0382] to [0385] of International Publication No. 2008/153110, Japanese Patent Application Laid-Open No. 2007-161707 and the like.

The acid generator may be used either alone or in combination of two or more thereof.

The content of the compound capable of generating an acid upon irradiation with an actinic ray or radiation (except for the case represented by Formula (ZI-3) or (ZI-4)) in the composition is preferably 0.1 to 30% by mass, more preferably 0.5 to 25% by mass, even more preferably 3 to 20% by mass, and particularly preferably 3 to 15% by mass, based on the total solid content of the actinic ray-sensitive or radiation-sensitive resin composition (I).

Furthermore, when the acid generator is represented by Formula (ZI-3) or (ZI-4), the content thereof is preferably 5 to 35% by mass, more preferably from 8 to 30% by mass, even more preferably from 9 to 30% by mass, and particularly preferably from 9 to 25% by mass, based on the total solid content of the composition.

[4] Hydrophobic Resin (D)

Particularly when applied to liquid immersion exposure, the actinic ray-sensitive or radiation-sensitive resin composition according to the present invention may contain a hydrophobic resin (hereinafter, also referred to as “hydrophobic resin (D)” or simply referred to as “resin (D)”). Here, resin (D) is usually a resin different from resin (P) and resin (A).

Accordingly, when hydrophobic resin (D) is unevenly distributed on the film top layer and the immersion medium is water, the static/dynamic contact angle of the resist film surface against water may be enhanced, thereby enhancing an immersion liquid follow-up property.

It is preferred that hydrophobic resin (D) is designed to be unevenly distributed at the interface as described above, but unlike a surfactant, hydrophobic resin (D) does not need to have a hydrophilic group in the molecule thereof, and may not contribute to the mixing of polar/non-polar materials homogeneously.

From the viewpoint of uneven distribution on the film top layer, hydrophobic resin (D) has preferably one or more of “a fluorine atom”, “a silicon atom” and “a CH₃ partial structure contained in a side chain moiety of a resin”, and more preferably two or more thereof.

When hydrophobic resin (D) includes a fluorine atom and/or a silicon atom, the fluorine atom and/or the silicon atom in hydrophobic resin (D) may be included in the main chain of the resin, and may be included in the side chain thereof.

When hydrophobic resin (D) includes a fluorine atom, hydrophobic resin (D) is preferably a resin having an alkyl group having a fluorine atom, a cycloalkyl group having a fluorine atom, or an aryl group having a fluorine atom as a partial structure having a fluorine atom.

The alkyl group (having preferably 1 to 10 carbon atoms, and more preferably 1 to 4 carbon atoms) having a fluorine atom is a straight chained or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

The aryl group having a fluorine atom is an aryl group in which at least one hydrogen atom in an aryl group such as a phenyl group and a naphthyl group is substituted with a fluorine atom, and may further have a substituent other than a fluorine atom.

Preferred examples of the alkyl group having a fluorine atom, the cycloalkyl group having a fluorine atom and the aryl group having a fluorine atom include groups represented by the following Formulas (F2) to (F4), but the present invention is not limited thereto.

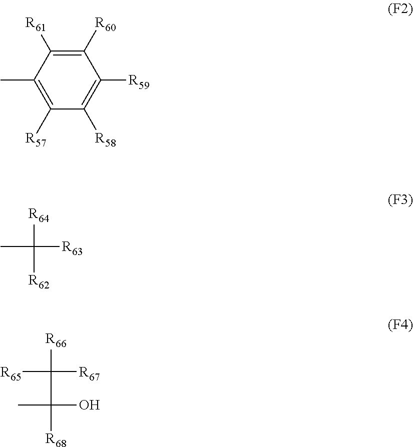

In Formulas (F2) to (F4),

each of R₅₇ to R₆₈ independently represents a hydrogen atom, a fluorine atom or an alkyl group (straight chained or branched). Provided that each of at least one of R₅₇ to R₆₁, at least one of R₆₂ to R₆₄ and at least one of R₆₅ to R₆₈ independently represents a fluorine atom or an alkyl group (preferably having 1 to 4 carbon atoms) in which at least one hydrogen atom is substituted with a fluorine atom.

All of R₅₇ to R₆₁ and R₆₅ to R₆₇ are preferably a fluorine atom. R₆₂, R₆₃ and R₆₈ are preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may combine with each other to form a ring.

Specific examples of the group represented by Formula (F2) include a p-fluorophenyl group, a pentafluorophenyl group, a 3,5-di(trifluoromethyl)phenyl group and the like.

Specific examples of the group represented by Formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group and the like. A hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred, and a hexafluoroisopropyl group and a heptafluoroisopropyl group are more preferred.

Specific examples of the group represented by Formula (F4) include —C(CF₃)₂OH, —C(C₂F₅)₂OH, —C(CF₃)(CH₃)OH, —CH(CF₃)OH and the like, and —C(CF₃)₂OH is preferred.

The partial structure including a fluorine atom may be bonded directly to the main chain or may be bonded to the main chain through a group selected from the group consisting of an alkylene group, a phenylene group, an ether bond, a thioether bond, a carbonyl group, an ester bond, an amide bond, a urethane bond and a ureylene bond, or a group formed by combining two or more thereof.

Hereinafter, specific examples of the repeating unit having a fluorine atom will be described, but the present invention is not limited thereto.

In the specific examples, X₁ represents a hydrogen atom, —CH₃, —F, or —CF₃. X₂ represents —F or —CF₃.

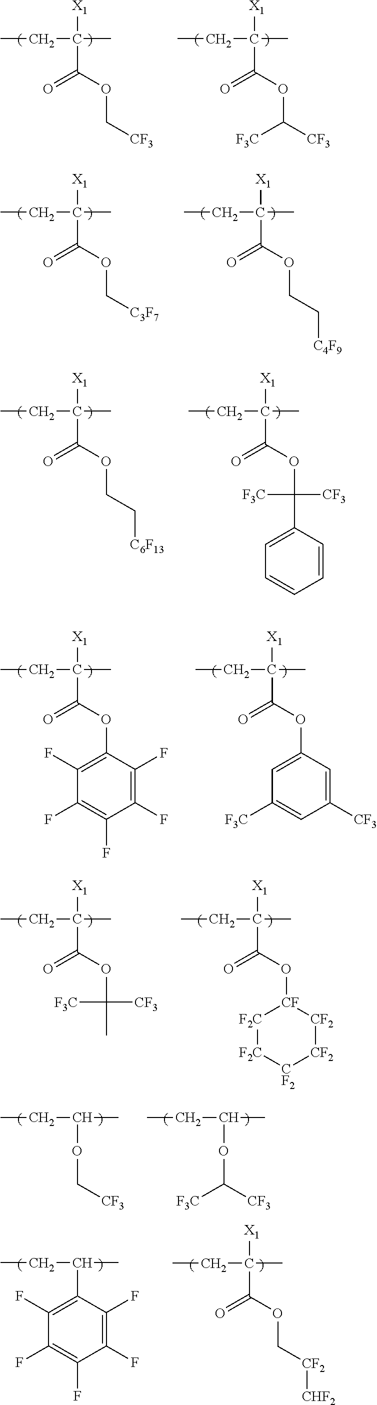

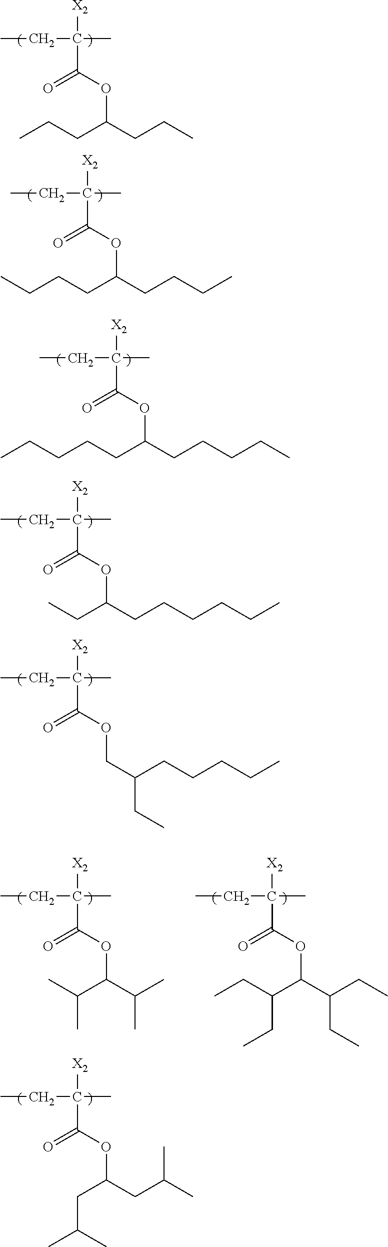

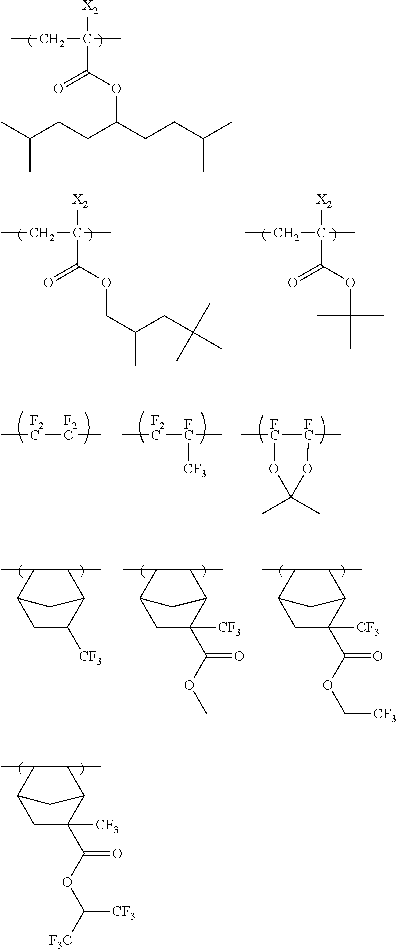

Hydrophobic resin (D) may contain a silicon atom. Hydrophobic resin (D) is a resin having an alkylsilyl structure (preferably a trialkylsilyl group) or a cyclic siloxane structure as a partial structure having a silicon atom.

Specific examples of the alkylsilyl structure or the cyclic siloxane structure include groups represented by the following Formulas (CS-1) to (CS-3) and the like.

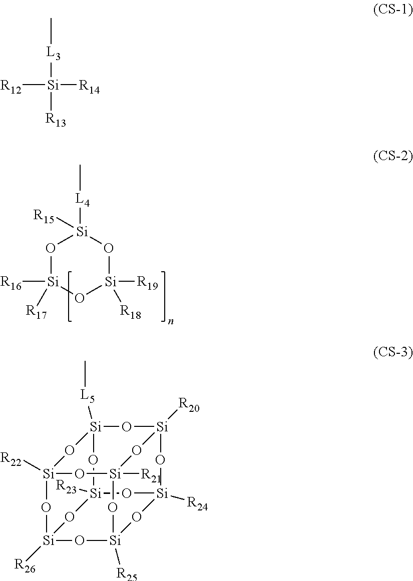

In Formulas (CS-1) to (CS-3),

each of R₁₂ to R₂₆ independently represents a straight chained or branched alkyl group (preferably having 1 to 20 carbon atoms) or a cycloalkyl group (preferably having 3 to 20 carbon atoms).

Each of L₃ to L₅ represents a single bond or a divalent linking group. Examples of the divalent linking group include a sole group or a combination of two or more groups (preferably having a total carbon number of 12 or less), selected from the group consisting of an alkylene group, a phenylene group, an ether bond, a thioether bond, a carbonyl group, an ester bond, an amide bond, a urethane bond and a urea bond.

n represents an integer of 1 to 5. n is preferably an integer of 2 to 4.

Hereinafter, specific examples of the repeating unit having a group represented by Formulas (CS-1) to (CS-3) will be shown, but the present invention is not limited thereto. Meanwhile, in the specific examples, X₁ represents a hydrogen atom, —CH₃, —F, or —CF₃.

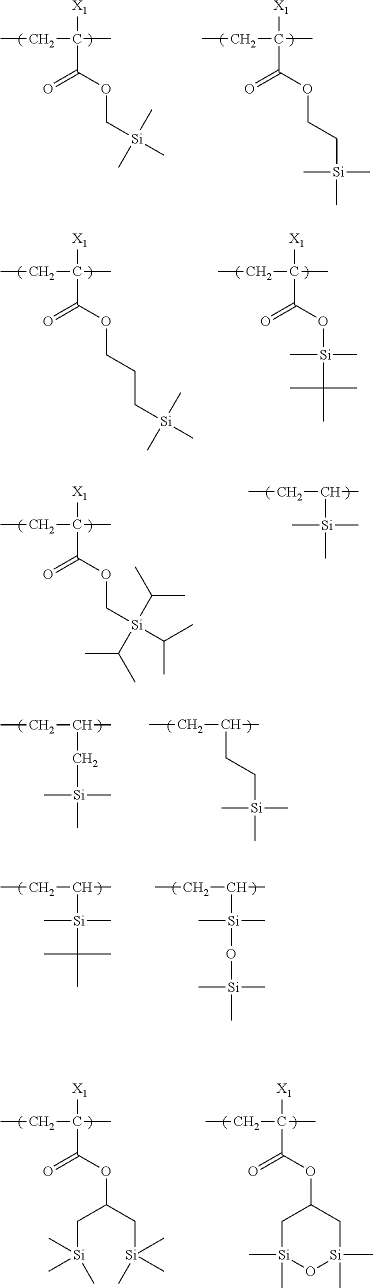

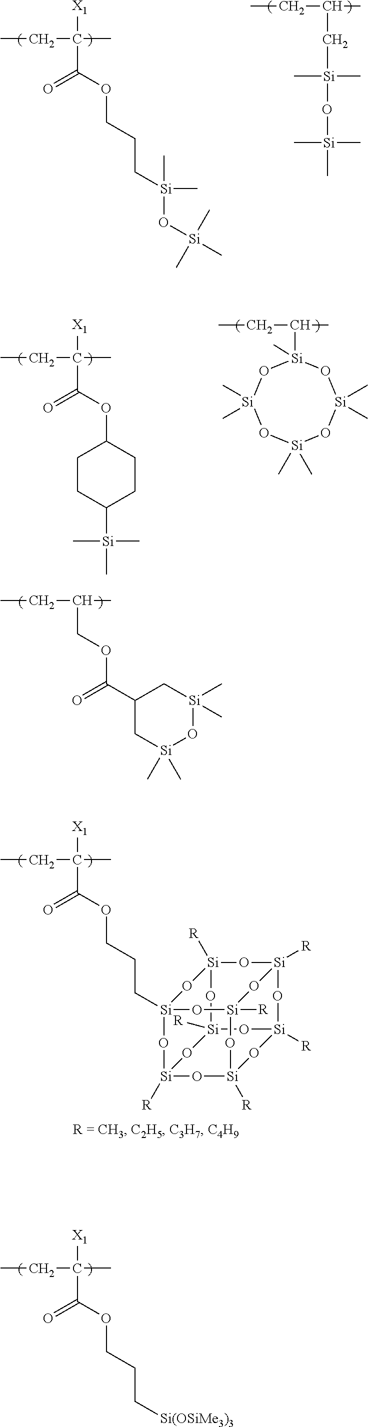

Hydrophobic resin (D) may contain a repeating unit having a sulfonic acid amine salt. Hereinafter, the repeating unit having a sulfonic acid amine salt structure will be exemplified, but the present invention is not limited thereto.

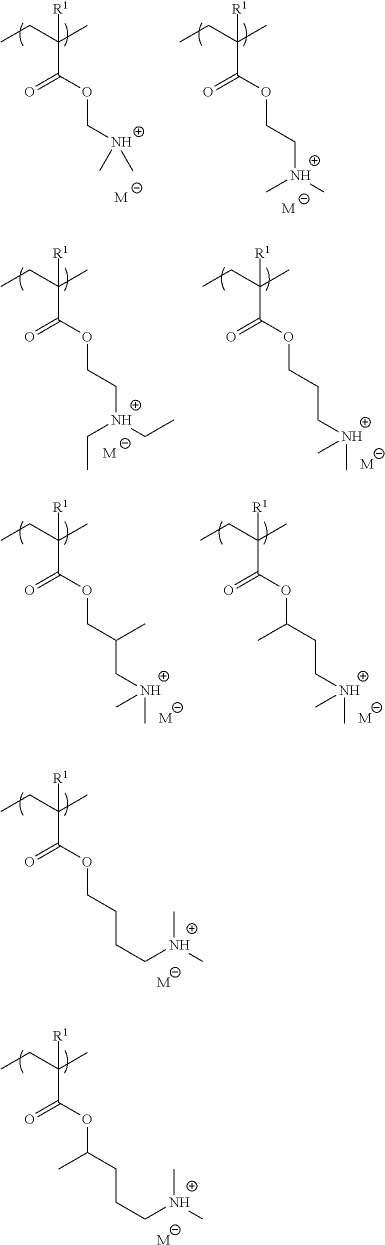

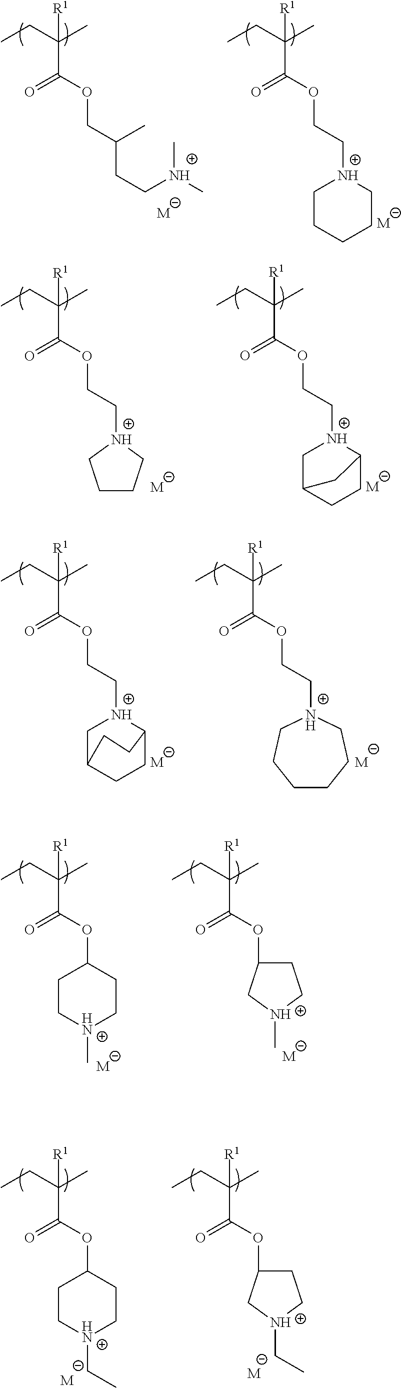

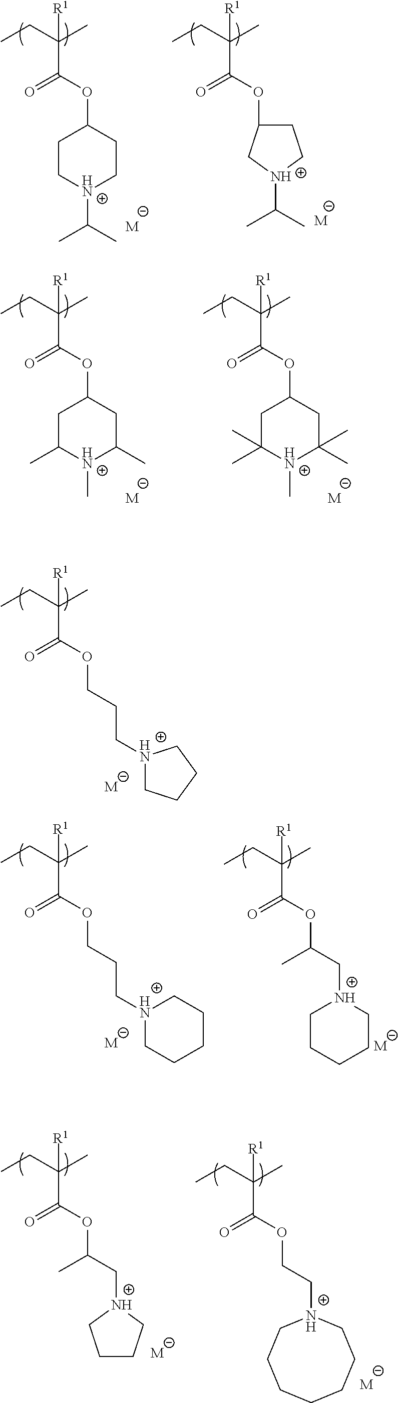

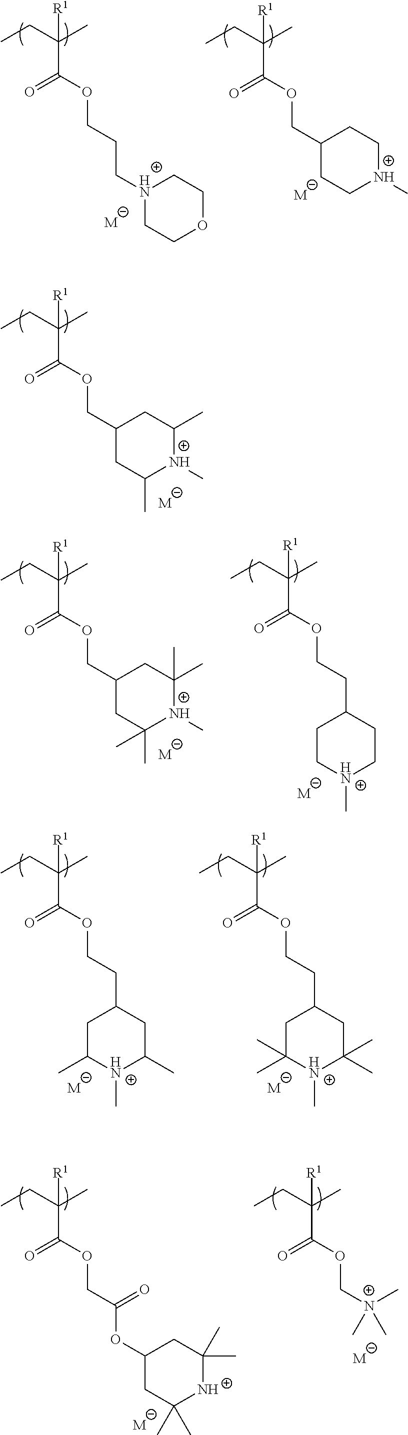

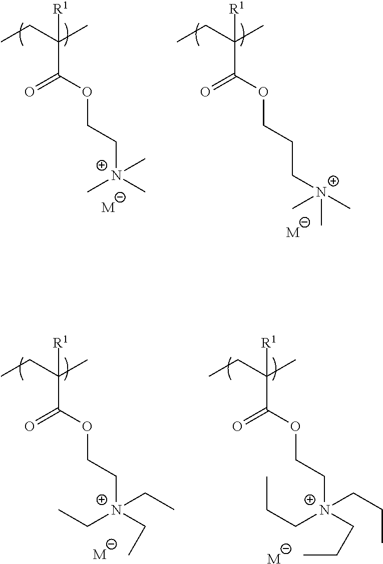

In each formula, R¹ represents a hydrogen atom or an alkyl group. M⁻ represents a sulfonic acid ion, and is preferably an aryl sulfonate such as tosylate, benzene sulfonate, 4-fluorobenzene sulfonate, 1,2,3,4,5-pentafluoro benzene sulfonate, mesitylene sulfonate, 2,4,6-triisopropyl benzene sulfonate, naphthyl sulfonate and pyrene sulfonate, and a sulfonic acid ion such as mesylate and butane sulfonate.

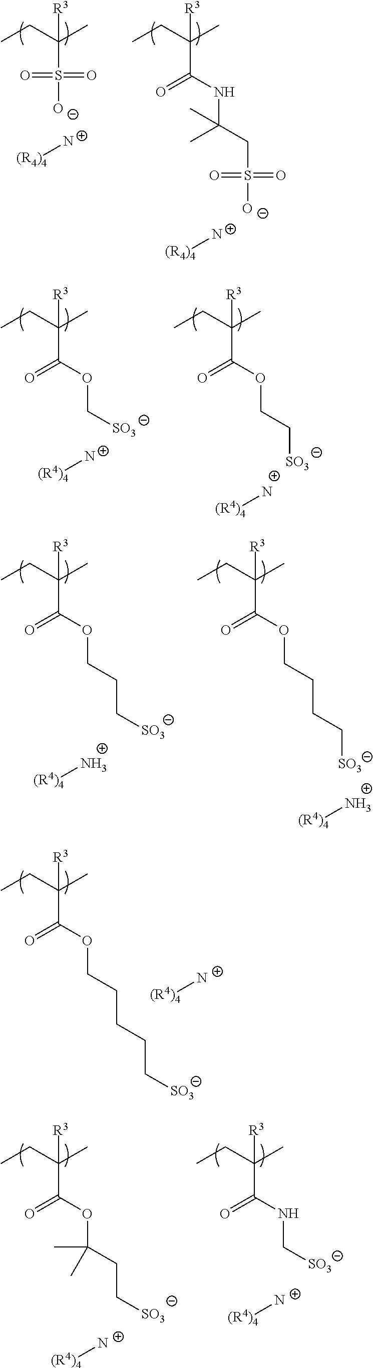

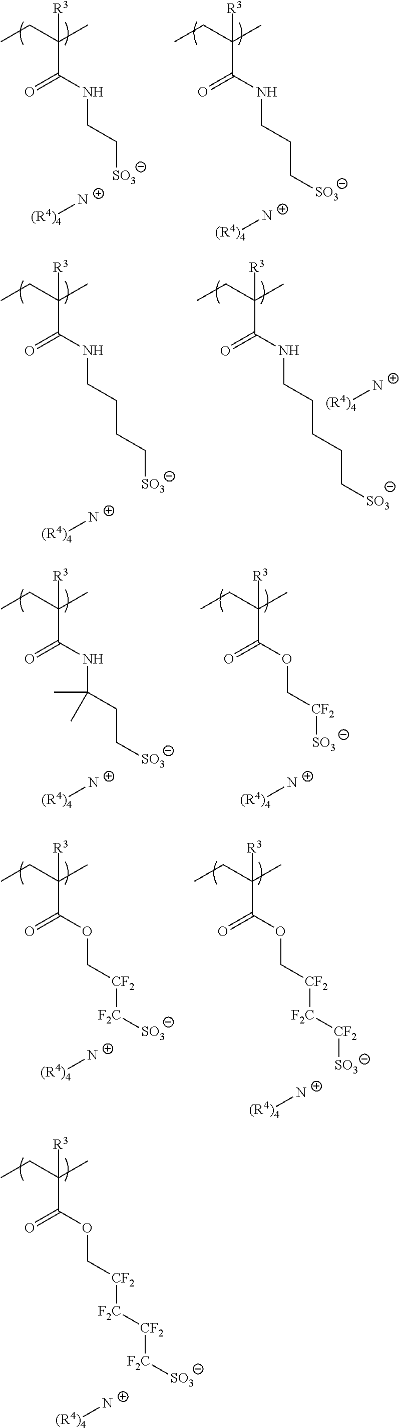

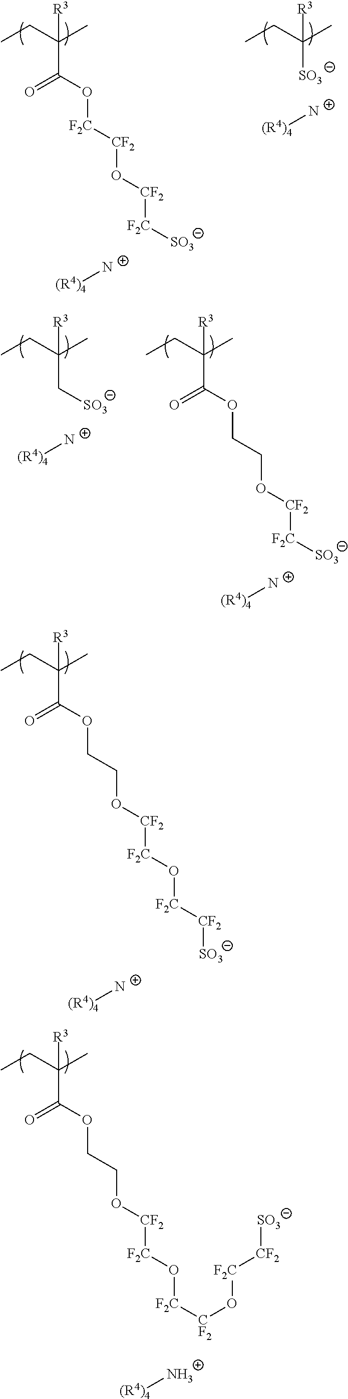

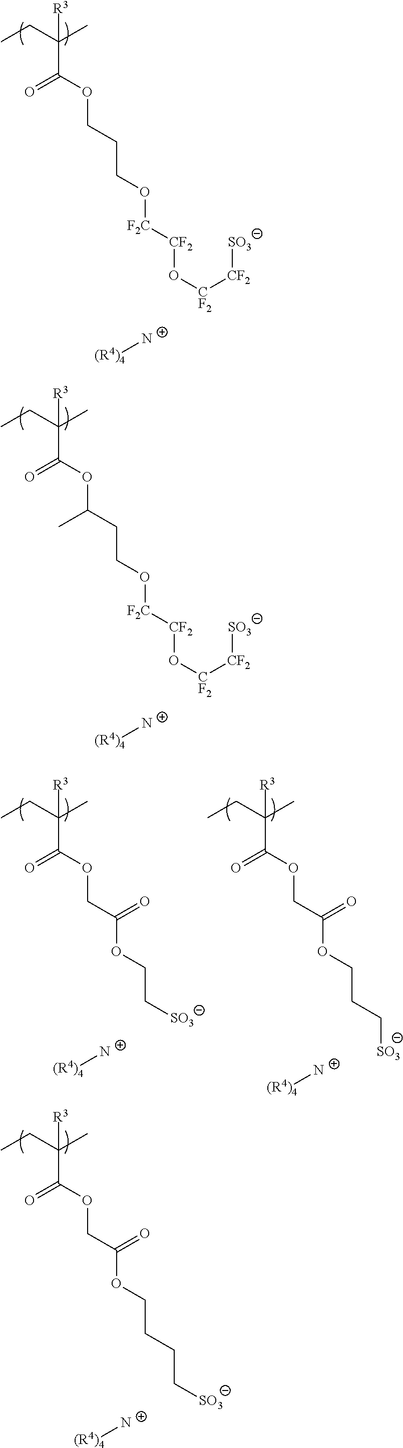

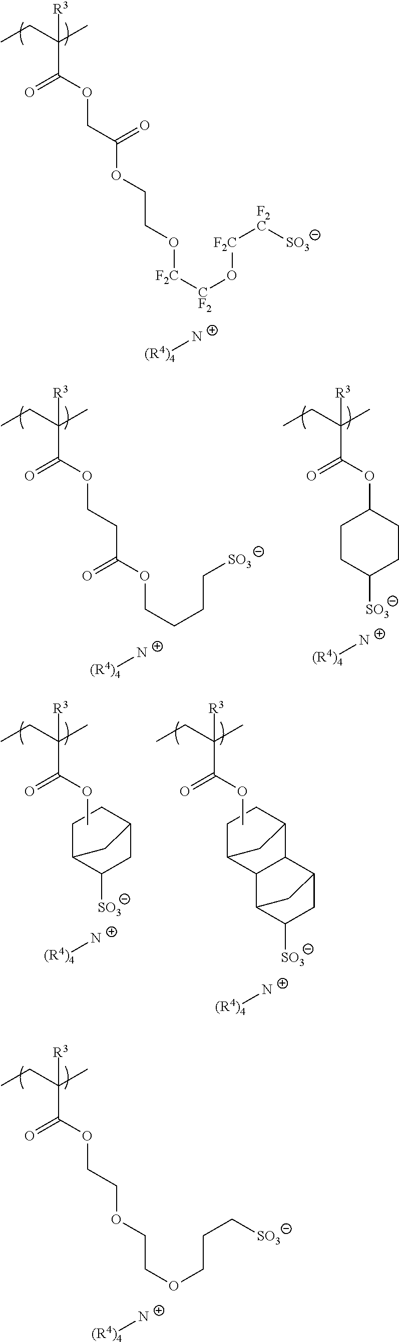

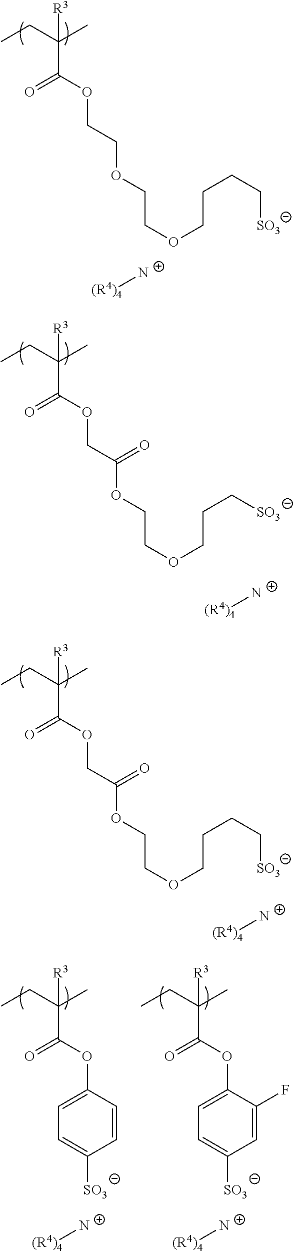

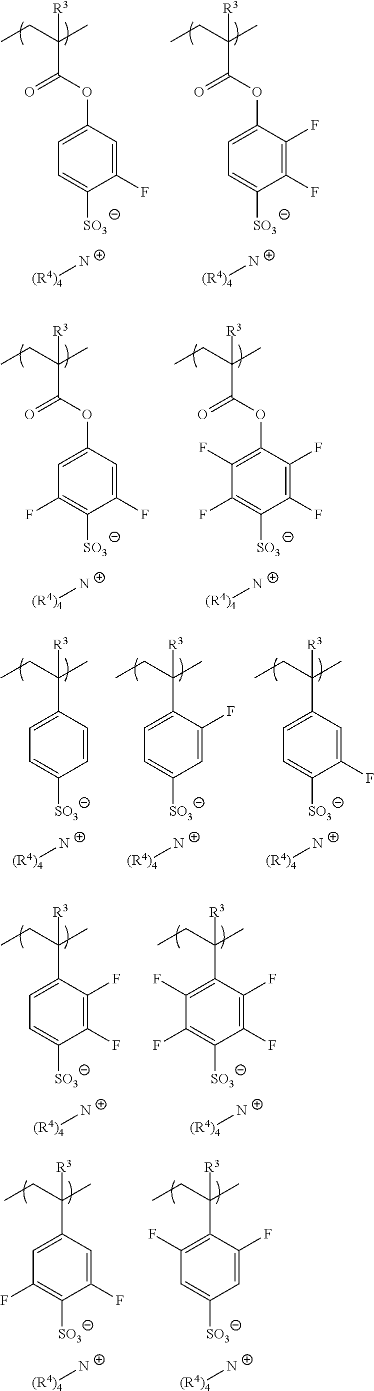

In each formula, R³ represents a hydrogen atom or an alkyl group.

Each R⁴ independently represents a hydrogen atom, a straight chained, branched or cyclic alkyl group having 1 to 20 carbon atoms, an alkenyl group having 2 to 20 carbon atoms, or an aryl group having 6 to 10 carbon atoms. The straight chained, branched or cyclic alkyl group having 1 to 20 carbon atoms and the alkenyl group having 2 to 20 carbon atoms for R⁴ may have a hydroxy group, an ether bond, an ester bond, a cyano group, an amino group, a double bond or a halogen atom. Two to four R⁴'s may combine with each other to form a ring having 3 to 20 carbon atoms.

Hydrophobic resin (D) may contain a repeating unit having a carboxylic acid amine salt structure. Hereinafter, the repeating unit having a carboxylic acid amine salt structure will be exemplified, but the present invention is not limited thereto.

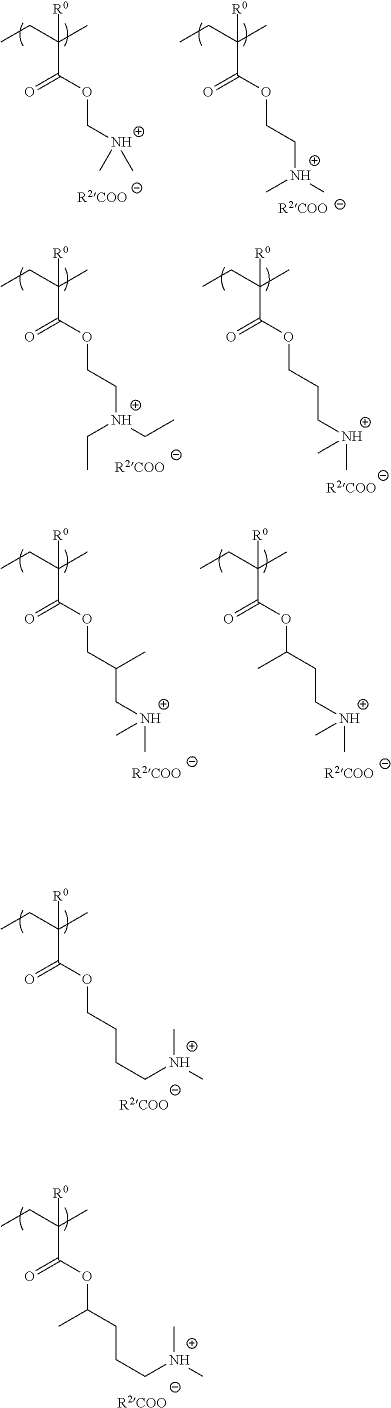

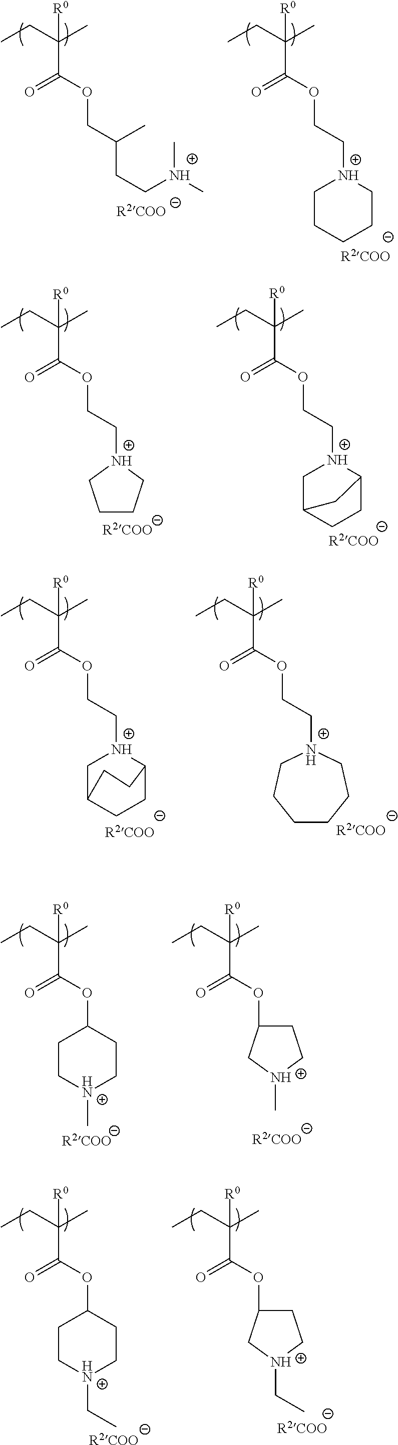

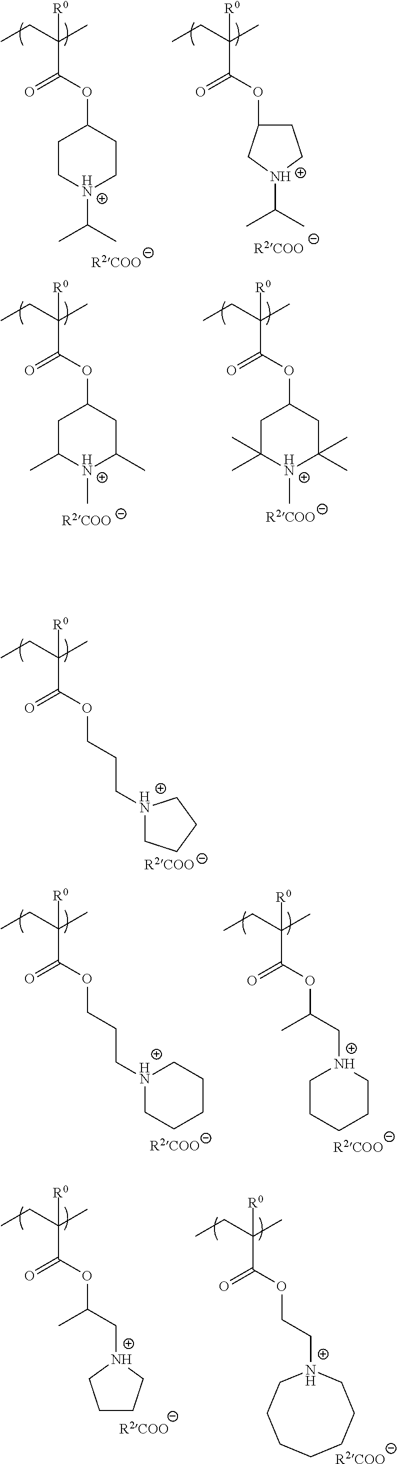

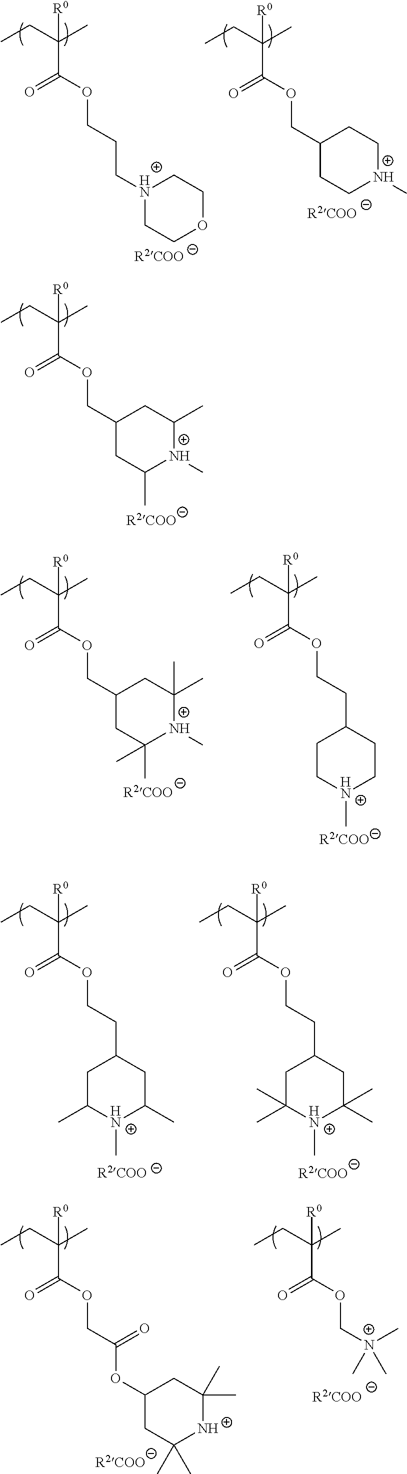

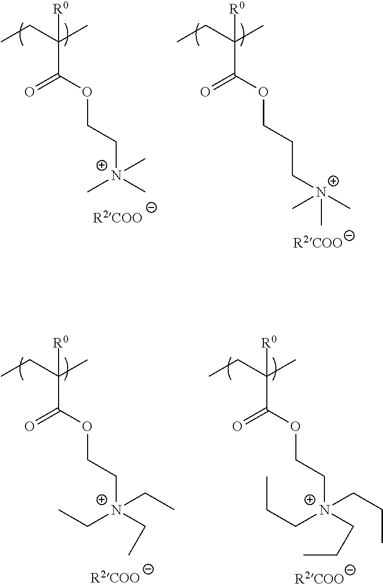

In each formula, R⁰ represents a hydrogen atom or an alkyl group.

Specific examples of a carboxylic acid anion represented by R²COO— include formic acid anion, acetic acid anion, propionic acid anion, butyric acid anion, isobutyric acid anion, valeric acid anion, isovaleric acid anion, pivalic acid anion, hexanoic acid anion, octanoic acid anion, cyclohexanecarboxylic acid anion, cyclohexylacetic acid anion, lauric acid anion, myristic acid anion, palmitic acid anion, stearic acid anion, phenylacetic acid anion, diphenylacetic acid anion, phenoxyacetic acid anion, mandelic acid anion, benzoylformic acid anion, cinnamic acid anion, dihydrocinnamic acid anion, benzoic acid anion, methylbenzoic acid anion, salicylic acid anion, naphthalenecarboxylic acid anion, anthracenecarboxylic acid anion, anthraquinonecarboxylic acid anion, hydroxyacetic acid anion, pivalic acid anion, lactic acid anion, methoxyacetic acid anion, 2-(2-methoxyethoxyl)acetic acid anion, 2-(2-(2-methoxyethoxyl)ethoxy)acetic acid anion, diphenolic acid anion, monochloroacetic acid anion, dichloroacetic acid anion, trichloroacetic acid anion, trifluoroacetic acid anion, pentafluoropropionic acid anion, heptafluorobutyric acid anion and the like, and monoanions of dicarboxylic acids such as succinic acid, tartaric acid, glutaric acid, pimelic acid, sebacic acid, phthalic acid, isophthalic acid, terephthalic acid, naphthalenedicarboxylic acid, cyclohexanedicarboxylic acid and cyclohexenedicarboxylic acid.

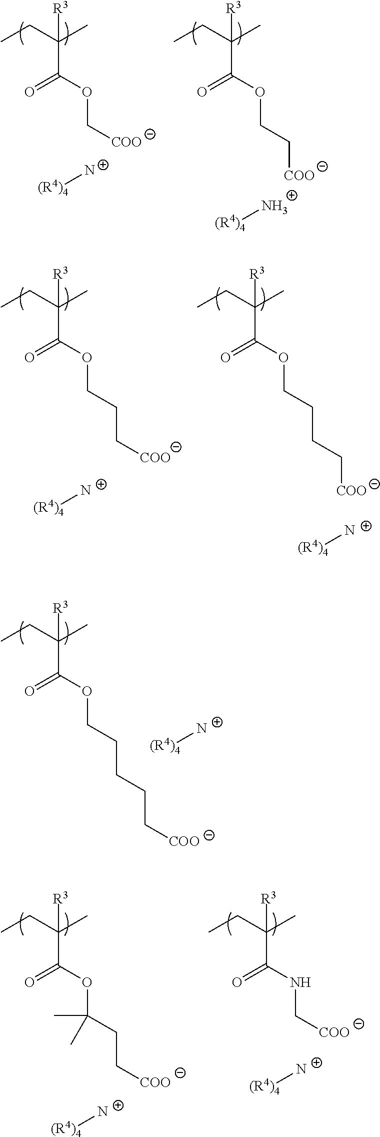

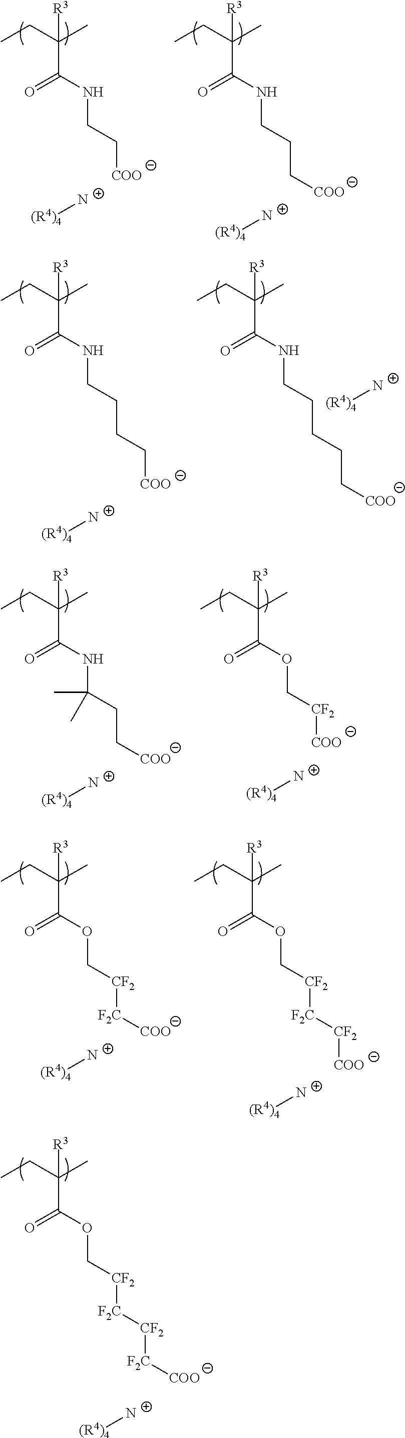

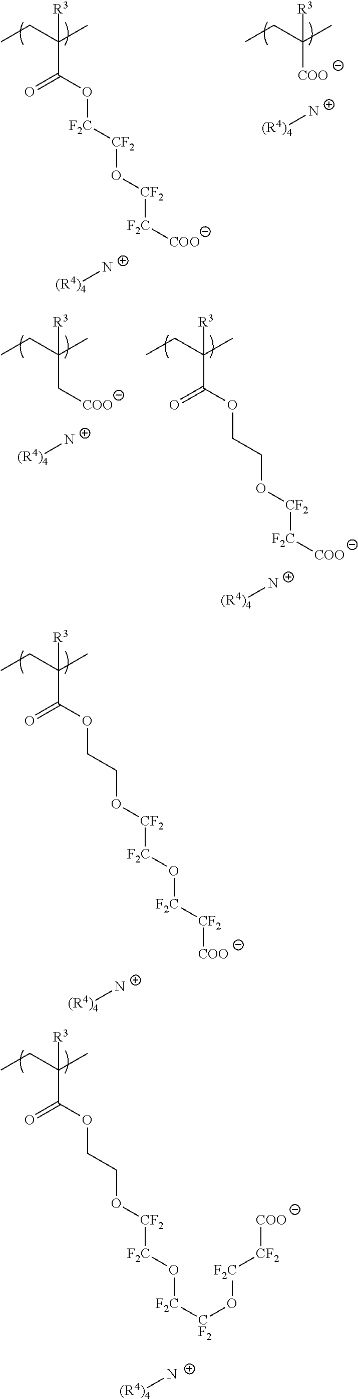

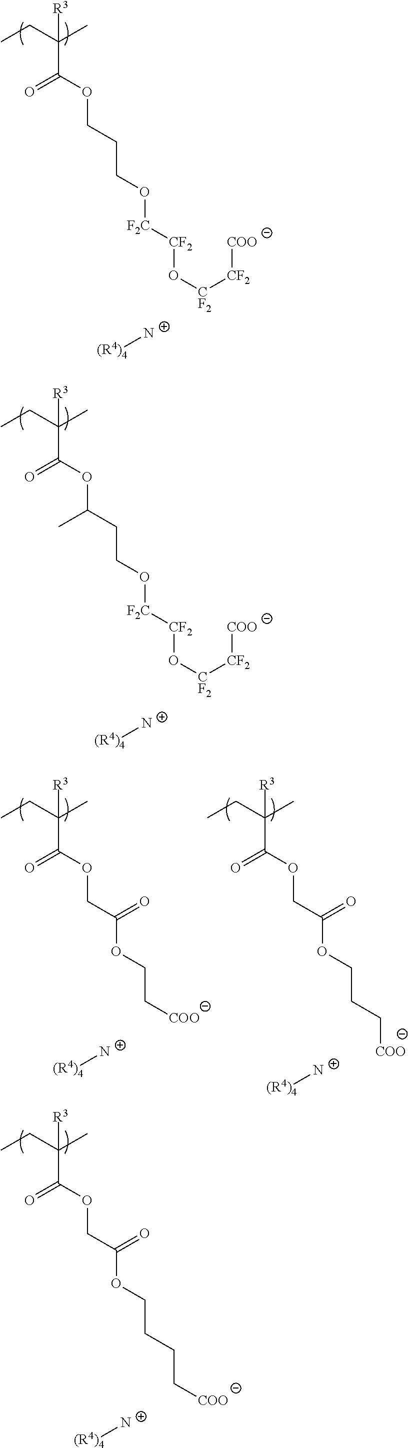

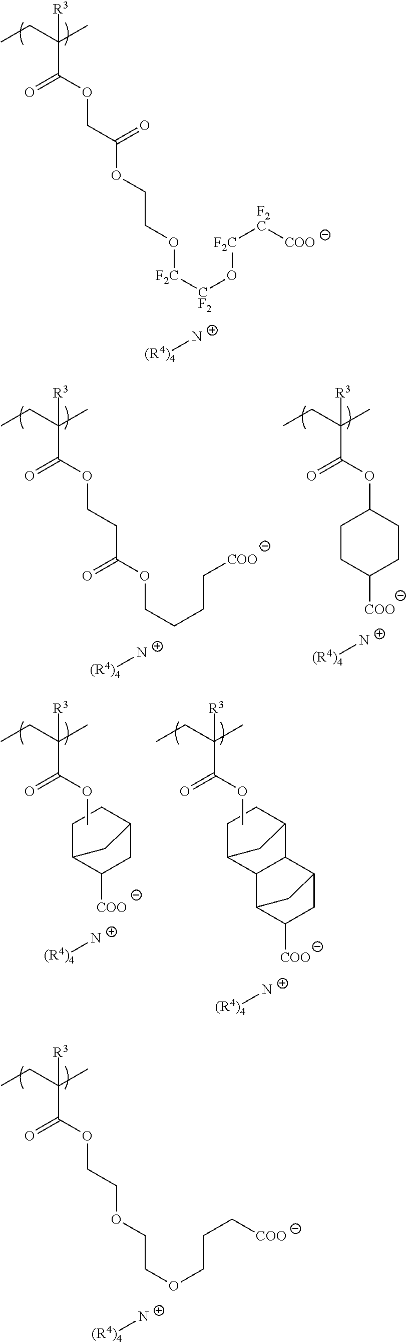

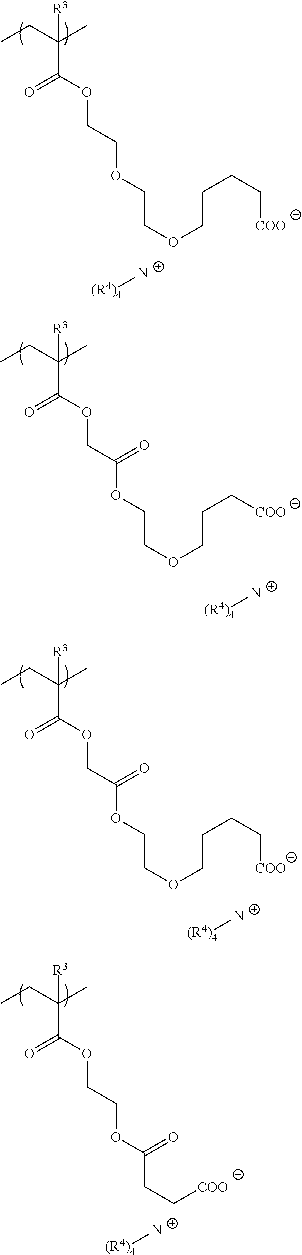

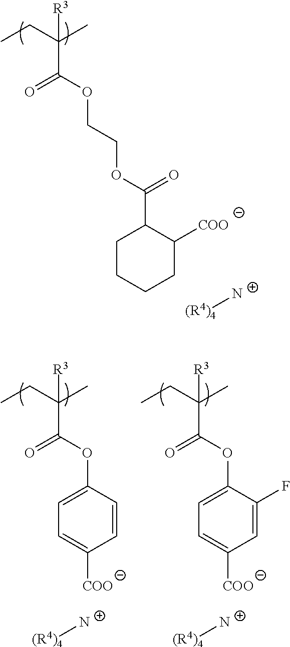

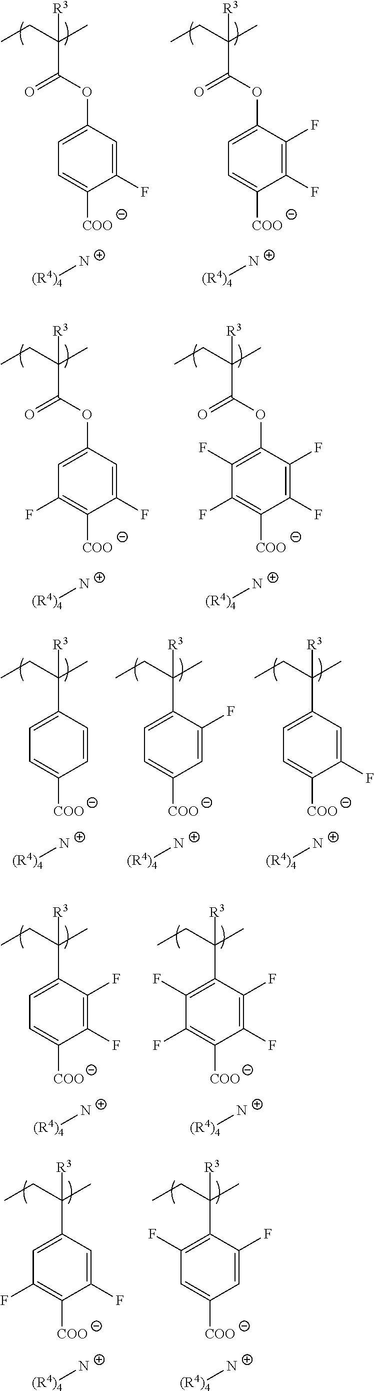

In each formula, R³ represents a hydrogen atom or an alkyl group.

Each R⁴ independently represents a hydrogen atom, a straight chained, branched or cyclic alkyl group having 1 to 20 carbon atoms, an alkenyl group having 2 to 20 carbon atoms, or an aryl group having 6 to 10 carbon atoms. The straight chained, branched or cyclic alkyl group having 1 to 20 carbon atoms and the alkenyl group having 2 to 20 carbon atoms for R⁴ may have a hydroxy group, an ether bond, an ester bond, a cyano group, an amino group, a double bond or a halogen atom. Two to four R⁴'s may combine with each other to form a ring having 3 to 20 carbon atoms.

Hydrophobic resin (D) may contain a repeating unit having an amine structure.

Hereinafter, the repeating unit having an amine structure will be exemplified, but the present invention is not limited thereto.

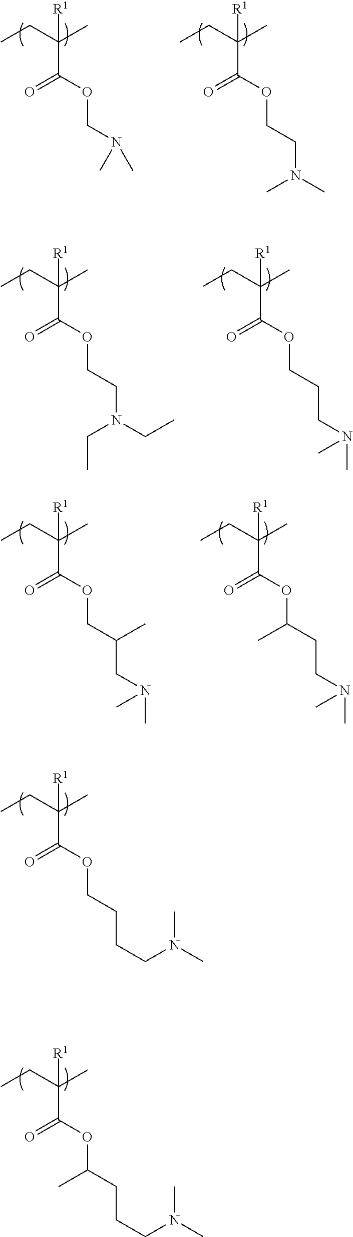

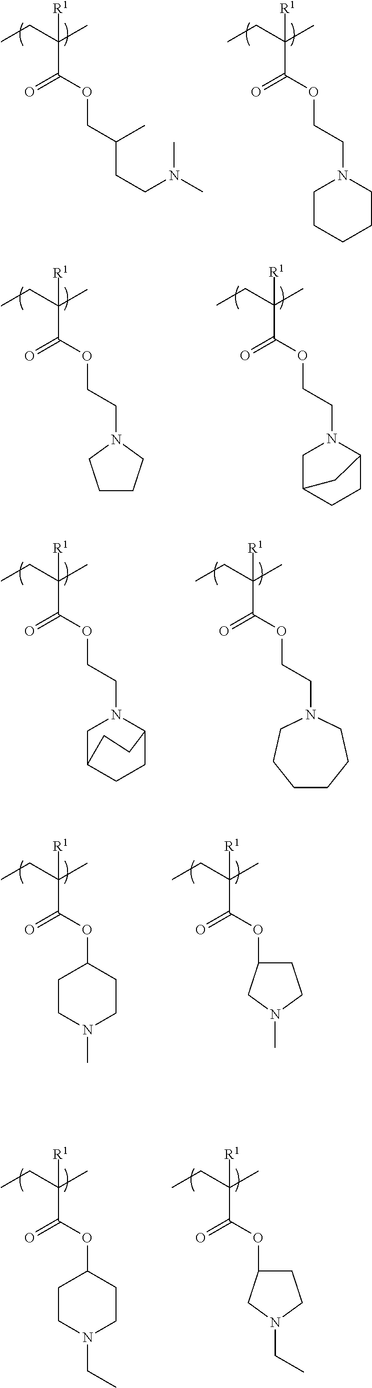

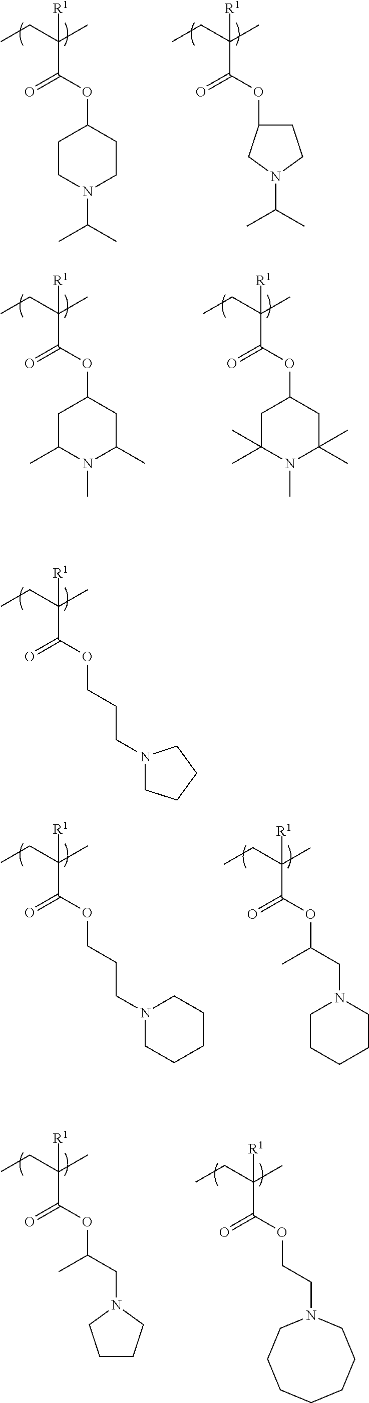

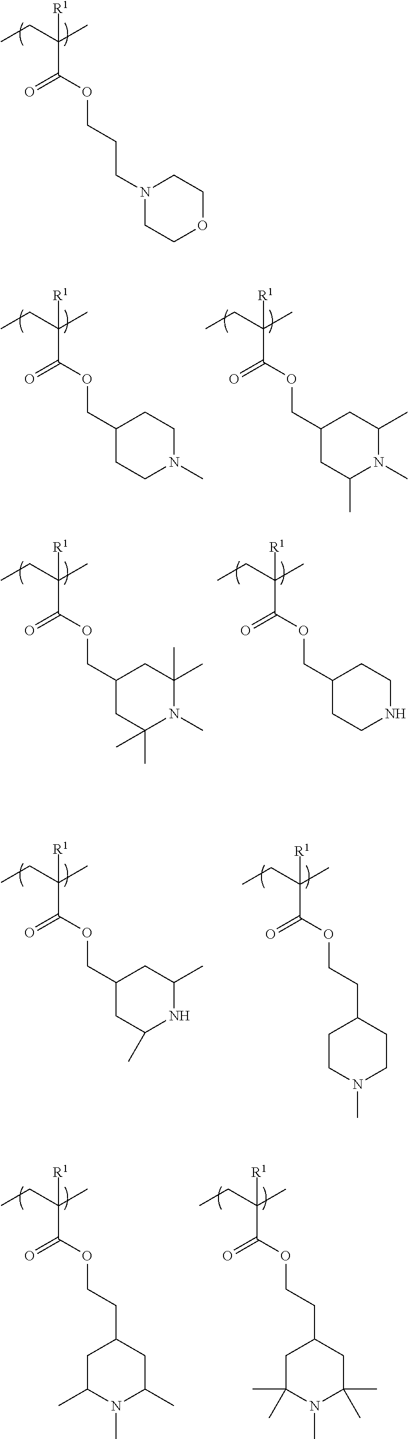

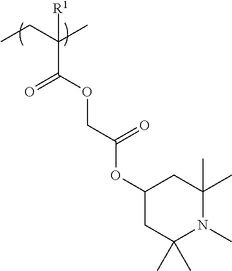

In each formula, R¹ represents a hydrogen atom or an alkyl group.

In the present invention, when hydrophobic resin (D) contains a repeating unit having a sulfonic acid amine salt structure, a repeating unit having a carboxylic acid amine salt structure or a repeating unit having an amine structure, each of the contents of the repeating unit having a sulfonic acid amine salt structure, the repeating unit having a carboxylic acid amine salt structure or the repeating unit having an amine structure in hydrophobic resin (D) is preferably 0 to 30 mol %, more preferably 0 to 20 mol %, and particularly preferably 0 to 10 mol %, based on all the repeating units of hydrophobic resin (D).

Further, as described above, it is preferred that hydrophobic resin (D) also includes a CH₃ partial structure in the side chain moiety thereof.

Here, the CH₃ partial structure (hereinafter, simply referred to as a “side chain CH₃ partial structure”), which the side chain moiety in resin (D) has, includes a CH₃ partial structure that an ethyl group, a propyl group and the like have.

Meanwhile, a methyl group (for example, an α-methyl group of the repeating unit having a methacrylic acid structure) directly bonded to the main chain of resin (D) slightly contributes to the surface uneven distribution of resin (D) due to the effects of the main chain and thus is not included in the CH₃ partial structure in the present invention.

More specifically, when resin (D) includes a repeating unit derived from a monomer having a polymerizable moiety having a carbon-carbon double bond, such as, for example, a repeating unit represented by the following Formula (M) and when R₁₁ to R₁₄ are a CH₃ “as it is”, the CH₃ is not included in the CH₃ partial structure in the present invention that the side chain moiety has.

Meanwhile, the CH₃ partial structure present through any atom from the C—C main chain is assumed to correspond to a CH₃ partial structure in the present invention. For example, when R₁₁ is an ethyl group (CH₂CH₃), R₁₁ is assumed to have “one” of the CH₃ partial structures in the present invention.

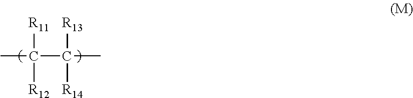

In Formula (M),

each of R₁₁ to R₁₄ independently represents a side chain moiety.

Examples of R₁₁ to R₁₄ in the side chain moiety include a hydrogen atom, a monovalent organic group and the like.

Examples of the monovalent organic group for R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, an arylaminocarbonyl group and the like, and these groups may further have a substituent.

Hydrophobic resin (D) is preferably a resin having a repeating unit having a CH₃ partial structure at the side chain moiety thereof, and more preferably has at least one repeating unit (x) of a repeating unit represented by the following Formula (II) and a repeating unit represented by the following Formula (III) as the repeating unit.

Hereinafter, the repeating unit represented by Formula (II) will be described in detail.

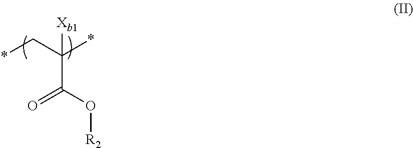

In Formula (II), X_{b1} represents a hydrogen atom, an alkyl group, a cyano group or a halogen atom, and R₂ represents an organic group which is stable against an acid and has one or more CH₃ partial structures. Here, more specifically, the organic group which is stable against an acid is preferably an organic group which does not have “a group capable of decomposing by the action of an acid to generate a polar group” described in resin (P).

The alkyl group of X_{b1} is preferably an alkyl group having 1 to 4 carbon atoms, and examples thereof include a methyl group, an ethyl group, a propyl group, a hydroxymethyl group, a trifluoromethyl group and the like, but a methyl group is preferred.

X_{b1} is preferably a hydrogen atom or a methyl group.

Examples of R₂ include an alkyl group, a cycloalkyl group, an alkenyl group, a cycloalkenyl group, an aryl group and an aralkyl group, which have one or more CH₃ partial structures. The aforementioned cycloalkyl group, alkenyl group, cycloalkenyl group, aryl group and aralkyl group may further have an alkyl group as a substituent.

R₂ is preferably an alkyl group or an alkyl-substituted cycloalkyl group, which has one or more CH₃ partial structures.

The organic group, which has one or more CH₃ partial structures and is stable against an acid as R₂, preferably has 2 to 10 CH₃ partial structures, and more preferably 2 to 8 CH₃ partial structures.

The alkyl group having one or more CH₃ partial structures in R₂ is preferably a branched alkyl group having 3 to 20 carbon atoms. Specific examples of the preferred alkyl group include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group and the like. An isobutyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group and a 2,3,5,7-tetramethyl-4-heptyl group are more preferred.

The cycloalkyl group having one or more CH₃ partial structures in R₂ may be monocyclic or polycyclic. Specific examples thereof include groups having a monocyclo, bicyclo, tricyclo and tetracyclo structure having 5 or more carbon atoms, and the like. The carbon number thereof is preferably 6 to 30, and particularly preferably 7 to 25. Preferred examples of the cycloalkyl group include an adamantyl group, a noradamantyl group, a decalin residue, a tricyclodecanyl group, a tetracyclododecanyl group, a norbornyl group, a cedrol group, a cyclopentyl group, a cyclohexyl group, a cycloheptyl group, a cyclooctyl group, a cyclodecanyl group and a cyclododecanyl group. More preferred examples thereof include an adamantyl group, a norbornyl group, a cyclohexyl group, a cyclopentyl group, a tetracyclododecanyl group and a tricyclodecanyl group. A norbornyl group, a cyclopentyl group and a cyclohexyl group are more preferred.

The alkenyl group having one or more CH₃ partial structures in R₂ is preferably a straight chained or branched alkenyl group having 1 to 20 carbons, and more preferably a branched alkenyl group.

The aryl group having one or more CH₃ partial structures in R₂ is preferably an aryl group having 6 to 20 carbon atoms, examples thereof include a phenyl group and a naphthyl group, and a phenyl group is preferred.

The aralkyl group having one or more CH₃ partial structures in R₂ is preferably an aralkyl group having 7 to 12 carbon atoms, and examples thereof include a benzyl group, a phenethyl group, a naphthylmethyl group and the like.

Specific examples of a hydrocarbon group having two or more CH₃ partial structures in R₂ include an isopropyl group, an isobutyl group, a t-butyl group, a 3-pentyl group, a 2-methyl-3-butyl group, a 3-hexyl group, a 2,3-dimethyl-2-butyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 4-isopropylcyclohexyl group, a 4-t-butylcyclohexyl group, an isobornyl group and the like. More preferred are an isobutyl group, a t-butyl group, a 2-methyl-3-butyl group, a 2,3-dimethyl-2-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 3,5-di-tert-butylcyclohexyl group, a 4-isopropylcyclohexyl group, a 4-t-butylcyclohexyl group and an isobornyl group.

Preferred specific examples of the repeating unit represented by Formula (II) will be described below. Meanwhile, the present invention is not limited thereto.

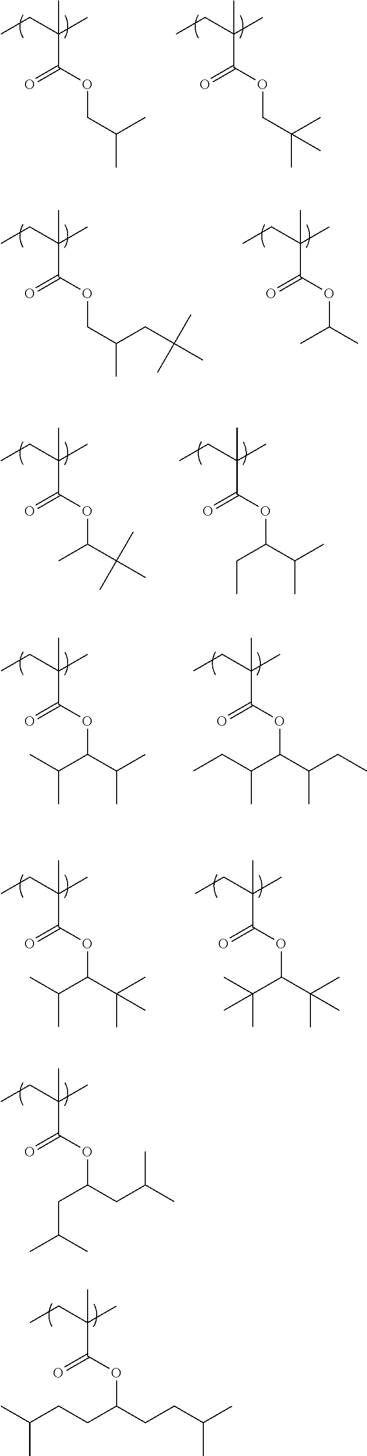

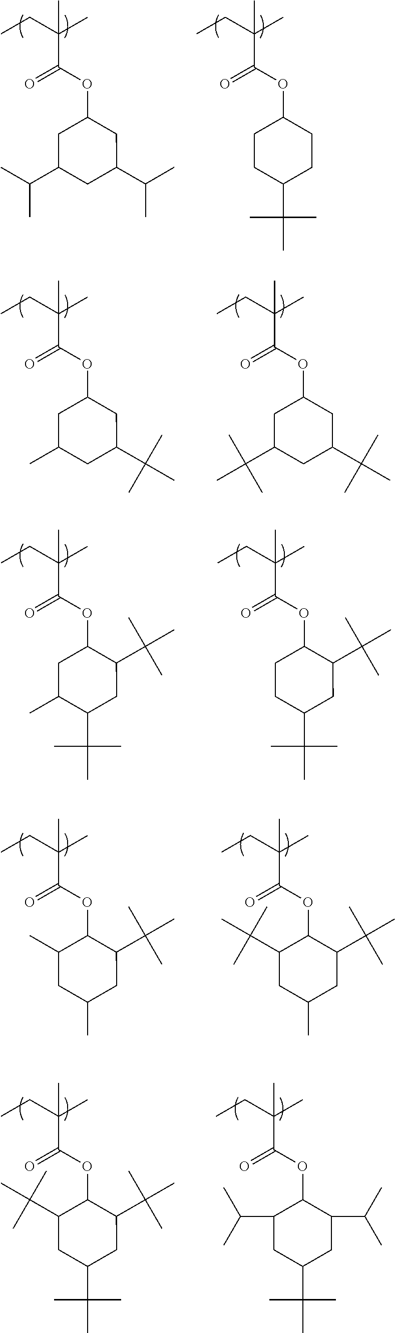

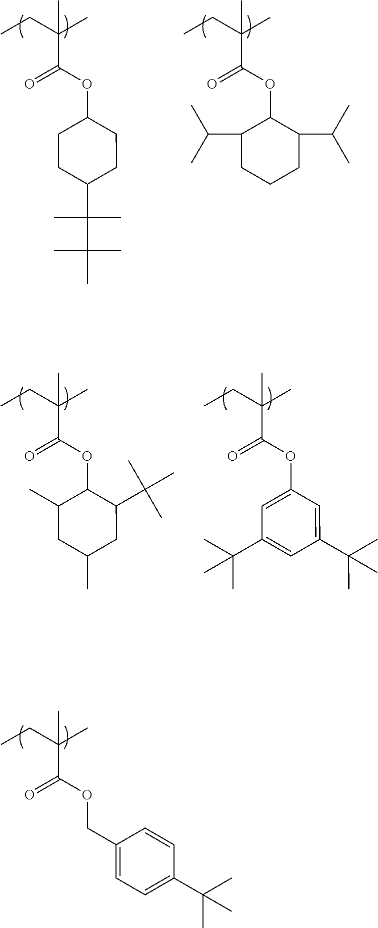

The repeating unit represented by Formula (II) is preferably a repeating unit that is stable against an acid (non-acid-decomposable), and specifically, is preferably a repeating unit having no group capable of decomposing by the action of an acid to generate a polar group.

Hereinafter, the repeating unit represented by Formula (III) will be described in detail.

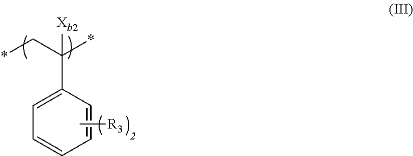

In Formula (III), X_{b2} represents a hydrogen atom, an alkyl group, a cyano group or a halogen atom, R₃ represents an organic group which is stable against an acid and has one or more CH₃ partial structures, and n represents an integer of 1 to 5.

The alkyl group of X_{b2} is preferably an alkyl group having 1 to 4 carbon atoms, and examples thereof include a methyl group, an ethyl group, a propyl group, a hydroxymethyl group, a trifluoromethyl group or the like, but a hydrogen atom is preferred.

X_{b2} is preferably a hydrogen atom.

Since R₃ is an organic group which is stable against an acid, more specifically, R₃ is preferably an organic group which does not have “a group capable of decomposing by the action of an acid to generate a polar group” described in resin (P).

Examples of R₃ include an alkyl group having one or more CH₃ partial structures.

The organic group as R₃, which has one or more CH₃ partial structures and is stable against an acid, preferably has 1 to 10 CH₃ partial structures, more preferably 1 to 8 CH₃ partial structures, and even more preferably 1 to 4 CH₃ partial structures.

The alkyl group having one or more CH₃ partial structures in R₃ is preferably a branched alkyl group having 3 to 20 carbon atoms. Specific examples of the preferred alkyl group include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group and the like. Examples of the more preferred alkyl group include an isobutyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group and a 2,3,5,7-tetramethyl-4-heptyl group.

Specific examples of the alkyl group having two or more CH₃ partial structures in R₃ include an isopropyl group, an isobutyl group, a t-butyl group, a 3-pentyl group, a 2,3-dimethylbutyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group and the like. More preferably, those having from 5 to 20 carbon atoms are more preferred, and examples thereof include an isopropyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group and a 2,6-dimethylheptyl group.

n represents an integer of 1 to 5, more preferably an integer of 1 to 3, and even more preferably 1 or 2.

Preferred specific examples of the repeating unit represented by Formula (III) will be described below. Meanwhile, the present invention is not limited thereto.

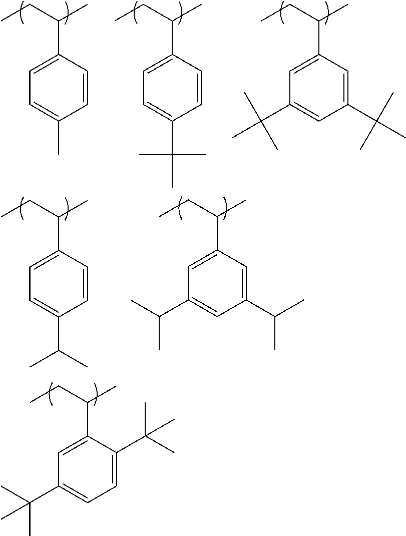

The repeating unit represented by Formula (III) is preferably a repeating unit that is stable against an acid (non-acid-decomposable), and specifically, is preferably a repeating unit having no group capable of decomposing by the action of an acid to generate a polar group.

When resin (D) includes a CH3 partial structure in the side chain moiety thereof and particularly has no fluorine atom and silicon atom, a content of at least one repeating unit (x) of the repeating unit represented by Formula (II) and the repeating unit represented by Formula (III) is preferably 90 mol % or more, and more preferably 95 mol % or more, based on all the repeating units of resin (D). The content is usually 100 mol % or less based on all the repeating units of resin (D).

Resin (D) contains at least one repeating unit (x) of the repeating unit represented by Formula (II) and the repeating unit represented by Formula (III) in an amount of 90 mol % or more based on all the repeating units of resin (D), thereby increasing the surface free energy of resin (D). As a result, it is difficult for resin (D) to be unevenly distributed on the surface of the resist film, and thus the static/dynamic contact angle of the resist film against water may be certainly enhanced, thereby enhancing an immersion liquid follow-up property.

In addition, even when hydrophobic resin (D) includes (i) a fluorine atom and/or a silicon atom and even when hydrophobic resin (D) includes (ii) a CH₃ partial structure in the side chain moiety thereof, hydrophobic resin (D) may have at least one group selected from the group of following (x) to (z).

(x) an acid group,

(y) a group having a lactone structure, an acid anhydride group or an acid imide group, and

(z) a group capable of decomposing by the action of an acid

Examples of the acid group (x) include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group and the like.

Preferred examples of the acid group include a fluorinated alcohol group (preferably hexafluoroisopropanol), a sulfonimide group and a bis(alkylcarbonyl)methylene group.

Examples of the repeating unit having the acid group (x) include a repeating unit, in which the acid group is directly bonded to the main chain of the resin, such as repeating unit by an acrylic acid or a methacrylic acid, a repeating unit in which the acid group is bonded to the main chain of the resin through a linking group or the like, and furthermore, the repeating unit may also be introduced into the end of the polymer chain by using a polymerization initiator or a chain transfer agent each having an acid group at the time of polymerization, and all of these cases are preferred. The repeating unit having the acid group (x) may have at least one of a fluorine atom and a silicon atom.

The content of the repeating unit having the acid group (x) is preferably 1 to 50 mol %, more preferably 3 to 35 mol %, and even more preferably 5 to 20 mol %, based on all the repeating units in hydrophobic resin (D).

Specific examples of the repeating unit having the acid group (x) will be shown below, but the present invention is not limited thereto. In the Formulas, Rₓ represents a hydrogen atom, CH₃, CF₃ or CH₂OH.

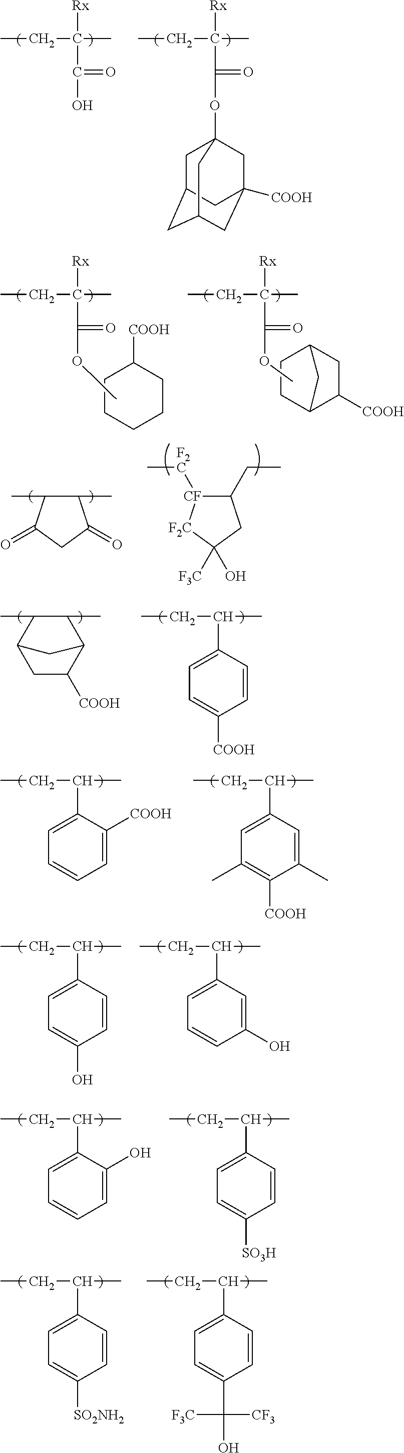

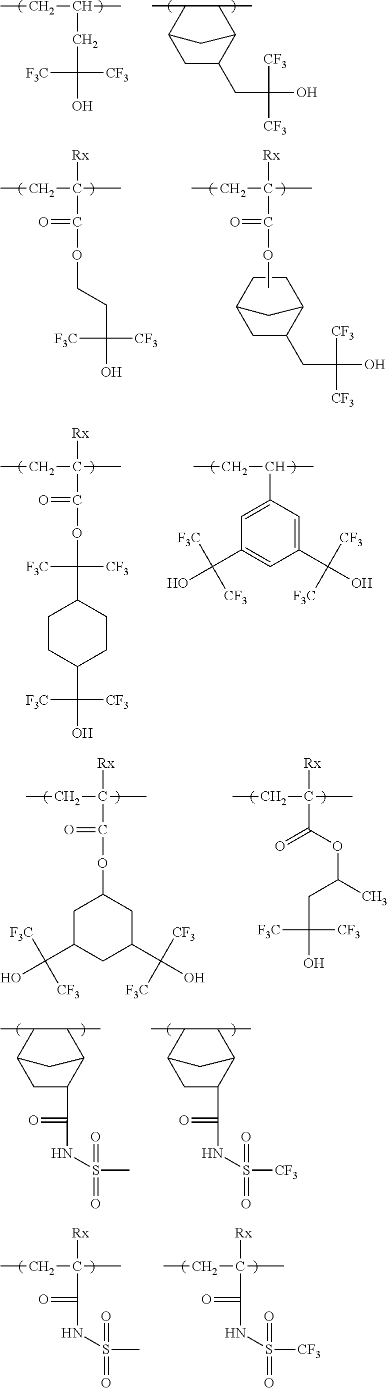

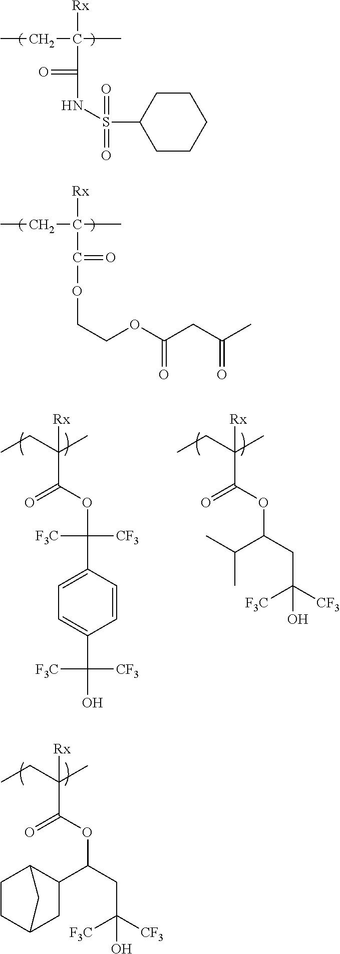

As (y) the group having a lactone structure, the acid anhydride group or the acid imide group, a group having a lactone structure is particularly preferred.

Examples of the repeating unit including these groups include a repeating unit in which the group is directly bonded to the main chain of the resin, such as a repeating unit by an acrylic acid ester or a methacrylic acid ester. In addition, the repeating unit may be a repeating unit in which the group is bonded to the main chain of the resin through a linking group. Furthermore, the repeating unit may be introduced into the end of the resin by using a polymerization initiator or a chain transfer agent having the group at the time of polymerization.

Examples of the repeating unit having a group having a lactone structure are the same as those of the repeating unit having a lactone structure, which is previously described in the paragraph of acid-decomposable resin (A).

The content of the repeating unit having a group having a lactone structure, an acid anhydride group or an acid imide group is preferably 1 to 100 mol %, more preferably 3 to 98 mol %, and even more preferably 5 to 95 mol %, based on all the repeating units in hydrophobic resin (D).

Examples of the repeating unit having (z) a group capable of decomposing by the action of an acid in hydrophobic resin (D) are the same as those of the repeating unit having an acid-decomposable group, which is exemplified in resin (A).

The repeating unit having (z) a group capable of decomposing by the action of an acid may have at least one of a fluorine atom and a silicon atom.

In hydrophobic resin (D), the content of the repeating unit having (z) a group capable of decomposing by the action of an acid is preferably 1 to 80 mol %, more preferably 10 to 80 mol %, and even more preferably 20 to 60 mol %, based on all the repeating units in resin (D).

Hydrophobic resin (D) may further have a repeating unit represented by the following Formula (III).

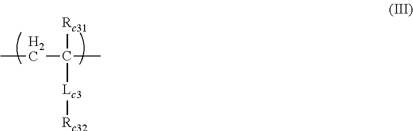

In Formula (III),

R_{c31} represents a hydrogen atom, an alkyl group (which may be substituted with a fluorine atom or the like), a cyano group or a —CH₂—O—Ra_{c2} group. In the formula, Rac₂ represents a hydrogen atom, an alkyl group or an acyl group. R_{c31} is preferably a hydrogen atom, a methyl group, a hydroxymethyl group and a trifluoromethyl group, and particularly preferably a hydrogen atom and a methyl group.

R_{c32} represents a group having an alkyl group, a cycloalkyl group, an alkenyl group, a cycloalkenyl group or an aryl group. These groups may be substituted with a group including a fluorine atom or a silicon atom.

L_{c3} represents a single bond or a divalent linking group.

In Formula (III), the alkyl group of R_{c32} is preferably a straight chained or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms, and more preferably a phenyl group or a naphthyl group, and these groups may have a substituent.

R_{c32} is preferably an unsubstituted alkyl group or an alkyl group substituted with a fluorine atom.

The divalent linking group of L_{c3} is preferably an alkylene group (preferably having 1 to 5 carbon atoms), an ether bond, a phenylene group or an ester bond (a group represented by —COO—).

The content of the repeating unit represented by Formula (III) is preferably 1 to 100 mol %, more preferably 10 to 90 mol %, and even more preferably 30 to 70 mol %, based on all the repeating units in the hydrophobic resin.

It is also preferred that hydrophobic resin (D) further has a repeating unit represented by the following Formula (CII-AB).

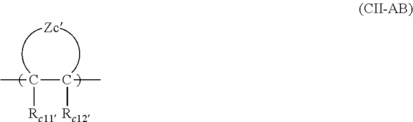

n Formula (CII-AB),

each of R_{c11}′ and R_{c12}′ independently represents a hydrogen atom, a cyano group, a halogen atom or an alkyl group.

Z_{c}′ includes two carbon atoms (C—C) to which Z_{c}′ is bonded and represents an atomic group for forming an alicyclic structure.

The content of the repeating unit represented by Formula (CII-AB) is preferably 1 to 100 mol %, more preferably 10 to 90 mol %, and even more preferably 30 to 70 mol %, based on all the repeating units in the hydrophobic resin.

Hereinafter, specific examples of the repeating units represented by Formulas (III) and (CII-AB) will be described below, but the present invention is not limited thereto. In the Formulas, Ra represents H, CH₃, CH₂OH, CF₃ or CN.

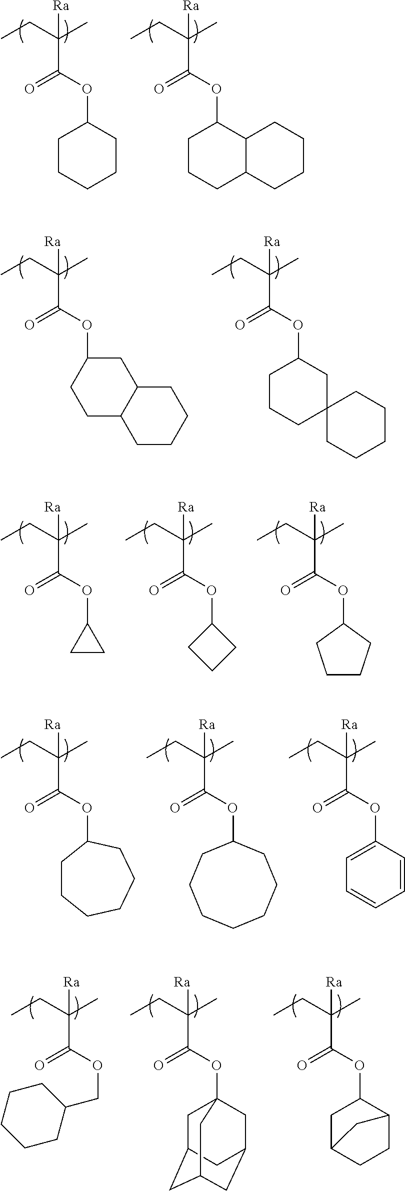

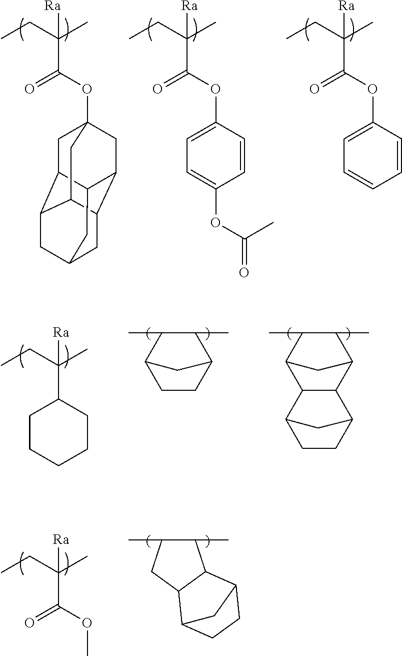

When the hydrophobic resin (D) has a fluorine atom, the content of the fluorine atom is preferably 5 to 80% by mass, and more preferably 10 to 80% by mass, based on the weight average molecular weight of hydrophobic resin (D). Furthermore, the repeating unit including a fluorine atom is preferably 10 to 100 mol %, and more preferably 30 to 100 mol %, based on all the repeating units included in the hydrophobic resin (D).

When hydrophobic resin (D) has a silicon atom, the content of the silicon atom is preferably from 2 to 50% by mass, and more preferably 2 to 30% by mass, based on the weight average molecular weight of the hydrophobic resin (D). Further, the repeating unit including a silicon atom is preferably 10 to 100 mol %, and more preferably 20 to 100 mol %, based on all the repeating units included in the hydrophobic resin (D).

Meanwhile, particularly when resin (D) includes a CH3 partial structure in the side chain moiety thereof, the form that resin (D) contains substantially no fluorine atom and silicon atom is also preferred, and in this case, specifically, the content of the repeating unit having a fluorine atom or a silicon atom is preferably 5 mol % or less, more preferably 3 mol % or less, and even more preferably 1 mol % or less, based on all the repeating units in resin (D), and is ideally 0 mol %, that is, containing no fluorine atom and silicon atom. In addition, it is preferred that resin (D) is substantially composed of only a repeating unit composed of only an atom selected from a carbon atom, an oxygen atom, a hydrogen atom, a nitrogen atom and a sulfur atom. More specifically, the repeating unit composed only of an atom selected from a carbon atom, an oxygen atom, a hydrogen atom, a nitrogen atom and a sulfur atom is present in an amount of preferably 95 mol % or more, more preferably 97 mol % or more, even more preferably 99 mol % or more, and ideally 100 mol %, based on all the repeating units of resin (D).

The weight average molecular weight of hydrophobic resin (D) in terms of a standard polystyrene in accordance with the GPC method is preferably 1,000 to 100,000, more preferably 1,000 to 50,000, and even more preferably 2,000 to 15,000.

Furthermore, hydrophobic resin (D) may be used either alone or in combination of a plurality thereof.

The content of the hydrophobic resin (D) in the composition is preferably 0.01 to 10% by mass, more preferably from 0.05 to 8% by mass, and even more preferably from 0.1 to 5% by mass, based on the total solid content in the composition of the present invention.

In hydrophobic resin (D), similarly to resin (P) and resin (A), it is natural that the content of impurities such as metal is small, and the content of residual monomers or oligomer components is preferably 0.01 to 5% by mass, more preferably 0.01 to 3% by mass, and even more preferably 0.05 to 1% by mass. Accordingly, it is possible to obtain an actinic ray-sensitive or radiation-sensitive resin composition free from extraneous substances in liquid and change in sensitivity and the like with time. Further, from the viewpoint of resolution, resist shape, side wall of resist pattern, roughness and the like, the molecular weight distribution (Mw/Mn, also referred to as polydispersity) is in a range of preferably 1 to 5, more preferably 1 to 3, and even more preferably 1 and 2.

As for resin (D), various commercially available products may be used, and resin (D) may be synthesized by a typical method (for example, radical polymerization). Examples of a general synthesis method include a batch polymerization method of dissolving monomer species and an initiator in a solvent and heating the solution, thereby performing the polymerization, a dropping polymerization method of adding dropwise a solution containing monomer species and an initiator to a heated solvent over 1 to 10 hours, and the like, and a dropping polymerization method is preferred.

The reaction solvent, polymerization initiator, reaction conditions (temperature, concentration and the like) and purification method after reaction are the same as those described in resin (A), but in the synthesis of hydrophobic resin (D), the reaction concentration is preferably 30 to 50% by mass.

Hereinafter, specific examples of hydrophobic resin (D) will be shown. In addition, the molar ratio (corresponding to each repeating unit sequentially from the left), the weight average molecular weight and the polydispersity of the repeating unit in each resin are shown in the following Tables.

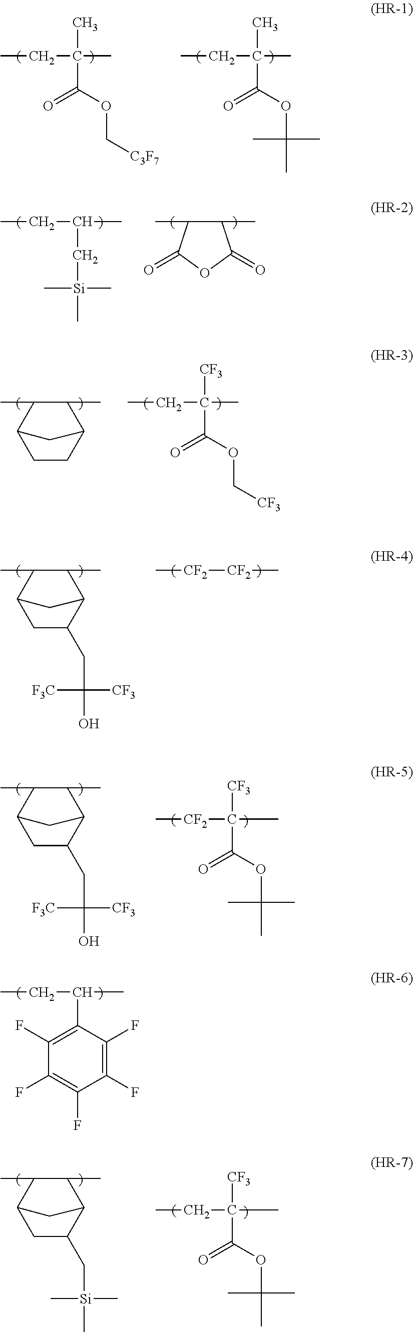

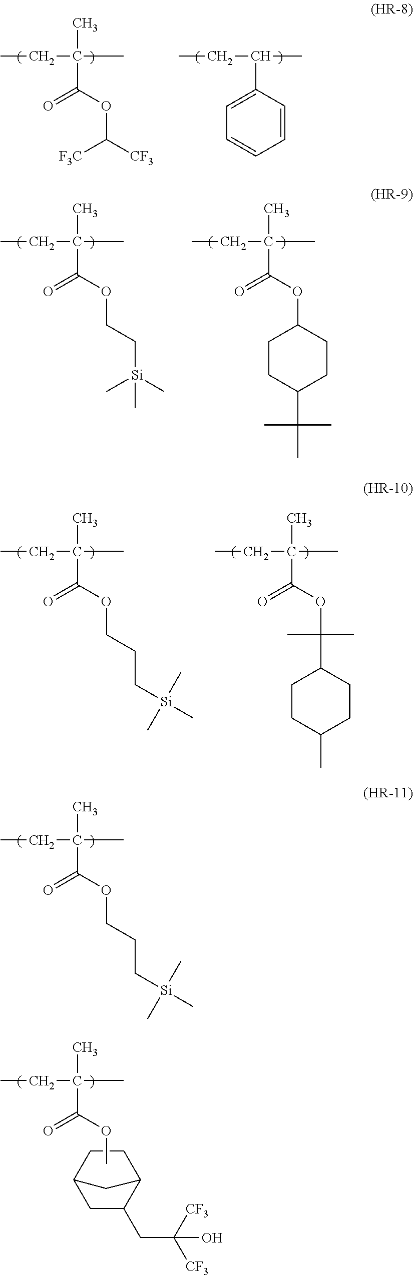

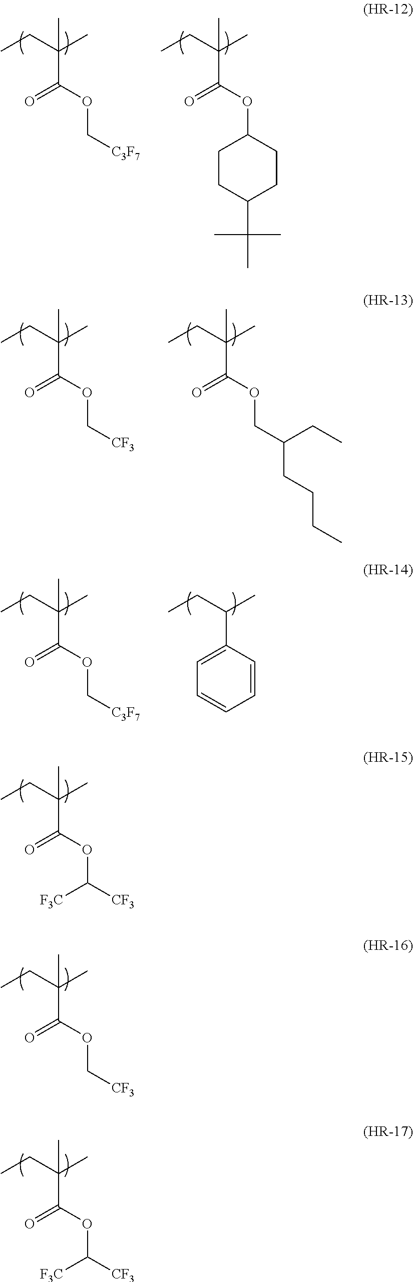

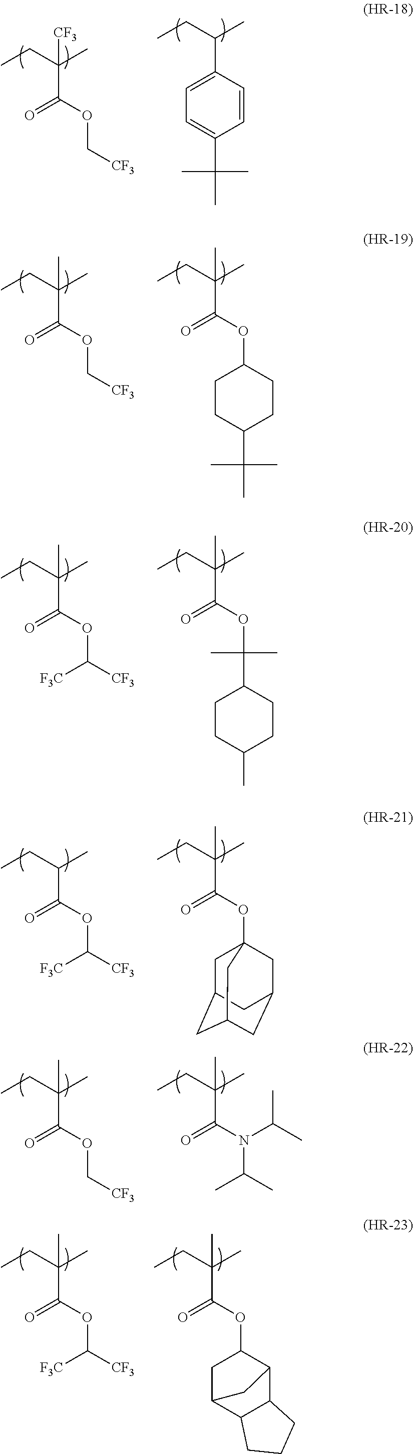

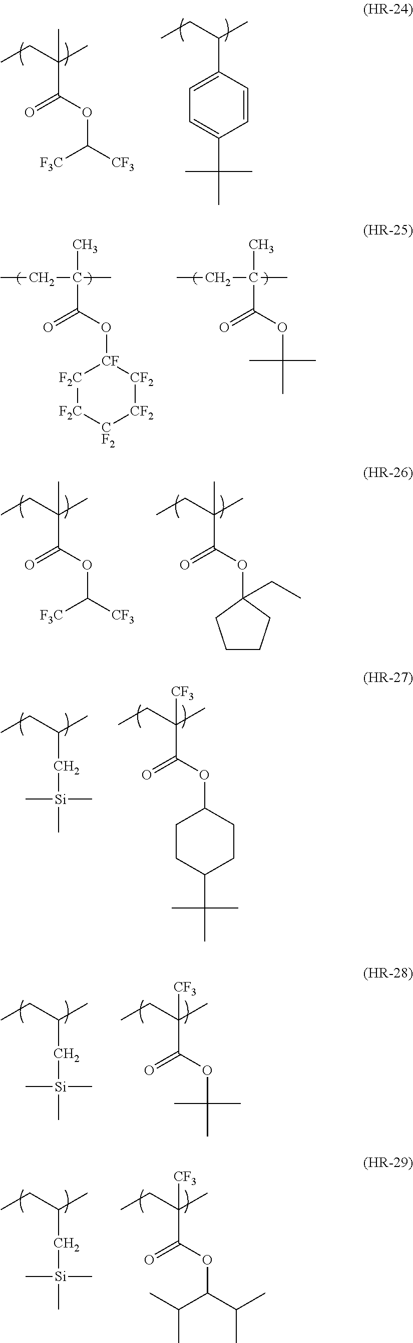

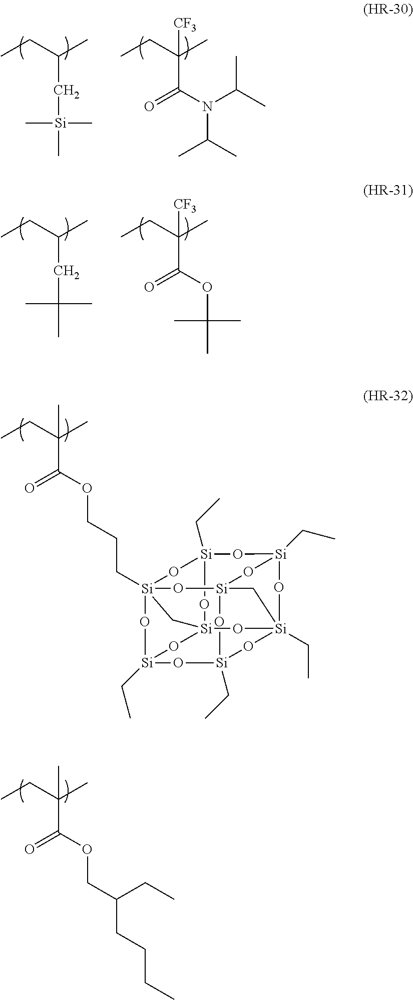

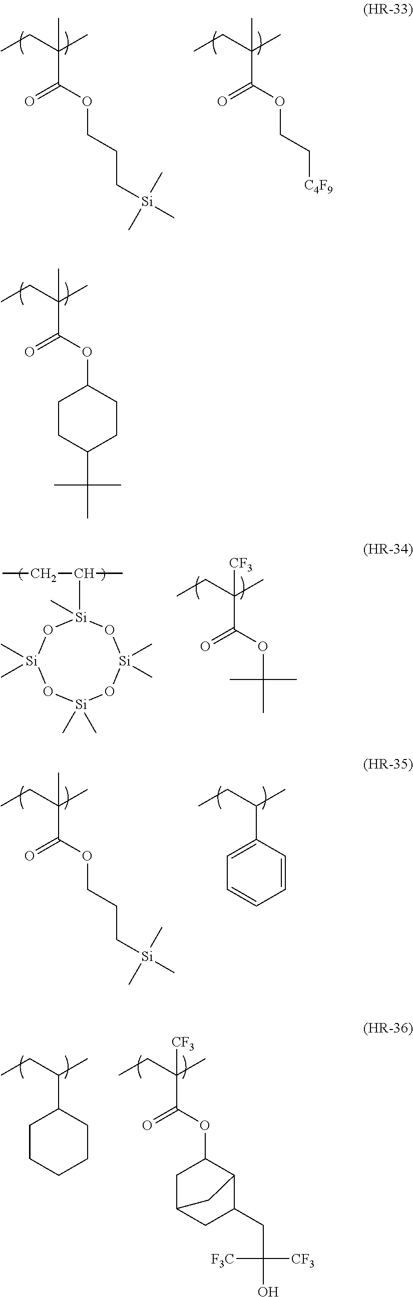

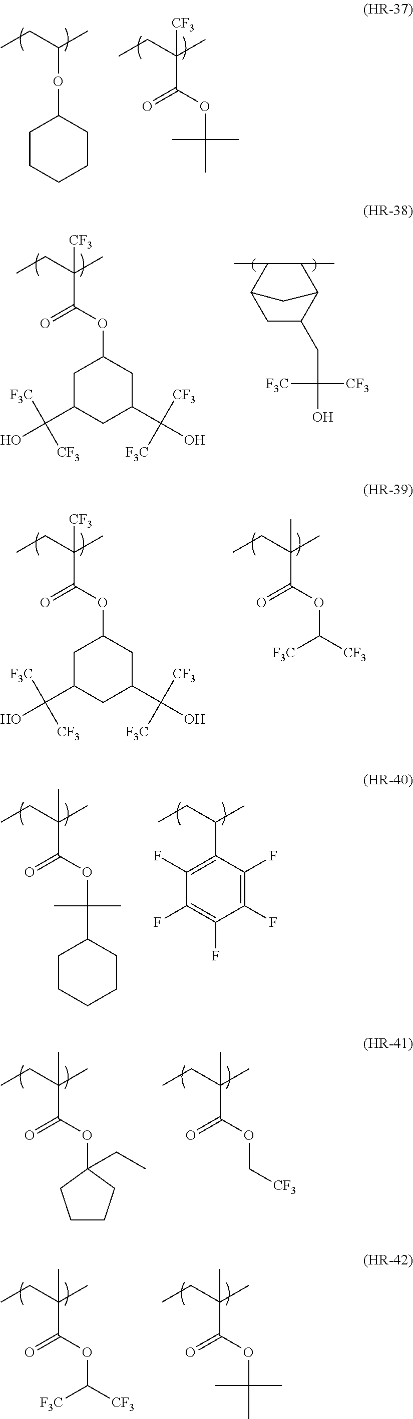

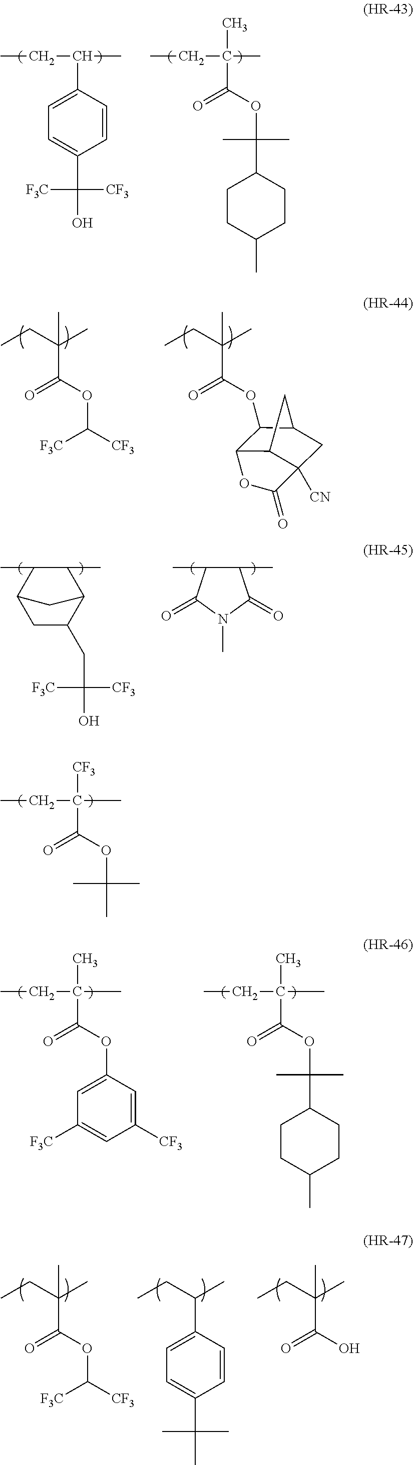

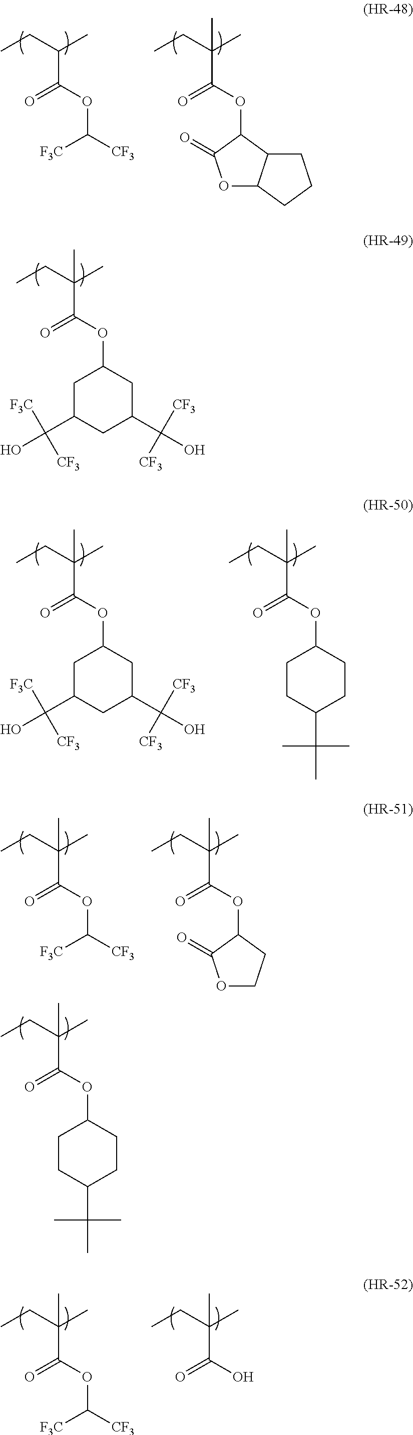

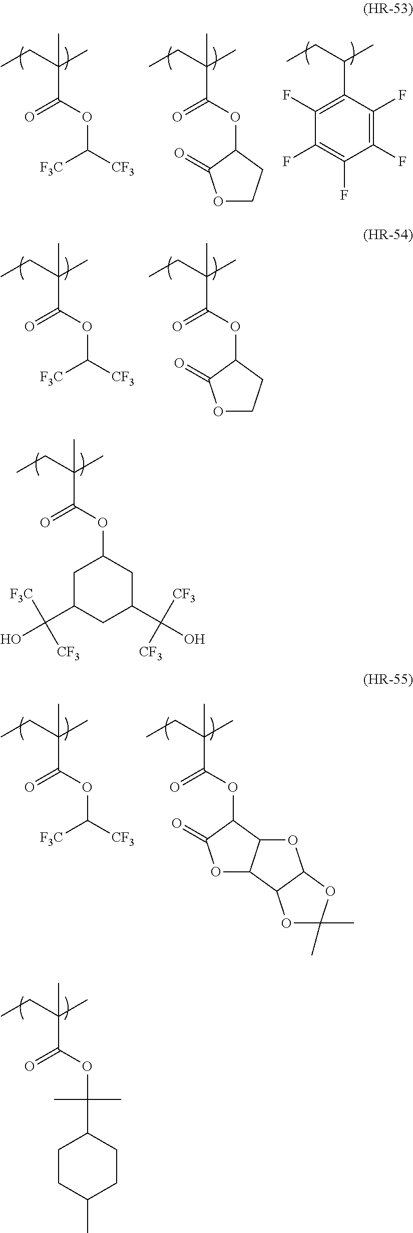

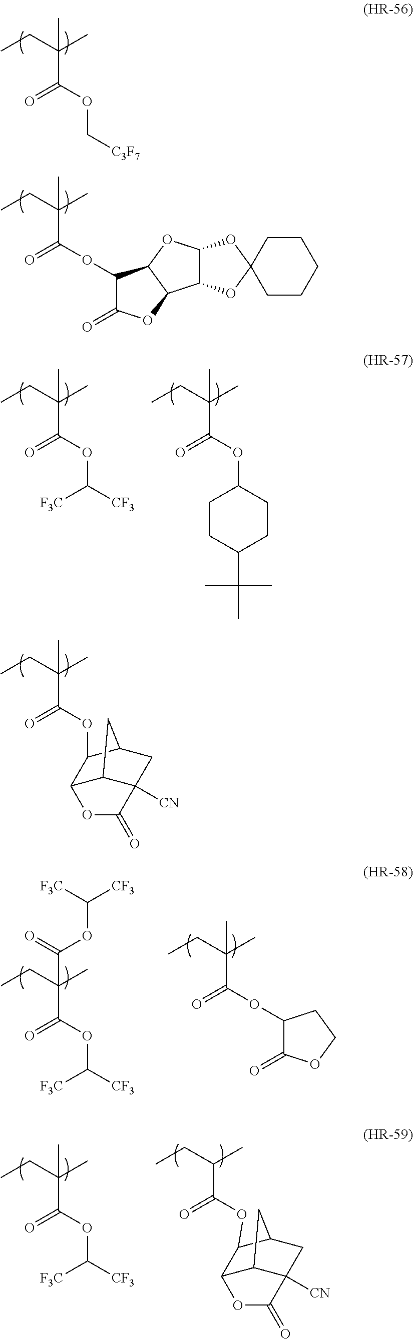

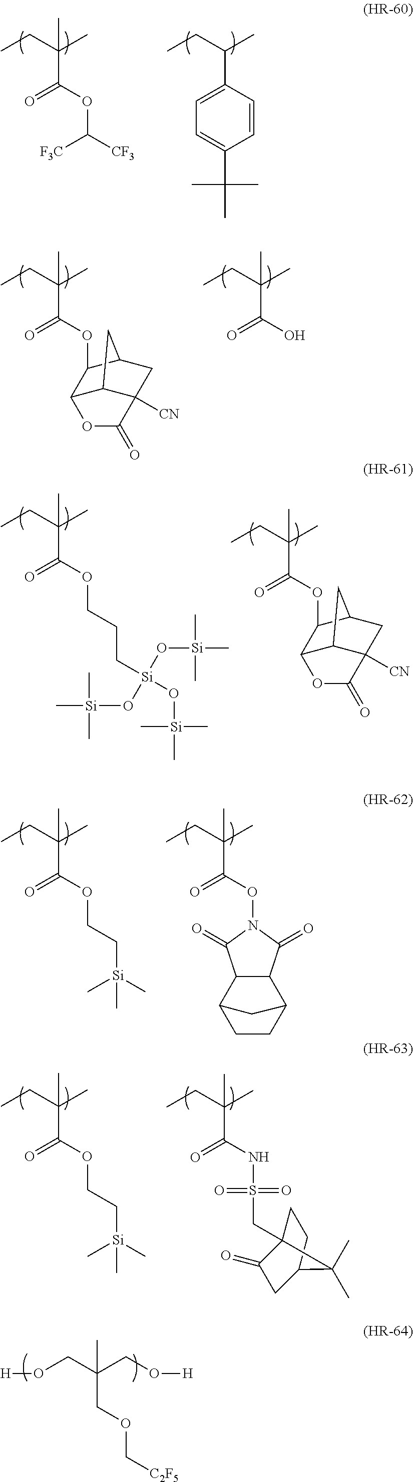

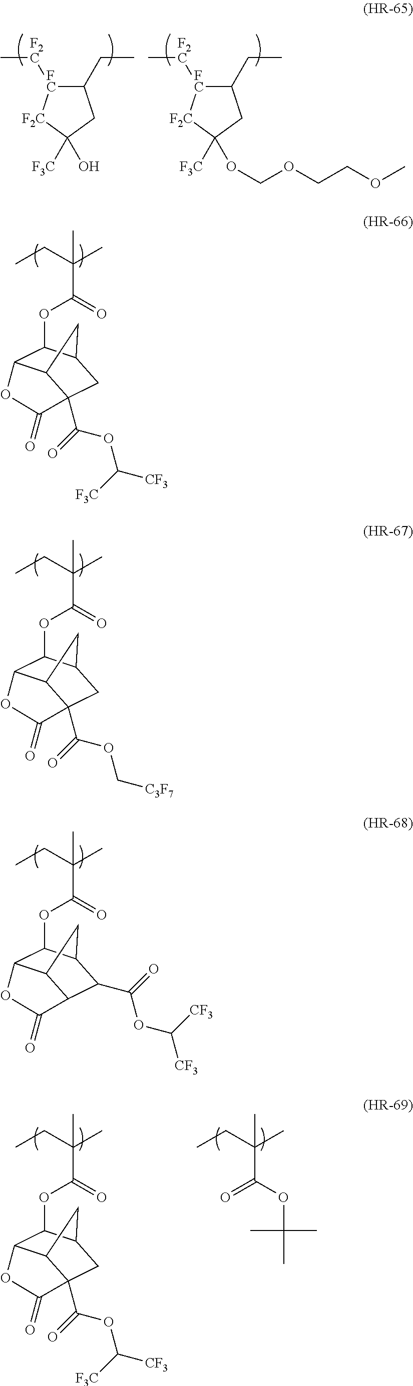

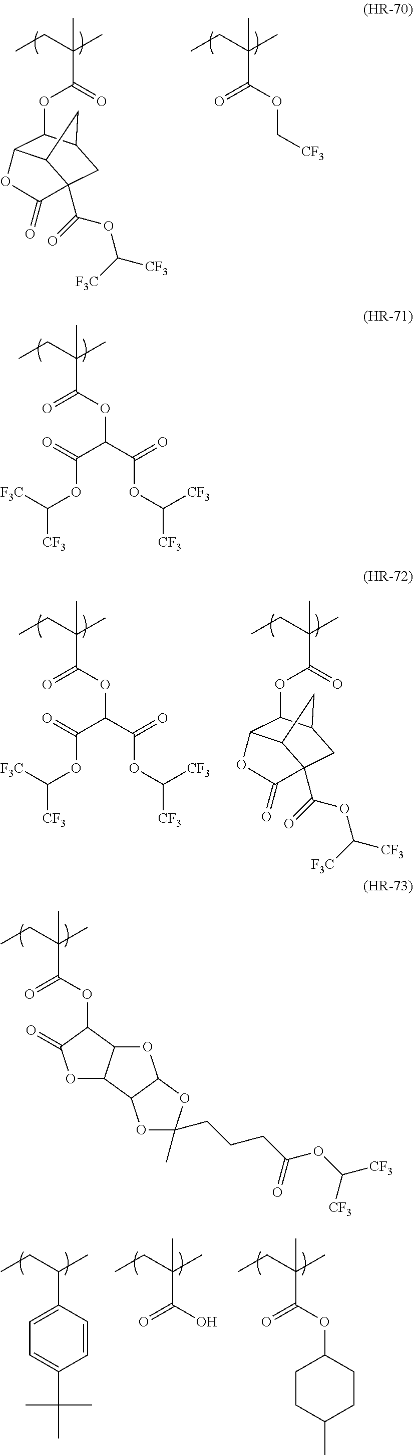

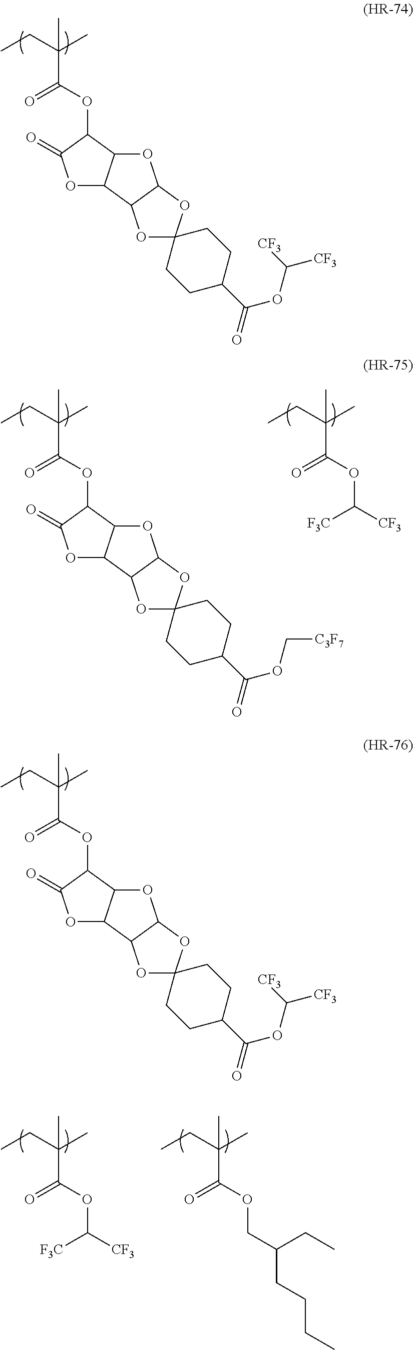

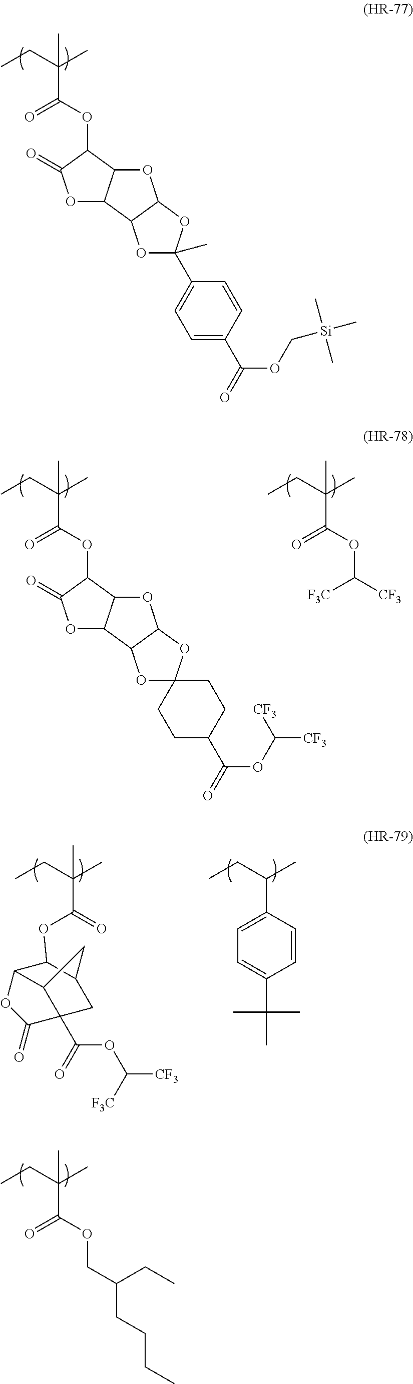

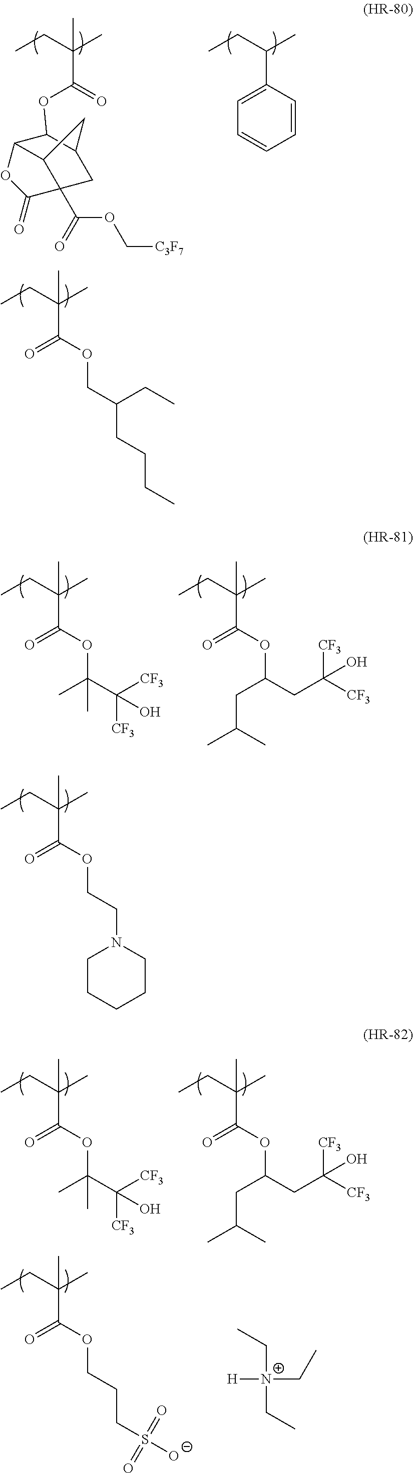

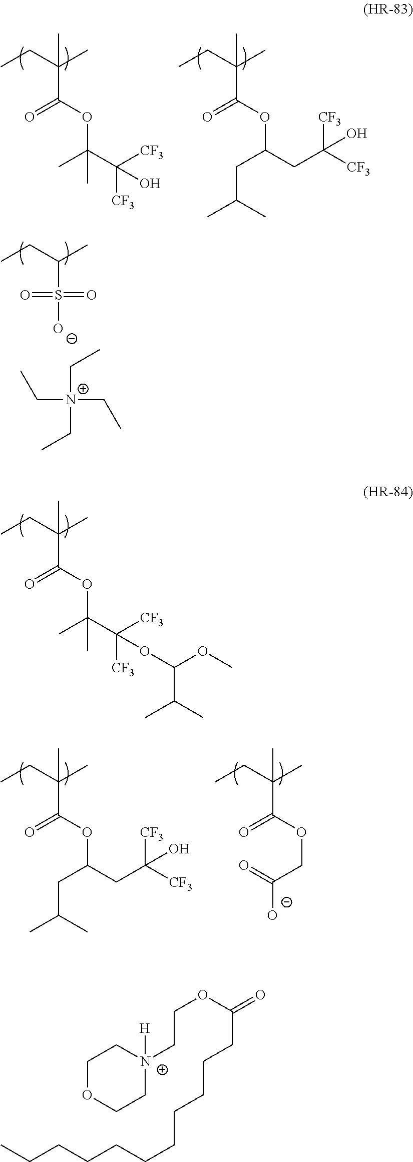

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

TABLE 2

| Resin | Composition | Mw | Mw/Mn |
|---|---|---|---|
| HR-66 | 100 | 6000 | 1.5 |
| HR-67 | 100 | 6000 | 1.4 |
| HR-68 | 100 | 9000 | 1.5 |
| HR-69 | 60/40 | 8000 | 1.3 |
| HR-70 | 80/20 | 5000 | 1.4 |
| HR-71 | 100 | 9500 | 1.5 |
| HR-72 | 40/60 | 8000 | 1.4 |
| HR-73 | 55/30/5/10 | 8000 | 1.3 |
| HR-74 | 100 | 13000 | 1.4 |
| HR-75 | 70/30 | 8000 | 1.3 |
| HR-76 | 50/40/10 | 9500 | 1.5 |
| HR-77 | 100 | 9000 | 1.6 |
| HR-78 | 80/20 | 3500 | 1.4 |
| HR-79 | 90/8/2 | 13000 | 1.5 |
| HR-80 | 85/10/5 | 5000 | 1.5 |

TABLE 2

| Resin | Composition | Mw | Mw/Mn |
|---|---|---|---|
| HR-81 | 35/60/5 | 8600 | 1.99 |
| HR-82 | 35/60/5 | 8700 | 1.71 |
| HR-83 | 35/60/5 | 8100 | 1.81 |
| HR-84 | 35/60/5 | 8900 | 1.89 |

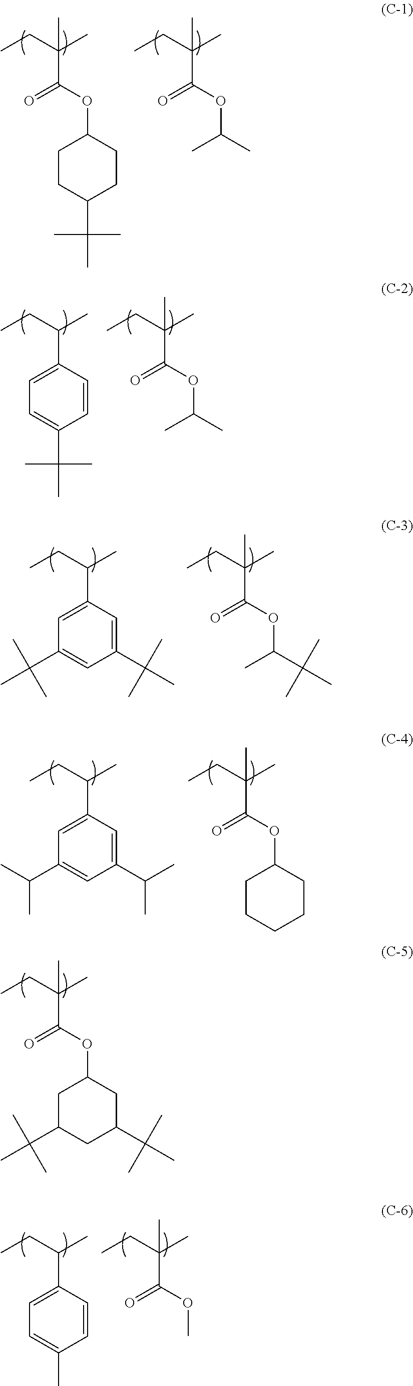

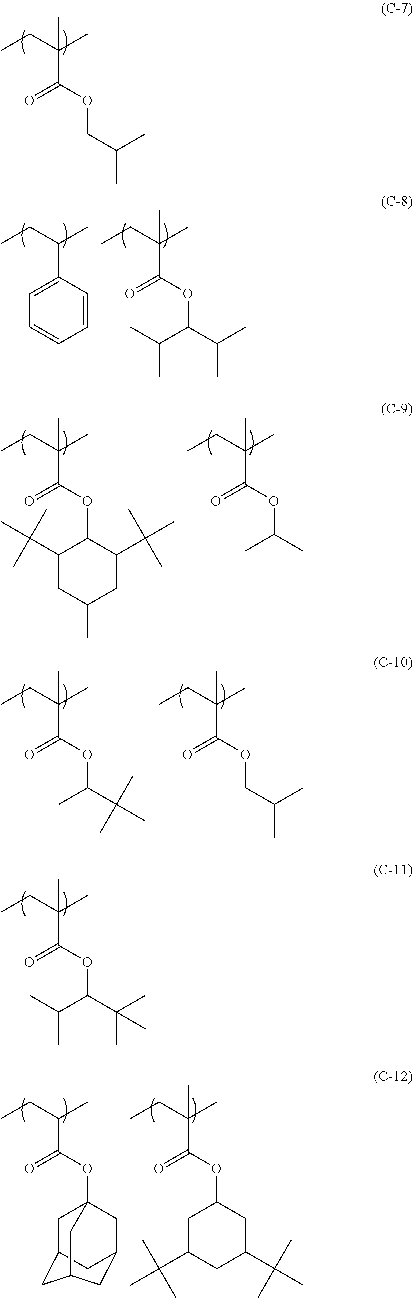

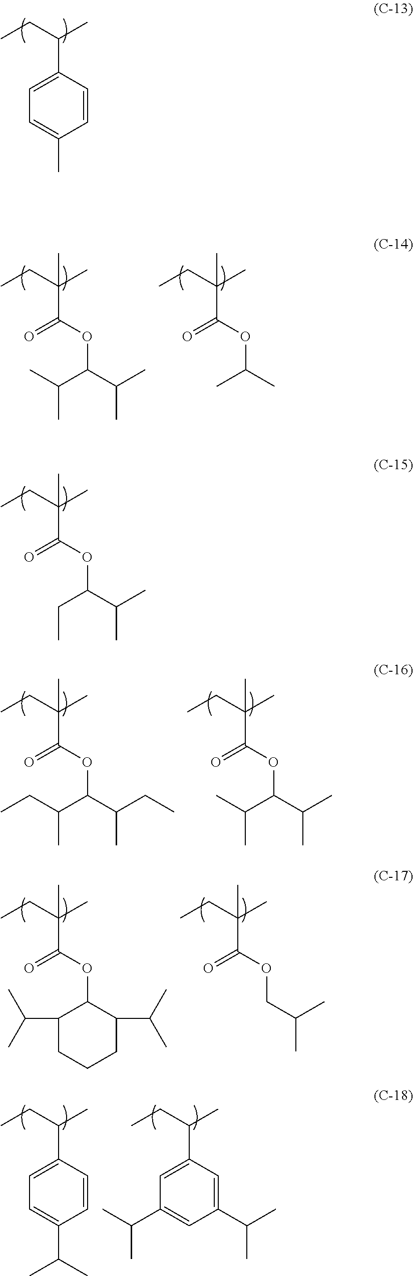

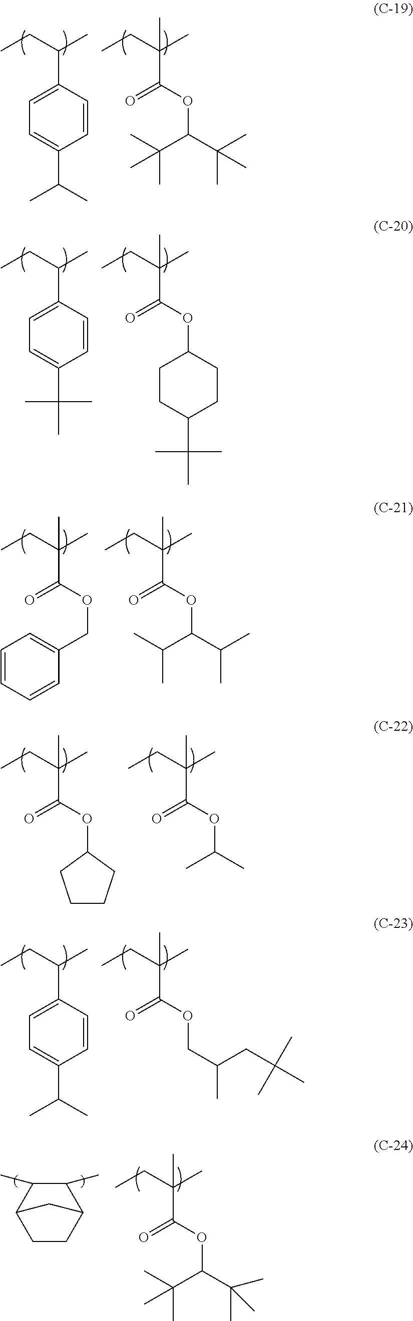

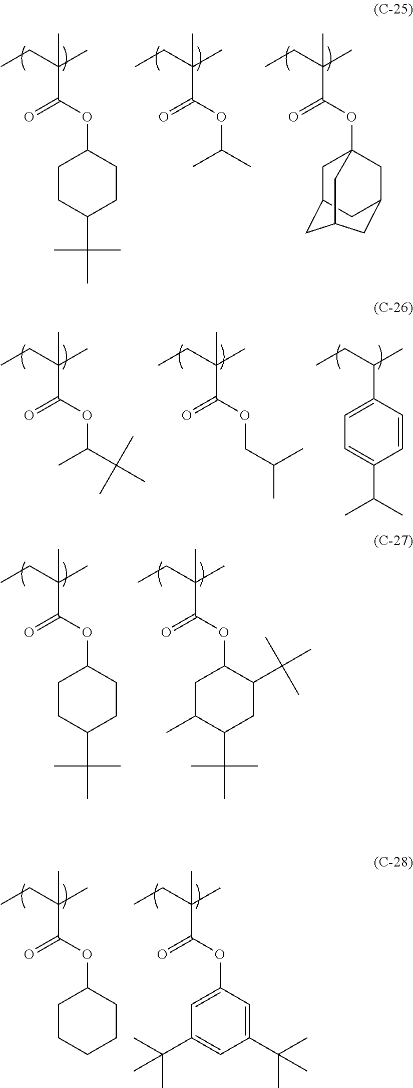

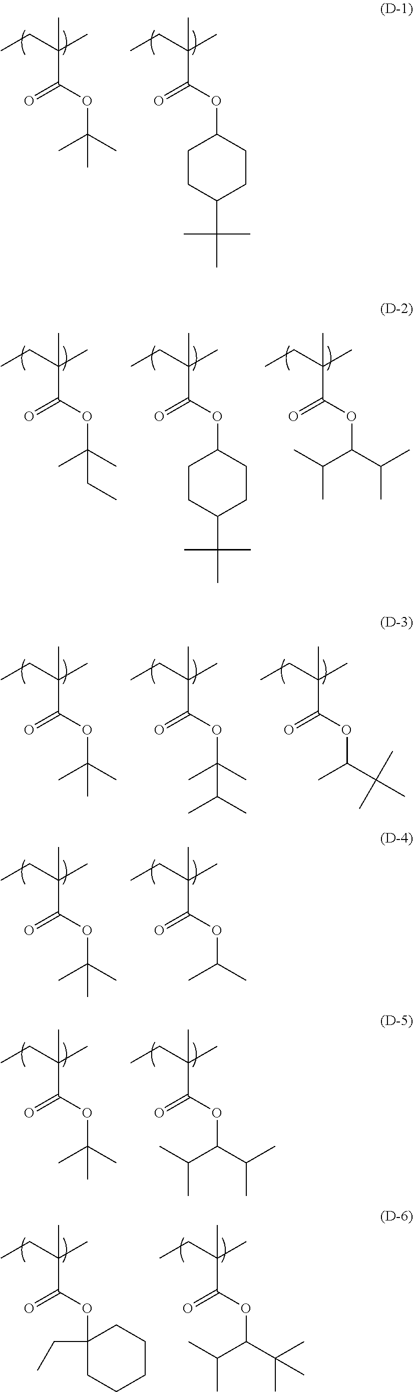

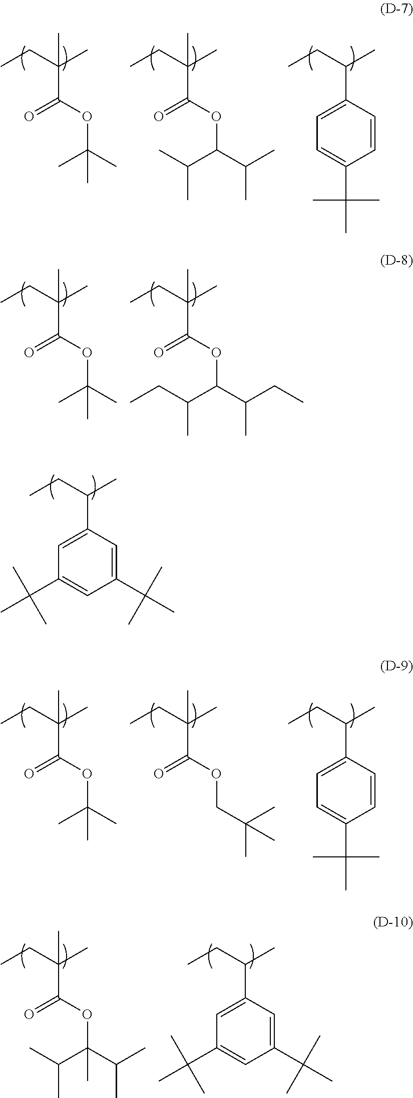

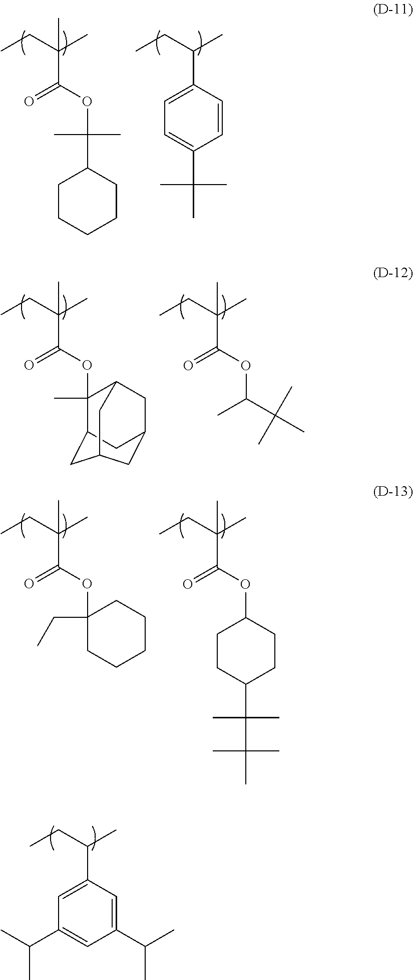

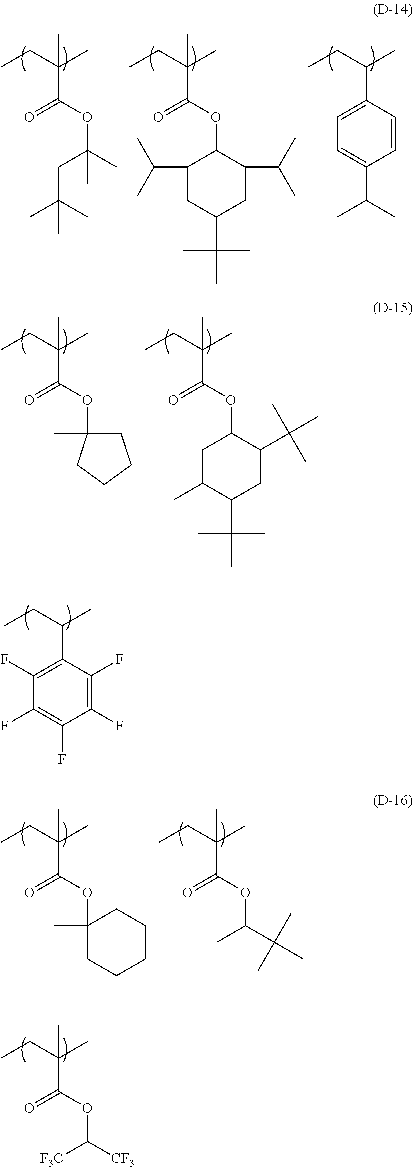

TABLE 4

| Resin | Composition | Mw | Mw/Mn |
|---|---|---|---|
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |

TABLE 5

| Resin | Composition | Mw | Mw/Mn |
|---|---|---|---|
| D-1 | 50/50 | 16500 | 1.72 |
| D-2 | 10/50/40 | 18000 | 1.77 |
| D-3 | 5/50/45 | 27100 | 1.69 |
| D-4 | 20/80 | 26500 | 1.79 |
| D-5 | 10/90 | 24700 | 1.83 |
| D-6 | 10/90 | 15700 | 1.99 |
| D-7 | 5/90/5 | 21500 | 1.92 |
| D-8 | 5/60/35 | 17700 | 2.10 |
| D-9 | 35/35/30 | 25100 | 2.02 |
| D-10 | 70/30 | 19700 | 1.85 |
| D-11 | 75/25 | 23700 | 1.80 |
| D-12 | 10/90 | 20100 | 2.02 |
| D-13 | 5/35/60 | 30100 | 2.17 |
| D-14 | 5/45/50 | 22900 | 2.02 |
| D-15 | 15/75/10 | 28600 | 1.81 |
| D-16 | 25/55/20 | 27400 | 1.87 |

[5-1] Basic Compound or Ammonium Salt Compound (N) Whose Basicity Decreases upon Irradiation of Actinic Ray or Radiation

The actinic ray-sensitive or radiation-sensitive resin composition in the present invention may contain a basic compound or an ammonium salt compound (hereinafter, also referred to as a “compound (N)”) whose basicity decreases upon irradiation with an actinic ray or radiation.

Compound (N) is preferably compound (N-1) having a basic functional group or an ammonium group and a group capable of generating an acidic functional group upon irradiation with an actinic ray or radiation. That is, compound (N) is preferably a basic compound having a basic functional group and a group capable of generating an acidic functional group upon irradiation with an actinic ray or radiation, or an ammonium salt compound having an ammonium group and a group capable of generating an acidic functional group upon irradiation with an actinic ray or radiation.

Compound (N) or (N-1) is a compound which is generated by decomposing upon irradiation with an actinic ray or radiation and whose basicity decreases, examples thereof include compounds represented by the following Formulas (PA-I), (PA-II) or (PA-III), and from the viewpoint of enhancing excellent effects relating to LWR, uniformity of a local pattern dimension and DOF at a high level, the compounds represented by Formula (PA-II) or (PA-III) are particularly preferred.

First, the compounds represented by Formula (PA-I) will be described.

Q-A₁-(X)ₙ—B—R (PA-I)

In Formula (PA-I),

A₁ represents a single bond or a divalent linking group.

Q represents —SO₃H, or —CO₂H. Q corresponds to an acidic functional group generated upon irradiation with an actinic ray or radiation.

X represents —SO₂—, or —CO—.

n represents 0 or 1.

B represents a single bond, an oxygen atom, or —N(Rx)—.

Rx represents a hydrogen atom, or a monovalent organic group.

R represents a monovalent organic group having a basic functional group or a monovalent organic group having an ammonium group.

The divalent linking group in A₁ is preferably a divalent linking group having from 2 to 12 carbon atoms, and examples thereof include an alkylene group, a phenylene group and the like. An alkylene group having at least one fluorine atom is more preferred, and the carbon number thereof is preferably from 2 to 6, and more preferably from 2 to 4. The alkylene chain may have a linking group such as an oxygen atom and a sulfur atom. The alkylene group is preferably an alkylene group in which 30 to 100% of the number of the hydrogen atom is substituted with a fluorine atom, and more preferably an alkylene group in which the carbon atom bonded to the Q site has a fluorine atom. Furthermore, a perfluoroalkylene group is preferred, and a perfluoroethylene group, a perfluoropropylene group and a perfluorobutylene group are more preferred.

The monovalent organic group in Rx preferably has 4 to 30 carbon atoms, and examples thereof include an alkyl group, a cycloalkyl group, an aryl group, an aralkyl group, an alkenyl group and the like.

The alkyl group in Rx may have a substituent and is preferably a straight chained or branched alkyl group having 1 to 20 carbon atoms, and the alkyl chain may have an oxygen atom, a sulfur atom or a nitrogen atom.

Meanwhile, examples of the alkyl group having a substituent particularly include a group in which a straight chained or branched alkyl group is substituted with a cycloalkyl group (for example, an adamantylmethyl group, an adamantylethyl group, a cyclohexylethyl group, a camphor residue and the like).

The cycloalkyl group in Rx may have a substituent and is preferably a cycloalkyl group having 3 to 20 carbon atoms, and may have an oxygen atom in the ring.

The aryl group in Rx may have a substituent, and is preferably an aryl group having 6 to 14 carbon atoms.

The aralkyl group in Rx may have a substituent and is preferably an aralkyl group having 7 to 20 carbon atoms.

The alkenyl group in Rx may have a substituent, and examples thereof include a group having a double bond at an arbitrary position of the alkyl group exemplified as Rx.

Examples of a preferred partial structure of the basic functional group include a structure such as a crown ether, a primary to tertiary amine, and a nitrogen-containing heterocyclic ring (pyridine, imidazole, pyrazine and the like).

Examples of the preferred partial structure of an ammonium group include a primary to tertiary ammonium structure, a pyridinium structure, an imidazolinium structure, a pyrazinium structure and the like.

Meanwhile, the basic functional group is preferably a functional group having a nitrogen atom, and more preferably a structure having a primary to tertiary amino group, or a nitrogen-containing heterocyclic structure. In these structures, from the viewpoint of improving basicity, it is preferred that all atoms adjacent to a nitrogen atom included in the structure are a carbon atom or a hydrogen atom. In addition, from the viewpoint of enhancing basicity, it is preferred that an electron-withdrawing functional group (a carbonyl group, a sulfonyl group, a cyano group, a halogen atom and the like) is not directly bonded to the nitrogen atom.

The monovalent organic group in the monovalent organic group (group R) including the structure preferably has 4 to 30 carbon atoms, examples thereof include an alkyl group, a cycloalkyl group, an aryl group, an aralkyl group, an alkenyl group and the like, and each group may have a substituent.

The alkyl group, the cycloalkyl group, the aryl group, the aralkyl group, and the alkenyl group in the alkyl group, the cycloalkyl group, the aryl group, the aralkyl group and the alkenyl group including a basic functional group or an ammonium group in R are the same as the alkyl group, the cycloalkyl group, the aryl group, the aralkyl group and the alkenyl group exemplified as Rx.

Examples of the substituent which each group may have include a halogen atom, a hydroxyl group, a nitro group, a cyano group, a carboxy group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 20 carbon atoms), an acyloxy group (preferably having 2 to 10 carbon atoms), an alkoxycarbonyl group (preferably having 2 to 20 carbon atoms), an aminoacyl group (preferably having 2 to 20 carbon atoms) and the like. For the cyclic structure in the aryl group, the cycloalkyl group and the like, examples of the substituent thereof also include an alkyl group (preferably having 1 to 20 carbon atoms). For the amino acyl group, examples of the substituent thereof also include one or two alkyl groups (preferably having 1 to 20 carbon atoms).

When B is —N(Rx)—, R and Rx preferably combine with each other to form a ring. By forming a ring structure, the stability is enhanced, and thus storage stability of the composition using the same is enhanced. The number of carbon atoms forming the ring is preferably 4 to 20, and the ring may be monocyclic or polycyclic and may include an oxygen atom, a sulfur atom or a nitrogen atom therein.

Examples of the monocyclic structure include a 4- to 8-membered ring including a nitrogen atom, and the like. Examples of the polycyclic structure include a structure composed of a combination of two or three or more monocyclic structures. The monocyclic structure and polycyclic structure may have a substituent, and preferred examples of the substituent include a halogen atom, a hydroxyl group, a cyano group, a carboxy group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 15 carbon atoms), an acyloxy group (preferably having 2 to 15 carbon atoms), an alkoxycarbonyl group (preferably having 2 to 15 carbon atoms), an aminoacyl group (preferably having 2 to 20 carbon atoms) and the like. For the cyclic structure in the aryl group, the cycloalkyl group and the like, examples of the substituent thereof also include an alkyl group (preferably having 1 to 15 carbon atoms). For the aminoacyl group, examples of the substituent thereof include one or two alkyl groups (preferably having 1 to 15 carbon atoms).

Among the compounds represented by Formula (PA-I), a compound in which the Q site is a sulfonic acid may be synthesized by using a general sulfonamidation reaction. For example, the compound may be obtained by a method of selectively reacting one sulfonyl halide moiety of a bis-sulfonyl halide compound with an amine compound to form a sulfonamide bond and then hydrolyzing the other sulfonyl halide moiety, or a method of ring-opening a cyclic sulfonic acid anhydride through reaction with an amine compound.

Subsequently, compounds represented by Formula (PA-II) will be described.

Q₁-X₁—NH—X₂-Q₂ (PA-II)

In Formula (PA-II),

each of Q₁ and Q₂ independently represents a monovalent organic group. Provided that either Q₁ or Q₂ has a basic functional group. Q₁ and Q₂ may combine with each other to form a ring, and the ring formed may have a basic functional group.

Each of X₁ and X₂ independently represents —CO— or —SO₂—.

Meanwhile, —NH— corresponds to an acidic functional group generated upon irradiation with an actinic ray or radiation.

The monovalent organic group as Q₁ and Q₂ in Formula (PA-II) preferably has 1 to 40 carbon atoms, and examples thereof include an alkyl group, a cycloalkyl group, an aryl group, an aralkyl group, an alkenyl group and the like.

The alkyl group in Q₁ and Q₂ may have a substituent and is preferably a straight chained or branched alkyl group having 1 to 30 carbon atoms, and the alkyl chain may have an oxygen atom, a sulfur atom or a nitrogen atom.

The cycloalkyl group in Q₁ and Q₂ may have a substituent, is preferably a cycloalkyl group having 3 to 20 carbon atoms, and may have an oxygen atom and a nitrogen atom in the ring.

The aryl group in Q₁ and Q₂ may have a substituent, and is preferably an aryl group having 6 to 14 carbon atoms.

The aralkyl group in Q₁ and Q₂ may have a substituent and is preferably an aralkyl group having 7 to 20 carbon atoms.

The alkenyl group in Q₁ and Q₂ may have a substituent, and examples thereof include a group having a double bond at an arbitrary position of the alkyl group.

Examples of the substituent which each group may have include a halogen atom, a hydroxyl group, a nitro group, a cyano group, a carboxy group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 20 carbon atoms), an acyloxy group (preferably having 2 to 10 carbon atoms), an alkoxycarbonyl group (preferably having 2 to 20 carbon atoms), an aminoacyl group (preferably having 2 to 10 carbon atoms) and the like. For the cyclic structure in the aryl group, the cycloalkyl group and the like, examples of the substituent thereof also include an alkyl group (preferably having 1 to 10 carbon atoms). For the aminoacyl group, examples of the substituent thereof also have an alkyl group (preferably having 1 to 10 carbon atoms). Examples of the alkyl group having a substituent include a perfluoroalkyl group such as a perfluoromethyl group, a perfluoroethyl group, a perfluoropropyl group and a perfluorobutyl group.

Preferred partial structures of the basic functional group that at least one of Q₁ and Q₂ has are the same as those described as the basic functional group that R of Formula (PA-I) has.

Examples of the structure in which Q₁ and Q₂ combine with each other to form a ring and the ring formed has a basic functional group include a structure in which the organic groups of Q₁ and Q₂ are also bonded to an alkylene group, an oxy group, an imino group or the like.

In Formula (PA-II), at least one of X₁ and X₂ is preferably —SO₂—.

Subsequently, compounds represented by Formula (PA-III) will be described.

Q₁-X₁—NH—X₂-A₂-(X₃)ₘ—B-Q₃ (PA-III)

In Formula (PA-III),

each of Q₁ and Q₃ independently represents a monovalent organic group. Provided that either Q₁ or Q₃ has a basic functional group. Q₁ and Q₃ may combine with each other to form a ring, and the ring formed may have a basic functional group.

Each of X₁, X₂ and X₃ independently represents —CO— or —SO₂—.

A₂ represents a divalent linking group.

B represents a single bond, an oxygen atom, or —N(Qx)—.

Qx represents a hydrogen atom, or a monovalent organic group.

When B is —N(Qx)—, Q and Qx may combine with each other to form a ring.

m represents 0 or 1.

Meanwhile, —NH— corresponds to an acidic functional group generated upon irradiation with an actinic ray or radiation.

Q₁ has the same meaning as Q₁ in Formula (PA-II).

Examples of the organic group of Q are the same as those of the organic group of Q₁ and Q₂ in Formula (PA-II).

Further, examples of the structure in which Q₁ and Q₃ combine with each other to form a ring and the ring formed has a basic functional group include a structure in which the organic groups of Q₁ and Q₃ are also bonded to an alkylene group, an oxy group, an imino group or the like.

The divalent linking group in A₂ is preferably a divalent linking group having from 1 to 8 carbon atoms and having a fluorine atom, and examples thereof include an alkylene group having from 1 to 8 carbon atoms and having a fluorine atom, a phenylene group having a fluorine atom and the like. An alkylene group having a fluorine atom is more preferred, and the number of carbon atoms is preferably 2 to 6, and more preferably 2 to 4. The alkylene chain may have a linking group such as an oxygen atom and sulfur atom. The alkylene group is preferably an alkylene group in which 30 to 100% of the number of the hydrogen atoms is substituted with a fluorine atom, preferably a perfluoroalkylene group, and particularly preferably a perfluoroalkylene group having 2 to 4 carbon atoms.

The monovalent organic group in Qx is preferably an organic group having 4 to 30 carbon atoms, and examples thereof include an, alkyl group, a cycloalkyl group, an aryl group, an aralkyl group, an alkenyl group and the like. Examples of the alkyl group, the cycloalkyl group, the aryl group, the aralkyl group and the alkenyl group are the same as those for Rx in Formula (PA-I).

In Formula (PA-III), X₁, X₂ and X₃ are preferably —SO₂—.

Compound (N) is preferably a sulfonium salt compound of the compound represented by Formula (PA-I), (PA-II) or (PA-III), or an iodonium salt compound of the compound represented by Formula (PA-I), (PA-II) or (PA-III), and more preferably a compound represented by the following Formula (PA1) or (PA2).

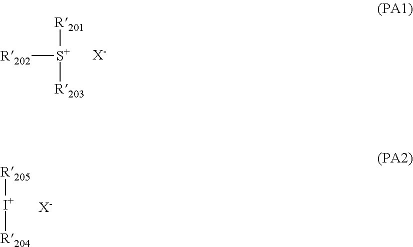

In Formula (PA1),

each of R′₂₀₁, R′₂₀₂ and R′₂₀₃ independently represents an organic group, and specifically, are the same as R₂₀₁, R₂₀₂ and R₂₀₃ of Formula ZI in component (B).

X⁻ represents a sulfonate anion or a carboxylate anion resulting from leaving of a hydrogen atom in the —SO₃H moiety or —COOH moiety of the compound represented by Formula (PA-I), or an anion resulting from leaving of a hydrogen atom from the —NH— moiety of the compound represented by Formula (PA-II) or (PA-III).

In Formula (PA2),

each of R′₂₀₄ and R′₂₀₅ independently represents an aryl group, an alkyl group or a cycloalkyl group, and specifically, are the same as R₂₀₄ and R₂₀₅ of Formula ZII in component (B).

X⁻ represents a sulfonate anion or a carboxylate anion resulting from leaving of a hydrogen atom in the —SO₃H moiety or —COOH moiety of the compound represented by Formula (PA-I), or an anion resulting from leaving of a hydrogen atom from the —NH— moiety of the compound represented by Formula (PA-II) or (PA-III).

Compound (N) decomposes upon irradiation with an actinic ray or radiation to generate, for example, a compound represented by Formula (PA-I), (PA-II) or (PA-III).

The compound represented by Formula (PA-I) is a compound whose basicity decreases, or is lost or changed from basic to acidic by having a sulfonic acid group or a carboxylic acid group together with a basic functional group or an ammonium group, as compared to compound (N).

The compound represented by Formula (PA-II) or (PA-III) is a compound whose basicity decreases, or is lost or changed from basic to acidic by having an organic sulfonylimino group or an organic carbonylimino group together with a basic functional group, as compared to compound (N).

In the present invention, decrease in the basicity upon irradiation with an actinic ray or radiation means that the acceptor property for a proton (an acid generated upon irradiation with an actinic ray or radiation) of compound (N) decreases upon irradiation with an actinic ray or radiation. The decrease in the acceptor property means that when an equilibrium reaction of producing a non-covalent bond complex as a proton adduct takes place from a basic functional group-containing compound and a proton or when an equilibrium reaction of letting the counter cation of the ammonium group-containing compound be exchanged with a proton takes place, the equilibrium constant in the chemical equilibrium decreases.

In this manner, it is assumed that compound (N) whose basicity decreases upon irradiation with an actinic ray or radiation is contained in the resist film, so that in the unexposed portion, the acceptor property of compound (N) may be sufficiently expressed, and thus an unintended reaction of an acid diffused from the exposed portion or the like with resin (A) may be suppressed, and simultaneously, in the exposed portion, the acceptor property of compound (N) decreases, and thus the intended reaction of an acid with resin (A) more certainly occurs, and the operation mechanism also contributes, thereby obtaining a pattern excellent in terms of line width roughness (LWR), uniformity of local pattern dimension, depth of focus (DOF) and pattern shape.

Meanwhile, the basicity may be confirmed by measuring the pH, and a calculated value may also be calculated by a commercially available software.

Hereinafter, specific examples of compound (N) capable of generating a compound represented by Formula (PA-I) upon irradiation with an actinic ray or radiation will be described, but the present invention is not limited thereto.

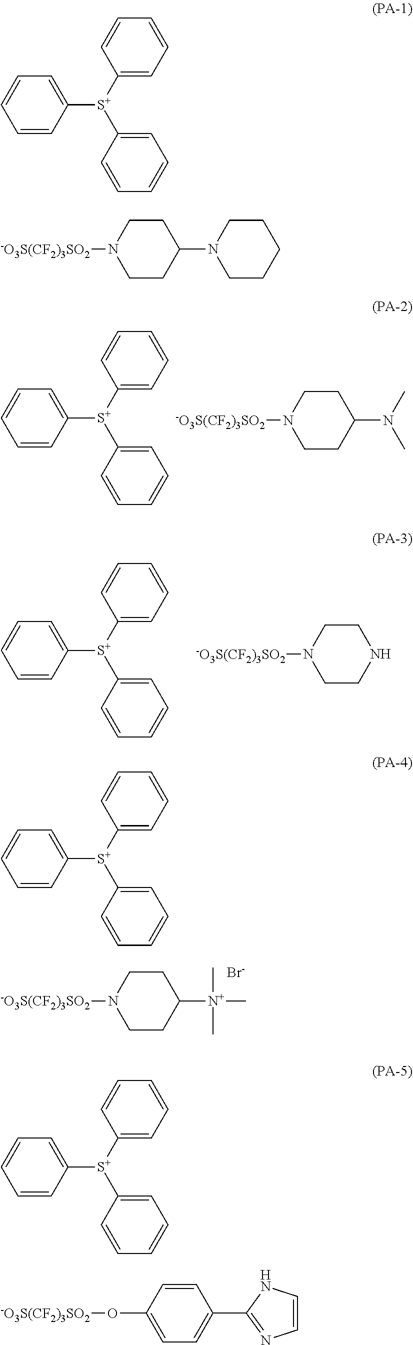

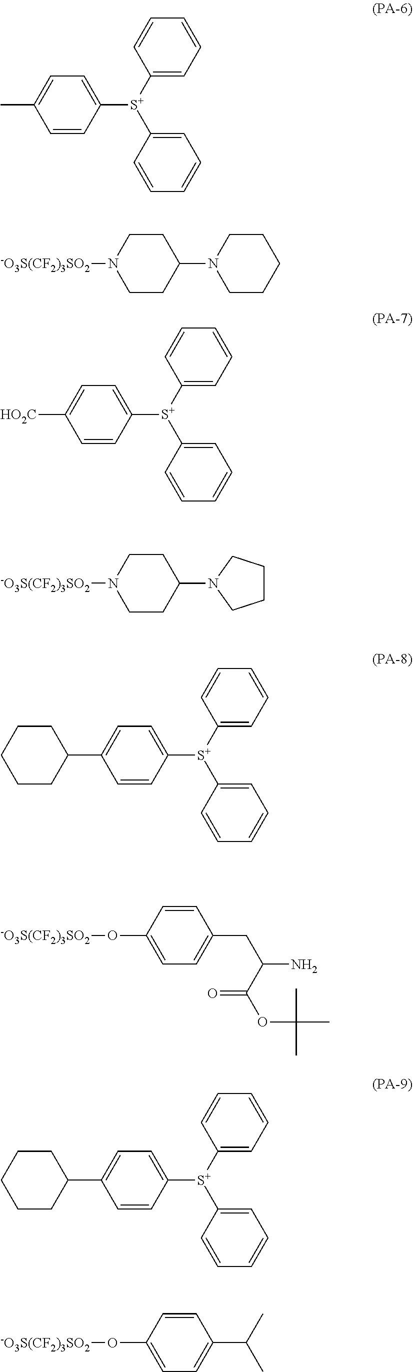

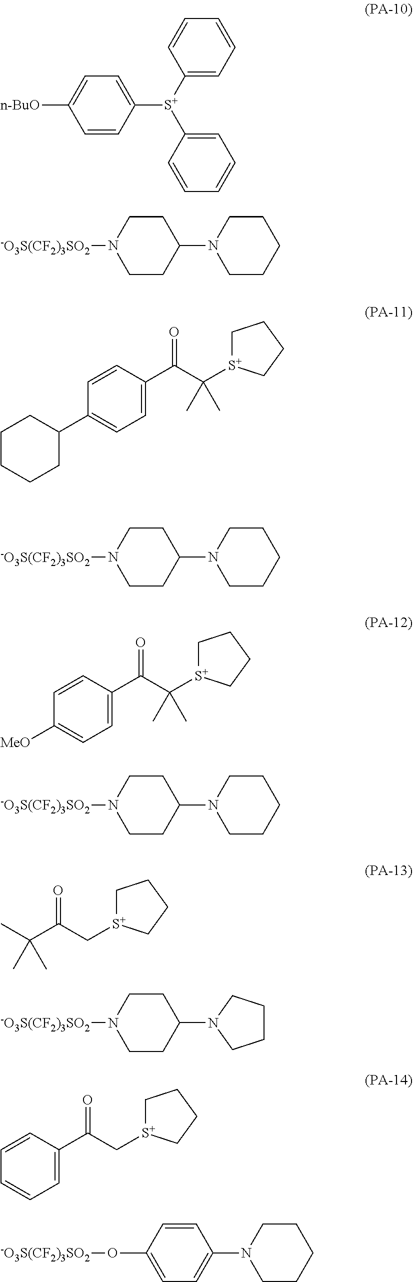

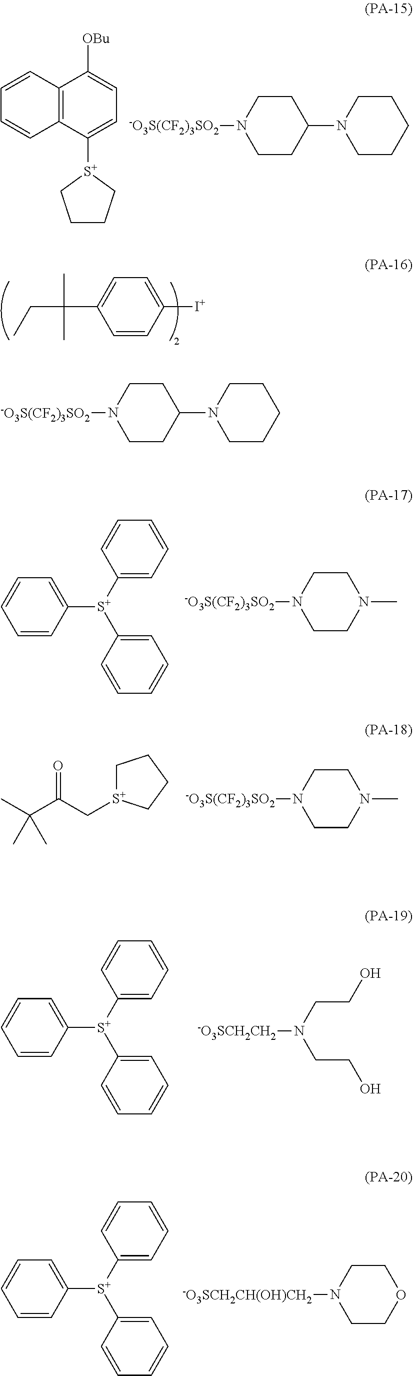

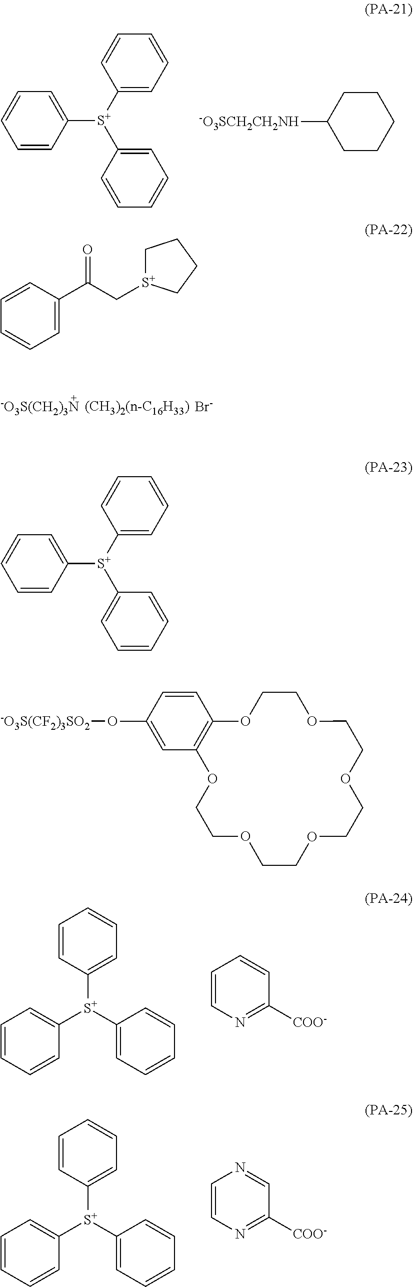

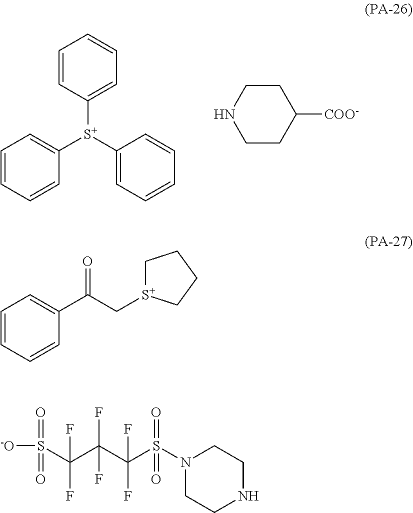

These compounds may be easily synthesized from a compound represented by Formula (PA-I) or a lithium, sodium or potassium salt thereof and a hydroxide, bromide, and chloride of iodonium or sulfonium and the like, by using the salt exchange method described in Japanese Patent Application Publication No. H11-501909 or Japanese Patent Application Laid-Open No. 2003-246786. In addition, the synthesis may also be performed in accordance with the synthesis method described in Japanese Patent Application Laid-Open No. H7-333851.

Hereinafter, specific examples of compound (N) capable of generating a compound represented by Formula (PA-II) or (PA-III) upon irradiation with an actinic ray or radiation will be described, but the present invention is not limited thereto.

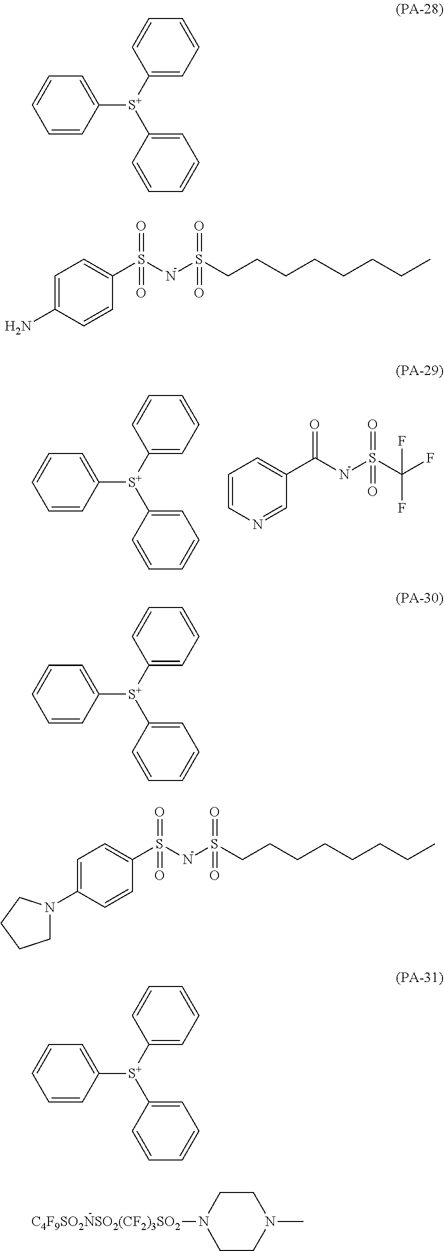

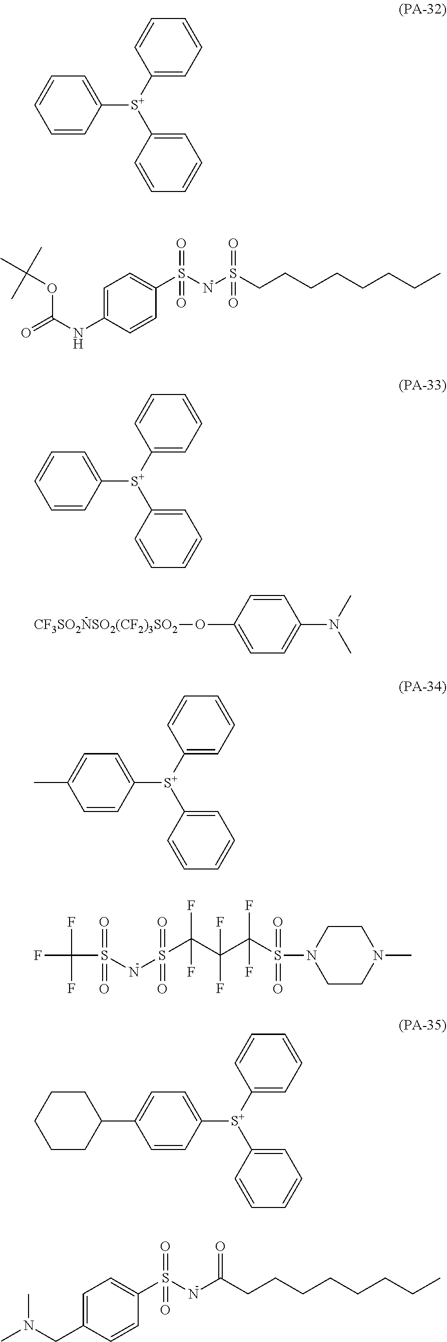

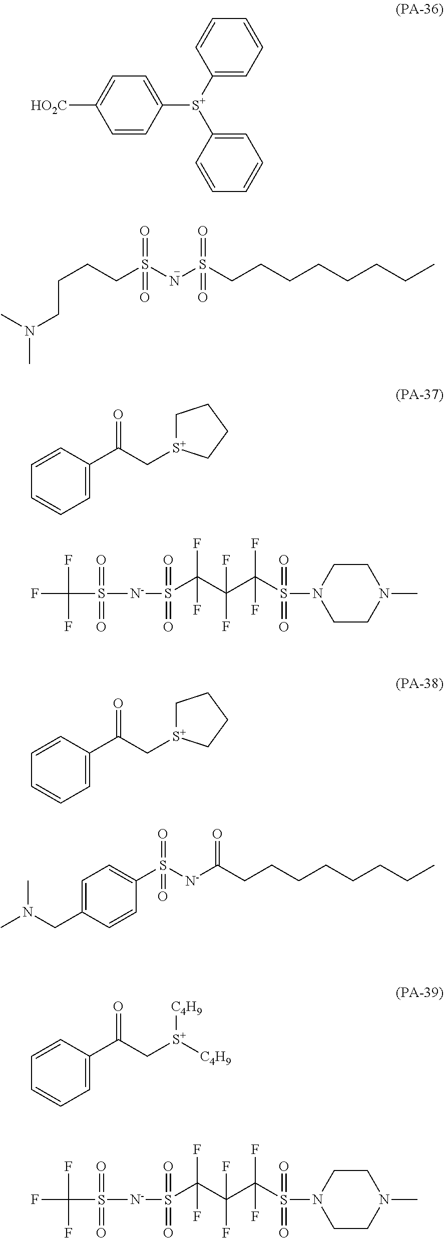

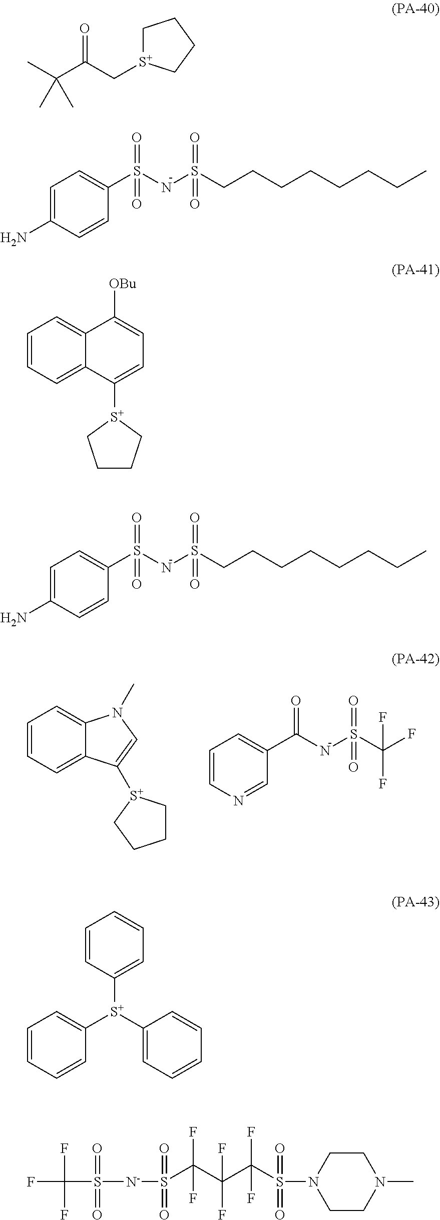

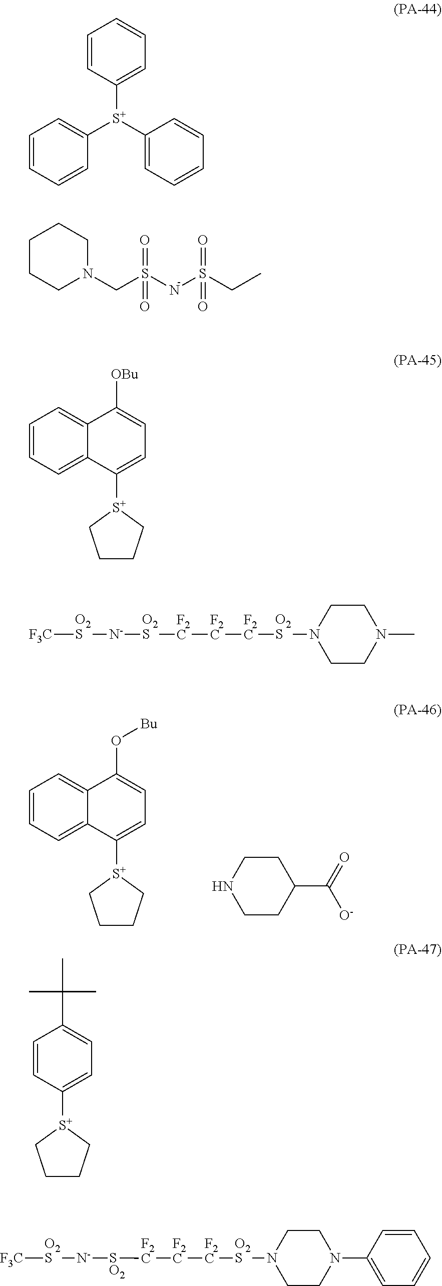

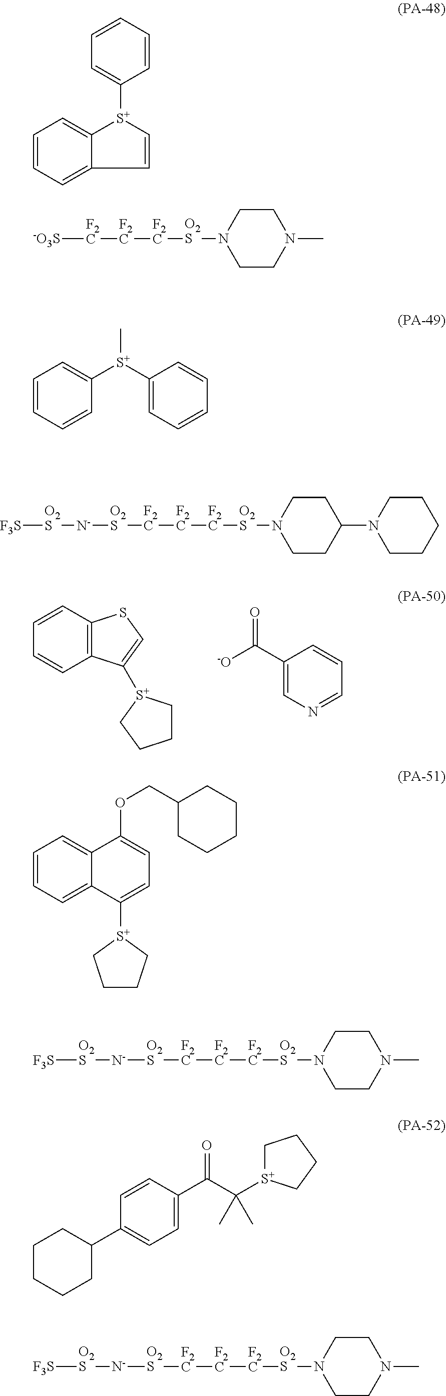

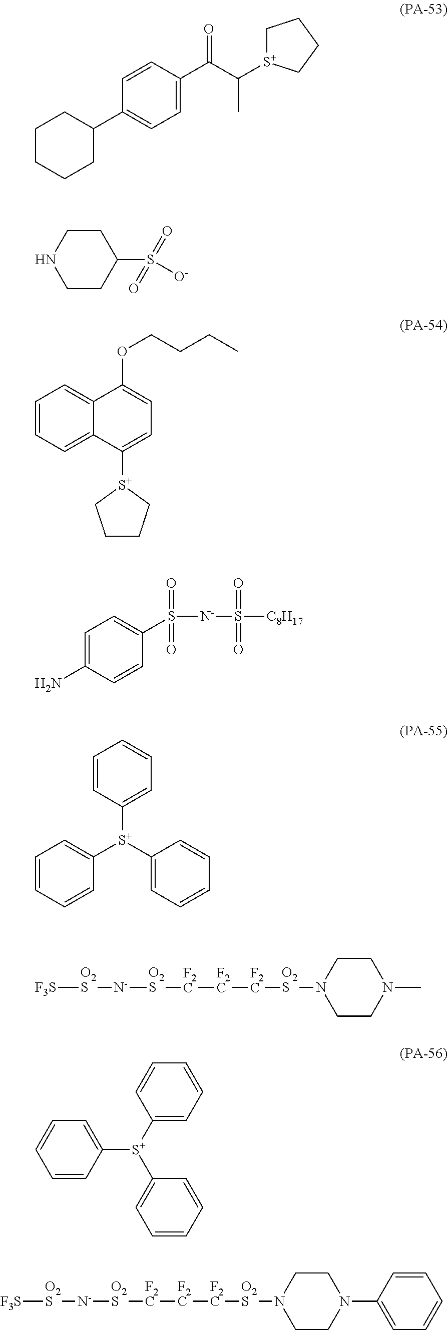

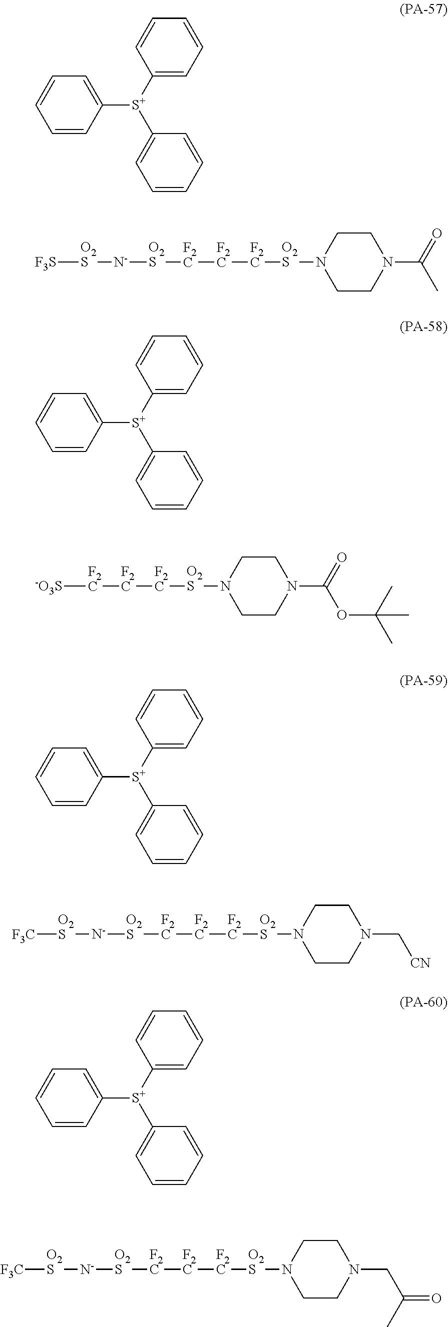

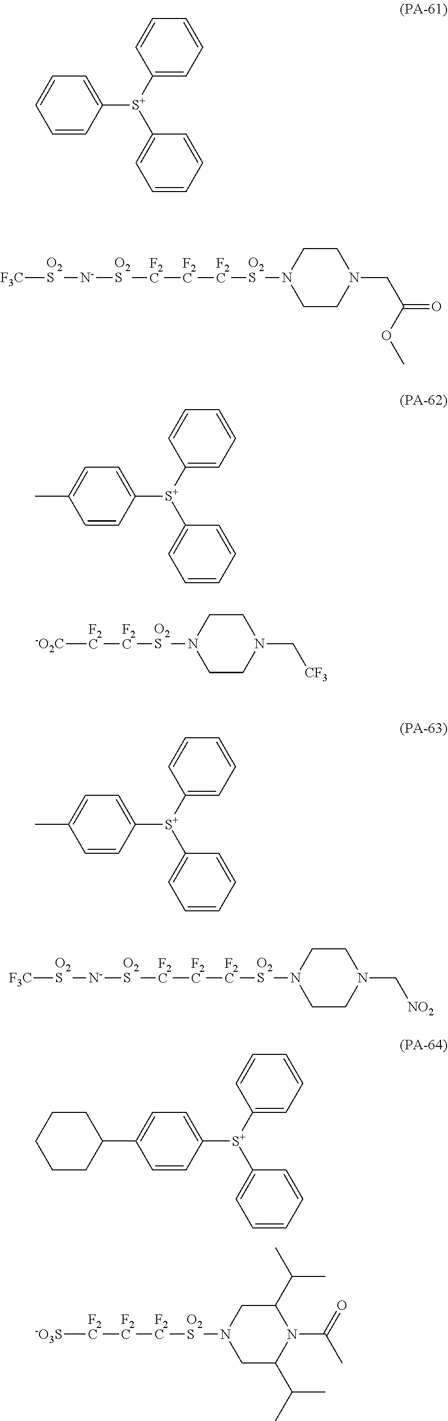

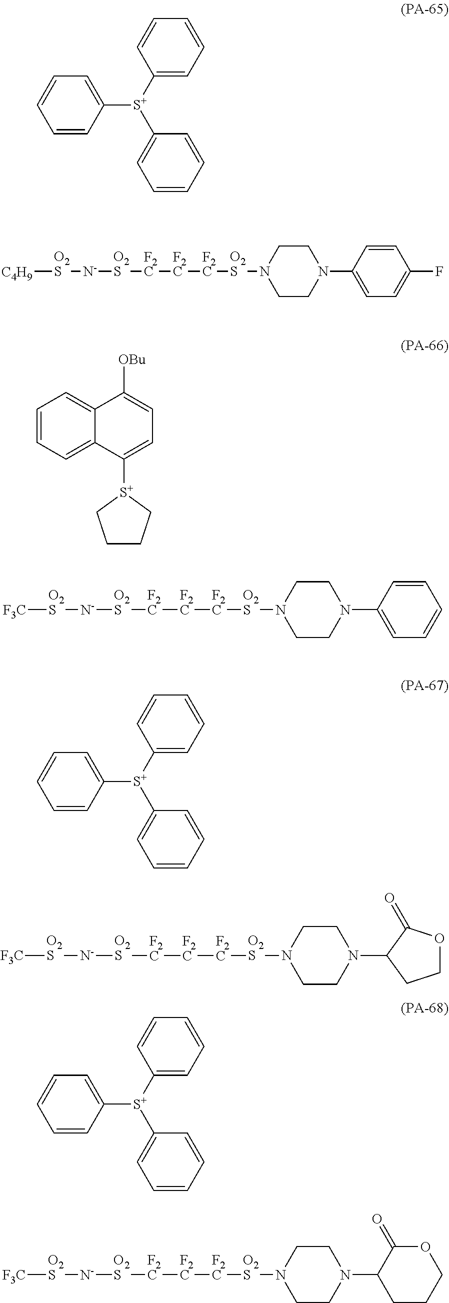

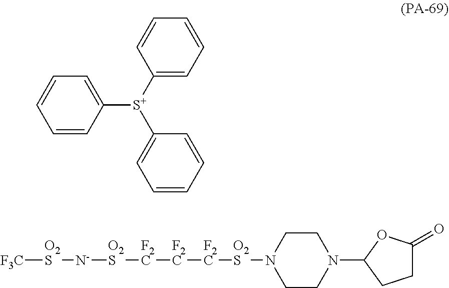 [SMILES: c1ccc([S+](c2ccccc2)c2ccccc2)cc1 ; O=C1CCC(N2CCN(S(=O)(=O)C(F)(F)C(F)(F)C(F)(F)S(=O)(=O)[N-]S(=O)(=O)C(F)(F)F)CC2)O1]

These compounds may be easily synthesized by using a general sulfonic acid esterification reaction or sulfonamidation reaction. For example, the compound may be obtained by a method of selectively reacting one sulfonyl halide moiety of a bis-sulfonyl halide compound with an amine, alcohol or the like including a partial structure represented by Formula (PA-II) or (PA-III) to form a sulfonamide bond or a sulfonic acid ester bond and then hydrolyzing the other sulfonyl halide moiety, or a method of ring-opening a cyclic sulfonic acid anhydride by an amine or alcohol including a partial structure represented by Formula (PA-II). The amine or alcohol including a partial structure represented by Formula (PA-II) or (PA-III) may be synthesized by reacting an amine or an alcohol with an anhydride such as (R′O₂C)₂O or (R'SO₂)₂O or an acid chloride compound such as R′O₂CCl or R′SO₂Cl (R′ is a methyl group, an n-octyl group or a trifluoromethyl group) under basicity conditions. In particular, the synthesis may be performed in accordance with synthesis examples and the like in Japanese Patent Application Laid-Open No. 2006-330098.

The molecular weight of compound (N) is preferably 500 to 1,000.

The actinic ray-sensitive or radiation-sensitive resin composition in the present invention may or may not contain compound (N), but when the composition contains compound (N), the content of compound (N) is preferably 0.1 to 20% by mass, and more preferably 0.1 to 10% by mass, based on the solid content of the actinic ray-sensitive or radiation-sensitive resin composition.

[5-2] Basic Compound (N′)

The actinic ray-sensitive or radiation-sensitive resin composition in the present invention may contain a basic compound (N′) different from resin (A) in order to reduce the change in performance with time from exposure to heating.

Preferred examples of basic compound (N′) include compounds having a structure represented by the following Formulas (A′) to (E′).

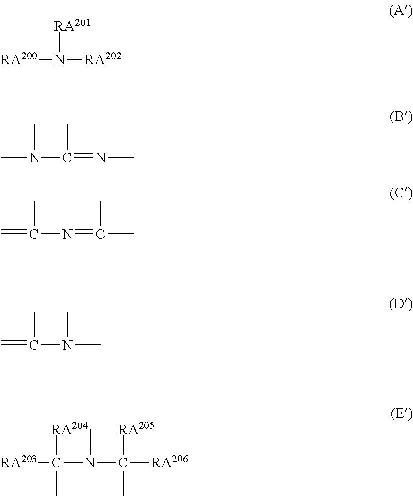

In Formulas (A′) to (E′),

each of RA²⁰⁰, RA²⁰¹ and RA²⁰² may be the same as or different from every other of RA²⁰⁰, RA²⁰¹ and RA²⁰² and represents a hydrogen atom, an alkyl group (preferably having 1 to 20 carbon atoms), a cycloalkyl group (preferably having 3 to 20 carbon atoms) or an aryl group (having 6 to 20 carbon atoms), and RA²⁰¹ and RA²⁰² may combine with each other to form a ring. Each of R²⁰³, R²⁰⁴, R²⁰⁵ and R²⁰⁶ may be the same as or different from each other of R²⁰³, R²⁰⁴, R²⁰⁵ and R²⁰⁶ and represents an alkyl group (preferably having 1 to 20 carbon atoms).

The alkyl group may have a substituent, and the alkyl group having a substituent is preferably an aminoalkyl group having 1 to 20 carbon atoms, a hydroxyalkyl group having 1 to 20 carbon atoms or a cyanoalkyl group having 1 to 20 carbon atoms.

The alkyl group in Formulas (A′) to (E′) is more preferably unsubstituted.

Preferred specific examples of basic compound (N′) include guanidine, aminopyrrolidine, pyrazole, pyrazoline, piperazine, aminomorpholine, aminoalkylmorpholine, piperidine and the like, and more preferred specific examples thereof include a compound having an imidazole structure, a diazabicyclo structure, an onium hydroxide structure, an onium carboxylate structure, a trialkylamine structure, an aniline structure or a pyridine structure, an alkylamine derivative having a hydroxyl group and/or an ether bond, an aniline derivative having a hydroxyl group and/or an ether bond and the like.

Examples of the compound having an imidazole structure include imidazole, 2,4,5-triphenylimidazole, benzimidazole and the like. Examples of the compound having a diazabicyclo structure include 1,4-diazabicyclo[2,2,2]octane, 1,5-diazabicyclo[4,3,0]non-5-ene, 1,8-diazabicyclo[5,4,0]undec-7-ene and the like. Examples of the compound having an onium hydroxide structure include triarylsulfonium hydroxide, phenacylsulfonium hydroxide, a sulfonium hydroxide having a 2-oxoalkyl group, specifically, triphenylsulfonium hydroxide, tris(t-butylphenyl)sulfonium hydroxide, bis(t-butylphenyl)iodonium hydroxide, phenacylthiophenium hydroxide, 2-oxopropylthiophenium hydroxide and the like. Examples of the compound having an onium carboxylate structure include a compound, in which the anion moiety of a compound having an onium hydroxide structure has been converted into carboxylate, such as acetate, adamantane-1-carboxylate and perfluoroalkylcarboxylate. Examples of the compound having a trialkylamine structure include tri(n-butyl)amine, tri(n-octyl)amine and the like. Examples of the compound having an aniline structure include 2,6-diisopropylaniline, N,N-dimethylaniline, N,N-dibutylaniline, N,N-dihexylaniline and the like. Examples of the alkylamine derivative having a hydroxyl group and/or an ether bond include ethanolamine, diethanolamine, triethanolamine, tris(methoxyethoxyethyl)amine and the like. Examples of the aniline derivative having a hydroxyl group and/or an ether bond include N,N-bis(hydroxyethyl)aniline and the like.

Examples of the preferred basic compound include an amine compound having a phenoxy group, an ammonium salt compound having a phenoxy group, an amine compound having a sulfonic acid ester group, and an ammonium salt compound having a sulfonic acid ester group.

It is preferred that the amine compound having a phenoxy group, the ammonium salt compound having a phenoxy group, the amine compound having a sulfonic acid ester group, and the ammonium salt compound having a sulfonic acid ester group have at least one alkyl group bonded to a nitrogen atom. Furthermore, it is preferred that the alkyl chain has an oxygen atom to form an oxyalkylene group. The number of oxyalkylene groups is one or more, preferably 3 to 9, and more preferably 4 to 6, in the molecule. Among the oxyalkylene groups, the structures of —CH₂CH₂O—, CH(CH₃)CH₂O— or —CH₂CH₂CH₂O— are preferred.

Specific examples of the amine compound having a phenoxy group, the ammonium salt compound having a phenoxy group, the amine compound having a sulfonic acid ester group, and the ammonium salt compound having a sulfonic acid ester group include compounds (C1-1) to (C3-3) exemplified in [0066] of U.S. Patent Application Publication No. 2007/0224539, but are not limited thereto.

Further, a nitrogen-containing organic compound having a group capable of leaving by the action of an acid may also be used as a kind of basic compound. Examples of the compound include a compound represented by the following Formula (F). Meanwhile, the compound represented by the following Formula (F) exhibits an effective basicity in the system as a result of leaving of the group capable of leaving by the action of an acid.

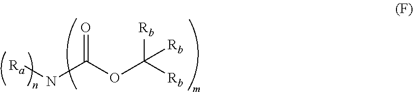

In Formula (F), each of Rₐ's independently represents a hydrogen atom, an alkyl group, a cycloalkyl group, an aryl group or an aralkyl group. In addition, when n=2, each of two Rₐ's may be the same as or different from every other Rₐ's, and two Rₐ's may combine with each other to form a divalent heterocyclic hydrocarbon group (preferably having 20 or less carbon atoms) or a derivative thereof.

Each of R_{b}'s independently represents a hydrogen atom, an alkyl group, a cycloalkyl group, an aryl group or an aralkyl group. Provided that in —C(R_{b})(R_{b})(R_{b}), when one or more R_{b}'s are a hydrogen atom, at least one of the remaining R_{b}'s is a cyclopropyl group or a 1-alkoxy alkyl group.

At least two R_{b}'s may combine with each other to form an alicyclic hydrocarbon group, an aromatic hydrocarbon group, a heterocyclic hydrocarbon group or a derivative thereof.

n represents an integer of 0 to 2, m represents an integer of 1 to 3, and n+m=3.

In Formula (F), each of the alkyl group, the cycloalkyl group, the aryl group and the aralkyl group represented by Rₐ and R_{b} may be substituted with a functional group such as a hydroxyl group, a cyano group, an amino group, a pyrrolidino group, a piperidino group, a morpholino group and an oxo group, an alkoxy group or a halogen atom.

Examples of the alkyl group, the cycloalkyl group, the aryl group or the aralkyl group (each of the alkyl group, the cycloalkyl group, the aryl group and the aralkyl group may be substituted with the functional group, an alkoxy group or a halogen atom) of the R include a group derived from a straight chained or branched alkane such as methane, ethane, propane, butane, pentane, hexane, heptane, octane, nonane, decane, undecane and dodecane, a group in which the group derived from the alkane is substituted with one or more kinds of or one or more of cycloalkyl groups such as, for example, a cyclobutyl group, a cyclopentyl group and a cyclohexyl group,

a group derived from a cycloalkane such as cyclobutane, cyclopentane, cyclohexane, cycloheptane, cyclooctane, norbornane, adamantine and noradamantane, a group in which the group derived from the cycloalkane is substituted with one or more kinds of or one or more of straight chained or branched alkyl groups such as, for example, a methyl group, an ethyl group, an n-propyl group, an i-propyl group, an n-butyl group, a 2-methylpropyl group, a 1-methylpropyl group and a t-butyl group,

a group derived from an aromatic compound such as benzene, naphthalene and anthracene, or a group in which the group derived from the aromatic compound is substituted with one or more kinds of or one or more groups of straight chained or branched alkyl groups such as, for example, a methyl group, an ethyl group, an n-propyl group, an i-propyl group, an n-butyl group, a 2-methylpropyl group, a 1-methylpropyl group and a t-butyl group,

a group derived from a heterocyclic compound such as pyrrolidine, piperidine, morpholine, tetrahydrofuran, tetrahydropyran, indole, indoline, quinoline, perhydroquinoline, indazole and benzimidazole, a group in which the group derived from the heterocyclic compound is substituted with one or more kinds of or one or more of straight chained or branched alkyl groups or groups derived from aromatic compounds, a group in which the group derived from a straight chained or branched alkane—the group derived from a cycloalkane is substituted with one or more kinds of or one or more of groups derived from aromatic compounds, such as a phenyl group, a naphthyl group and an anthracenyl group, or a group in which the above-described substituent is substituted with a functional group such as a hydroxyl group, a cyano group, an amino group, a pyrrolidino group, a piperidino group, a morpholino group and an oxo group, and the like.

In addition, examples of the divalent heterocyclic hydrocarbon group (preferably having from 1 to 20 carbon atoms) formed by combining Rₐ's with each other or a derivative thereof include a group derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline and 1,5,9-triazacyclododecane, a group in which the group derived from the heterocyclic compound is substituted with one or more kinds of or one or more of straight chained or branched groups derived from alkane, groups derived from cycloalkane, groups derived from aromatic compounds, groups derived from heterocyclic compounds and functional groups such as a hydroxy group, a cyano group, an amino group, a pyrrolidino group, a piperidino group, a morpholino group and an oxo group, and the like.

Specific examples of the compound represented by Formula (F) will be described below.

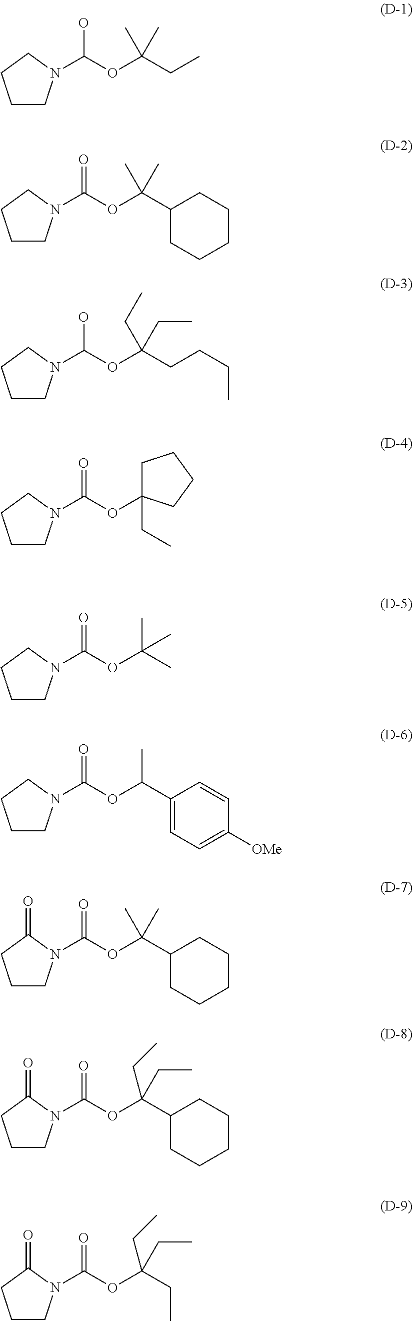

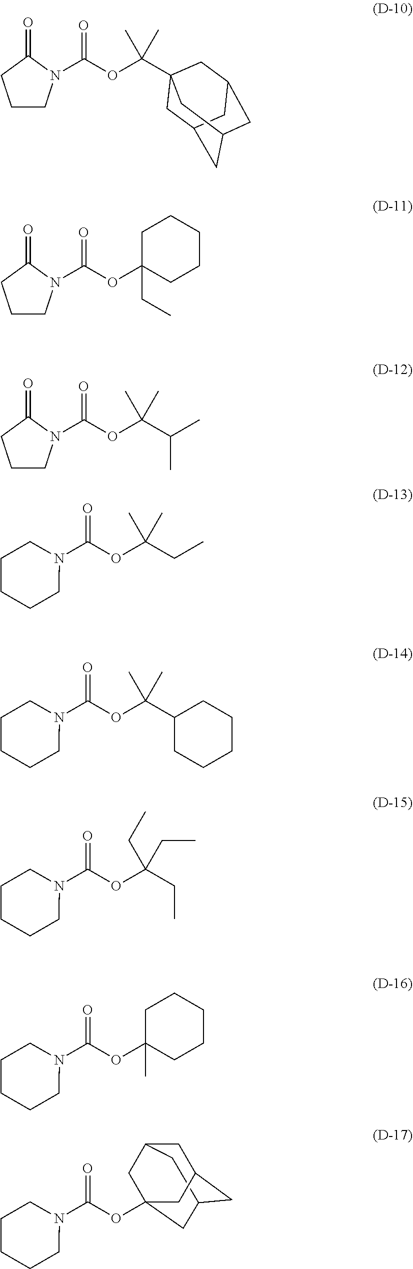

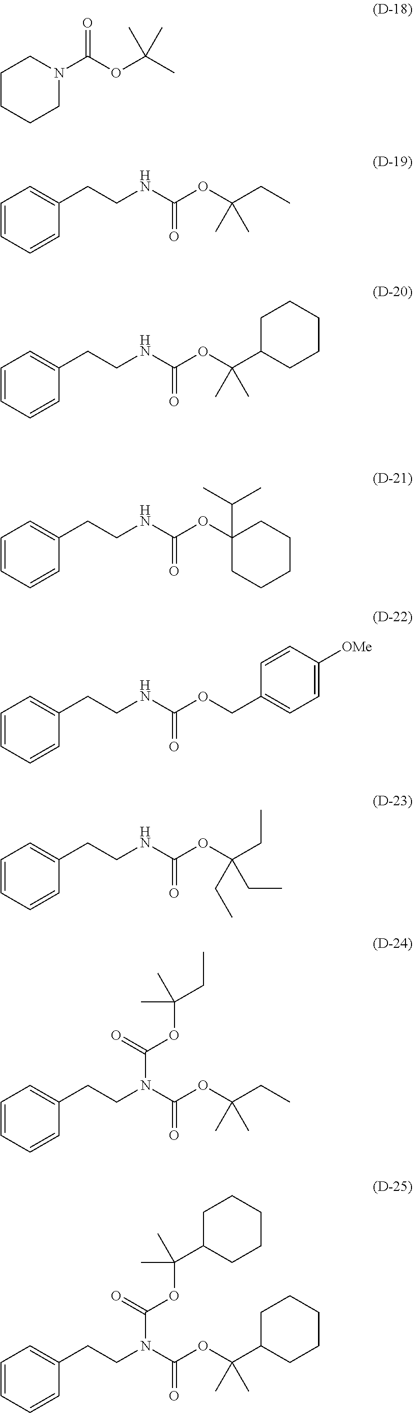

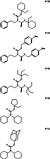 [SMILES: CCC1(OC(=O)N(CCc2ccccc2)C(=O)OC2(CC)CCCCC2)CCCCC1 ; COc1ccc(COC(=O)N(CCc2ccccc2)C(=O)OCc2ccc(OC)cc2)cc1 ; CCC(CC)(CC)OC(=O)N(CCc1ccccc1)C(=O)OC(CC)(CC)CC ; CCC1(OC(=O)N(C2CCCCC2)C2CCCCC2)CCCC1 ; O=C(OC12CC3CC(CC(C3)C1)C2)N(C1CCCCC1)C1CCCCC1]

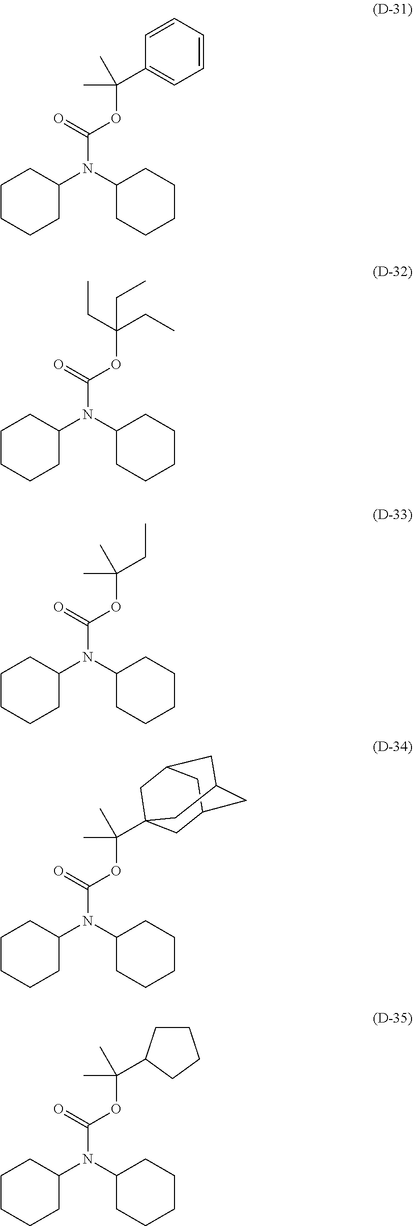

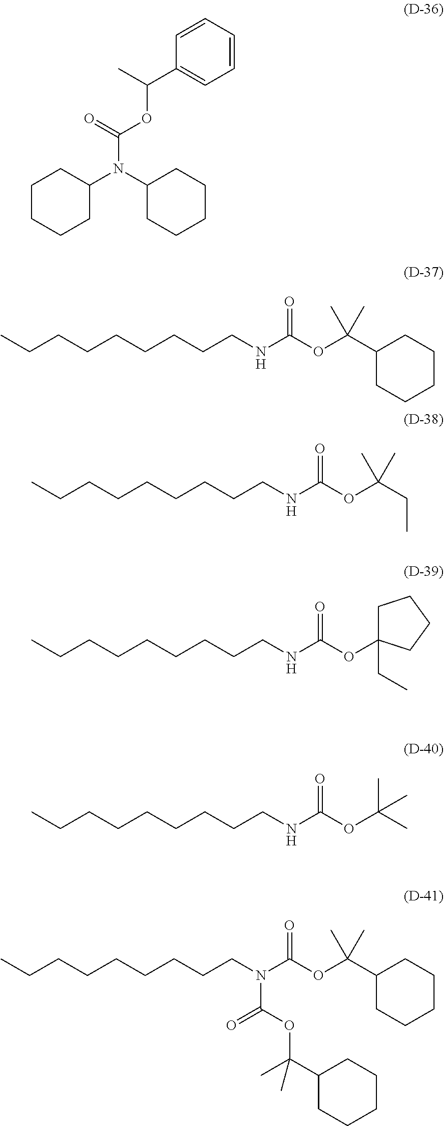

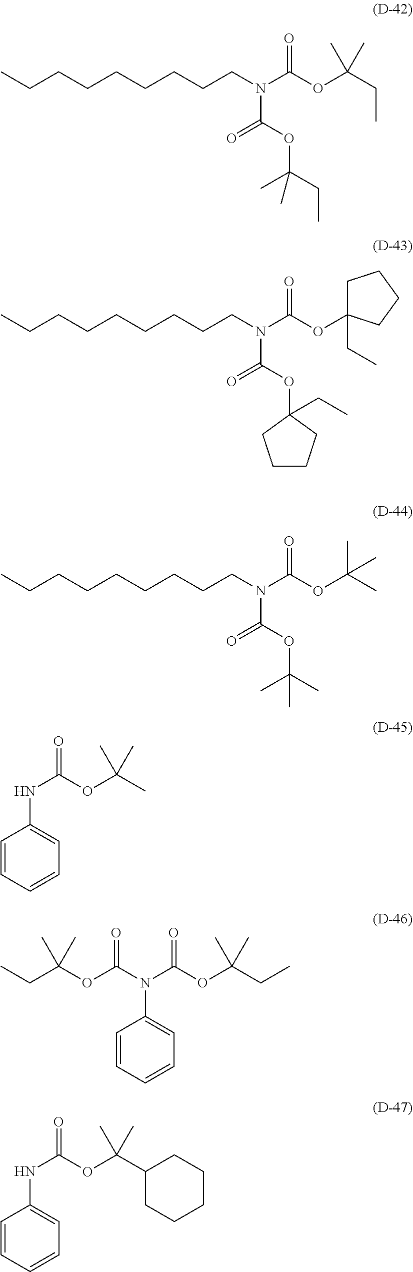

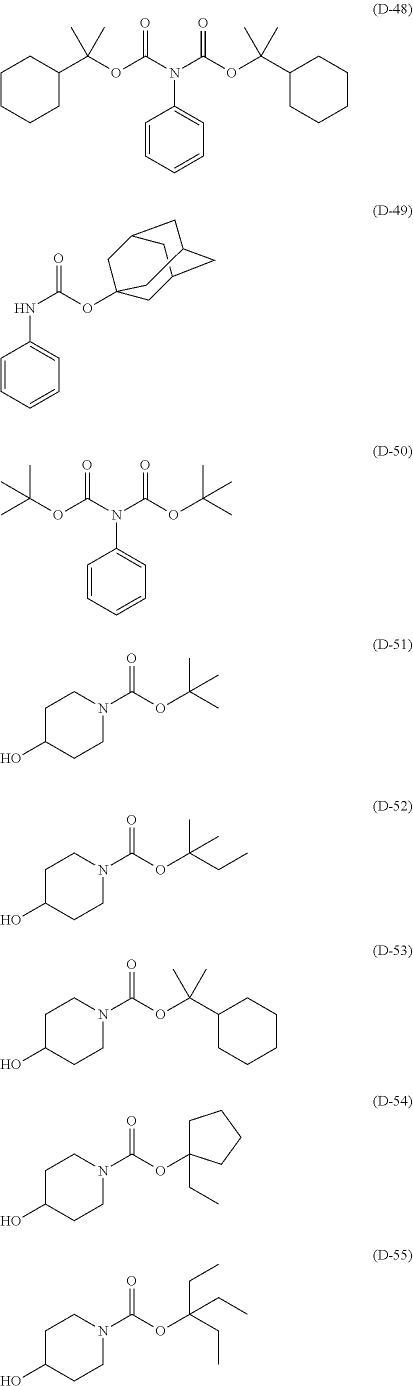

As for the compound represented by Formula (F), a commercially available product may be used, or the compound may be synthesized from a commercially available amine by the method described in the Protective Groups in Organic Synthesis, 4th Edition and the like. The compound may be synthesized in accordance with the method described, for example, in Japanese Patent Application Laid-Open No. 2009-199021, as the most general method.

Furthermore, a compound having an amine oxide structure as basic compound (N′) may also be used. As specific examples of the compound, it is possible to use triethylamine pyridine N-oxide, tributylamine N-oxide, triethanolamine N-oxide, tris(methoxyethyl)amine N-oxide, tris(2-(methoxymethoxy)ethyl)amine=oxide, 2,2′,2″-nitrilotriethylpropionate N-oxide, N-2-(2-methoxyethoxy)methoxyethylmorpholine N-oxide, and an amine oxide compound exemplified in Japanese Patent Application Laid-Open No. 2008-102383.

The molecular weight of basic compound (N′) is preferably 250 to 2,000, and more preferably 400 to 1,000. From the viewpoint of more reduction in LWR and uniformity of local pattern dimension, the molecular weight of the basic compound is preferably 400 or more, more preferably 500 or more, and even more preferably 600 or more.

These basic compounds (N′) may be used in combination with compound (N), and are used either alone or in combination of two or more thereof

The actinic ray-sensitive or radiation-sensitive resin composition in the present invention may or may not contain basic compound (N′), but when the composition contains basic compound (N′), the amount of basic compound (N′) used is usually 0.001 to 10% by mass, and preferably 0.01 to 5% by mass, based on the solid content of the actinic ray-sensitive or radiation-sensitive resin composition.

[6] Solvent (E)

Examples of the solvent, which may be used at the time of preparing the actinic ray-sensitive or radiation-sensitive resin composition in the present invention, include an organic solvent such as alkylene glycol monoalkyl ether carboxylate, alkylene glycol monoalkyl ether, alkyl ester lactate, alkyl alkoxypropionate, cyclic lactone (preferably having 4 to 10 carbon atoms), a monoketone compound (preferably having 4 to 10 carbon atoms) which may have a ring, alkylene carbonate, alkyl alkoxyacetate and alkyl pyruvate.

Specific examples of these solvents include those described in [0441] to [0455] of U.S. Patent Application Publication No. 2008/0187860.

In the present invention, a mixed solvent in which a solvent containing a hydroxyl group and a solvent containing no hydroxyl group in the structure thereof are mixed may be used as an organic solvent.

As the solvent containing a hydroxy group and the solvent containing no hydroxy group, the above-described exemplary compound may be appropriately selected, but the solvent containing a hydroxyl group is preferably alkylene glycol monoalkyl ether, alkyl lactate and the like, and more preferably propylene glycol monomethyl ether (PGME, another name 1-methoxy-2-propanol) and ethyl lactate. Further, the solvent containing no hydroxy group is preferably alkylene glycol monoalkyl ether acetate, alkyl alkoxypropionate, a monoketone compound which may contain a ring, a cyclic lactone, alkyl acetate and the like, and among them, propylene glycol monomethyl ether acetate (PGMEA, another name 1-methoxy-2-acetoxypropane), propylene glycol monomethyl ether propionate, ethyl ethoxypropionate, propylene carbonate, 2-heptanone, γ-butyrolactone, cyclohexanone and butyl acetate are particularly preferred, and propylene glycol monomethyl ether acetate, ethyl ethoxypropionate and 2-heptanone are most preferred.

The mixing ratio (by mass) of the solvent containing a hydroxyl group to the solvent containing no hydroxyl group is 1/99 to 99/1, preferably 10/90 to 90/10, and more preferably 20/80 to 60/40. A mixed solvent in which the solvent containing no hydroxyl group is contained in an amount of 50% by mass or more is particularly preferred in view of coating uniformity.

The solvent preferably includes propylene glycol monomethyl ether acetate, and a single solvent of propylene glycol monomethyl ether acetate or a mixed solvent of two or more containing propylene glycol monomethyl ether acetate is preferred.

[7] Surfactant (F)

The actinic ray-sensitive or radiation-sensitive resin composition in the present invention may or may not contain a surfactant, but when the composition contains a surfactant, it is more preferred that the composition contains any one of fluorine and/or silicone-based surfactants (a fluorine-based surfactant, a silicone-based surfactant and a surfactant having both a fluorine atom and a silicon atom), or two or more thereof.

The actinic ray-sensitive or radiation-sensitive resin composition in the present invention contains a surfactant, thereby imparting a resist pattern with adhesion and reduced development defects due to improved sensitivity and resolution when using an exposure light source with a wavelength of 250 nm or less, particularly 220 nm or less.

Examples of the fluorine-based and/or silicone-based surfactants include surfactants described in [0276] of U.S. Patent Application Publication No. 2008/0248425, such as F-Top EF301 and EF303 (manufactured by Shin-Akita Chemical Co., Ltd.), Fluorad FC430, 431 and 4430 (manufactured by Sumitomo-3M Co., Ltd.), Megafac F171, F173, F176, F189, F113, F110, F177, F120 and R08 (manufactured by DIC Corporation), Surflon S-382, SC101, 102, 103, 104, 105 and 106 and KH-20 (manufactured by Asahi Glass Co., Ltd.), Troysol S-366 (manufactured by Troy Chemical Corp.), GF-300 and GF-150 (manufactured by TOAGOSEI Chemical Industry Co., Ltd.), Surflon S-393 (manufactured by Seimi Chemical Co., Ltd.), F-Top EF121, EF122A, EF122B, RF122C, EF125M, EF135M, EF351, EF352, EF801, EF802 and EF601 (manufactured by JEMCO Inc.), PF636, PF656, PF6320 and PF6520 (manufactured by OMNOVA Solutions, Inc.), FTX-204G, 208G, 218G, 230G, 204D, 208D, 212D, 218D and 222D (manufactured by NEOS Corporation) and the like. In addition, polysiloxane polymer KP-341 (manufactured by Shin-Etsu Chemical Co., Ltd.) may also be used as the silicone-based surfactant.

Furthermore, other than those publicly known surfactants described above, it is possible to use a surfactant using a polymer having a fluoro-aliphatic group derived from a fluoro-aliphatic compound which is prepared by a telomerization method (also referred to as a telomer method) or an oligomerization method (also referred to as an oligomer method) as the surfactant. The fluoro-aliphatic compound may be synthesized by the method described in Japanese Patent Application Laid-Open No. 2002-90991.

Examples of a surfactant corresponding to the above-described surfactant include Megafac F178, F-470, F-473, F-475, F-476 and F-472 (manufactured by DIC Corporation), a copolymer of an acrylate having a C₆Fi₃ group (or methacrylate) with a (poly(oxyalkylene))acrylate (or methacrylate), a copolymer of an acrylate having a C₃F₇ group (or methacrylate) with a (poly(oxyethylene))acrylate (or methacrylate) and a (poly(oxypropylene))acrylate (or methacrylate), and the like.

Further, in the present invention, it is also possible to use a surfactant other than the fluorine-based and/or silicone-based surfactant, described in [0280] of U.S. Patent Application Publication No. 2008/0248425.

These surfactants may be used either alone or in combination of several thereof.

When the actinic ray-sensitive or radiation-sensitive resin composition contains a surfactant, the amount of surfactant used is preferably 0.0001 to 2% by mass, and more preferably 0.0005 to 1% by mass, based on the total amount of the actinic ray-sensitive or radiation-sensitive resin composition (excluding the solvent).

Meanwhile, by adjusting the amount of surfactant added to 10 ppm or less based on the total amount of actinic ray-sensitive or radiation-sensitive resin composition (excluding the solvent), the surface uneven distribution of the hydrophobic resin is increased, and accordingly, the surface of the resist film may be made to be more hydrophobic, thereby enhancing the water follow-up property at the time of liquid immersion exposure.

[8] Other Additives (G)

The actinic ray-sensitive or radiation-sensitive resin composition in the present invention may or may not contain a carboxylic acid onium salt. Examples of the carboxylic acid onium salt include those described in [0605] and [0606] of U.S. Patent Application Publication No. 2008/0187860.

The carboxylic acid onium salt may be synthesized by reacting sulfonium hydroxide, iodonium hydroxide, ammonium hydroxide and carboxylic acid with silver oxide in an appropriate solvent.

When the actinic ray-sensitive or radiation-sensitive resin composition contains a carboxylic acid onium salt, the content thereof is generally 0.1 to 20% by mass, preferably 0.5 to 10% by mass, and more preferably 1 to 7% by mass, based on the total solid content of the composition.

The actinic ray-sensitive or radiation-sensitive resin composition of the present invention may further contain a dye, a plasticizer, a photosensitizer, a light absorber, an alkali-soluble resin, a dissolution inhibitor, a compound for accelerating solubility in a developer (for example, a phenol compound having a molecular weight of 1,000 or less, or an alicyclic or aliphatic compound having a carboxyl group) and the like, if necessary.

The phenol compound having a molecular weight of 1,000 or less may be easily synthesized by a person skilled in the art by referring to the methods described in, for example, Japanese Patent Application Laid-Open No. H4-122938, Japanese Patent Application Laid-Open No. H2-28531, U.S. Pat. No. 4,916,210, European Patent No. 219294 and the like.

Specific examples of the alicyclic or aliphatic compound having a carboxyl group include a carboxylic acid derivative having a steroid structure, such as cholic acid, deoxycholic acid and lithocholic acid, an adamantanecarboxylic acid derivative, adamantanedicarboxylic acid, cyclohexanecarboxylic acid, cyclohexanedicarboxylic acid and the like, but are not limited thereto.

From the viewpoint of enhancing the resolution, the actinic ray-sensitive or radiation-sensitive resin composition in the present invention is used preferably in a film thickness of 30 to 250 nm, and more preferably in a film thickness of 30 to 200 nm. Such a film thickness may be achieved by setting a solid concentration in the composition to an appropriate range to have an appropriate viscosity, thereby enhancing coatability and film-formation property.

The solid content concentration of the actinic ray-sensitive or radiation-sensitive resin composition in the present invention is usually 1.0 to 10% by mass, preferably 2.0 to 5.7% by mass, and more preferably 2.0 to 5.3% by mass. By setting the solid content concentration to the above-described range, the resist solution may be uniformly applied on a substrate and a resist pattern having excellent line width roughness may be formed The reason is not clear, but it is thought that by setting the solid content concentration to 10% by mass or less and preferably 5.7% by mass or less, aggregation of materials, particularly, a photo-acid generator, in the resist solution is suppressed, and as a result, a uniform resist film may be formed.

The solid content concentration is a weight percentage of the weight of other resist components excluding the solvent, based on the total weight of the actinic ray-sensitive or radiation-sensitive resin composition.

The actinic ray-sensitive or radiation-sensitive resin composition in the present invention is used by dissolving the aforementioned components in a predetermined organic solvent, preferably in the mixed solvent, filtering the solution through a filter, and then applying the filtered solution on a predetermined support (substrate). The filter used for filtration is preferably a polytetrafluoroethylene-, polyethylene- or nylon-made filter having a pore size of 0.1 μm or less, more preferably 0.05 μm or less, and even more preferably 0.03 μm or less. In the filtration through a filter, as described in, for example, Japanese Patent Application Laid-Open No. 2002-62667, circulating filtration may be performed, or the filtration may be performed by connecting a plurality of kinds of filters in series or in parallel. In addition, the composition may be filtered a plurality of times. Furthermore, a deaeration treatment or the like may be applied to the composition before or after filtration through a filter.

[9] Pattern Forming Method

The pattern forming method (negative-type pattern forming method) of the present invention at least includes

(a) a process of forming a film (resist film) by the aforementioned actinic ray-sensitive or radiation-sensitive resin composition,

(b) a process of exposing the film, and

(c) a process of performing development using a developer including an organic solvent to form a negative-type pattern.

The exposure in the process (b) may be liquid immersion exposure.

It is preferred that the pattern forming method of the present invention includes (d) a heating process after (b) the exposure process.

The pattern forming method of the present invention may further include (e) a process of performing development using an alkali developer.

In the present invention, a portion in which exposure strength is weak is removed by an organic solvent developing process, and a portion in which exposure strength is strong is also removed by performing an alkali development process. By multiple development processes of performing a plurality of development processes as described above, a pattern may be formed without dissolving an area of intermediate exposure strength alone, so that a pattern which is finer than a usual pattern may be formed (the mechanism as disclosed in [0077] of Japanese Patent Application Laid-Open No. 2008-292975).

In the pattern forming method of the present invention, the sequence of the alkali development process and the organic solvent developing process is not particularly limited, but it is more preferred that the alkali developing process is performed before the organic solvent developing process.

The pattern forming method of the present invention may include plural times of (b) the exposure process.

The pattern forming method of the present invention may include plural times of (e) a heating process.

The present invention also relates to a resist film formed of the actinic ray-sensitive or radiation-sensitive resin composition according to the present invention.

The resist film is formed of the actinic ray-sensitive or radiation-sensitive resin composition according to the present invention as described above, and more specifically, it is preferred that the resist film is formed on a substrate. In the pattern forming method of the present invention, the process of forming a film by an actinic ray-sensitive or radiation-sensitive resin composition on a substrate, the process of exposing the film, and the process of performing development may be performed by a generally known method.

It is also preferred that the method includes, after film formation, a pre-baking process (PB) before the exposure process.

Further, it is also preferred that the method includes a post-exposure baking process (PEB) after the exposure process and before the development process.

As for the heating temperature, both PB and PEB are performed preferably at 70 to 130° C., and more preferably at 80 to 120° C.

The heating time is preferably 30 to 300 seconds, more preferably 30 to 180 seconds, and even more preferably 30 to 90 seconds.

The heating may be performed using a means equipped with a typical exposure developing machine or may be performed using a hot plate or the like.

By means of baking, the reaction in the exposed portion is accelerated, and thus the sensitivity or a pattern profile is improved.

The light source wavelength used in the exposure apparatus in the present invention is not limited, but examples thereof include an infrared light, visible light, ultraviolet light, far ultraviolet light, an extreme-ultraviolet light, X-ray, an electron beam and the like, and the light source wavelength is preferably far ultraviolet light at a wavelength of preferably 250 nm or less, more preferably 220 nm or less, and particularly preferably from 1 nm to 200 nm Specific examples thereof include a KrF excimer laser (248 nm), an ArF excimer laser (193 nm), an F₂ excimer laser (157 nm), an X-ray, an EUV (13 nm), an electron beam and the like, and a KrF excimer laser, an ArF excimer laser, an EUV or an electron beam is preferred, and an ArF excimer laser is more preferred.

In addition, in the process of performing exposure of the present invention, a liquid immersion exposure method may be applied.

The liquid immersion exposure method is, as the technique to increase the resolution, a technique of performing the exposure by filling a high refractive-index liquid (hereinafter, also referred to as a “liquid for liquid immersion”) between a projection lens and a sample.

As described above, for the “effect of liquid immersion”, assuming that λ₀ is the wavelength of exposure light in air, n is the refractive index of the liquid for liquid immersion for air, θ is the convergence of a half-angle of beam and NAₒ=sin θ, the resolution and the depth of focus in liquid immersion may be expressed by the following equations. Here, k₁ and k₂ are coefficients related to the process.

(Resolution)=k₁(λ₀/n)/NA₀

(Depth of focus)=±k₂·(λ₀/n)/NA₀²

That is, the effect of liquid immersion is equivalent to the use of an exposure wavelength having a wavelength of 1/n. In other words, in the case of a projection optical system having the same NA, the depth of focus may be made n times larger by the liquid immersion. This is effective for all pattern shapes and may be combined with the super-resolution technology that is now being currently studied, such as a phase-shift method and a modified illumination method.

In the case of performing liquid immersion exposure, a process of washing the surface of the film with an aqueous chemical solution may be performed (1) before forming the film on a substrate and then performing exposure and/or (2) after the process of exposing the film through a liquid for liquid immersion but before the process of heating the film.

The liquid for liquid immersion is preferably a liquid which is transparent to light at the exposure wavelength and has a temperature coefficient of refractive index as small as possible in order to minimize the distortion of an optical image projected on the film, and particularly, when the exposure light source is an ArF excimer laser (wavelength; 193 nm), water is preferably used from the viewpoint of easy availability and easy handleability in addition to the above-described viewpoint.

When water is used, an additive (liquid) capable of decreasing the surface tension of water and increasing the interfacial activity may be added in a small ratio. It is preferred that the additive does not dissolve the resist layer on the wafer and has only a negligible effect on the optical coat at the undersurface of the lens element.

Such an additive is preferably an aliphatic alcohol having a refractive index almost equal to that of, for example, water, and specific examples thereof include methyl alcohol, ethyl alcohol, isopropyl alcohol and the like. By adding an alcohol having a refractive index almost equal to that of water, even when the alcohol component in water is evaporated and the content concentration thereof is changed, it is possible to obtain an advantage in that the change in the refractive index of the liquid as a whole may be made very small.

Meanwhile, when a substance opaque to light at 193 nm or an impurity greatly differing from water in the refractive index is incorporated, the incorporation incurs distortion of the optical image projected on the resist, and thus, the water used is preferably distilled water. Furthermore, pure water filtered through an ion exchange filter or the like may also be used.

The electrical resistance of water used as the liquid for liquid immersion is preferably 18.3 MQcm or more, and TOC (organic concentration) is preferably 20 ppb or less and the water is preferably subjected to deaeration treatment.

Further, the lithography performance may be enhanced by raising the refractive index of the liquid for liquid immersion. From this viewpoint, an additive for raising the refractive index may be added to water, or heavy water (D₂O) may be used in place of water.

When a film formed by using the composition of the present invention is exposed through a liquid immersion medium, the above-described hydrophobic resins (D) may be further added, if necessary. The hydrophobic resin (D) is added, thereby enhancing the receding contact angle of the surface. The receding contact angle of the film is preferably 60° to 90°, and more preferably 70° or more.

In the liquid immersion exposure process, the liquid for liquid immersion needs to move on a wafer following the movement of an exposure head that scans on the wafer at a high speed and forms an exposure pattern, and thus the contact angle of the liquid for liquid immersion for the resist film in a dynamic state is important, and the resist requires a performace of following the high-speed scanning of the exposure head, while a liquid droplet no longer remains.

In order to cause the film not to directly contact the liquid for liquid immersion, a film (hereinafter, also referred to as a “topcoat”) that is sparingly soluble in a liquid for liquid immersion may be formed between the film formed using the composition of the present invention and the liquid for liquid immersion. Examples of a function required for the topcoat include coating suitability to the upper layer portion of the resist, transparency to radiation, particularly radiation having a wavelength of 193 nm, and poor solubility in the liquid for liquid immersion. It is preferred that the topcoat may be uniformly coated onto the upper layer of the resist without being mixed with the resist.

The topcoat is preferably a polymer which does not contain an aromatic group from the viewpoint of the transparency at 193 nm.

Specific examples of the polymer include a hydrocarbon polymer, an acrylic acid ester polymer, polymethacrylic acid, polyacrylic acid, polyvinyl ether, a silicone-containing polymer, a fluorine-containing polymer and the like. The described-above hydrophobic resin (D) is also suitable as the topcoat. If impurities are eluted from the topcoat to the liquid for liquid immersion, the optical lens is contaminated, and thus it is preferred that the amounts of residual monomer components of the polymer included in the topcoat are small.

When the topcoat is peeled off, a developer may be used, or a peeling agent may separately be used. As the peeling agent, a solvent that rarely penetrates the film is preferred. From the viewpoint that the peeling process may be performed simultaneously with the developing treatment process of the film, it is preferred that the topcoat may be peeled off by an alkali developer. From the viewpoint of peeling off the topcoat with an alkali developer, the topcoat is preferably acidic, but from the viewpoint of a non-intermixture property with respect to the film, the topcoat may be neutral or alkaline.

It is preferred that there is no difference or a small difference in the refractive index between the topcoat and the liquid for liquid immersion. In this case, the resolution may be enhanced. When the exposure light source is an ArF excimer laser (wavelength: 193 nm), it is preferred that water is used as the liquid for liquid immersion, and thus the topcoat for ArF liquid immersion exposure preferably has a refractive index close to the refractive index (1.44) of water. Furthermore, from the viewpoint of transparency and refractive index, the topcoat is preferably a thin film.

It is preferred that the topcoat is not mixed with the film and the liquid for liquid immersion. From this viewpoint, when the liquid for liquid immersion is water, it is preferred that the solvent used for the topcoat is sparingly soluble in the solvent used for the composition of the present invention and is a water-insoluble medium. Further, when the liquid for liquid immersion is an organic solvent, the topcoat may be water-soluble or water-insoluble.

In the present invention, the substrate on which the film is formed is not particularly limited, and it is possible to use an inorganic substrate such as silicone, SiN, SiO₂ or SiN, a coating-type inorganic substrate such as SOG, or a substrate generally used in the process of manufacturing a semiconductor such as IC or manufacturing a liquid crystal or a circuit board such as a thermal head or in the lithography process of other photo-fabrication processes. Furthermore, if necessary, an organic antireflection film may be formed between the film and the substrate.

When the pattern forming method of the present invention further includes a process of performing development using an alkali developer, it is possible to use an alkaline aqueous solution of inorganic alkalis such as sodium hydroxide, potassium hydroxide, sodium carbonate, sodium silicate, sodium metasilicate and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, and cyclic amines such as pyrrole and piperidine as the alkali developer.

Furthermore, alcohols and a surfactant may be added to the alkaline aqueous solution each in an appropriate amount and the mixture may be used.

The alkali concentration of the alkali developer is usually 0.1 to 20% by mass.

The pH of the alkali developer is usually 10.0 to 15.0.

In particular, an aqueous solution of 2.38% by mass of tetramethylammonium hydroxide is preferred.

As for the rinsing liquid in the rinsing treatment performed after the alkali development, pure water is used, and an appropriate amount of a surfactant may be added thereto to use the mixture.

Further, after the development treatment or rinsing treatment, a treatment of removing the developer or rinsing liquid adhering on the pattern by a supercritical fluid may be performed.

As the developer (hereinafter, also referred to as an organic-based developer) in the process of performing developing using a developer containing an organic solvent to form a negative-type pattern, a polar solvent such as a ketone-based solvent, an ester-based solvent, an alcohol-based solvent, an amide-based solvent and an ether-based solvent, and a hydrocarbon-based solvent may be used.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, propylene carbonate and the like.

Examples of the ester-based solvent include methyl acetate, butyl acetate, ethyl acetate, isopropyl acetate, pentyl acetate, isopentyl acetate, amyl acetate, cyclohexyl acetate, isobutyl isobutyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate and the like.

Examples of the alcohol-based solvent include an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol and n-decanol, a glycol-based solvent such as ethylene glycol, diethylene glycol and triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethyl butanol, and the like.

Examples of the ether-based solvent include, in addition to the glycol ether-based solvents, dioxane, tetrahydrofuran, phenetol, dibutyl ether and the like.

As the amide-based solvent, it is possible to use N-methyl-2-pyrrolidone, N,N-dimethylacetamide, N,N-dimethylformamide, hexamethylphosphoric triamide, 1,3-dimethyl-2-imidazolidinone and the like.

Examples of the hydrocarbon-based solvent include an aromatic hydrocarbon-based solvent such as toluene and xylene, and an aliphatic hydrocarbon-based solvent such as pentane, hexane, octane and decane.

A plurality of the aforementioned solvents may be mixed, or the solvents may be used by being mixing with a solvent other than those described above or with water. Provided that in order to sufficiently exhibit the effects of the present invention, the water content ratio of the entire developer is preferably less than 10% by mass, and it is more preferred that the developer contains substantially no moisture.

That is, the amount of the organic solvent used in the organic-based developer is preferably 90% by mass to 100% by mass, and preferably 95% by mass to 100% by mass, based on the total amount of the developer.

In particular, the organic-based developer is preferably a developer containing at least one of the organic solvents selected from the group consisting of a ketone-based solvent, an ester-based solvent, an alcohol-based solvent, an amide-based solvent and an ether-based solvent.

The vapor pressure of the organic-based developer is preferably 5 kPa or less, more preferably 3 kPa or less, and particularly preferably 2 kPa or less, at 20° C. By adjusting the vapor pressure of the organic-based developer to 5 kPa or less, evaporation of the developer on a substrate or in a development cup is suppressed so that temperature uniformity in the wafer plane is enhanced, and as a result, the dimensional uniformity in the wafer plane is improved.

Specific examples of the solvent having a vapor pressure of 5 kPa or less include a ketone-based solvent such as 1-octanone, 2-octanone, 1-nonanone, 2-nonanone, 2-heptanone (methyl amyl ketone), 4-heptanone, 2-hexanone, diisobutyl ketone, cyclohexanone, methylcyclohexanone, phenylacetone and methyl isobutyl ketone, an ester-based solvent such as butyl acetate, pentyl acetate, isopentyl acetate, amyl acetate, cyclohexyl acetate, isobutyl isobutyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate and propyl lactate, an alcohol-based solvent such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol and n-decanol, a glycol-based solvent such as ethylene glycol, diethylene glycol and triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol, an ether-based solvent such as tetrahydrofuran, phenetol and dibutyl ether, an amide-based solvent such as N-methyl-2-pyrrolidone, N,N-dimethylacetamide and N,N-dimethylformamide, an aromatic hydrocarbon-based solvent such as toluene and xylene, and an aliphatic hydrocarbon-based solvent such as octane and decane.

Specific examples of the solvent having a vapor pressure of 2 kPa or less that is a particularly preferred range include a ketone-based solvent such as 1-octanone, 2-octanone, 1-nonanone, 2-nonanone, 4-heptanone, 2-hexanone, diisobutyl ketone, cyclohexanone, methylcyclohexanone and phenylacetone, an ester-based solvent such as butyl acetate, amyl acetate, cyclohexyl acetate, isobutyl isobutyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate and propyl lactate, an alcohol-based solvent such as n-butyl alcohol, sec-butyl alcohol, tert-butyl alcohol, isobutyl alcohol, n-hexyl alcohol, n-heptyl alcohol, n-octyl alcohol and n-decanol, a glycol-based solvent such as ethylene glycol, diethylene glycol and triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol, an ether-based solvent such as phenetol and dibutyl ether, an amide-based solvent such as N-methyl-2-pyrrolidone, N,N-dimethylacetamide and N,N-dimethylformamide, an aromatic hydrocarbon-based solvent such as xylene, and an aliphatic hydrocarbon-based solvent such as octane and decane.

The organic-based developer may include a basic compound. Specific examples and preferred examples of the basic compound which the developer used in the present invention may include are the same as those in the above-descirbed basic compound which the actinic ray-sensitive or radiation-sensitive resin composition may include. Meanwhile, with respect to the case where the organic-based developer includes a nitrogen-containing compound as the basic compound, please refer to Japanese Patent No. 5056974 and the like.

In the organic-based developer, a surfactant may be added in an appropriate amount, if necessary.

The surfactant is not particularly limited but, for example, ionic or nonionic fluorine-based and/or silicon-based surfactant and the like may be used. Examples of the fluorine and/or silicone-based surfactants include surfactants described in Japanese Patent Application Laid-Open Nos. S62-36663, S61-226746, S61-226745, S62-170950, S63-34540, H7-230165, H8-62834, H9-54432, and H9-5988 and U.S. Pat. Nos. 5,405,720, 5,360,692, 5,529,881, 5,296,330, 5,436,098, 5,576,143, 5,294,511 and 5,824,451, and a nonionic surfactant is preferred. The nonionic surfactant is not particularly limited, but a fluorine-based surfactant or a silicone-based surfactant is more preferably used.

The amount of the surfactant used is usually 0.001 to 5% by mass, preferably 0.005 to 2% by mass, and more preferably 0.01 to 0.5% by mass, based on the total amount of the developer.

As for the developing method, it is possible to apply, for example, a method of dipping a substrate in a bath filled with a developer for a predetermined time (a dipping method), a method of raising a developer on a substrate surface sufficiently by the effect of a surface tension and keeping the substrate still for a predetermined time, thereby performing development (a puddle method), a method of spraying a developer on a substrate surface (a spray method), a method of continuously ejecting a developer on a substrate spinning at a constant speed while scanning a developer ejecting nozzle at a constant rate (a dynamic dispense method) and the like.

When the above-described various developing methods include a process of ejecting a developer toward a resist film from a development nozzle of a developing apparatus, the ejection pressure of the developer ejected (the flow velocity per unit area of the developer ejected) is preferably 2 mL/sec/mm² or less, more preferably 1.5 mL/sec/mm² or less, and even more preferably 1 mL/sec/mm² or less. The flow velocity has no particular lower limit, but is preferably 0.2 mL/sec/mm² or more in consideration of throughput.

By setting the ejection pressure of the ejected developer to the aforementioned range, pattern defects resulting from the resist scum after development may be significantly reduced.

Details on the mechanism are not clear, but it is thought that it is because the pressure imposed on the resist film by the developer is decreased by setting the ejection pressure to the above-described range, so that the resist film•resist pattern is suppressed from being inadvertently cut or collapsing.

Meanwhile, the ejection pressure (mL/sec/mm²) of the developer is the value at the outlet of the development nozzle in the developing apparatus.

Examples of the method for adjusting the ejection pressure of the developer include a method of adjusting the ejection pressure by a pump or the like, a method of supplying a developer from a pressurized tank and adjusting the pressure to change the ejection pressure and the like.

In addition, after the process of performing development using a developer including an organic solvent, a process of stopping the development while replacing the solvent with another solvent may be performed.

It is preferred that a process of rinsing the resist using a rinsing liquid is included after the process of performing development using a developer including an organic solvent.

The rinsing liquid used in the rinsing process after the process of performing development using a developer including an organic solvent is not particularly limited as long as the rinsing liquid does not dissolve the resist pattern, and a solution including a general organic solvent may be used. As for the rinsing liquid, a rinsing liquid containing at least one of the organic solvents selected from the group consisting of a hydrocarbon-based solvent, a ketone-based solvent, an ester-based solvent, an alcohol-based solvent, an amide-based solvent and an ether-based solvent is preferably used.

Specific examples of the hydrocarbon-based solvent, the ketone-based solvent, the ester-based solvent, the alcohol-based solvent, the amide-based solvent and the ether-based solvent are the same as those described above for the developer including an organic solvent.

After the process of performing development using a developer including an organic solvent, a process of performing rinsing using a rinsing liquid containing at least one of organic solvents selected from the group consisting of a ketone-based solvent, an ester-based solvent, an alcohol-based solvent and an amide-based solvent is more preferably performed, a process of performing rinsing using a rinsing liquid containing an alcohol-based solvent or an ester-based solvent is even more preferably performed, a process of performing rinsing using a rinsing liquid containing a monohydric alcohol is particularly preferably performed, and a process of performing rinsing using a rinsing liquid containing a monohydric alcohol having 5 or more carbon atoms is most preferably performed.

Here, examples of the monohydric alcohol used in the rinsing process includes a straight chained, branched or cyclic monohydric alcohol, and specifically, it is possible to use 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol and the like, and as the particularly preferred monohydric alcohol having 5 or more carbon atoms, it is possible to use 1-hexanol, 2-hexanol, 4-methyl-2-pentanol, 1-pentanol, 3-methyl-1-butanol and the like.

A plurality of the components may be mixed, or the components may be used by being mixed with an organic solvent other than those described above.

The water content ratio in the rinsing liquid is preferably 10% by mass or less, more preferably 5% by mass or less, and particularly preferably 3% by mass or less. By setting the water content ratio to 10% by mass or less, good development characteristics may be obtained.

The vapor pressure of the rinsing liquid used after the process of performing development using a developer including an organic solvent is preferably 0.05 kPa to 5 kPa, more preferably 0.1 kPa to 5 kPa, and most preferably 0.12 kPa to 3 kPa, at 20° C. By setting the vapor pressure of the rinsing liquid to 0.05 kPa to 5 kPa, the temperature uniformity in the wafer plane is enhanced, and furthermore, swelling caused by permeation of the rinsing liquid is suppressed, and as a result, the dimensional uniformity in the wafer plane is improved.

The rinsing liquid may also be used by adding an appropriate amount of a surfactant thereto.

In the rinsing process, the wafer subjected to development using a developer including an organic solvent is rinsed by using the aforementioned rinsing liquid including an organic solvent. The method of rinsing treatment is not particularly limited, but it is possible to apply, for example, a method of continuously ejecting a rinsing liquid on a substrate spinning at a constant speed (spin coating method), a method of dipping a substrate in a bath filled with a rinsing liquid for a predetermined time (dipping method), a method of spraying a rinsing liquid on a substrate surface (spraying method), and the like, and among them, it is preferred that the rinsing treatment is performed by the spin coating method and after the rinsing, the substrate is spun at a rotational speed of 2,000 rpm to 4,000 rpm to remove the rinsing liquid from the substrate. Furthermore, it is also preferred that a heating process (post bake) is included after the rinsing process. The developer and rinsing liquid remaining between patterns and in the inside of the pattern are removed by the bake. The heating process after the rinsing process is performed at usually 40 to 160° C., and preferably 70 to 95° C., for usually 10 seconds to 3 minutes, and preferably 30 to 90 seconds.

Further, the present invention also relates to a method for manufacturing an electronic device, including the aforementioned pattern forming method of the present invention, and an electronic device manufactured by this manufacturing method.

The electronic device of the present invention is suitably mounted on electric electronic devices (such as home appliances, OA•media-related devices, optical devices and communication devices).

### EXAMPLES

Hereinafter, the present invention will be described in detail with reference to the Examples, but the content of the present invention is not limited thereby.

### Synthesis Example

### Resin (P-1)

115.7 parts by mass of cyclohexanone was heated at 80° C. under nitrogen flow. While the liquid was stirred, a mixed solution of 31.2 parts by mass of a monomer represented by the following Structural Formula A, 2.8 parts by mass of a monomer represented by the following Structural Formula B, 12.6 parts by mass of a monomer represented by the following Structural Formula C, 11.7 parts by mass of a monomer represented by the following Structural Formula D, 214.8 parts by mass of cyclohexanone, and 2.99 parts by mass of 2,2′-dimethyl azobisisobutyrate [V-601, manufactured by Wako Pure Chemical Industries, Ltd.] was added dropwise thereto over 5 hours. After the completion of the dropwise addition, the solution was further stirred at 80° C. for 2 hours. The reaction solution was allowed to cool, then subjected to reprecipitation with a large amount of hexane/ethyl acetate (mass ratio 8:2), and filtered to obtain a solid, and the solid was vacuum dried to obtain 52.5 parts by mass of Resin (A-1) of the present invention.

The weight average molecular weight (Mw: in terms of polystyrene) obtained from the GPC (carrier: tetrahydrofuran (THF)) of the obtained resin was Mw=8,900 with a polydispersity Mw/Mn=1.58. The composition ratio measured by ¹³C-NMR was 45/5/30/20.

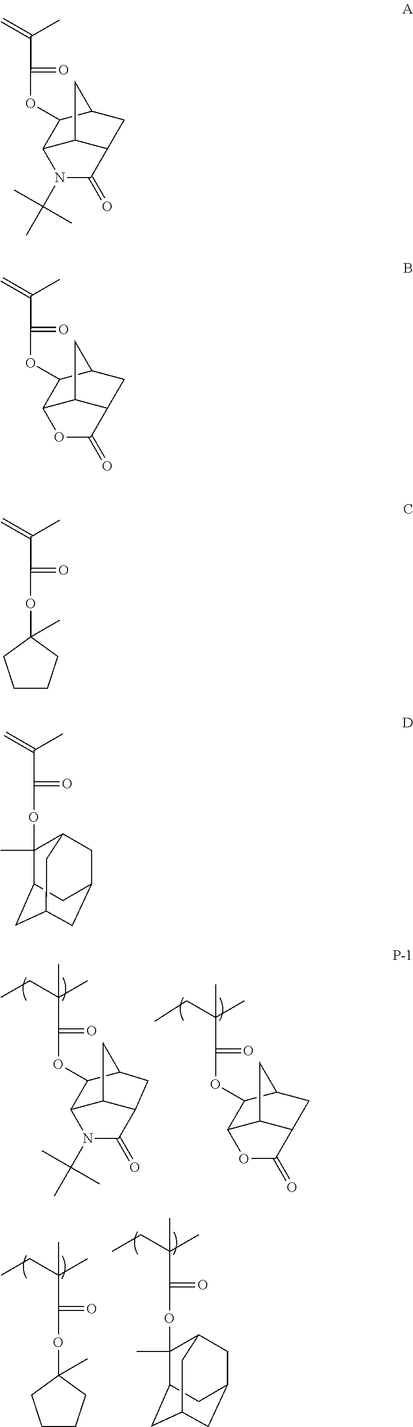

<Acid-Decomposable Resin>

Hereinafter, Resins (P-2) to (P-17) were synthesized in the same manner as above. The structure, composition ratio (molar ratio) of the repeating unit, mass average molecular weight and polydispersity of the synthesized resins will be shown below.

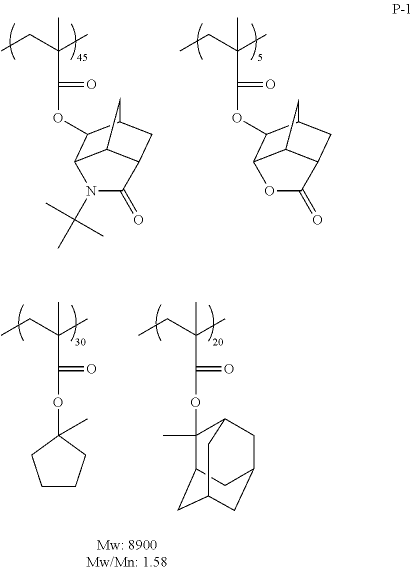

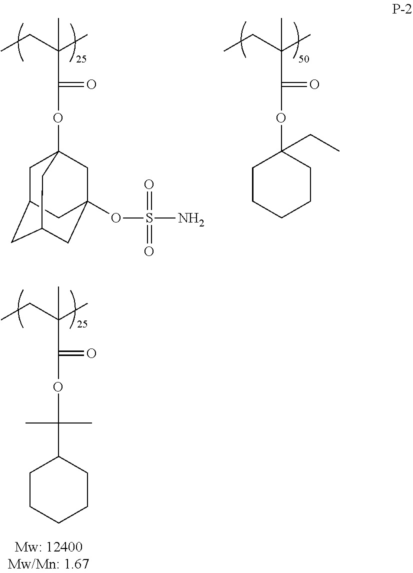

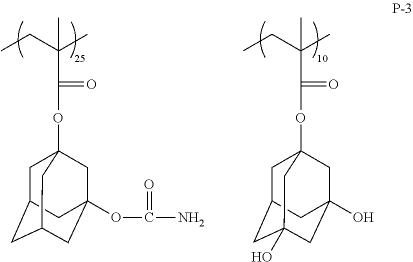

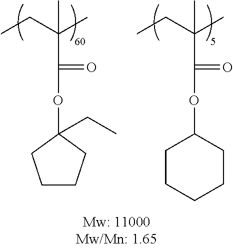

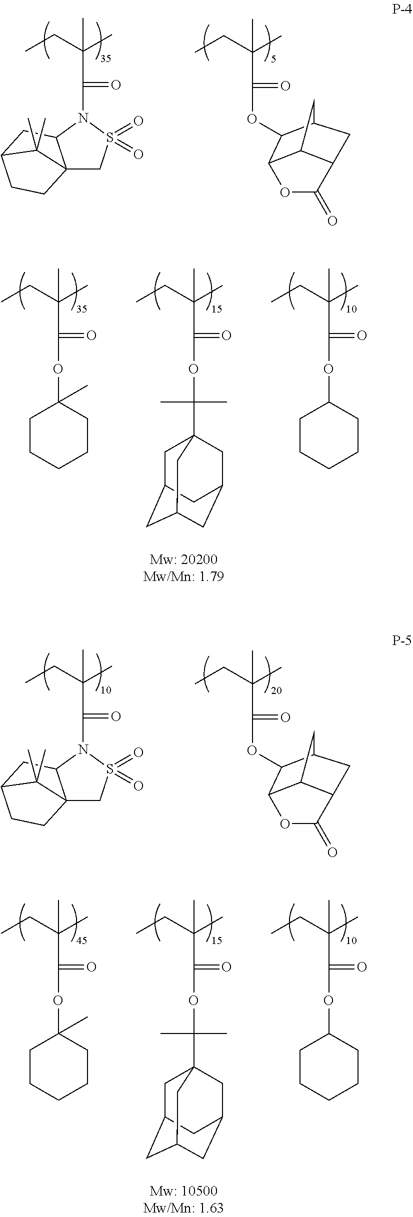

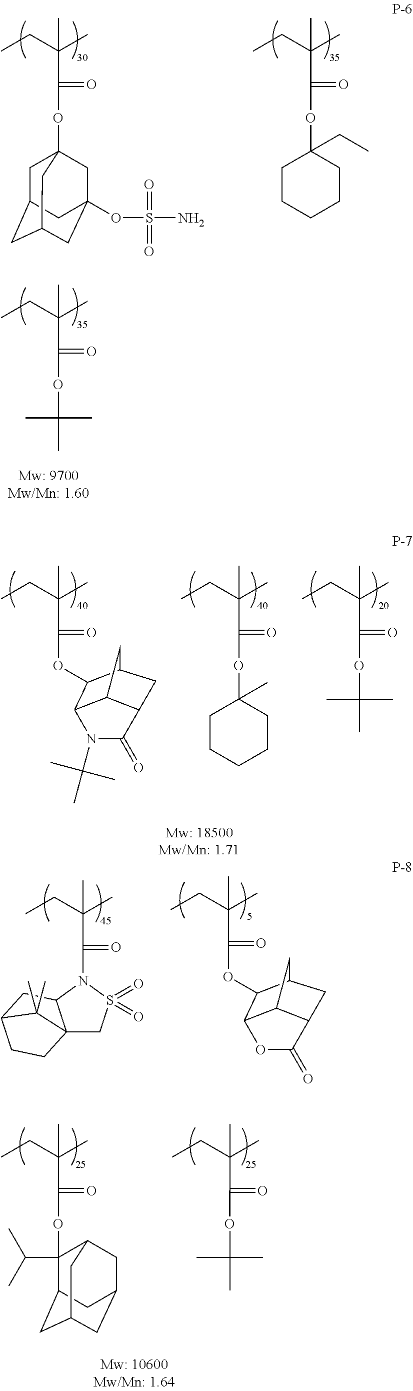

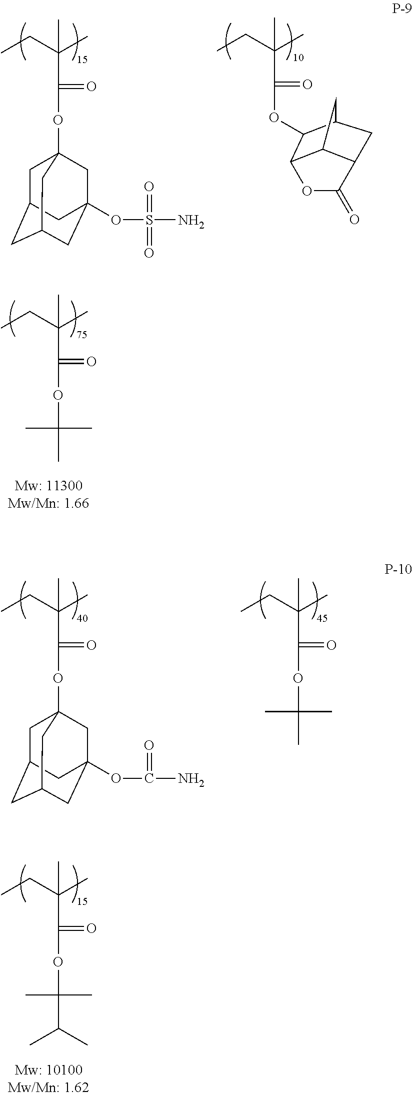

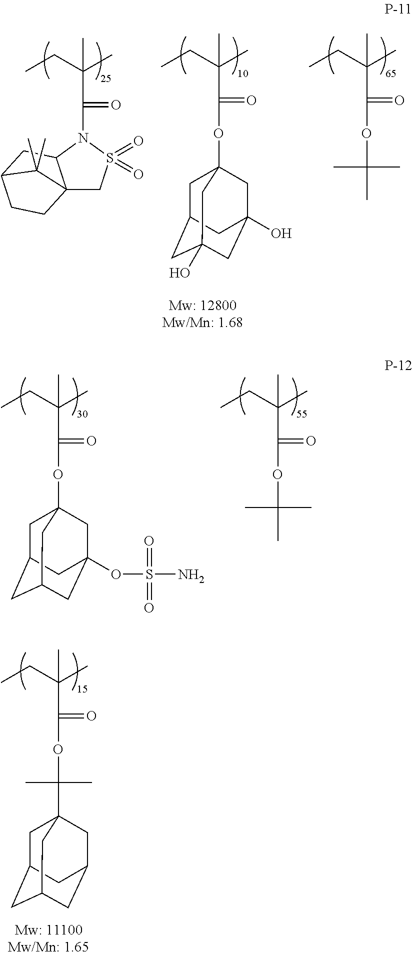

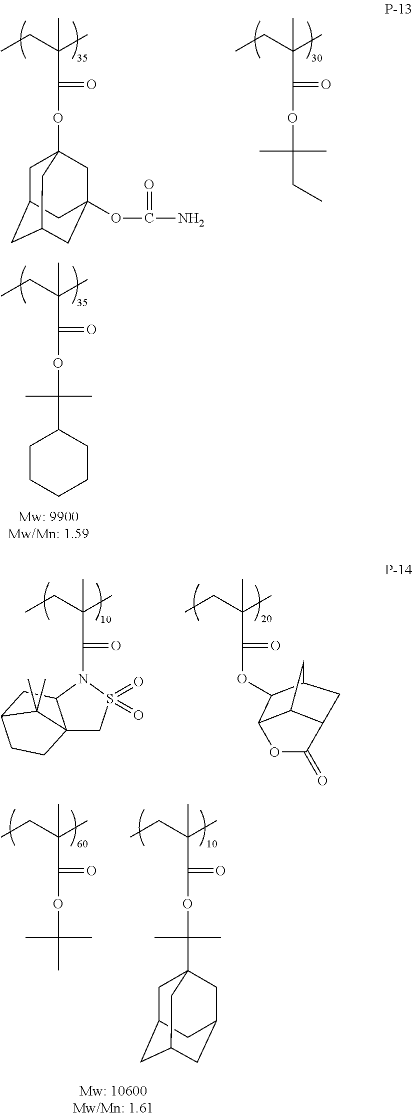

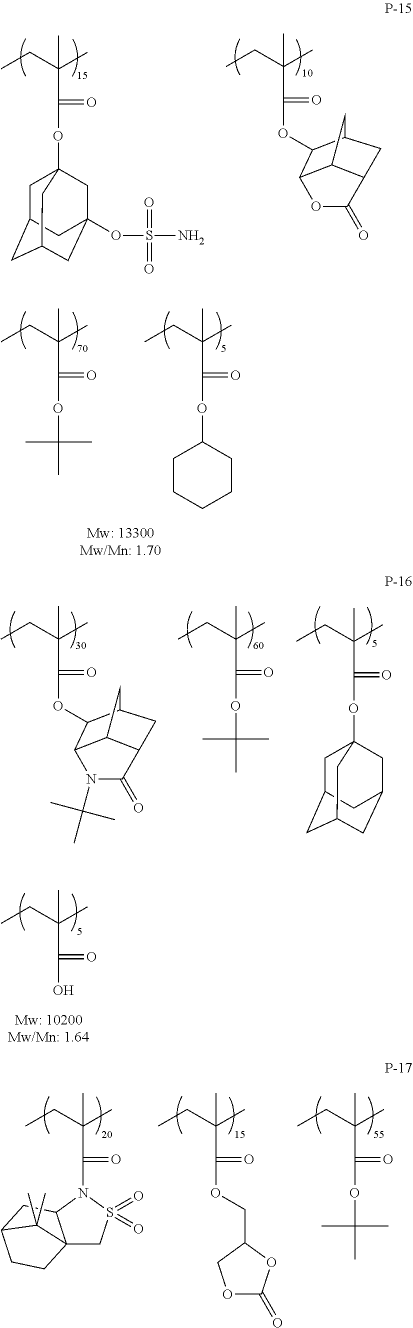

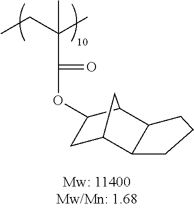

<Acid Generator>

The following compounds were used as the acid generator.

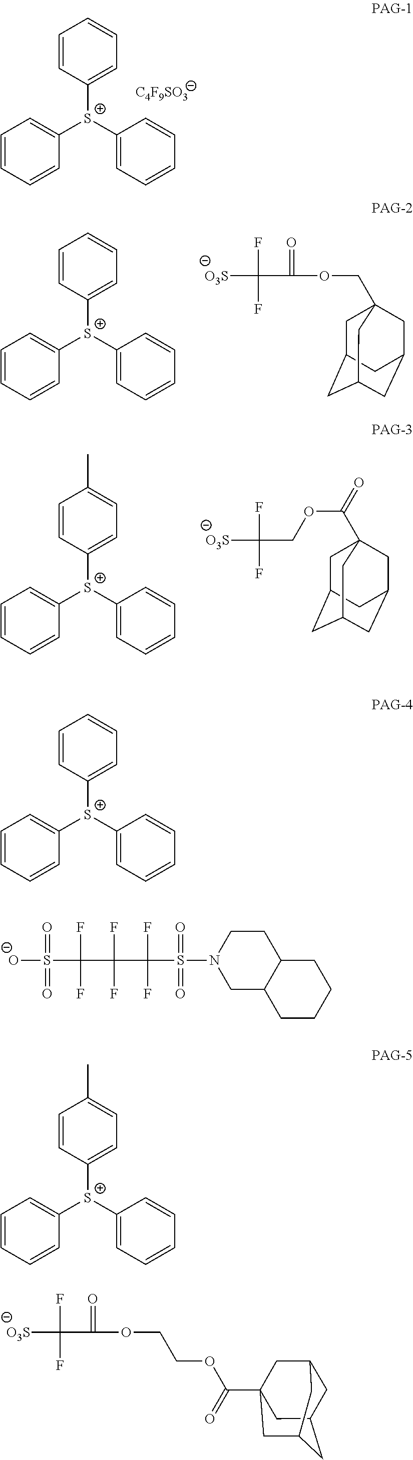

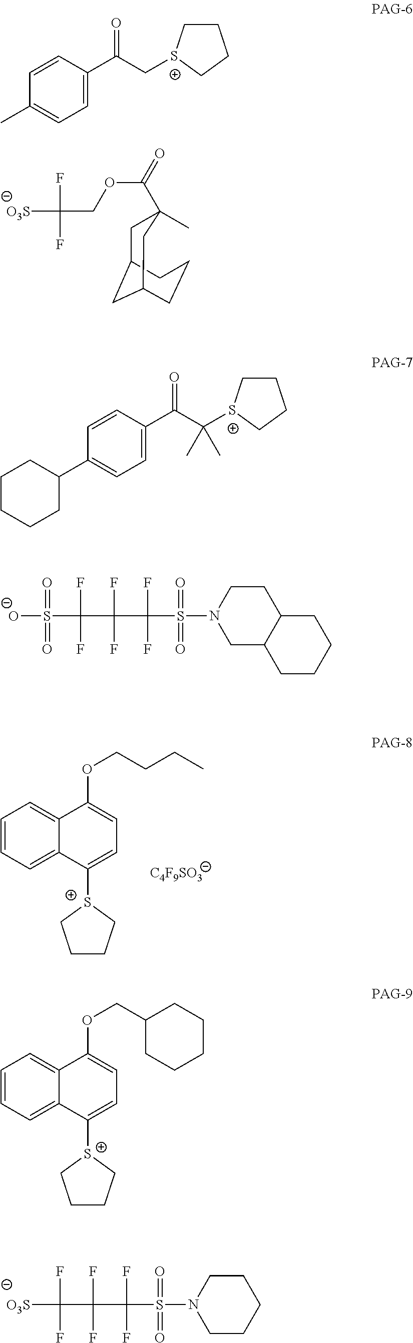

<Basic Compound (N) Whose Basicity Decreases Upon Irradiation of Actinic Ray or Radiation, and Basic Compound (N′)>

The following compounds were used as the basic compound whose basicity decreases upon irradiation of an actinic ray or radiation, or the basic compound.

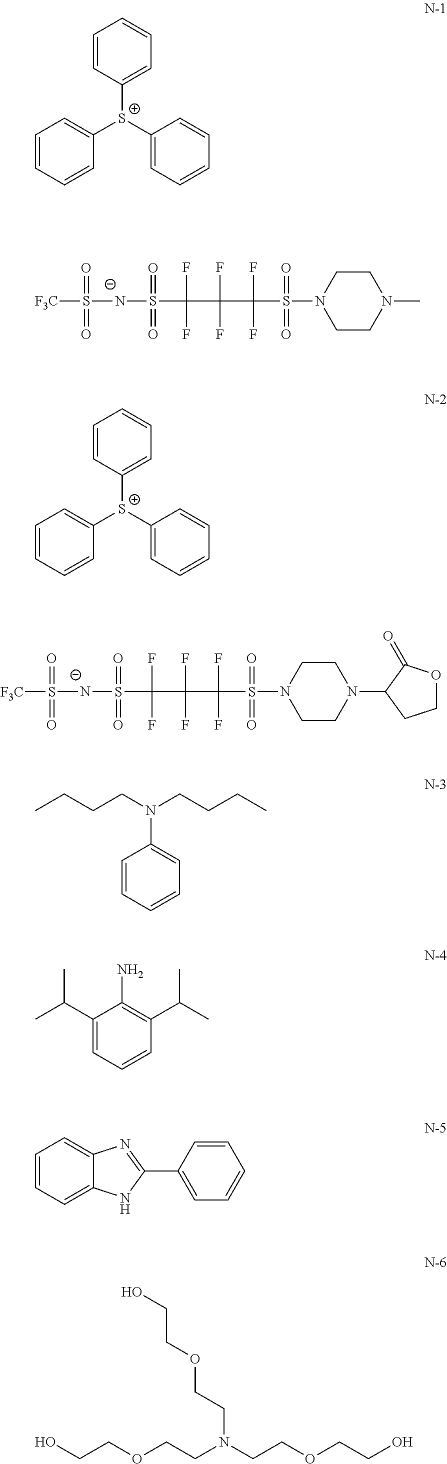

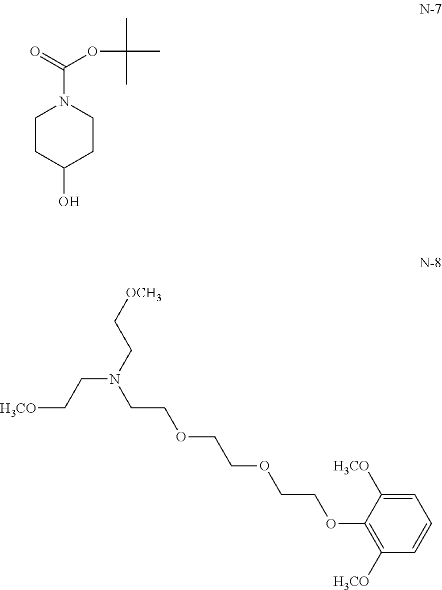 [SMILES: CC(C)(C)OC(=O)N1CCC(O)CC1 ; COCCN(CCOC)CCOCCOCCOc1c(OC)cccc1OC]

<Hydrophobic Resin (D)>

As the hydrophobic resin, Resins (HR-1) to (HR-84) previously exemplified were appropriately selected and used.

<Surfactant>

The followings were used as the surfactant.

W-1: Megafac F176 (manufactured by DIC Corporation; fluorine-based)

W-2: Megafac R08 (manufactured by DIC Corporation; fluorine- and silicone-based)

W-3: Polysiloxane Polymer KP-341 (manufactured by Shin-Etsu Chemical Co., Ltd.; silicone-based)

W-4: Troysol S-366 (manufactured by Troy Chemical Corp.)

W-5: KH-20 (manufactured by Asahi Glass Co., Ltd.)

W-6: PolyFox PF-6320 (manufactured by OMNOVA Solutions Inc.; fluorine-based)

<Solvent>

The followings were used as the solvent. (Group a)

SL-1: Propylene glycol monomethyl ether acetate (PGMEA)

SL-2: Propylene glycol monomethyl ether propionate

SL-3: 2-Heptanone (Group b)

SL-4: Ethyl lactate

SL-5: Propylene glycol monomethyl ether (PGME)

SL-6: Cyclohexanone (Group c)

SL-7: γ-butyrolactone

SL-8: Propylene carbonate

<Developer>

The followings were used as the developer.

SG-1: Butyl acetate

SG-2: Methyl amyl ketone

SG-3: Ethyl-3-ethoxypropionate

SG-4: Pentyl acetate

SG-5: Isopentyl acetate

SG-6: Propylene glycol monomethyl ether acetate (PGMEA)

SG-7: Cyclohexanone

<Rinsing liquid>

The followings were used as the rinsing liquid.

SR-1: 4-methyl-2-pentanol

SR-2: 1-hexanol

SR-3: Butyl acetate

SR-4: Methyl amyl ketone

SR-5: Ethyl-3-ethoxypropionate

### Examples 1 to 34 and Comparative Examples 1 to 4

### Preparation of Resist

The components shown in the following Table 1 were dissolved in the solvent shown in the same Table to have a total solid content of 3.8% by mass, and each was filtered through a polyethylene filter having a pore size of 0.03 μm to prepare an actinic ray-sensitive or radiation-sensitive resin composition (resist composition). An organic antireflection film ARC29SR (manufactured by Nissan Chemical Industries, Ltd.) was applied on a silicon wafer and baked at 205° C. for 60 seconds to form an antireflection film having a film thickness of 95 nm. The actinic ray-sensitive or radiation-sensitive resin composition was applied thereon and baked (PB: prebake) at 100° C. over 60 seconds to form a resist film having a film thickness of 100 nm.

The obtained wafer was subjected to pattern exposure by using an ArF excimer laser liquid immersion scanner (manufactured by ASML Co., Ltd.; XT1700i, NA 1.20, C-Quad, outer sigma 0.900, inner sigma 0.812, XY deflection) through a halftone mask having a square arrangement in which a pitch between holes was 90 nm while having holes with a hole size of 60 nm as a light shielding portion (that is, portions other than holes were composed of light transmitting portions). As the liquid for liquid immersion, ultrapure water was used. Thereafter, heating (PEB: Post Exposure Bake) was performed at 105° C. for 60 seconds. Subsequently, the wafer was developed by performing puddling using the developer described in the following Table 1 for 30 seconds, and then rinsed by performing puddling using the rinsing liquid described in the following Table 1 for 30 seconds (however, in Example 27, rinsing was not performed). Subsequently, a contact hole pattern of 45 nm was obtained by spinning the wafer at a rotational speed of 4,000 rpm for 30 seconds.

However, with respect to Comparative Examples 1 to 4, a pattern was formed by subjecting the wafer to pattern exposure through a halftone mask having a square arrangement in which a pitch between holes was 90 nm while having holes with a hole size of 60 nm as a light transmitting portion (that is, portions other than holes were composed of light shielding portions), and using 2.38% by mass of a tetramethylammonium hydroxide (TMAH) aqueous solution as the developer and pure water as the linsing liquid.

[Exposure Latitude (EL, %)]

A hole size was observed by a critical dimension scanning electron microscope (SEM) (manufactured by Hitachi, Ltd., S-9380 II), and an optimal exposure amount at the time of resolving a contact hole pattern having a hole size of 45 nm was defined as the sensitivity (Eₒₚₜ)(mJ/cm²). An exposure amount was obtained when the obtained optimal exposure amount (Eₒₚₜ) was used as a reference and subsequently, the hole size became 45 nm±10% (that is, 40.5 nm and 49.5 nm) which was a target value. Moreover, an exposure latitude (EL, %) defined as the following equation was calculated. The larger EL value, the smaller the change in performance due to change in exposure amount, indicating that EL was good.

[EL(%)]=[(exposure amount when the hole size was 40.5 nm)−(exposure amount when the hole size was 49.5 nm)]/Eₒₚₜ×100

[Uniformity of Local Pattern Dimension (Local CDU, Nm)]

Within one shot exposed as the optimal exposure amount in the exposure latitude evaluation, in twenty sites having an interval of 1 μm therebetween, hole sizes at arbitrary 25 points in each site, that is, 500 points in total were measured and a standard deviation thereof was obtained to calculate 3σ. The smaller the value, the smaller the variation in dimension was, indicating that the performance was good.

The evaluation results are shown in the following Table 1.

TABLE 6

| | | | | | | | Basic | | Hydrophobic | |
|---|---|---|---|---|---|---|---|---|---|---|
| | | | Compound | | Compoud | | Compound | | Resin | |
| Example | Resin | (g) | (B) | (g) | (N) | (g) | (N′) | (g) | (D) | (g) |
| Ex. 1 | P-1 | 10 | PAG-2 | 1.24 | None | — | N-5 | 0.15 | HR-24 | 0.06 |
| Ex. 2 | P-1 | 10 | PAG-3/PAG-6 | 0.6/0.6 | None | — | N-3 | 0.14 | HR-24 | 0.06 |
| Ex. 3 | P-2 | 10 | PAG-4 | 1.19 | None | — | N-6 | 0.14 | HR-24 | 0.06 |
| Ex. 4 | P-2 | 10 | PAG-2/PAG-7 | 0.5/0.7 | None | — | N-5 | 0.14 | HR-3 | 0.06 |
| Ex. 5 | P-3 | 10 | PAG-3 | 1.26 | None | — | N-8 | 0.15 | HR-47 | 0.06 |
| Ex. 6 | P-3 | 10 | PAG-2/PAG-9 | 0.6/0.7 | N-1 | 0.70 | None | — | HR-24 | 0.06 |
| Ex. 7 | P-4 | 10 | PAG-5 | 1.28 | None | — | N-5 | 0.16 | HR-24 | 0.06 |
| Ex. 8 | P-4 | 10 | PAG-1/PAG-8 | 0.5/0.7 | None | — | N-7 | 0.15 | HR-24 | 0.06 |
| Ex. 9 | P-5 | 10 | PAG-2 | 1.31 | None | — | N-4 | 0.16 | HR-9 | 0.06 |
| Ex. 10 | P-5 | 10 | PAG-3/PAG-7 | 0.5/0.7 | None | — | N-5 | 0.15 | HR-24 | 0.06 |
| Ex. 11 | P-6 | 10 | PAG-3 | 1.16 | None | — | N-3 | 0.14 | HR-26 | 0.06 |
| Ex. 12 | P-6 | 10 | PAG-2/PAG-9 | 0.4/0.8 | None | — | N-5 | 0.14 | HR-47 | 0.06 |
| Ex. 13 | P-7 | 10 | PAG-2 | 1.20 | None | — | N-5 | 0.15 | HR-24/HR-79 | 0.04/0.02 |
| Ex. 14 | P-7 | 10 | PAG-3/PAG-6 | 0.5/0.7 | N-2 | 0.54 | None | — | HR-24 | 0.06 |
| Ex. 15 | P-8 | 10 | PAG-2 | 1.25 | None | — | N-4 | 0.15 | HR-24 | 0.06 |
| Ex. 16 | P-8 | 10 | PAG-4/PAG-7 | 0.5/0.7 | None | — | N-3 | 0.14 | HR-3 | 0.06 |
| Ex. 17 | P-9 | 10 | PAG-4 | 1.17 | None | — | N-5 | 0.14 | HR-47 | 0.06 |
| Ex. 18 | P-9 | 10 | PAG-3/PAG-6 | 0.6/0.7 | None | — | N-8 | 0.13 | HR-24 | 0.06 |
| Ex. 19 | P-10 | 10 | PAG-3 | 1.19 | None | — | N-4 | 0.14 | HR-26 | 0.06 |
| Ex. 20 | P-10 | 10 | PAG-2/PAG-9 | 0.4/0.8 | None | — | N-5 | 0.14 | HR-47 | 0.06 |
| Ex. 21 | P-11 | 10 | PAG-2 | 1.24 | None | — | N-5 | 0.15 | HR-24 | 0.06 |
| Ex. 22 | P-11 | 10 | PAG-4/PAG-7 | 0.6/0.7 | N-1 | 0.62 | N-4 | 0.03 | HR-9 | 0.06 |
| Ex. 23 | P-12 | 10 | PAG-4 | 1.29 | None | — | N-3 | 0.15 | HR-24 | 0.06 |
| Ex. 24 | P-12 | 10 | PAG-3/PAG-6 | 0.5/0.7 | None | — | N-5/N-7 | 0.07/0.07 | HR-24 | 0.06 |
| Ex. 25 | P-13 | 10 | PAG-3 | 1.30 | None | — | N-5 | 0.16 | HR-47 | 0.06 |
| Ex. 26 | P-13 | 10 | PAG-2/PAG-8 | 0.6/0.7 | None | — | N-6 | 0.15 | HR-3 | 0.06 |
| Ex. 27 | P-14 | 10 | PAG-5 | 1.24 | None | — | N-8 | 0.15 | HR-24 | 0.06 |
| Ex. 28 | P-14 | 10 | PAG-4/PAG-7 | 0.4/0.8 | None | — | N-5 | 0.16 | HR-47 | 0.06 |
| Ex. 29 | P-15 | 10 | PAG-2 | 1.26 | None | — | N-3 | 0.15 | HR-24 | 0.06 |
| Ex. 30 | P-15 | 10 | PAG-4/PAG-8 | 0.6/0.7 | N-2 | 0.64 | None | — | HR-24 | 0.06 |
| Ex. 31 | P-16 | 10 | PAG-2 | 1.30 | None | — | N-7 | 0.16 | HR-47 | 0.06 |
| Ex. 32 | P-16 | 10 | PAG-2/PAG-9 | 0.5/0.7 | None | — | N-5 | 0.15 | HR-24 | 0.06 |
| Ex. 33 | P-17 | 10 | PAG-4 | 1.33 | None | — | N-4 | 0.16 | HR-26 | 0.06 |
| Ex. 34 | P-17 | 10 | PAG-5/PAG-6 | 0.4/0.8 | None | — | N-3 | 0.15 | HR-47 | 0.06 |
| Comp. Ex. 1 | P-1 | 10 | PAG-2 | 1.24 | None | — | N-5 | 0.15 | HR-24 | 0.06 |
| Comp. Ex. 2 | P-2 | 10 | PAG-4 | 1.19 | None | — | N-6 | 0.14 | HR-24 | 0.06 |
| Comp. Ex. 3 | P-6 | 10 | PAG-3 | 1.16 | None | — | N-3 | 0.14 | HR-26 | 0.06 |
| Comp. Ex. 4 | P-6 | 10 | PAG-2/PAG-9 | 0.4/0.8 | None | — | N-5 | 0.14 | HR-47 | 0.06 |

| | | | | | | | | | | Local |
|---|---|---|---|---|---|---|---|---|---|---|
| | | Mass | | | | Mass | Rinsing | Mass | EL | CDU |
| Example | Solvent | ratio | Surfactant | (g) | Developer | ratio | liquid | ratio | (%) | (nm) |
| Ex. 1 | SL-1/SL-5 | 60/40 | W-1 | 0.003 | SG-1 | 100 | SR-1 | 100 | 19.5 | 6.3 |
| Ex. 2 | SL-1/SL-3 | 80/20 | W-3 | 0.003 | SG-1/SG-4 | 50/50 | SR-1 | 100 | 19.7 | 5.7 |
| Ex. 3 | SL-1/SL-5 | 60/40 | W-1 | 0.003 | SG-1 | 100 | SR-1 | 100 | 19.2 | 6.0 |
| Ex. 4 | SL-1/SL-5 | 70/30 | W-3 | 0.001 | SG-1 | 100 | SR-1 | 100 | 20.3 | 5.4 |
| Ex. 5 | SL-1/SL-5 | 60/40 | None | — | SG-1 | 100 | SR-1 | 100 | 19.4 | 5.9 |
| Ex. 6 | SL-1 | 100 | W-1 | 0.003 | SG-1 | 100 | SR-1 | 100 | 20.1 | 5.2 |
| Ex. 7 | SL-1/SL-5 | 60/40 | W-6 | 0.003 | SG-1 | 100 | SR-1 | 100 | 19.2 | 6.1 |
| Ex. 8 | SL-1/SL-5 | 80/20 | W-1 | 0.003 | SG-1 | 100 | SR-1 | 100 | 13.8 | 5.6 |
| Ex. 9 | SL-1/SL-5 | 60/40 | None | — | SG-1/SG-7 | 90/10 | SR-1 | 100 | 19.4 | 5.9 |
| Ex. 10 | SL-1/SL-5 | 80/20 | W-1 | 0.003 | SG-1 | 100 | SR-2 | 100 | 19.9 | 5.3 |
| Ex. 11 | SL-1/SL-5 | 60/40 | W-4 | 0.003 | SG-1 | 100 | SR-1 | 100 | 19.3 | 4.7 |
| Ex. 12 | SL-1/SL-4 | 90/10 | W-4 | 0.003 | SG-1 | 100 | SR-1 | 100 | 20.2 | 4.3 |
| Ex. 13 | SL-1/SL-2 | 60/40 | W-1 | 0.003 | SG-1 | 100 | SR-1 | 100 | 19.4 | 4.7 |
| Ex. 14 | SL-1/SL-7 | 70/30 | W-2 | 0.003 | SG-1/SG-3 | 90/10 | SR-1 | 100 | 20.4 | 4.2 |
| Ex. 15 | SL-1/SL-5 | 60/40 | W-5 | 0.003 | SG-1 | 100 | SR-1 | 100 | 19.7 | 4.6 |
| Ex. 16 | SL-1/SL-5 | 70/30 | W-2 | 0.003 | SG-2 | 100 | SR-1 | 100 | 20.4 | 4.2 |
| Ex. 17 | SL-1/SL-5 | 60/40 | W-1 | 0.003 | SG-1 | 100 | SR-1 | 100 | 19.6 | 4.6 |
| Ex. 18 | SL-1/SL-5 | 70/30 | W-6 | 0.003 | SG-1 | 100 | SR-1/SR-3 | 90/10 | 20.5 | 4.1 |
| Ex. 19 | SL-1/SL-5 | 60/40 | W-3 | 0.003 | SG-1 | 100 | SR-1 | 100 | 19.4 | 4.7 |
| Ex. 20 | SL-5/SL-6 | 30/70 | W-1 | 0.003 | SG-1 | 100 | SR-1 | 100 | 20.3 | 4.4 |
| Ex. 21 | SL-1/SL-5 | 60/40 | W-2 | 0.003 | SG-1 | 100 | SR-1 | 100 | 19.6 | 4.6 |
| Ex. 22 | SL-1/SL-5 | 80/20 | W-1 | 0.003 | SG-1/SG-2 | 80/20 | SR-1/SR-5 | 90/10 | 20.6 | 4.2 |
| Ex. 23 | SL-1/SL-5 | 60/40 | W-1/W-6 | 0.002/0.001 | SG-1 | 100 | SR-1 | 100 | 19.9 | 4.8 |
| Ex. 24 | SL-1 | 100 | W-1 | 0.003 | SG-1 | 100 | SR-1 | 100 | 20.2 | 4.1 |
| Ex. 25 | SL-1/SL-5 | 60/40 | W-1 | 0.003 | SG-1 | 100 | SR-1 | 100 | 19.8 | 4.7 |
| Ex. 26 | SL-6/SL-5 | 60/40 | W-2 | 0.003 | SG-1/SG-6 | 90/10 | SR-1 | 100 | 17.5 | 4.2 |
| Ex. 27 | SL-1/SL-5 | 60/40 | None | — | SG-1 | 100 | None | — | 19.4 | 4.8 |
| Ex. 28 | SL-1/SL-5 | 80/20 | W-1 | 0.003 | SG-4 | 100 | SR-1 | 100 | 20.5 | 4.3 |
| Ex. 29 | SL-1/SL-5 | 60/40 | None | — | SG-1 | 100 | SR-1 | 100 | 19.2 | 4.4 |
| Ex. 30 | SL-1 | 100 | W-1 | 0.003 | SG-1 | 100 | SR-1 | 100 | 18.2 | 4.1 |
| Ex. 31 | SL-1/SL-5 | 60/40 | W-5 | 0.003 | SG-1 | 100 | SR-1 | 100 | 19.6 | 4.6 |
| Ex. 32 | SL-1/SL-5 | 70/30 | W-6 | 0.003 | SG-5 | 100 | SR-1 | 100 | 20.1 | 4.2 |
| Ex. 33 | SL-1/SL-5 | 60/40 | W-4 | 0.003 | SG-1 | 100 | SR-1 | 100 | 19.6 | 5.0 |
| Ex. 34 | SL-1/SL-8 | 90/10 | W-5 | 0.003 | SG-1 | 100 | SR-1/SR-4 | 80/20 | 20.3 | 4.5 |

| | | | | | | |
|---|---|---|---|---|---|---|
| Comp. Ex. 1 | SL-1/SL-5 | 60/40 | W-1 | 0.003 | Alkali development was performed | Images could not be formed |
| Comp. Ex. 2 | SL-1/SL-5 | 60/40 | W-1 | 0.003 | Alkali development was performed | Images could not be formed |
| Comp. Ex. 3 | SL-1/SL-5 | 60/40 | W-4 | 0.003 | Alkali development was performed | Images could not be formed |
| Comp. Ex. 4 | SL-1/SL-4 | 90/10 | W-4 | 0.003 | Alkali development was performed | Images could not be formed |

As clear from the results shown in Table 1, a desired contact hole pattern could not be formed in Comparative Examples 1 to 4 in which a positive-type image forming method by an alkali developer was used.

In contrast, according to Examples 1 to 34 which simultanesouly used the resist composition of the present invention, and a negative-type image forming method by an organic-based developer, it could be known that the exposure latitude (EL) was small and the local CDU was large.

In particular, in Examples 11 to 34 which used resins having the repeating unit represented by Formula (III′), it could be known that the local CDU became smaller

In addition, in Examples 2, 4, 6, 8, 10, 12, 14, 16, 18, 20, 22, 24, 26, 28, 30, 32 and 34 which used the compound represented by Formula (ZI-2), (ZI-3) or (ZI-4) as the acid generator, it could be known that the local CDU became smaller.

### INDUSTRIAL APPLICABILITY

According to the present invention, it is possible is to provide a pattern forming method having excellent exposure latitude and uniformity of a local pattern dimension, an actinic ray-sensitive or radiation-sensitive resin composition used therefor, a resist film, a method of manufacturing an electronic device, and an electronic device.

Although the present invention has been described with reference to detailed and specific aspects, it is obvious to those skilled in the art that various changes or modifications can be made without departing from the spirit and scope of the present invention.

The present application is based on Japanese Patent Application (Patent Application No. 2012-146001) filed on Jun. 28, 2012, the content of which is incorporated herein by reference.

1. A pattern forming method comprising:
(i) forming a film by an actinic ray-sensitive or radiation-sensitive resin composition containing a resin (P) having a repeating unit (a) having a cyclic structure and a partial structure represented by Formula (I), (II-1) or (II-2), and a repeating unit (b) having a group which decomposes by the action of an acid to generate a polar group and a compound (B) which generates acid upon irradiation with an actinic ray or radiation,
(ii) exposing the film, and
(iii) forming a negative pattern by performing development using a developer containing an organic solvent: 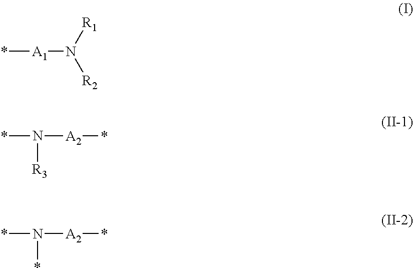
wherein, in the formulas, each of A₁ and A₂ independently represents —CO— or —SO₂—,
each of R₁ and R₂ independently represents a hydrogen atom or an alkyl group, and R₁ and R₂ optionally combine with each other to form a ring,
R₃ represents a hydrogen atom or an alkyl group, and
* represents a bonding hand, provided that two bonding hands of the partial structure of Formula (II-1) are directly or indirectly bonded to a ring of the cyclic structure, and two or more of the three bonding hands of the partial structure of Formula (II-2) are directly or indirectly bonded to the ring of the cyclic structure.

2. The pattern forming method according to claim 1,
wherein the resin (P) is a resin having a repeating unit represented by Formula (III′) as the repeating unit (b): 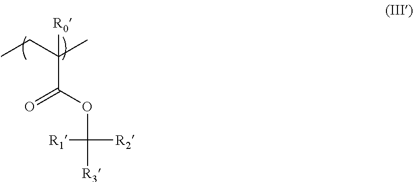
wherein in the formula, R₀′ represents a hydrogen atom or an alkyl group,
each of R₁′, R₂′ and R₃′ independently represents a straight chained or branched alkyl group.

3. The pattern forming method according to claim 1,
wherein the resin (P) contains 55 mol % or more of the repeating unit (b) based on all repeating units of the resin (P).

4. The pattern forming method according to claim 1,
wherein the actinic ray-sensitive or radiation-sensitive resin composition contains a compound represented by Formula (ZI-2), (ZI-3) or (ZI-4) as the compound (B): 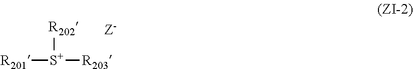
wherein in Formula (ZI-2),
each of R₂₀₁′ to R₂₀₃′ independently represents an organic group having no aromatic ring, and
Z⁻ represents a non-nucleophilic anion: 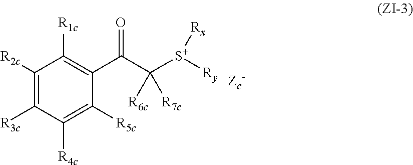
wherein in Formula (ZI-3),
each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group,
each of R_{6c} and R_{7c} independently represents a hydrogen atom, an alkyl group, a cycloalkyl group, a halogen atom, a cyano group or an aryl group,
each of Rₓ and R_{y} independently represents an alkyl group, a cycloalkyl group, a 2-oxoalkyl group, a 2-oxocycloalkyl group, an alkoxycarbonylalkyl group, an allyl group or a vinyl group,
any two or more of R_{1c} to R_{5c}, R_{5c} and R_{6c}, R_{6c} and R_{7c}, R_{5c} and Rₓ, and Rₓ and R_{y} optionally combine with each other to form a ring structure, respectively, and
Z⁻ represents a non-nucleophilic anion: 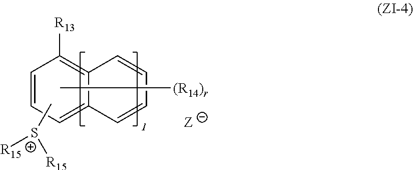
wherein in Formula (ZI-4),
R₁₃ represents a hydrogen atom, a fluorine atom, a hydroxyl group, an alkyl group, a cycloalkyl group, an alkoxy group, an alkoxycarbonyl group or a group having a cycloalkyl group,
each R₁₄ independently represents, when a plurality of R₁₄ is present, a hydroxyl group, an alkyl group, a cycloalkyl group, an alkoxy group, an alkoxycarbonyl group, an alkylcarbonyl group, an alkylsulfonyl group, a cycloalkylsulfonyl group or a group having a cycloalkyl group,
each R₁₅ independently represents an alkyl group, a cycloalkyl group or a naphthyl group, and two of R₁₅ optionally combine with each other to form a ring,
l represents an integer of 0 to 2,
r represents an integer of 0 to 8, and
Z⁻ represents a non-nucleophilic anion.

5. The pattern forming method according to claim 1,
wherein the repeating unit (a) is a repeating unit represented by Formula (V) or (VI): 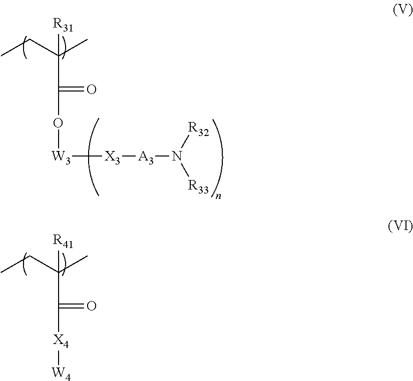
wherein in Formula (V), each of R₃₁, R₃₂ and R₃₃ independently represents a hydrogen atom or an alkyl group, and R₃₂ and R₃₃ optionally combine with each other to form a ring,
W₃ represents a (n+1)-valent alicyclic group which optionally includes an oxygen atom as a ring member,
X₃ represents a single bond, —O— or —NR₃₄—,
R₃₄ represents a hydrogen atom or an alkyl group,
A₃ represents —CO— or —SO₂—, and
n represents 1 or 2,
wherein in Formula (VI), R₄₁ represents a hydrogen atom or an alkyl group,
X₄ represents a single bond or —O—, and
W₄ represents an alicyclic group which optionally includes an oxygen atom as a ring member, and which is directly or indirectly bonded to two bonding hands of a partial structure represented by Formula (VII-1) or two or more of the three bonding hands of a partial structure represented by Formula (VII-2): 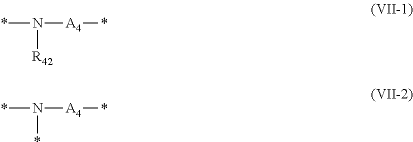
wherein A₄ represents —CO— or —SO₂—,
R₄₂ represents a hydrogen atom or an alkyl group, and
* represents a bonding hand.

6. The pattern forming method according to claim 1,
wherein the resin (P) is a resin having at least any one of the following repeating units as the repeating unit (a): 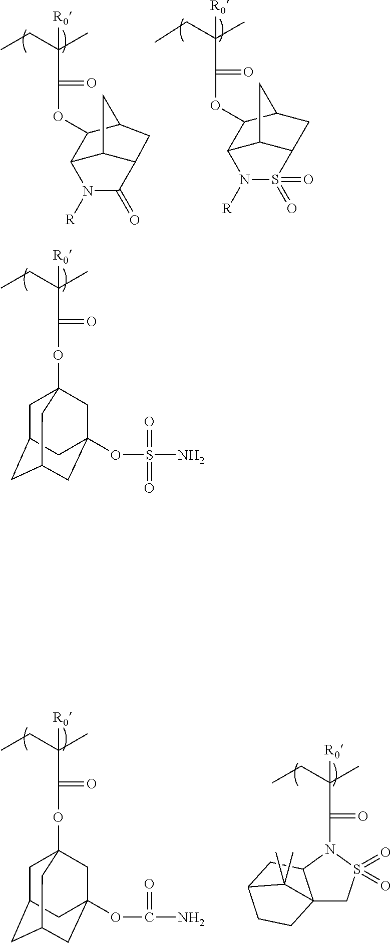
wherein R₀′ represents a hydrogen atom or an alkyl group, and
R represents a hydrogen atom or an alkyl group.

7. The pattern forming method according to claim 1,
wherein the actinic ray-sensitive or radiation-sensitive resin composition further contains a basic compound or an ammonium salt compound (N) whose basicity decreases upon irradiation with an actinic ray or radiation.

8. The pattern forming method according to claim 1,
wherein the actinic ray-sensitive or radiation-sensitive resin composition further contains a hydrophobic resin.

9. The pattern forming method according to claim 1,
wherein the developer is a developer containing at least one organic solvent selected from the group consisting of a ketone-based solvent, an ester-based solvent, an alcohol-based solvent, an amide-based solvent, and an ether-based solvent.

10. The pattern forming method according to claim 1, further comprising:
(d) performing rinsing using a rinsing liquid containing an organic solvent.

11. An actinic ray-sensitive or radiation-sensitive resin composition, comprising:
a resin (P) having a repeating unit (a) having a cyclic structure and a partial structure represented by Formula (I), (II-1) or (II-2), and a repeating unit (b) having a group which decomposes by the action of an acid to generate a polar group; and
a compound (B) which generates acid upon irradiation with an actinic ray or radiation: 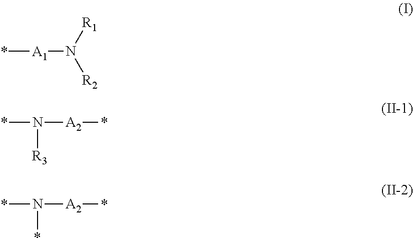
wherein, in the formulas, each of A₁ and A₂ independently represents —CO— or —SO₂—,
each of R₁ and R₂ independently represents a hydrogen atom or an alkyl group, and R₁ and R₂ optionally combine with each other to form a ring,
R₃ represents a hydrogen atom or an alkyl group, and
* represents a bonding hand, provided that two bonding hands of the partial structure of Formula (II-1) are directly or indirectly bonded to a ring of the cyclic structure, and two or more of the three bonding hands of the partial structure of Formula (II-2) are directly or indirectly bonded to the ring of the cyclic structure.

12. The actinic ray-sensitive or radiation-sensitive resin composition according to claim 11,
wherein the resin (P) is a resin having a repeating unit represented by Formula (III′) as the repeating unit (b): 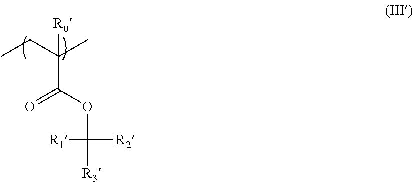
wherein in the formula, R₀′ represents a hydrogen atom or an alkyl group,
each of R₁′, R₂′ and R₃′ independently represents a straight chained or branched alkyl group.

13. The actinic ray-sensitive or radiation-sensitive resin composition according to claim 11,
wherein the resin (P) contains 55 mol % or more of the repeating unit (b) based on all repeating units of the resin (P).

14. The actinic ray-sensitive or radiation-sensitive resin composition according to claim 11,
wherein the repeating unit (a) is a repeating unit represented by Formula (V) or (VI): 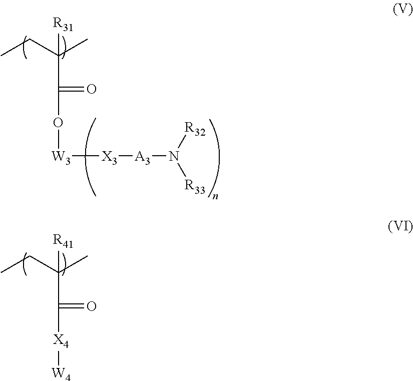
wherein in Formula (V), each of R₃₁, R₃₂ and R₃₃ independently represents a hydrogen atom or an alkyl group, and R₃₂ and R₃₃ optionally combine with each other to form a ring,
W₃ represents a (n+1)-valent alicyclic group which optionally includes an oxygen atom as a ring member,
X₃ represents a single bond, —O— or —NR₃₄—,
R₃₄ represents a hydrogen atom or an alkyl group,
A₃ represents —CO— or —SO₂—, and
n represents 1 or 2,
wherein in Formula (VI), R₄₁ represents a hydrogen atom or an alkyl group,
X₄ represents a single bond or —O—, and
W₄ represents an alicyclic group which optionally includes an oxygen atom as a ring member, and which is directly or indirectly bonded to two bonding hands of a partial structure represented by Formula (VII-1) or two or more of the three bonding hands of a partial structure represented by Formula (VII-2): 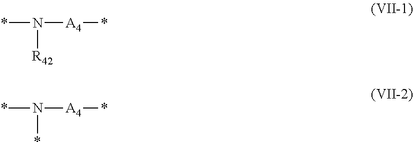
wherein A₄ represents —CO— or —SO₂—,
R₄₂ represents a hydrogen atom or an alkyl group, and
* represents a bonding hand.

15. The actinic ray-sensitive or radiation-sensitive resin composition according to claim 11,
wherein the resin (P) is a resin having at least any one of the following repeating units as the repeating unit (a): 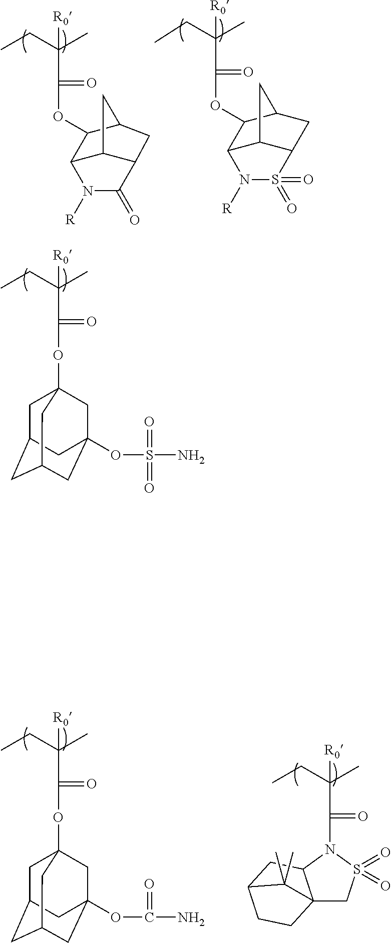
wherein R₀′ represents a hydrogen atom or an alkyl group, and
R represents a hydrogen atom or an alkyl group.

16. The actinic ray-sensitive or radiation-sensitive resin composition according to claim 11,
wherein the actinic ray-sensitive or radiation-sensitive resin composition further contains a basic compound or an ammonium salt compound (N) whose basicity decreases upon irradiation with an actinic ray or radiation.

17. The actinic ray-sensitive or radiation-sensitive resin composition according to claim 11,
wherein the actinic ray-sensitive or radiation-sensitive resin composition further contains a hydrophobic resin.

18. A resist film formed from the actinic ray-sensitive or radiation-sensitive resin composition of claim 11.

19. A method of manufacturing an electronic device, comprising the pattern forming method according to claim 1.

20. An electronic device manufactured from the method of manufacturing an electronic device according to claim 19.
